(19) United States
(12) Patent Application Publication
(10) Pub. No.: US 2025/0287772 A1
(43) Pub. Date: Sep. 11, 2025

(54) ORGANIC LIGHT EMITTING ELEMENT AND VARIOUS DEVICES USING THE SAME

(71) Applicant: CANON KABUSHIKI KAISHA, Tokyo (JP)

(72) Inventors: MASAHITO MIYABE, Kanagawa (JP); HITOSHI NAGASHIMA, Kanagawa (JP); YOSUKE NISHIDE, Kanagawa (JP); SATORU SHIOBARA, Kanagawa (JP); NAOKI YAMADA, Tokyo (JP)

(21) Appl. No.: 19/070,227

(22) Filed: Mar. 4, 2025

(30) Foreign Application Priority Data
Mar. 6, 2024 (JP) 2024-033850

(51) Int. Cl. H10K 50/11; C09K 11/06; H10K 50/19; H10K 85/60; H10K 101/40

(52) U.S. Cl. CPC H10K 50/11; C09K 11/06; H10K 50/19; H10K 85/622; H10K 85/626; H10K 85/6572; H10K 85/6574; H10K 85/6576; C09K 2211/1007; C09K 2211/1011; C09K 2211/1018; H10K 2101/40

(57) ABSTRACT

An organic light emitting element includes a first electrode, a first light emitting unit, a charge generation layer, a second light emitting unit, and a second electrode that are arranged in this order. The second light emitting unit includes a first light emitting layer. The first light emitting unit includes a first organic layer, a second light emitting layer, and a second organic layer arranged in this order of proximity to the first electrode. The first light emitting layer contains a first compound and a second compound. The first organic layer contains a third compound. The second light emitting layer contains a fourth compound. The second organic layer contains a fifth compound. The first compound and the second compound satisfy relationship LUMO(A)>LUMO(B), where LUMO(A) and LUMO(B) respectively represent lowest unoccupied molecular orbital energy levels of the first compound and the second compound.

### BACKGROUND

### Technical Field

The present disclosure relates to an organic light emitting element and various devices using the same.

### Description of the Related Art

An organic electroluminescence element (hereinafter may also be referred to as an “organic EL element” or an “organic light emitting element”) is an element that emits light when an anode, a cathode, and an organic compound layer that is interposed between these electrodes and includes a light emitting layer are energized.

Recent years have seen development of organic light emitting elements in which light emitting layers that respectively emit red, green, and blue light are stacked in addition to single-layer organic light emitting elements that emit white light by containing light emitting materials that respectively emit red, green, and blue colors in one light emitting layer. Compared with single layer organic light emitting elements, multilayer organic light emitting elements have a tendency to have high drive voltage, and thus a structure that includes an intermediate layer that is called a charge generation layer or an intermediate electrode is known. The intermediate layer is prone to deteriorate compared to other organic layers. Deterioration of the intermediate layer results in high drive voltage, low efficiency, and lower durability, and thus development of stable multilayer organic light emitting elements is desired.

Japanese Patent Laid-Open No. 2022-117963 (PTL 1) and Japanese Patent Laid-Open No. 2023-029747 (PTL 2) disclose multilayer organic light emitting elements that have charge generation layers.

However, the organic light emitting element disclosed in PTL 1 has a structure in which two light emitting layers have a tendency to trap electrons. In contrast, the organic light emitting element disclosed in PTL 2 has a structure in which one of the light emitting layers has a tendency to trap electrons while the other has a tendency to trap holes. As such, the organic light emitting elements disclosed in PTL 1 and PTL 2 do not take into account the relationship between the HOMO energy levels and the LUMO energy levels of the compounds contained in the light emitting layers and neighboring layers, and do not sufficiently take into account the carrier injectability into the light emitting layers. Thus, the organic light emitting elements disclosed in PTL 1 and PTL 2 have room for improvement from the viewpoint of the drive voltage.

### SUMMARY

The present disclosure has been made to address the disadvantages described above and provides an organic light emitting element that exhibits low drive voltage.

An organic light emitting element according to an aspect of the present disclosure includes a first electrode; a first light emitting unit, a charge generation layer, a second light emitting unit, and a second electrode that are arranged in this order, in which the second light emitting unit includes a first light emitting layer, the first light emitting unit includes a first organic layer, a second light emitting layer, and a second organic layer arranged in this order of proximity to the first electrode, the first light emitting layer contains a first compound and a second compound, the first organic layer contains a third compound, the second light emitting layer contains a fourth compound, the second organic layer contains a fifth compound, and the first compound and the second compound satisfy relationship (a):

LUMO(A)>LUMO(B) (a)
where LUMO(A) and LUMO(B) respectively represent a lowest unoccupied molecular orbital (LUMO) energy level of the first compound and a LUMO energy level of the second compound.

Further features of the present disclosure will become apparent from the following description of exemplary embodiments with reference to the attached drawings.

### BRIEF DESCRIPTION OF THE DRAWINGS

FIG. 1A is a schematic cross sectional view of one example of a pixel of a display apparatus according to one embodiment of the present disclosure, and FIG. 1B is a schematic cross sectional view of one example of a display apparatus that uses an organic EL element according to one embodiment of the present disclosure.

FIG. 2 is a schematic diagram illustrating one example of a display apparatus according to one embodiment of the present disclosure.

FIG. 3A is a schematic diagram illustrating one example of an imaging apparatus according to an embodiment of the present disclosure, and FIG. 3B is a schematic diagram illustrating one example of electronic equipment according to one embodiment of the present disclosure.

FIG. 4A is a schematic diagram illustrating one example of a display apparatus according to one embodiment of the present disclosure, and FIG. 4B is a schematic diagram illustrating one example of a foldable display apparatus.

FIG. 5A is a schematic diagram illustrating one example of a lighting apparatus according to one embodiment of the present disclosure, and FIG. 5B is a schematic diagram illustrating one example of an automobile that includes a vehicle lighting unit according to one embodiment of the present disclosure.

FIG. 6A is a schematic diagram illustrating one example of a wearable device according to one embodiment of the present disclosure, and FIG. 6B is a schematic diagram illustrating one example of a wearable device according to one embodiment of the present disclosure equipped with an imaging apparatus.

FIG. 7A is a schematic diagram illustrating one example of an image forming apparatus according to one embodiment of the present disclosure.

FIG. 7B is a schematic diagram illustrating one example of an exposure light source of an image forming apparatus according to one embodiment of the present disclosure, and FIG. 7C is a schematic diagram illustrating one example of an exposure light source of an image forming apparatus according to one embodiment of the present disclosure.

FIG. 8 is a schematic cross sectional view of one example of an organic light emitting element according to one embodiment of the present disclosure.

### DESCRIPTION OF THE EMBODIMENTS

In this description, a halogen atom may be, for example, a fluorine atom, a chlorine atom, a bromine atom, or an iodine atom, but is not limited to this. Among these, a fluorine atom is preferable.

An alkali metal atom may be, for example, a lithium atom, a sodium atom, a potassium atom, a rubidium atom, or a cesium atom, but is not limited to this. Among these, a lithium atom or a cesium atom is preferable.

An alkaline earth metal atom may be, for example, a beryllium atom, a magnesium atom, a calcium atom, or a strontium atom, but is not limited to this.

An alkyl group may have 1 or more and 20 or less carbon atoms. Specific examples thereof include, but are not limited to, a methyl group, an ethyl group, an n-propyl group, an isopropyl group, an n-butyl group, an isobutyl group, a sec-butyl group, a tert-butyl group, an n-pentyl group, an isopentyl group, a tert-pentyl group, a neopentyl group, an n-hexyl group, an octyl group, a cyclohexyl group, a 1-adamantyl group, and a 2-adamantyl group. The alkyl group preferably has 1 or more and 10 or less carbon atoms and more preferably has 1 or more and 6 or less carbon atoms. Specifically, a methyl group or a tert-butyl group is preferable.

An alkoxy group may have 1 or more and 10 or less carbon atoms. Specific examples thereof include, but are not limited to, a methoxy group, an ethoxy group, an n-propoxy group, an isopropoxy group, an n-butoxy group, a tert-butoxy group, a 2-ethyl-octyloxy group, and a benzyloxy group. The alkoxy group preferably has 1 or more and 4 or less carbon atoms. Specifically, a methoxy group is preferable.

An aryl group may have 6 or more and 30 or less carbon atoms. Specific examples thereof include, but are not limited to, a phenyl group, a naphthyl group, a phenanthryl group, an anthryl group, a fluorenyl group, a biphenylenyl group, an acenaphthylenyl group, a chrysenyl group, a pyrenyl group, a triphenylenyl group, a picenyl group, a fluoranthenyl group, a perylenyl group, a naphthacenyl group, a biphenyl group, a ter-phenyl group, a phenylene group, a naphthylene group, a phenanthrenylene group, a biphenyl group, a fluoranthenylene group, a chrysenylene group, and a pyrenylene group.

A heterocyclic group may have 3 or more and 27 or less carbon atoms. Specific examples thereof include, but are not limited to, a thienyl group, a pyrrolyl group, a pyrazinyl group, a pyridyl group, an indolyl group, a quinolyl group, an isoquinolyl group, a naphthyridinyl group, an acridinyl group, a phenanthrolinyl group, a carbazolyl group, a benzo[a]carbazolyl group, a benzo[b]carbazolyl group, a benzo[c]carbazolyl group, a phenazinyl group, a phenoxazinyl group, a phenothiazinyl group, a benzothiophenyl group, a dibenzothiophenyl group, a benzofuranyl group, a dibenzofuranyl group, an oxazolyl group, and an oxadiazolyl group.

Specific examples of a silyl group include, but are not limited to, a trimethylsilyl group and a triphenylsilyl group.

Specific examples of an amino group include, but are not limited to, an N-methylamino group, an N-ethylamino group, an N,N-dimethylamino group, an N,N-diethylamino group, an N-methyl-N-ethylamino group, an N-benzylamino group, an N-methyl-N-benzylamino group, an N,N-dibenzylamino group, an anilino group, an N,N-diphenylamino group, an N,N-dinaphthylamino group, an N,N-difluorenylamino group, an N-phenyl-N-tolylamino group, an N,N-ditolylamino group, an N-methyl-N-phenylamino group, an N,N-dianisolylamino group, an N-mesityl-N-phenylamino group, an N,N-dimesitylamino group, an N-phenyl-N-(4-tert-butylphenyl)amino group, and an N-phenyl-N-(4-trifluoromethylphenyl)amino group. The amino group is preferably an N,N-dimethylamino group or an N,N-diphenylamino group.

The substituents that the aforementioned alkyl, aryl, heterocyclic, silyl, and amino groups may further have are not particularly limited, and the examples thereof include alkyl groups such as a methyl group, an ethyl group, an n-propyl group, an isopropyl group, an n-butyl group, an isobutyl group, a sec-butyl group, a tert-butyl group, an n-pentyl group, an isopentyl group, a tert-pentyl group, a neopentyl group, an n-hexyl group, and a cyclohexyl group; alkoxy groups such as a methoxy group, an ethoxy group, an isopropoxy group, an n-butoxy group, and a tert-butoxy group; substituted amino groups such as an N-methylamino group, an N-ethylamino group, an N,N-dimethylamino group, an N,N-diethylamino group, an N-methyl-N-ethylamino group, an N-benzylamino group, an N-methyl-N-benzylamino group, an N,N-dibenzylamino group, an anilino group, an N,N-diphenylamino group, an N,N-dinaphthylamino group, an N,N-difluorenylamino group, an N-phenyl-N-tolylamino group, an N,N-ditolylamino group, an N-methyl-N-phenylamino group, an N,N-dianisolylamino group, an N-mesityl-N-phenylamino group, an N,N-dimesitylamino group, an N-phenyl-N-(4-tert-butylphenyl)amino group, and an N-phenyl-N-(4-trifluoromethylphenyl)amino group; aryl groups such as a phenyl group, a naphthyl group, a phenanthryl group, an anthryl group, a fluorenyl group, a biphenylenyl group, an acenaphthylenyl group, a chrysenyl group, a pyrenyl group, a triphenylenyl group, a picenyl group, a fluoranthenyl group, a perylenyl group, a naphthacenyl group, a biphenyl group, and a ter-phenyl group; heteroaryl groups such as a thienyl group, a pyrrolyl group, a pyrazinyl group, a pyridyl group, an indolyl group, a quinolyl group, an isoquinolyl group, a naphthyridinyl group, an acridinyl group, a phenanthrolinyl group, a carbazolyl group, a benzo[a]carbazolyl group, a benzo[b]carbazolyl group, a benzo[c]carbazolyl group, a phenazinyl group, a phenoxazinyl group, a phenothiazinyl group, a benzothiophenyl group, a dibenzothiophenyl group, a benzofuranyl group, a dibenzofuranyl group, an oxazolyl group, and an oxadiazolyl group; a cyano group; and a trifluoromethyl group.

A fused polycyclic hydrocarbon skeleton refers to a compound that has a structure in which two or more ring structures are fused and that is composed of a hydrocarbon. Specific examples thereof include a naphthalene skeleton, a phenanthroline skeleton, an anthracene skeleton, a fluorene skeleton, an acenaphthylene skeleton, a chrysene skeleton, a pyrene skeleton, a triphenylene skeleton, a fluoranthene skeleton, a perylene skeleton, a biphenylene skeleton, and a tetracene skeleton. The fused polycyclic hydrocarbon skeleton may further has a substituent such as an alkyl group, an aralkyl group, or an aryl group. Specific examples include a methyl group, an ethyl group, an isobutyl group, a tert-butyl group, a phenyl group, a biphenyl group, a naphthyl group, a ter-phenyl group, a benzyl group, and a phenylethyl group.

A heterocyclic skeleton refers to a structure that has a ring structure containing heteroatoms. Specific examples thereof include a thiophene skeleton, a pyrroline skeleton, a pyrazine skeleton, a pyridine skeleton, an indoline skeleton, a quinoline skeleton, an isoquinoline skeleton, a naphthyridine skeleton, an acridine skeleton, a phenanthroline skeleton, a carbazole skeleton, a benzo[a]carbazole skeleton, a benzo[b]carbazole skeleton, a benzo[c]carbazole skeleton, a phenazine skeleton, a phenoxazine skeleton, a phenothiazine skeleton, a benzothiophene skeleton, a dibenzothiophene skeleton, a benzofuran skeleton, a dibenzofuran skeleton, an oxazoline skeleton, and an oxadiazine skeleton.

HOMO(A), HOMO(B), HOMO(C), HOMO(D), and HOMO(E) respectively represent a HOMO energy level of a first compound, a HOMO energy level of a second compound, a HOMO energy level of a third compound, a HOMO energy level of a fourth compound, and a HOMO energy level of a fifth compound.

LUMO(A), LUMO(B), LUMO(C), LUMO(D), and LUMO(E) respectively represent a LUMO energy level of a first compound, a LUMO energy level of a second compound, a LUMO energy level of a third compound, a LUMO energy level of a fourth compound, and a LUMO energy level of a fifth compound.

HOMO stands for Highest Occupied Molecular Orbital, and LUMO stands for Lowest Unoccupied Molecular Orbital.

In this description, a host material refers to a compound that has the largest mass ratio among the compounds constituting a light emitting layer. A guest (dopant) material refers to a compound that has a mass ratio smaller than that of the host compound among the compounds constituting the light emitting layer and that is responsible for main light emission. Furthermore, an assist material refers to a compound that has a mass ratio smaller than that of the host compound among the compounds constituting the light emitting layer and that assists light emission of the guest compound. Here, the assist compound may also be referred to as a second host compound.

### Organic Light Emitting Element

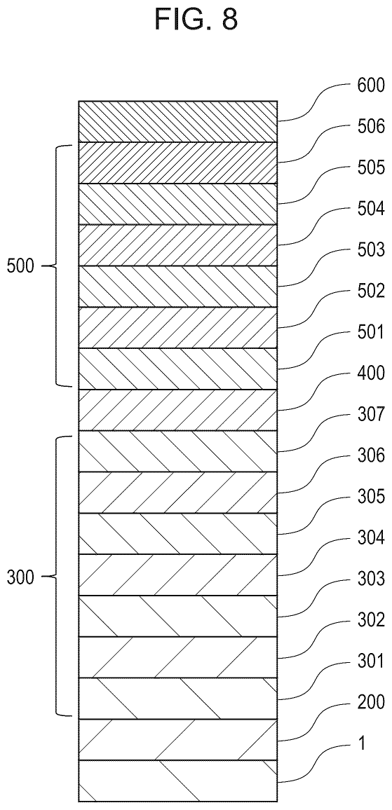

An organic light emitting element according to an embodiment will now be described with reference to FIG. 8.

An organic light emitting element according to this embodiment includes a first electrode 200, a first light emitting unit 300, a charge generation layer 400, a second light emitting unit 500, and a second electrode 600 arranged in this order. These may be disposed on a substrate 1. In the organic light emitting element according to this embodiment, the first electrode 200 may be an anode and the second electrode 600 may be a cathode.

The organic light emitting element according to this embodiment is a so-called tandem-type light emitting element (multilayer organic light emitting element) that has a charge generation layer, and the first light emitting unit 300 and the second light emitting unit 500 that sandwich the charge generation layer.

The organic light emitting element according to this embodiment includes a second light emitting layer 304 in the first light emitting unit 300. The first light emitting unit 300 may include a first organic layer 303, a second light emitting layer 304, and a second organic layer 305 arranged in this order of proximity to the first electrode 200. The first organic layer 303 may be a first electron blocking layer, and the second organic layer 305 may be a first hole blocking layer. In addition, the first light emitting unit 300 may further include a first hole injection layer 301, a first hole transport layer 302, a first electron transport layer 306, a first electron injection layer 307, etc. The first organic layer 303 and the second light emitting layer 304 may be in contact with each other. The second light emitting layer 304 and the second organic layer 305 may be in contact with each other. In the organic light emitting element according to this embodiment, the first organic layer 303 may contain a third compound, the second light emitting layer 304 may contain a fourth compound, and the second organic layer 305 may contain a fifth compound.

The organic light emitting element according to this embodiment includes a first light emitting layer 503 in the second light emitting unit 500. In the organic light emitting element according to this embodiment, the first light emitting layer 503 contains a first compound and a second compound.

In addition, in the organic light emitting element according to this embodiment, the first light emitting layer 503 may include a first light emitting portion and a second light emitting portion. Here, the first light emitting portion may contain the first compound and the second compound, the second light emitting portion may contain the first compound and the second compound, or one of the first light emitting portion and the second light emitting portion may contain the first compound while the other may contain the second compound. The first light emitting portion and the second light emitting portion may contain the first compound. In addition, the first light emitting portion and the second light emitting portion may be in contact with each other.

In the organic light emitting element according to this embodiment, the first light emitting layer 503 may contain a first light emitting material, and the second light emitting layer 304 may contain a third light emitting material. When the first light emitting layer 503 has a first light emitting portion and a second light emitting portion, the first light emitting portion may contain a first light emitting material, the second light emitting portion may contain a second light emitting material, and the second light emitting layer 304 may contain a third light emitting material. The second compound may be the first light emitting material or the second light emitting material, and the fourth compound may be the third light emitting material.

The organic light emitting element according to this embodiment may further include, in the second light emitting unit 500, a second hole transport layer 501, a second electron blocking layer 502, a second hole blocking layer 504, a second electron transport layer 505, a second electron injection layer 506, etc.

The organic light emitting element according to this embodiment includes a charge generation layer 400 between the first light emitting unit 300 and the second light emitting unit 500. A specific structure of the charge generation layer 400 is described below but is not limited to what is described below.
(i) n-type charge generation layer/hole injection layer
(ii) n-type charge generation layer/p-type charge generation layer
(iii) n-type charge generation layer/connection layer/hole injection layer
(iv) n-type charge generation layer/connection layer/p-type charge generation layer

In the organic light emitting element according to this embodiment, the n-type charge generation layer may contain an organic compound with high electron donor properties, such as a compound having an alkali metal atom, an alkaline earth metal atom, and an imidazolidine skeleton, preferably contains an alkali metal atom or an alkaline earth metal atom, and more preferably contains a lithium atom or a cesium atom. In addition, the n-type charge generation layer may be a mixed layer containing a first organic compound and a second organic compound.

The first organic compound is, for example, a nitrogen-containing aromatic compound. Specific examples thereof include a phenanthrolinyl group, an oxazolyl group, an oxadiazolyl group, a diazolyl group, a thiadiazolyl group, a triazolyl group, a naphthyridinyl group, and derivatives thereof. In particular, the first organic compound is preferably a phenanthroline derivative or a naphthyridine derivative. A phenanthroline derivative and a naphthyridine derivative have particularly strong interaction with alkali metals and thus are particularly preferable as the material for the n-type charge generation layer.

The second organic compound is a fused polycyclic hydrocarbon compound or an organic compound represented by general formulae (A-1) to (A-10).

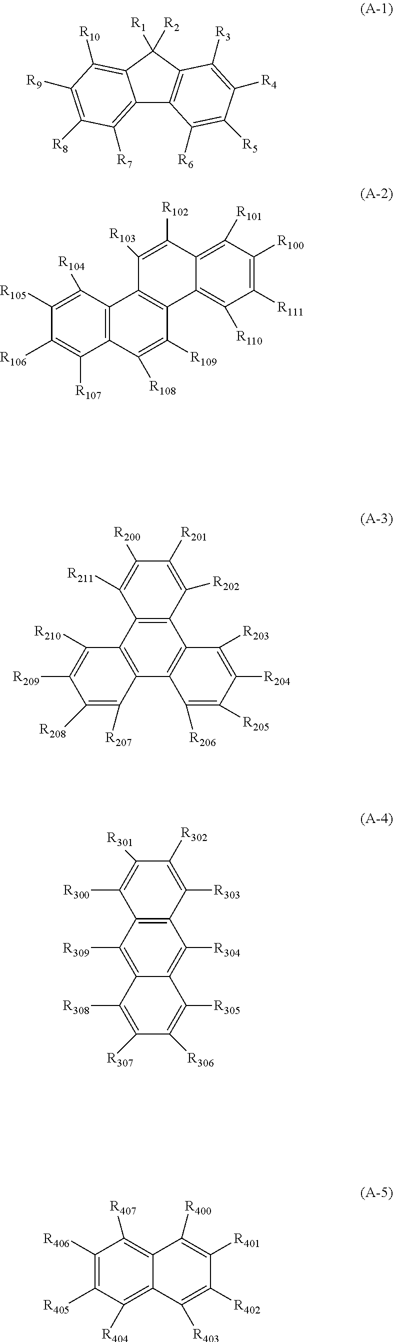

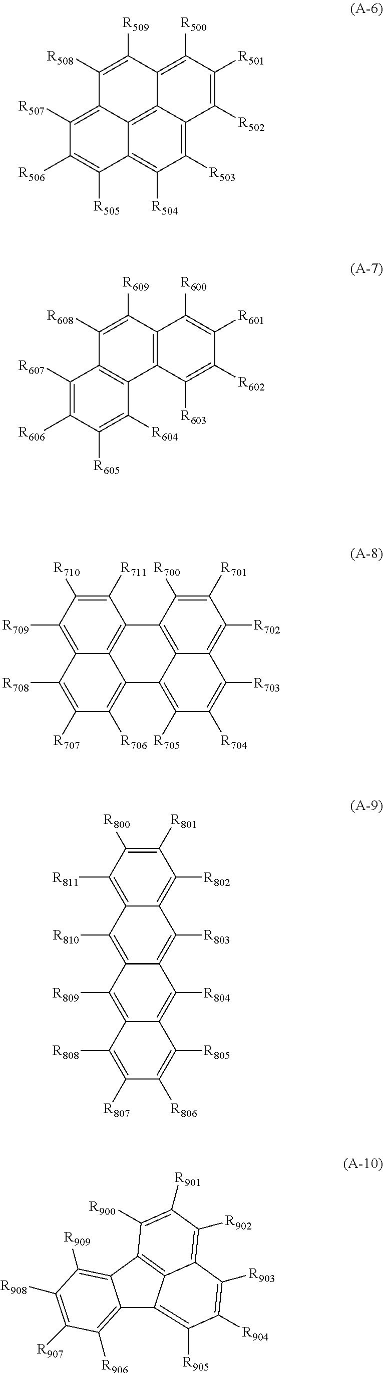

In general formulae (A-1) to (A-10). R₁ to R₉₀₉ are each independently selected from the group consisting of a hydrogen atom, a deuterium atom, a halogen atom, a substituted or unsubstituted alkyl group, a substituted or unsubstituted alkoxy group, a substituted or unsubstituted aryl group, a substituted or unsubstituted silyl group, and a substituted or unsubstituted amino group.

The p-type charge generation layer may be a mixed layer containing a hole transport compound and an electron-withdrawing compound.

The hole injection layer may be a layer that contains an electron-withdrawing compound or a metal oxide.

The connection layer may be a layer that contains an electron transport compound or a hole transport compound. An n-type organic semiconductor layer containing a compound having a LUMO of −5.0 eV or less may be disposed between the n-type charge generation layer and the p-type charge generation layer. Furthermore, the connection layer may be a layer composed of a fused polycyclic hydrocarbon compound and is more preferably a layer solely composed of a fused polycyclic hydrocarbon compound. The connection layer may include both a layer that contains an electron transport compound or a hole transport compound, and a layer composed of a fused polycyclic hydrocarbon compound.

The charge generation layer 400 has a role of injecting electrons to the first light emitting unit 300. Thus, in the organic light emitting element according to this embodiment, the first light emitting unit 300 does not have to include the first electron injection layer 307. When the first light emitting unit 300 does not include the first electron injection layer 307, the drive voltage of the organic light emitting element can be decreased.

In the organic light emitting element according to this embodiment, the first light emitting unit 300 may include the first electron injection layer 307. Here, the first electron injection layer 307 and the charge generation layer 400 can share a common material, and the first electron injection layer 307 and the n-type charge generation layer can share a common material. When the first electron injection layer 307 and the charge generation layer 400 share a common material, adhesion between the first electron injection layer 307 and the charge generation layer 400 is enhanced, and thus the function as the electron injection layer is further improved.

The charge generation layer 400 has a role of injecting holes to the second light emitting unit 500. Thus, in the organic light emitting element according to this embodiment, the second light emitting unit 500 does not have to include a second hole injection layer. When the second light emitting unit 500 does not include a second hole injection layer, the drive voltage of the organic light emitting element can be decreased.

In the organic light emitting element according to this embodiment, the second light emitting unit 500 may include a second hole injection layer. Here, the second hole injection layer and the charge generation layer 400 can share a common material, and the second hole injection layer and the p-type charge generation layer or the hole injection layer included in the charge generation layer 400 can share a common material. When the second hole injection layer and the charge generation layer 400 share a common material, adhesion between the second hole injection layer and the charge generation layer 400 is enhanced, and thus the function as the hole injection layer is further improved.

The organic light emitting element according to this embodiment may include a third light emitting unit in addition to the first light emitting unit 300 and the second light emitting unit 500. The third light emitting unit may be disposed between the first electrode 200 and the first light emitting unit 300, between the first light emitting unit 300 and the second light emitting unit 500, or between the second light emitting unit 500 and the second electrode 600.

The organic light emitting element according to this embodiment may have an element structure capable of emitting white light. Specifically, the first light emitting unit 300 may emit blue light and the second light emitting unit 500 may emit red and green light. Alternatively, the first light emitting unit 300 may emit red and green light, and the second light emitting unit 500 may emit blue light. The first light emitting unit 300, the second light emitting unit 500, and the third light emitting unit may respectively emit red, green, and blue light.

The organic light emitting element according to this embodiment may have an element structure capable of emitting light other than white light. Specifically, the first light emitting unit 300 and the second light emitting unit 500 may emit light of the same color. According to this element structure, an organic light emitting element with further improved luminance can be manufactured.

The organic light emitting element according to this embodiment has the following features.

### (1) the First Compound and the Second Compound Satisfy Relationship (a):

LUMO(A)>LUMO(B) (a)

This feature will now be described in detail.

The organic light emitting element according to this embodiment includes a charge generation layer 400 between the first light emitting unit 300 and the second light emitting unit 500. In such an organic light emitting element, electrons supplied from the second electrode 600 are trapped in the first light emitting layer 503, and thus a low drive voltage is exhibited.

Specifically, the first compound and the second compound satisfy relationship (a). In addition, relationship (a1) or (a2) is preferably satisfied.

$$LUMO ( A ) > LUMO ( B ) \qquad ( a )$$

$$LUMO ( A ) - LUMO ( B ) \geq 0.15 eV \qquad ( a1 )$$

$$LUMO ( A ) - LUMO ( B ) \geq 0.2 eV \qquad ( a2 )$$

Furthermore, in the organic light emitting element according to this embodiment, the content of the second compound is smaller than the content of the first compound. The first compound may be a host material and the second compound may be an assist material or a guest material; or the first compound may be a guest material and the second compound may be a guest material.

Table 1 indicates the structure of the first light emitting layer 503 in the second light emitting unit 500, and the voltage ratio.

The voltage ratio is an improvement rate with respect to the drive voltage of Comparative Example 1, 1.0 (for example, when the comparative example exhibited 1.0 V and an example exhibited 0.5 V, the improvement rate is 2.0). In Table 1, ΔLUMO is as follows.

$$Δ LUMO = LUMA ( A ) - LUMO ( B )$$

Here, HOMO and LUMO can be calculated by molecular orbital calculation. The molecular orbital calculation is done according to the density functional theory (DFT) or the like by using B3LYP as the functional and 6-31G* as the basis function, for example.

The molecular orbital calculation can be performed by using, for example, Gaussian 09 (Gaussian 09, Revision C.01, M. J. Frisch, G. W. Trucks, H. B. Schlegel, G. E. Scuseria, M. A. Robb, J. R. Cheeseman, G. Scalmani, V. Barone, B. Mennucci, G. A. Petersson, H. Nakatsuji, M. Caricato, X. Li, H. P. Hratchian, A. F. Izmaylov, J. Bloino, G. Zheng, J. L. Sonnenberg, M. Hada, M. Ehara, K. Toyota, R. Fukuda, J. Hasegawa, M. Ishida, T. Nakajima, Y. Honda, O. Kitao, H. Nakai, T. Vreven, J. A. Montgomery, Jr., J. E. Peralta, F. Ogliaro, M. Bearpark, J. J. Heyd, E. Brothers, K. N. Kudin, V. N. Staroverov, T. Keith, R. Kobayashi, J. Normand, K. Raghavachari, A. Rendell, J. C. Burant, S. S. Iyengar, J. Tomasi, M. Cossi, N. Rega, J. M. Millam, M. Klene, J. E. Knox, J. B. Cross, V. Bakken, C. Adamo, J. Jaramillo, R. Gomperts, R. E. Stratmann, O. Yazyev, A. J. Austin, R. Cammi, C. Pomelli, J. W. Ochterski, R. L. Martin, K. Morokuma, V. G. Zakrzewski, G. A. Voth, P. Salvador, J. J. Dannenberg, S. Dapprich, A. D. Daniels, O. Farkas, J. B. Foresman, J. V. Ortiz, J. Cioslowski, and D. J. Fox, Gaussian, Inc., Wallingford CT, 2010.).

HOMO and LUMO can also be calculated by using ionization potentials and bandgaps. HOMO can be estimated by measuring the ionization potential. For the ionization potential, a compound to be measured is vapor-deposited on a substrate such as glass to form a vapor deposited film. This vapor deposited film can then analyzed with a measurement instrument such as AC-3. The bandgap can be measured by dissolving a compound to be measured in a solvent such as toluene and then irradiating the resulting solution with excitation light. The bandgap can be measured by measuring the absorption edge of the absorption spectrum obtained as the solution absorbs the excitation light. Alternatively, the bandgap can be measured by vapor-depositing a compound to be measured on a substrate such as glass, and irradiating the vapor deposited film with excitation light. The bandgap can be measured by measuring the absorption edge of the absorption spectrum obtained as the vapor deposited film absorbs the excitation light.

LUMO can be calculated by using the values of the bandgap and the ionization potential. LUMO can be estimated by adding the value of the bandgap to the ionization potential.

LUMO can also be estimated from the reduction potential. For example, the one-electron reduction potential is estimated by cyclic volumetry (CV). CV can be performed in, for example, a DMF solution of a 0.1 M tetrabutylammonium perchlorate with a Ag/Ag⁺ reference electrode, a Pt counter electrode, and a glassy carbon working electrode. LUMO can be estimated by subtracting the difference between the ferrocene reduction potential and the obtained reduction potential of the compound from the ferrocene ionization potential, which is −4.8 eV.

In the present disclosure, the ionization potential and the bandgap of the vapor deposited film described above are measured, HOMO is estimated from the obtained ionization potential, and LUMO is calculated by adding the bandgap to the ionization potential.

TABLE 1

| | Second light emitting unit | | | | | |
|---|---|---|---|---|---|---|
| | First compound | | Second | | | |
| | | LUMO/eV | compound | | | |
| | | HOMO/ | | LUMO/eV | | Voltage |
| | No. | eV | No. | HOMO/eV | ΔLUMO | Ratio |
| Example A | Z-16 | −2.7 | GD11 | −3.1 | 0.4 | 1.3 |
| | | −6.2 | | −5.4 | | |
| Compar- | EM28 | −3.1 | GD7 | −3.1 | 0.0 | 1.0 |
| ative | | −6.2 | | −5.4 | | |
| Example A | | | | | | |
| Compar- | EM30 | −3.4 | GD7 | −3.1 | −0.3 | 0.9 |
| ative | | −6.6 | | −5.4 | | |
| Example B | | | | | | |

In Table 1, Comparative Examples A and B both have a structure in which the LUMO energy level of the second compound is high (close to the vacuum level) with respect to the LUMO energy level of the first compound. In contrast, Example A has a structure in which the LUMO energy level of the second compound is low (far from the vacuum level) with respect to the LUMO energy level of the first compound. Thus, the structure of the organic light emitting element according to this embodiment has a tendency to trap electrons in the first light emitting layer 503. Thus, the organic light emitting element according to this embodiment has a structure in which recombination of electrons supplied from the second electrode 600 and the holes generated in the charge generation layer 400 smoothly occurs in the first light emitting layer 503. Therefore, the organic light emitting element according to this embodiment can exhibit low drive voltage.

Furthermore, since the organic light emitting element according to this embodiment has a structure that promotes electron-hole recombination in the first light emitting layer 503, excellent light emission efficiency is exhibited.

The organic light emitting element according to this embodiment more preferably has the following features.
(2) A third compound, a fourth compound, and a fifth compound satisfy relationship (b).

$$LUMO ( E ) - LUMO ( D ) \geq 0 eV \qquad ( b )$$

(3) The third compound, the fourth compound, and the fifth compound satisfy relationship (c).

$$HOMO ( D ) - HOMO ( C ) \geq 0 eV \qquad ( c )$$

(4) The freely rotatable bond that the first compound has is a carbon-carbon bond.
(5) The first compound is a compound that has a fused polycyclic hydrocarbon skeleton that may have a substituent or a heterocyclic skeleton that may have a substituent.
(6) The first light emitting layer 503 is a phosphorescence emitting layer, and the second light emitting layer 304 is a fluorescence emitting layer.
   These features will now be described in detail.

### (2) the Third Compound, the Fourth Compound, and the Fifth Compound Satisfy Relationship (b).

$$LUMO ( E ) - LUMO ( D ) \geq 0 eV \qquad ( b )$$

The organic light emitting element according to this embodiment more preferably satisfies relationship (b1).

$$LUMO ( E ) - LUMO ( D ) > HOMO ( D ) - HOMO ( C ) \qquad ( b1 )$$

In the organic light emitting element according to this embodiment, relationship (b) indicates that the LUMO energy level of the second organic layer 305 is higher than the LUMO energy level of the second light emitting layer 304. In addition, relationship (b1) indicates that the difference between the LUMO energy level of the second organic layer 305 and the LUMO energy level of the second light emitting layer 304 is larger than the difference between the HOMO energy level of the first organic layer 303 and the HOMO energy level of the second light emitting layer 304.

Here, the HOMO energy level of the first organic layer 303 is the HOMO energy level of the third compound. Here, the LUMO energy level of the second organic layer 305 is the LUMO energy level of the fifth compound. The LUMO energy level of the second light emitting layer 304 may be a LUMO energy level of a compound that has the lowest LUMO energy level among the compounds contained in the second light emitting layer 304, may be a LUMO energy level of a compound that has the largest content in the second light emitting layer 304, may be a

LUMO energy level of a compound that has the lowest LUMO energy level among the compounds other than the compound having the lowest content in the second light emitting layer 304, or may be a LUMO energy level of a compound that has the lowest LUMO energy level among the compounds that are contained in the second light emitting layer 304 and have a content of 10 parts by mass or more per 100 parts by mass of the second light emitting layer 304. For example, the LUMO energy level of the second light emitting layer 304 may be the LUMO energy level of the fourth compound, specifically, the LUMO energy level of the host material, the LUMO energy level of the assist material, or the LUMO energy level of the guest material. The HOMO energy level of the second light emitting layer 304 may be a HOMO energy level of a compound that has the highest HOMO energy level among the compounds contained in the second light emitting layer 304, may be a HOMO energy level of a compound that has the largest content in the second light emitting layer 304, may be a HOMO energy level of a compound that has the highest HOMO energy level among the compounds in the second light emitting layer 304 other than the compound having the smallest content, or may be a HOMO energy level of a compound that has the highest HOMO energy level among the compounds that are contained in the second light emitting layer 304 and have a content of 10 parts by mass or more per 100 parts by mass of the second light emitting layer 304. For example, the HOMO energy level of the second light emitting layer 304 may be the HOMO energy level of the fourth compound, specifically, the HOMO energy level of the host material, the HOMO energy level of the assist material, or the HOMO energy level of the guest material.

Since the organic light emitting element according to this embodiment satisfies relationship (b), electrons generated in the charge generation layer 400 can be easily injected into the second light emitting layer 304. As a result, the organic light emitting element according to this embodiment exhibits a still lower drive voltage.

Furthermore, since the electrons generated in the charge generation layer 400 are easily injected into the second light emitting layer 304, the electrons are less likely to stay in the charge generation layer 400. Since the electrons are less likely to stay in the charge generation layer 400, deterioration of the charge generation layer caused by the electrons can be expected to be less. Thus, the organic light emitting element according to this embodiment has superior durability.

The organic light emitting element according to this embodiment more preferably satisfies relationship (b2) or (b3).

$$LUMO ( E ) - LUMO ( D ) \geq 0 eV > HOMO ( D ) - HOMO ( C ) \qquad ( b2 )$$

$$LUMO ( E ) - LUMO ( D ) > HOMO ( D ) - HOMO ( C ) \geq 0 eV \qquad ( b3 )$$

The organic light emitting element according to this embodiment preferably satisfies relationship (b2) or (b3) since electrons rather than holes are more easily injected to the second light emitting layer 304. In addition, in the organic light emitting element that satisfies formula (b3), holes are easily injected into the second light emitting layer 304, and there is a structure in which the electron-hole recombination region easily stays within the second light emitting layer 304; thus, the light emission efficiency can also be expected to improve.

Here, in the organic light emitting element according to this embodiment, the fourth compound may be a host material, an assist material, or a guest material. The fourth compound is more preferably a host material or an assist material.

### (3) the Third Compound, the Fourth Compound, the Fifth Compound, and the Sixth Compound Satisfy Relationship (c).

$$HOMO ( D ) - HOMO ( C ) \geq 0 eV \qquad ( c )$$

The organic light emitting element according to this embodiment more preferably satisfies relationship (c1).

$$HOMO ( D ) - HOMO ( C ) > LUMO ( E ) - LUMO ( D ) \qquad ( c1 )$$

In the organic light emitting element according to this embodiment, relationship (c) indicates that the HOMO energy level of the second light emitting layer 304 is higher than the HOMO energy level of the second organic layer 305. In addition, relationship (c1) indicates that the difference between the HOMO energy level of the first organic layer 303 and the HOMO energy level of the second light emitting layer 304 is larger than the difference between the LUMO energy level of the second organic layer 305 and the LUMO energy level of the second light emitting layer 304.

Here, the HOMO energy level of the first organic layer 303 is the HOMO energy level of the third compound. Here, the LUMO energy level of the second organic layer 305 is the LUMO energy level of the fifth compound. The LUMO energy level of the second light emitting layer 304 may be a LUMO energy level of a compound that has the lowest LUMO energy level among the compounds contained in the second light emitting layer 304, may be a LUMO energy level of a compound that has the largest content in the second light emitting layer 304, may be a

LUMO energy level of a compound that has the lowest LUMO energy level among the compounds other than the compound having the lowest content in the second light emitting layer 304, or may be a LUMO energy level of a compound that has the lowest LUMO energy level among the compounds that are contained in the second light emitting layer 304 and have a content of 10 parts by mass or more per 100 parts by mass of the second light emitting layer 304. For example, the LUMO energy level of the second light emitting layer 303 may be the LUMO energy level of the fourth compound, specifically, the LUMO energy level of the host material, the LUMO energy level of the assist material, or the LUMO energy level of the guest material. THE HOMO energy level of the second light emitting layer 304 may be a HOMO energy level of a compound that has the highest HOMO energy level among the compounds contained in the second light emitting layer 304, may be a HOMO energy level of a compound that has the largest content in the second light emitting layer 304, may be a HOMO energy level of a compound that has the highest HOMO energy level among the compounds in the second light emitting layer 304 other than the compound having the smallest content, or may be a HOMO energy level of a compound that has the highest HOMO energy level among the compounds that are contained in the second light emitting layer 304 and have a content of 10 parts by mass or more per 100 parts by mass of the second light emitting layer 304. For example, the HOMO energy level of the second light emitting layer 304 may be the HOMO energy level of the fourth compound, specifically, the HOMO energy level of the host material, the HOMO energy level of the assist material, or the HOMO energy level of the guest material.

Since the organic light emitting element according to this embodiment satisfies relationship (c), there is a structure in which holes supplied from the first electrode 200 are easily injected into the second light emitting layer 304. As a result, the organic light emitting element according to this embodiment exhibits a still lower drive voltage.

The organic light emitting element according to this embodiment more preferably satisfies relationship (c2) or (c3).

$$HOMO ( D ) - HOMO ( C ) \geq 0 eV > LUMO ( E ) - LUMO ( D ) \qquad ( c2 )$$

$$HOMO ( D ) - HOMO ( C ) > LUMO ( E ) - LUMO ( D ) \geq 0 eV \qquad ( c3 )$$

The organic light emitting element according to this embodiment preferably satisfies relationship (c2) or (c3) since holes rather than electrons are more easily injected to the second light emitting layer 304. In addition, in the organic light emitting element that satisfies relationship (c3), electrons are easily injected into the second light emitting layer 304, and there is a structure in which the electron-hole recombination region easily stays within the second light emitting layer 304; thus, the light emission efficiency can also be expected to improve.

Here, in the organic light emitting element according to this embodiment, the fourth compound may be a host material, an assist material, or a guest material. The fourth compound is more preferably a host material or an assist material.

(4) the Freely Rotatable Bond that the First Compound has is a Carbon-Carbon Bond.

In the organic light emitting element according to this embodiment, the freely rotatable single bond in the first compound is preferably a carbon-carbon bond and more preferably an sp2 carbon-sp2 carbon bond, and all of freely rotatable single bonds are more preferably carbon-carbon bonds and yet more preferably sp2 carbon-sp2 carbon bonds.

The organic light emitting element according to this embodiment has a structure in which electrons are injected into the first light emitting layer 503 via the first compound. In addition, the first compound has a role of generating excitons in the organic light emitting element. Thus, the first compound may have a skeleton resistant to degradation by electrons or in a high energy excited state. In the present description, a freely rotatable single bond refers to a bond that exists in “A-B” representing a state in which unit A and unit B are single-bonded but are not fused. Units A and B may be atoms such as carbon atoms or nitrogen atoms or may be molecules such as benzenes and carbazoles. Table 2 indicates bond energy of each bond.

TABLE 2

| | |
|---|---|
| 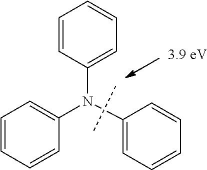 | F1 |
| 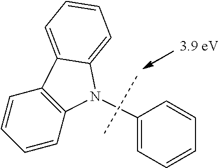 | F2 |
| 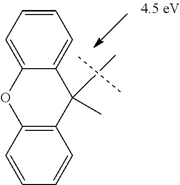 | F3 |
| 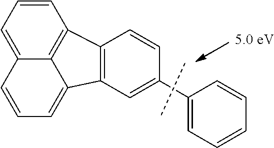 | F4 |

The bond energy of F1 and F2 that have carbon-nitrogen bonds is 3.9 eV. Meanwhile, the bond energy of F3 that has a freely rotatable carbon-carbon bond is 4.5 eV, and the bond energy of F4 that has a freely rotatable sp2 carbon bond is 5.0 eV.

Thus, the freely rotatable single bond may be a carbon-carbon bond since such a skeleton is resistant to degradation. Among the carbon-carbon bonds, a bond between sp2 carbon atoms has particularly high bond energy, and thus the freely rotatable single bond is more preferably an sp2 carbon-sp2 carbon bond since such a skeleton is highly resistant to degradation.

(5) the First Compound is a Compound that has a Fused Polycyclic Hydrocarbon Skeleton that May have a Substituent or a Heterocyclic Skeleton that May have a Substituent.

In the organic light emitting element according to this embodiment, the first compound may be a compound that has a fused polycyclic hydrocarbon skeleton that may have a substituent or a heterocyclic skeleton that may have a substituent.

The fused polycyclic hydrocarbon skeleton may have 10 or more and 25 or less carbon atoms, and specific examples thereof include a naphthalene skeleton, a fluorene skeleton, an anthracene skeleton, a phenanthrene skeleton, a pyrene skeleton, a chrysene skeleton, a triphenylene skeleton, a tetracene skeleton, a fluoranthene skeleton, and a perylene skeleton.

The heterocyclic skeleton may have 3 or more and 30 or less carbon atoms or 3 or more and 18 or less carbon atoms, and examples thereof include a dibenzofuran skeleton, a dibenzothiophene skeleton, a xanthone skeleton, a thioxanthone skeleton, a carbazole skeleton, an indolocarbazole skeleton, and a triazine skeleton.

The first compound may be a compound that has a triphenylene skeleton, a xanthone skeleton, or an indolocarbazole skeleton. In other words, the first compound may be a triphenylene derivative, a xanthone derivative, or an indolocarbazole derivative. Since these skeletons are highly planar, charge mobility is increased. Thus, charges can be more easily injected into the light emitting layer, and thus a lower drive voltage is exhibited.

Specific examples of the first compound include, but are not limited to, compounds represented by general formulae (1) to (3) below and example compounds EM1 to EM43 and Z-1 to Z-17 described below.

### (5-1) Compounds Represented by General Formula (1)

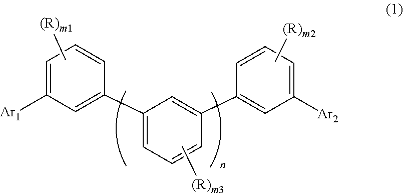

In general formula (1), Ar₁ and Ar₂ are each independently selected from tricyclic or higher substituted or unsubstituted aryl groups or tricyclic or higher substituted or unsubstituted heterocyclic groups. The substituent represented by R is selected from a deuterium atom, a halogen atom, a substituted or unsubstituted alkyl group, a substituted or unsubstituted alkoxy group, a substituted or unsubstituted amino group, a substituted or unsubstituted aryloxy group, a substituted or unsubstituted aryl group, a substituted or unsubstituted heterocyclic group, a substituted or unsubstituted silyl group, or a cyano group. When there are multiple R, those R may be the same or different. Moreover, n represents an integer of 2 to 5, and m1 to m3 each represent an integer of 0 to 4.

Furthermore, the compound represented by general formula (1) may have at least one of the following features.
(5-1-1) In general formula (1), Ar₁ and Ar₂ have no sp3 carbon.
(5-1-2) In general formula (1), the substituent represented by R bonds at the m site of benzene constituting a phenylene chain.
(5-1-3) In general formula (1), m1 to m3 are each 0.
(5-1-4) In general formula (1), n is 3 or 4.
(5-1-5) In general formula (1), Ar₁ and Ar₂ are skeletons different from each other.
(5-1-6) In general formula (1), when Ar₁ and Ar₂ are each a dibenzothiophene skeleton or a dibenzofuran skeleton, the organic compound has at least one substituent.
(5-1-7) Of Ar₁ and Ar₂, one is a tricyclic or higher substituted or unsubstituted aryl group and the other is a tricyclic or higher substituted or unsubstituted heterocyclic group.

### (5-2) A Compound Having a Skeleton Represented by General Formula (2) or (3)

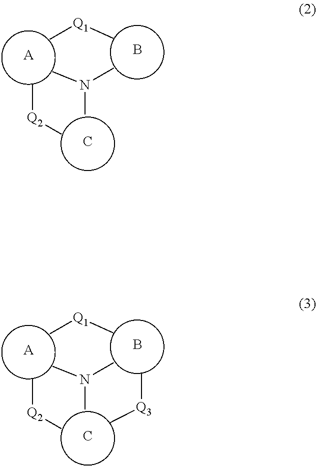

In general formulae (2) and (3), ring units A to C are each independently selected from substituted or unsubstituted aryl groups or substituted or unsubstituted heteroaryl groups. Q₁ to Q₃ are each independently selected from a direct bond, C(R_{A})(R_{B}), N(R_{C}), an oxygen atom, a sulfur atom, a selenium atom, and a tellurium atom. R_{A} to R_{C} are each independently selected from a hydrogen atom, a deuterium atom, a halogen atom, a substituted or unsubstituted alkyl group, a substituted or unsubstituted alkoxy group, a substituted or unsubstituted aryl group, or a substituted or unsubstituted heteroaryl group. R_{C} forms a ring with adjacent ring units A to C.

Specific examples of the skeletons represented by general formulae (2) and (3) are as follows.

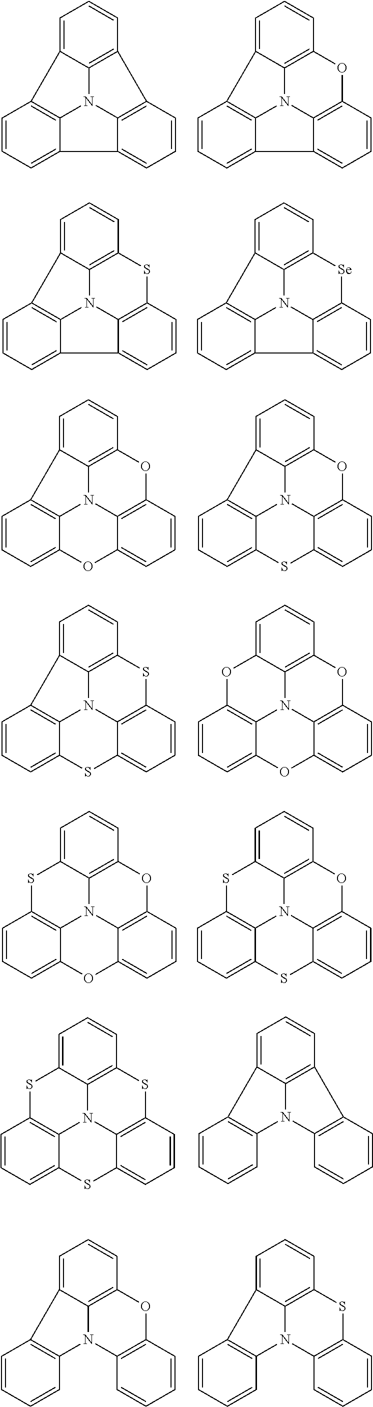

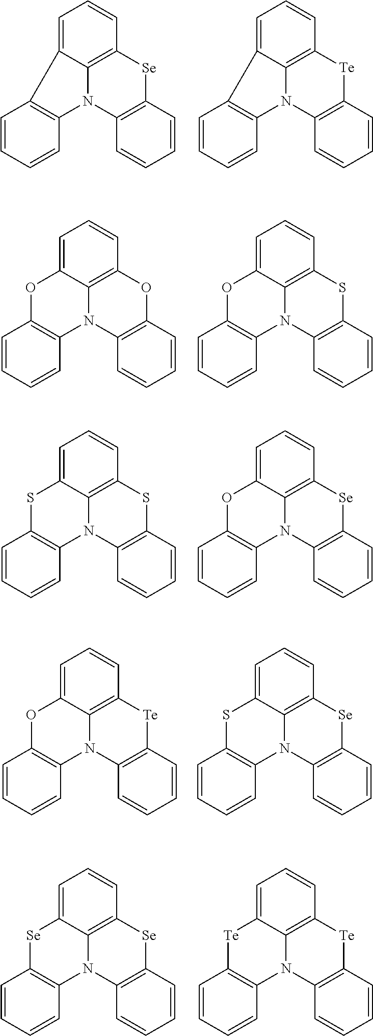

Although specific examples of general formulae (1) to (3) are described below, these examples are not limiting.

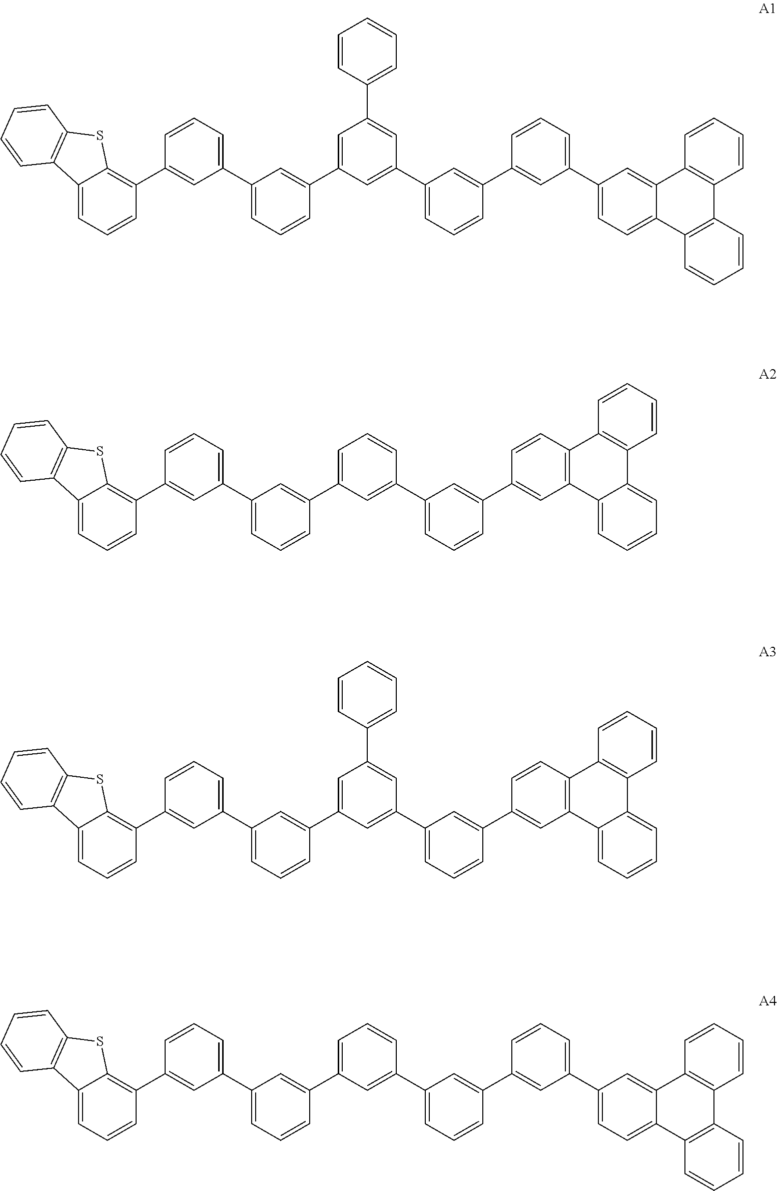

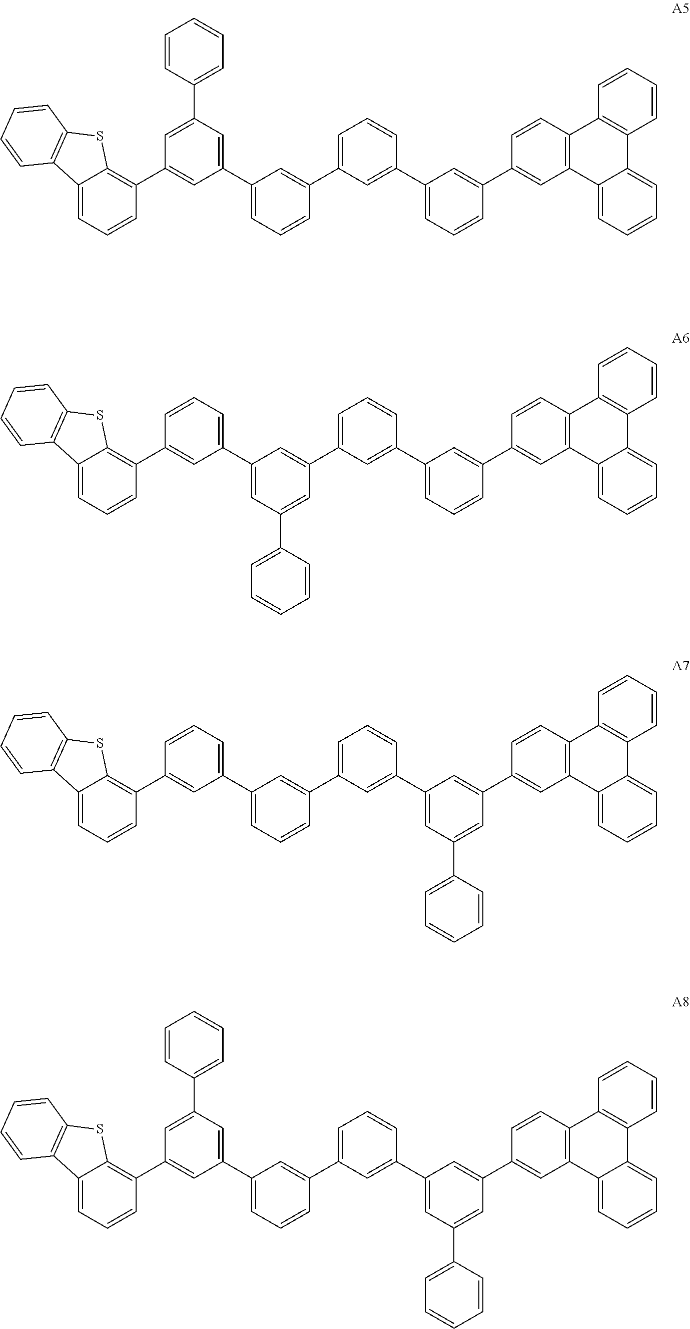

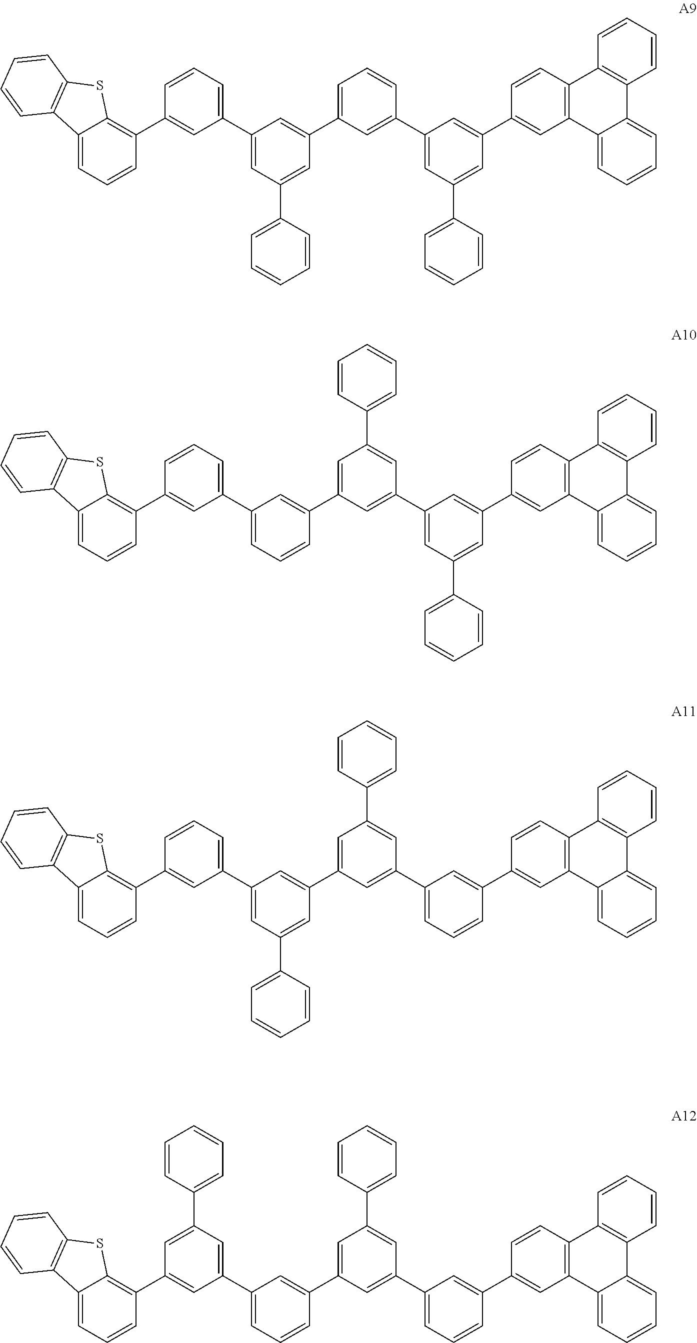

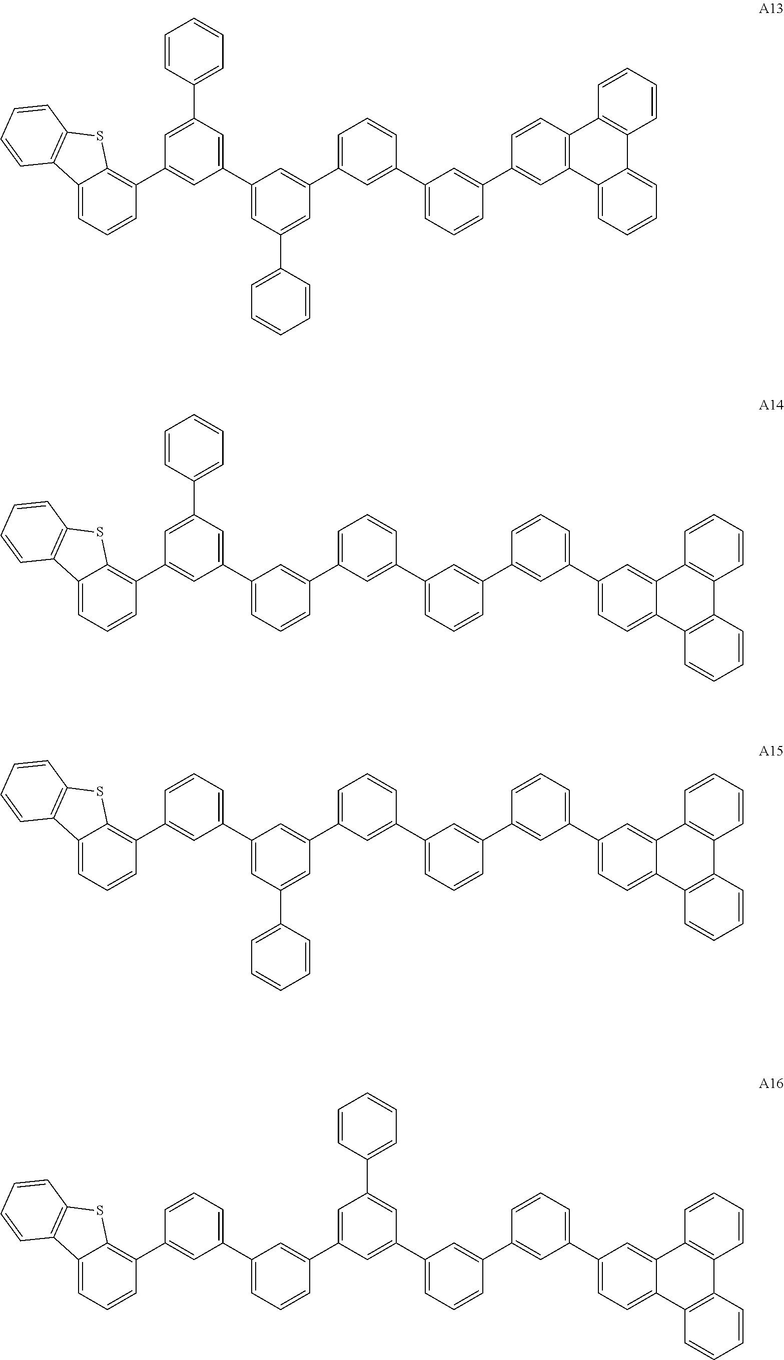

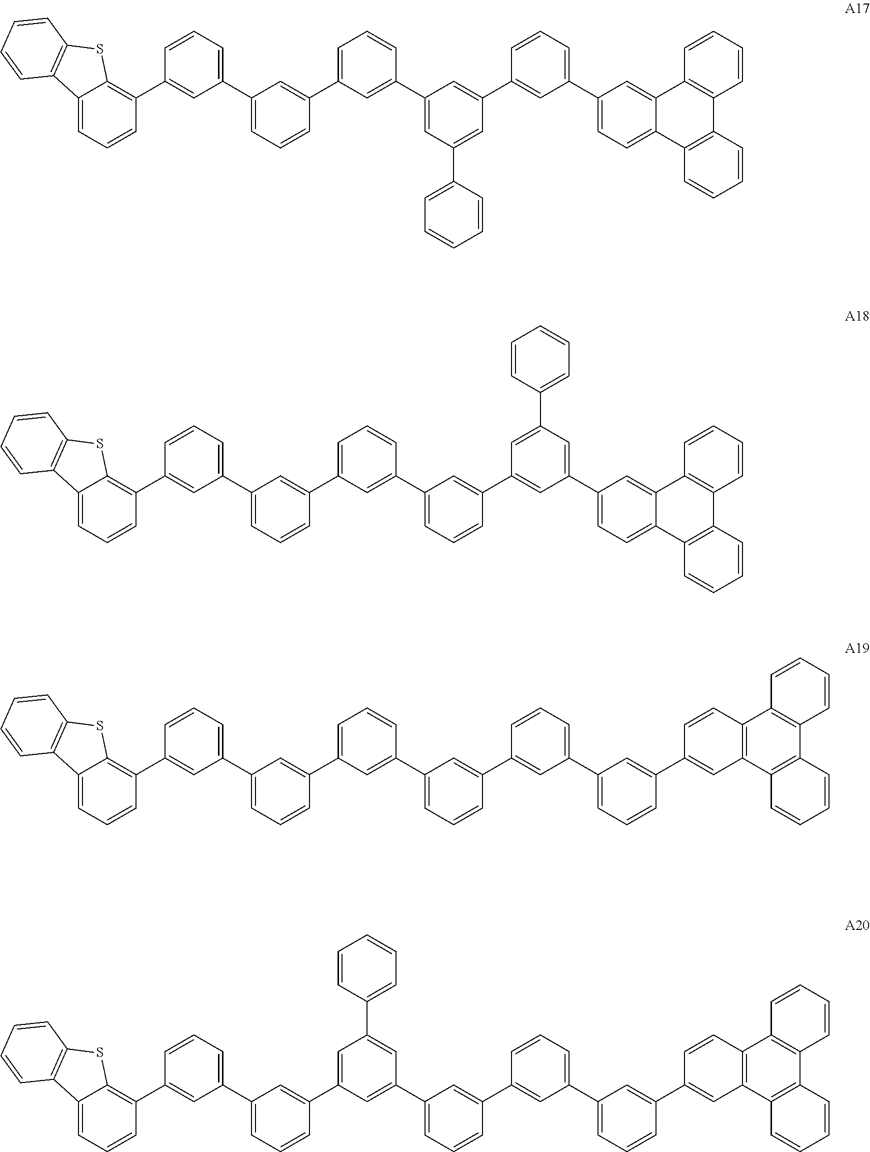

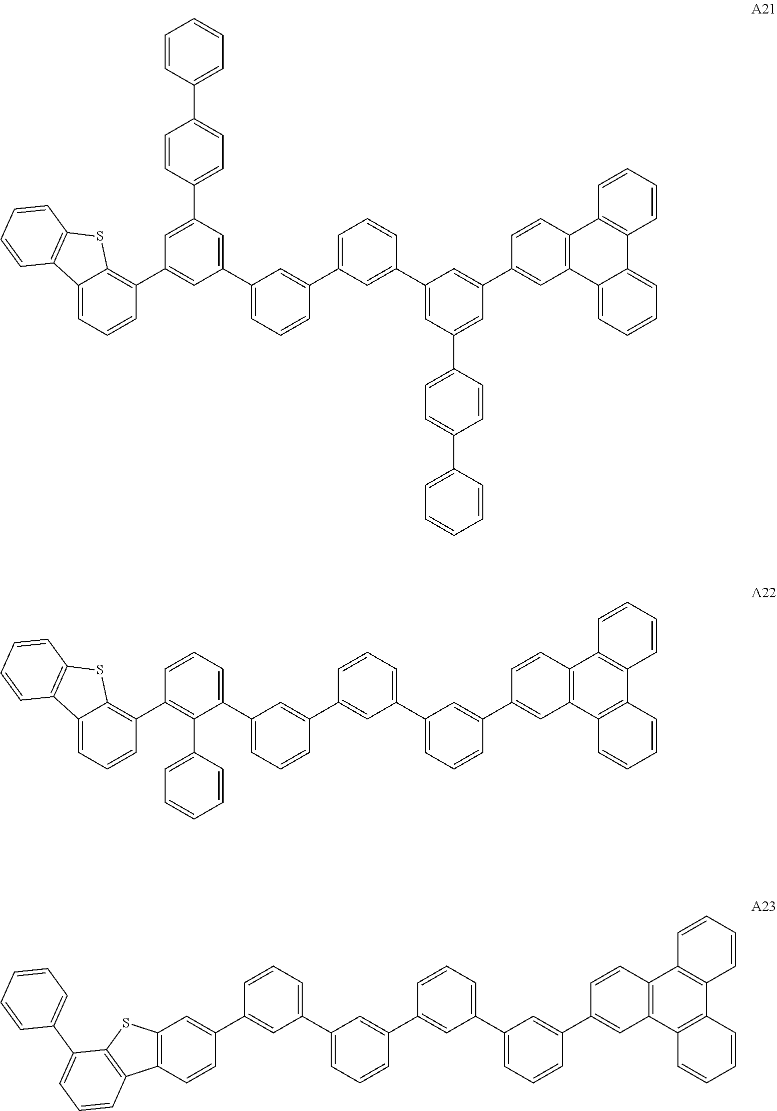

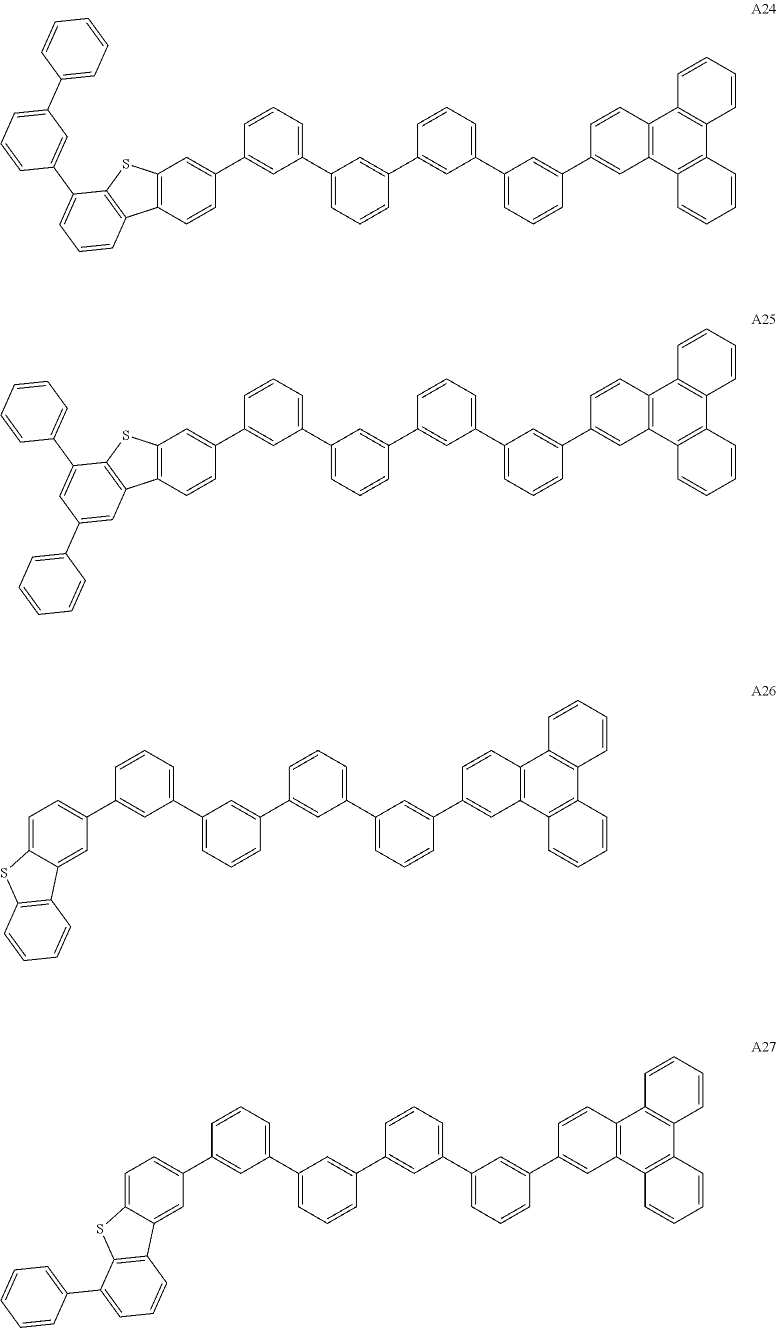

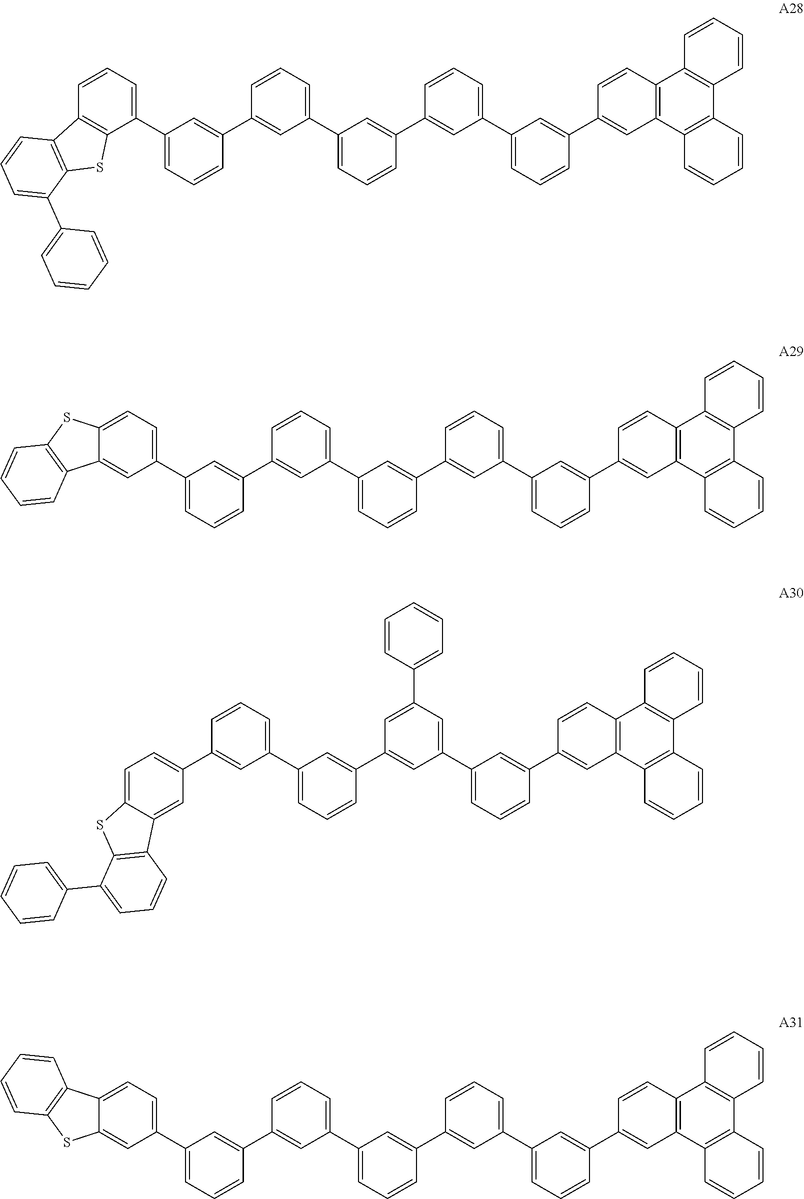

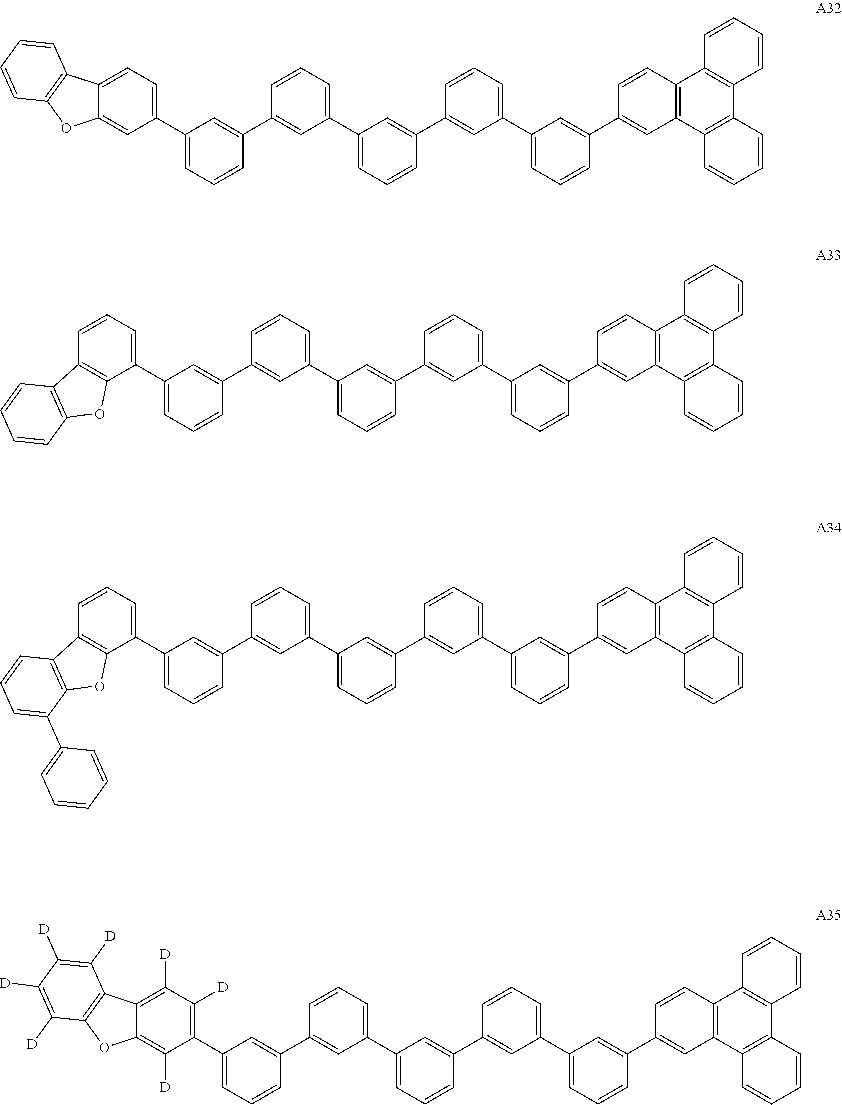

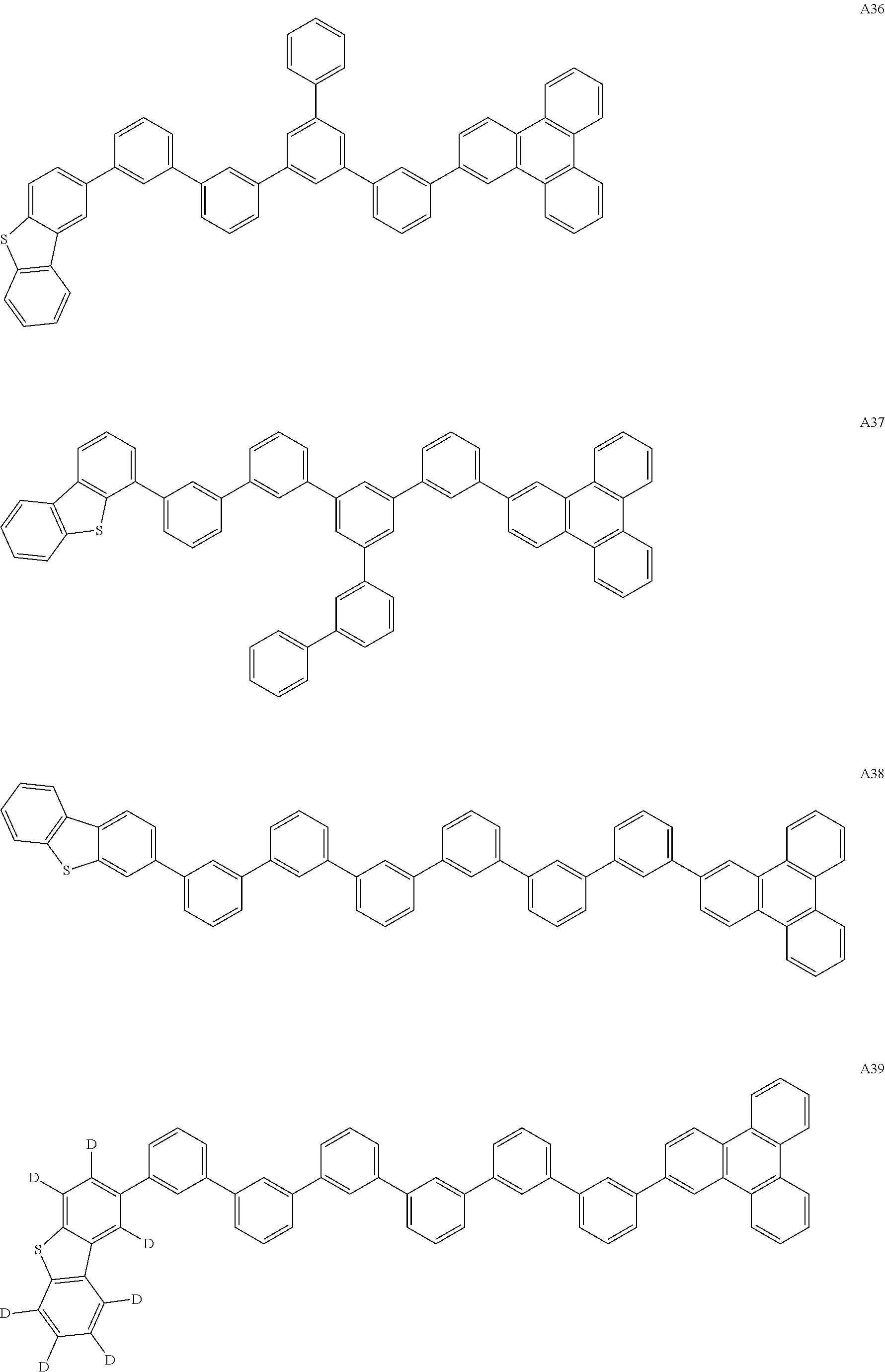

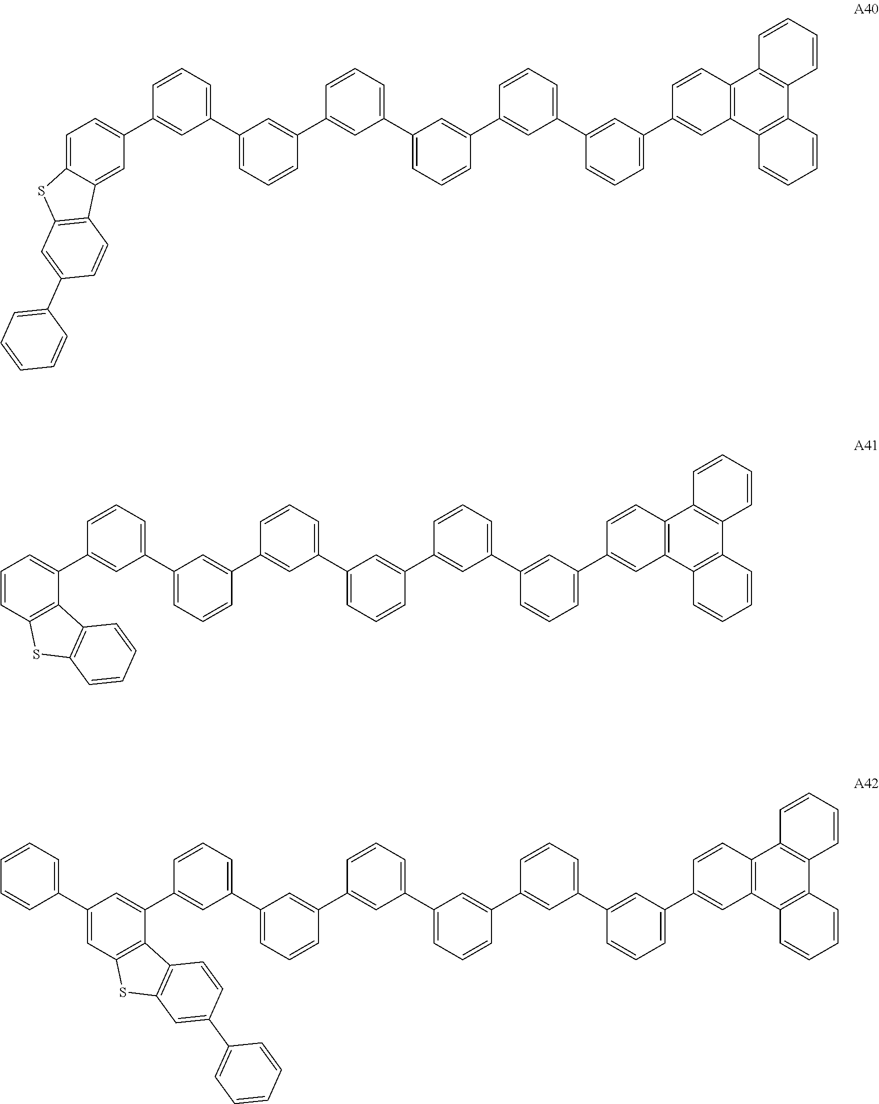

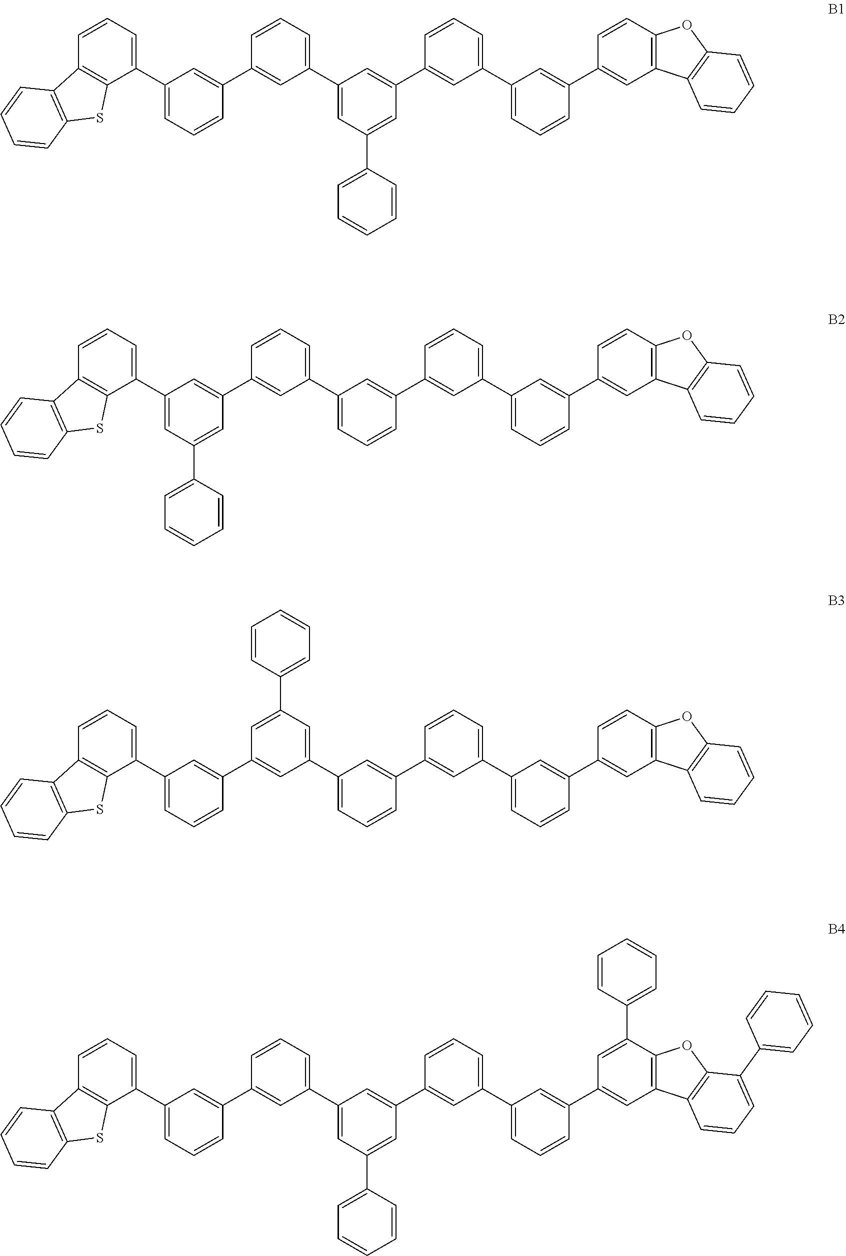

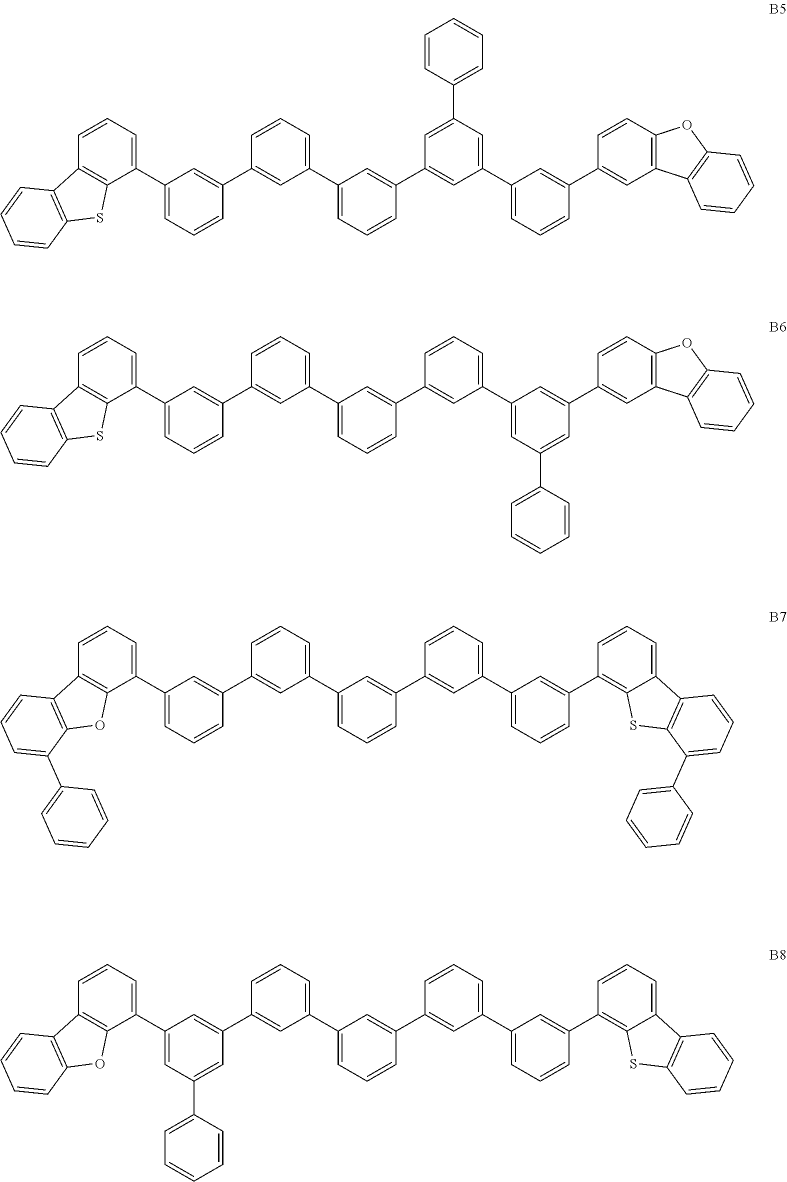

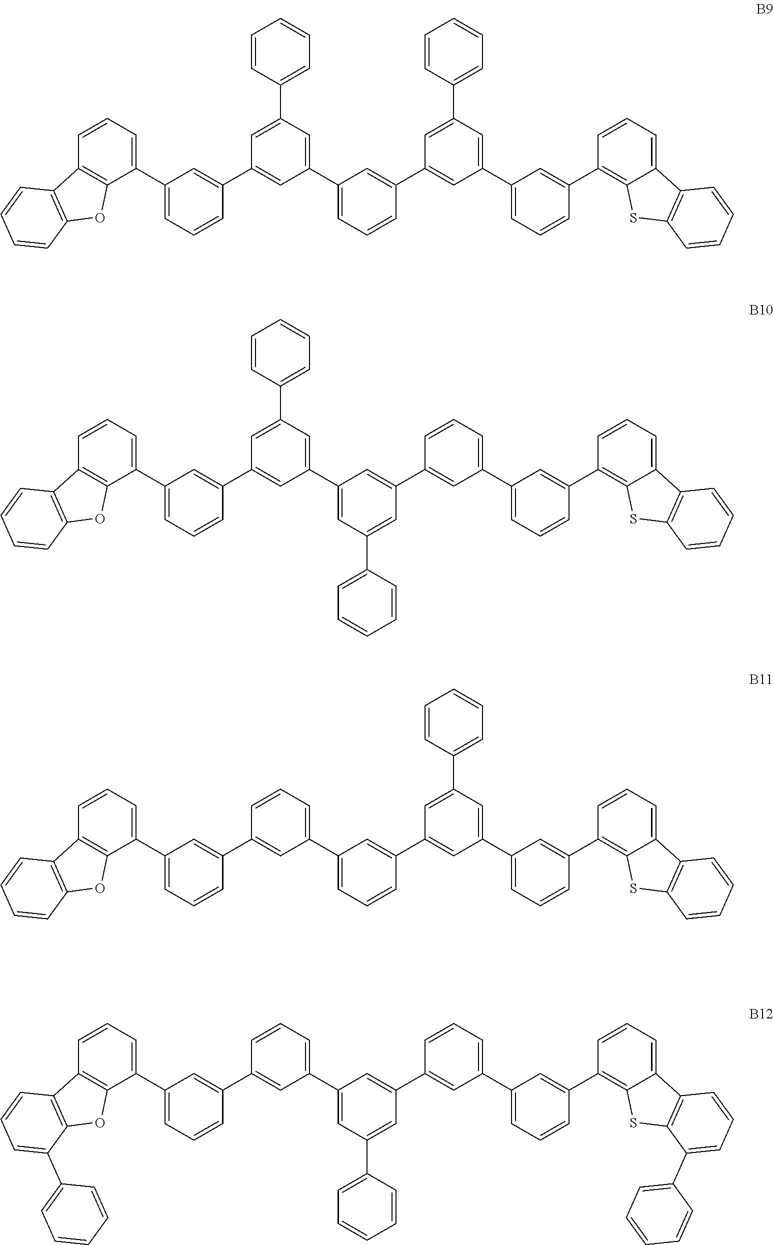

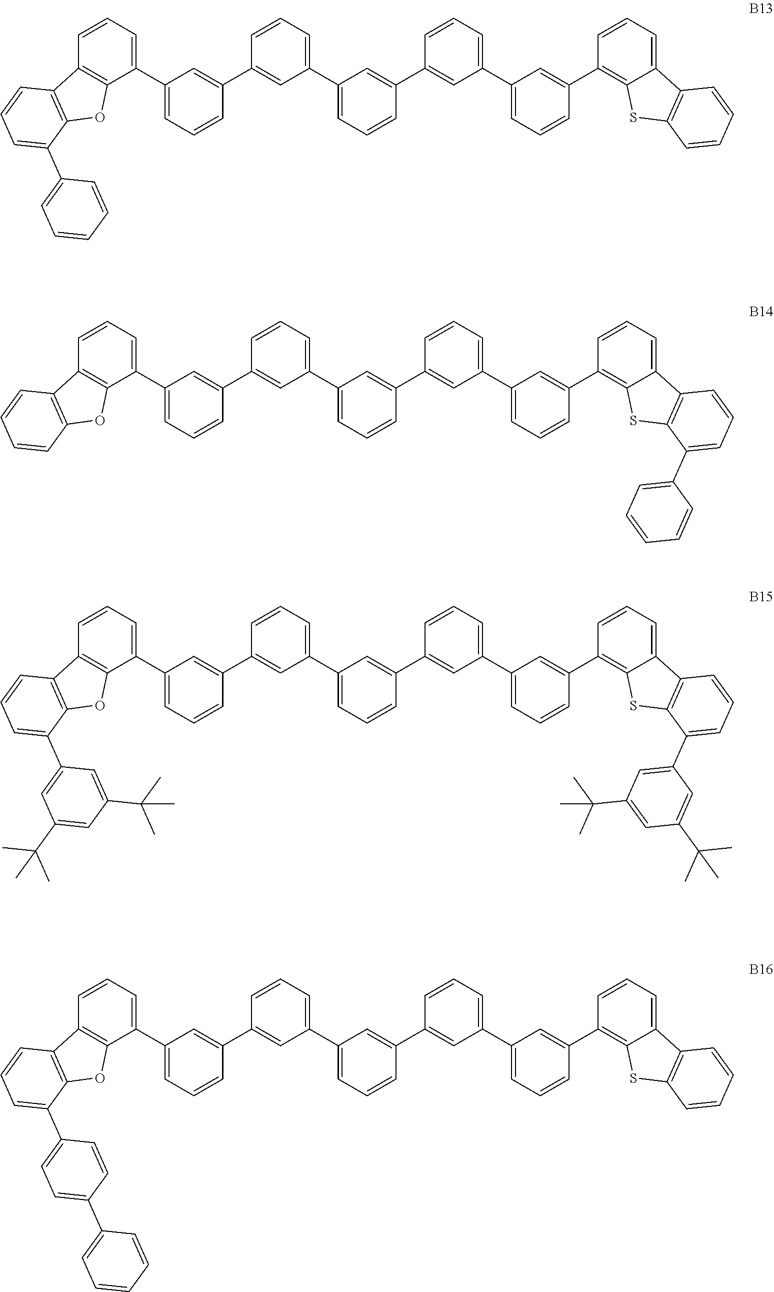

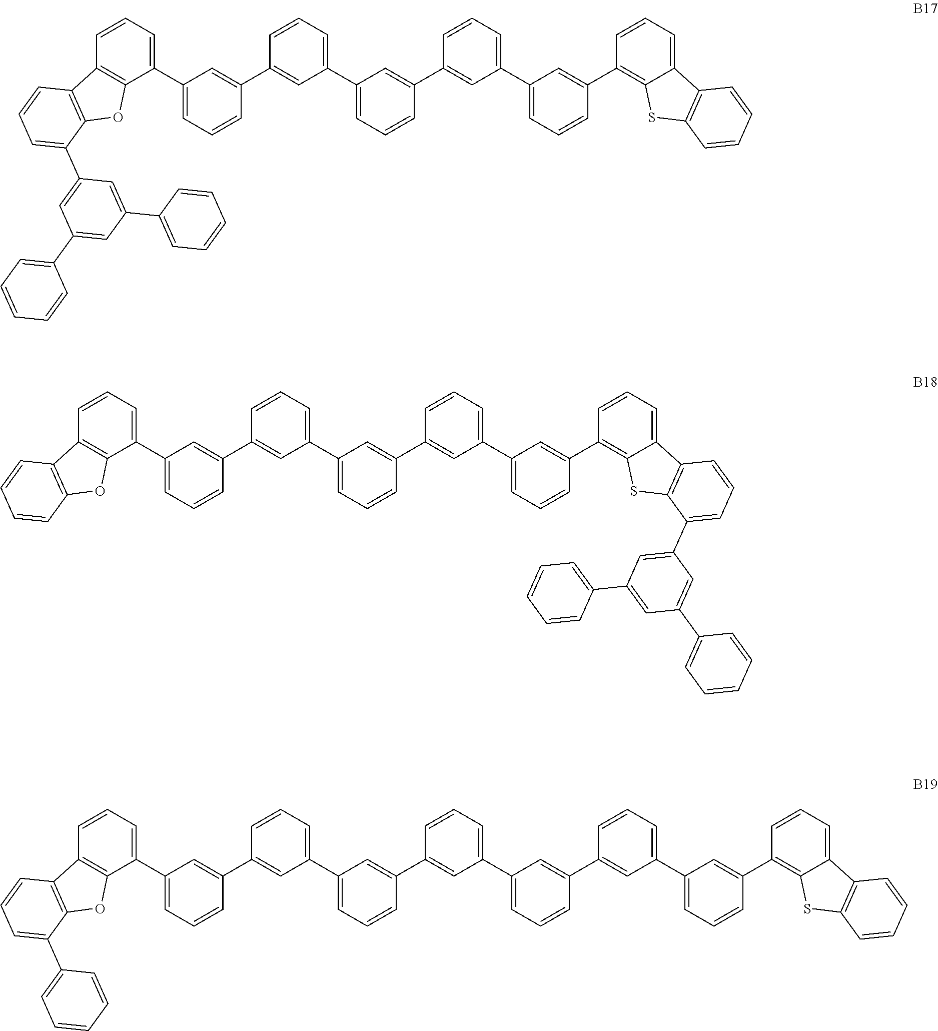

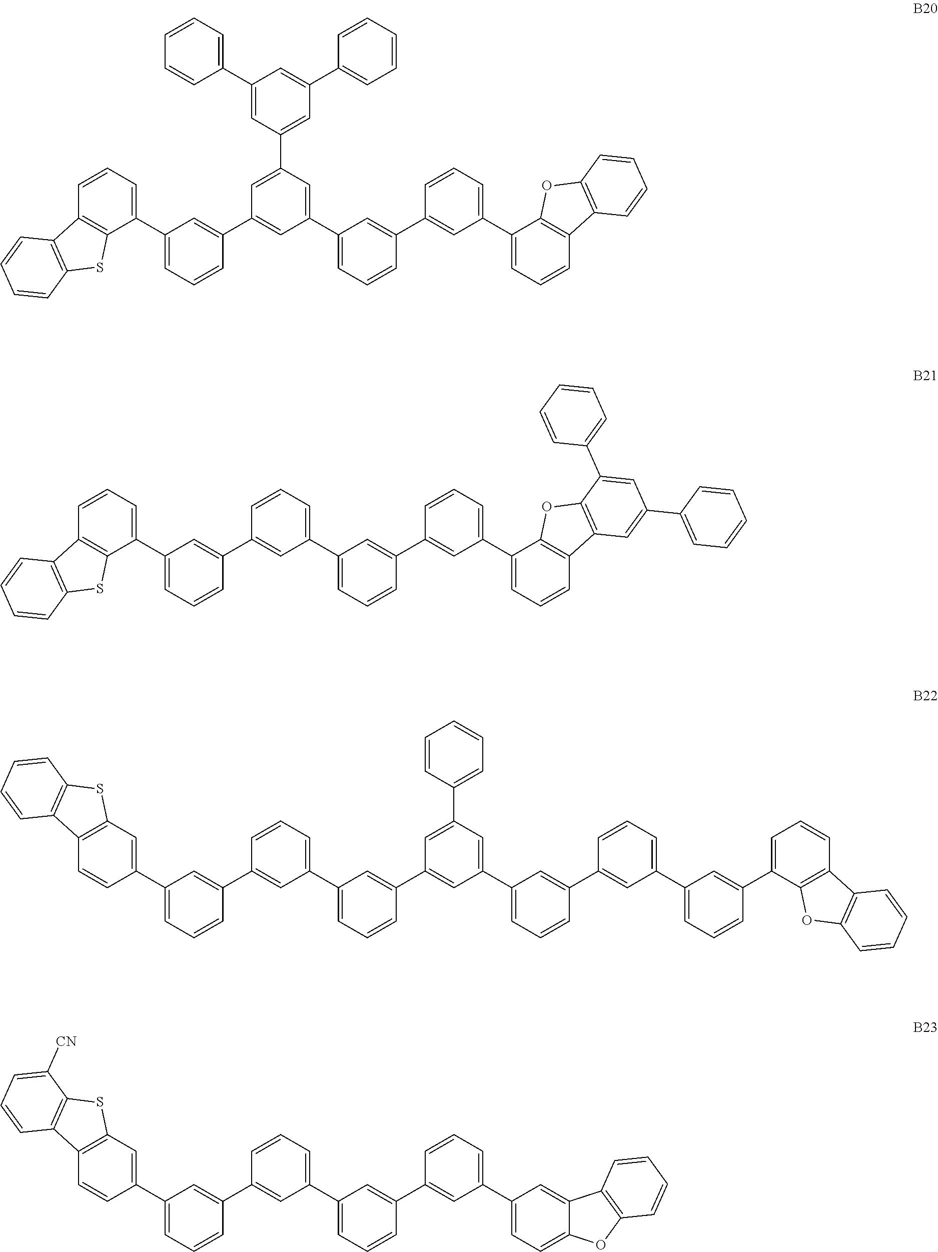

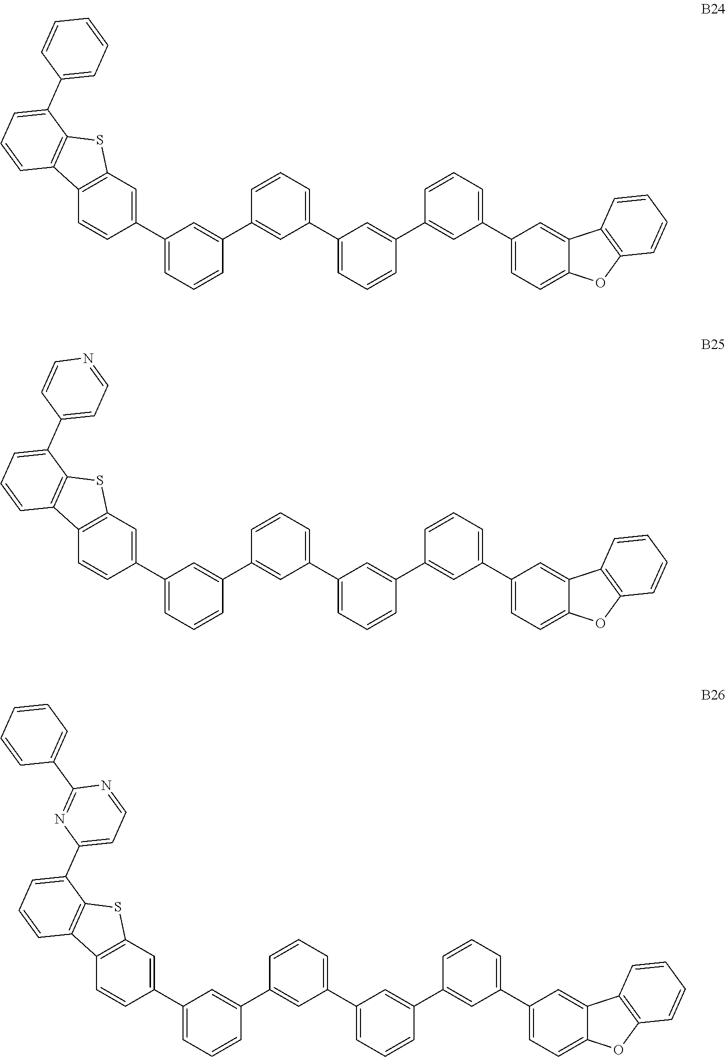

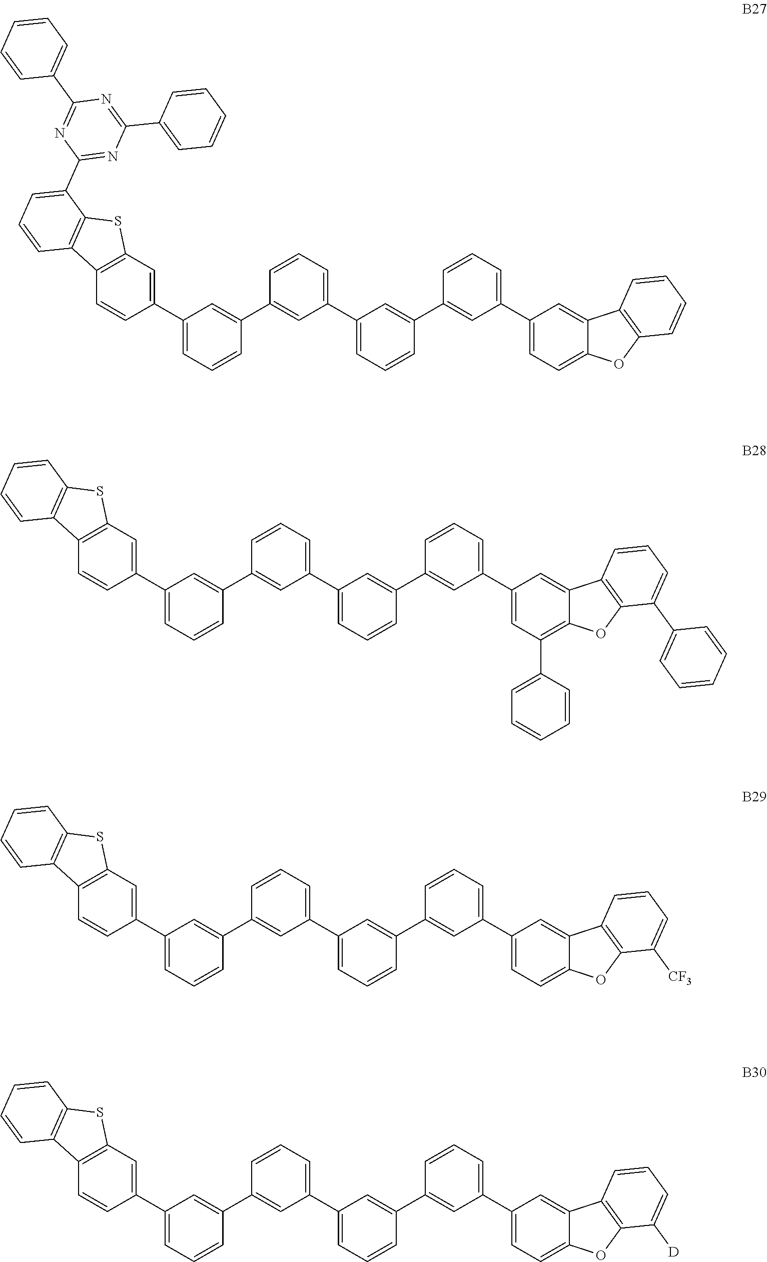

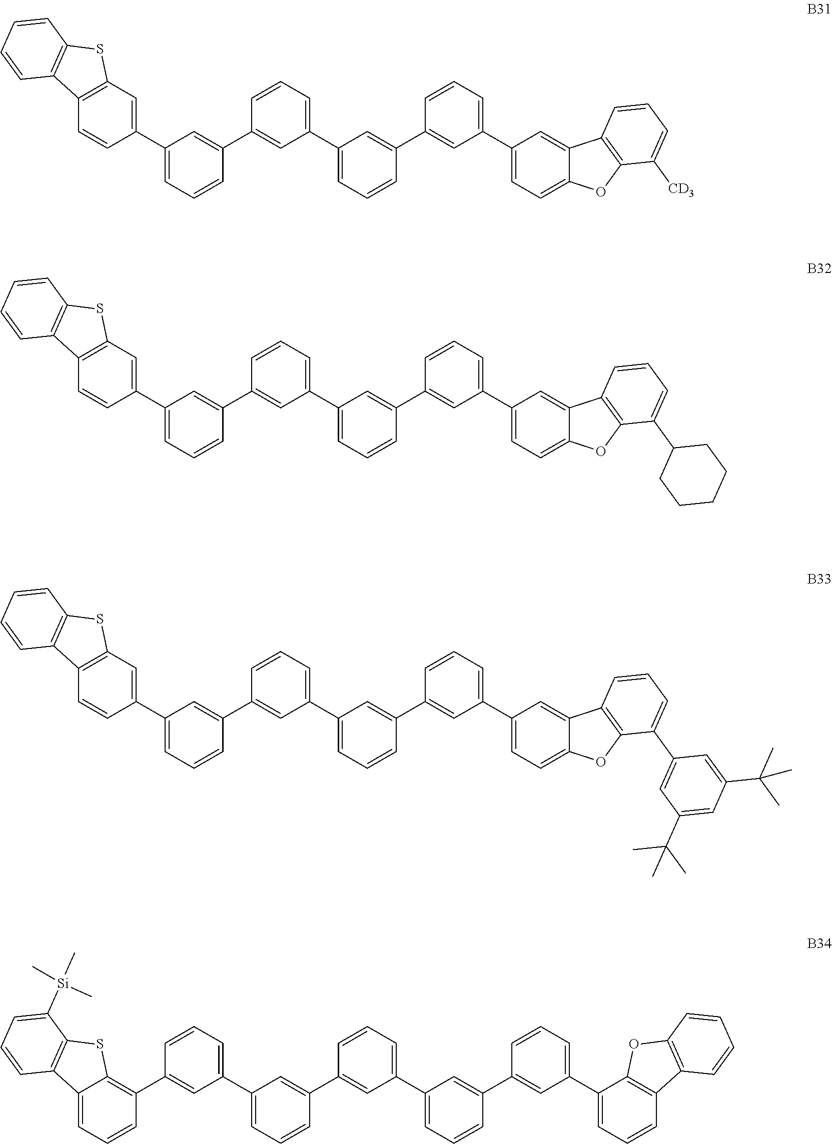

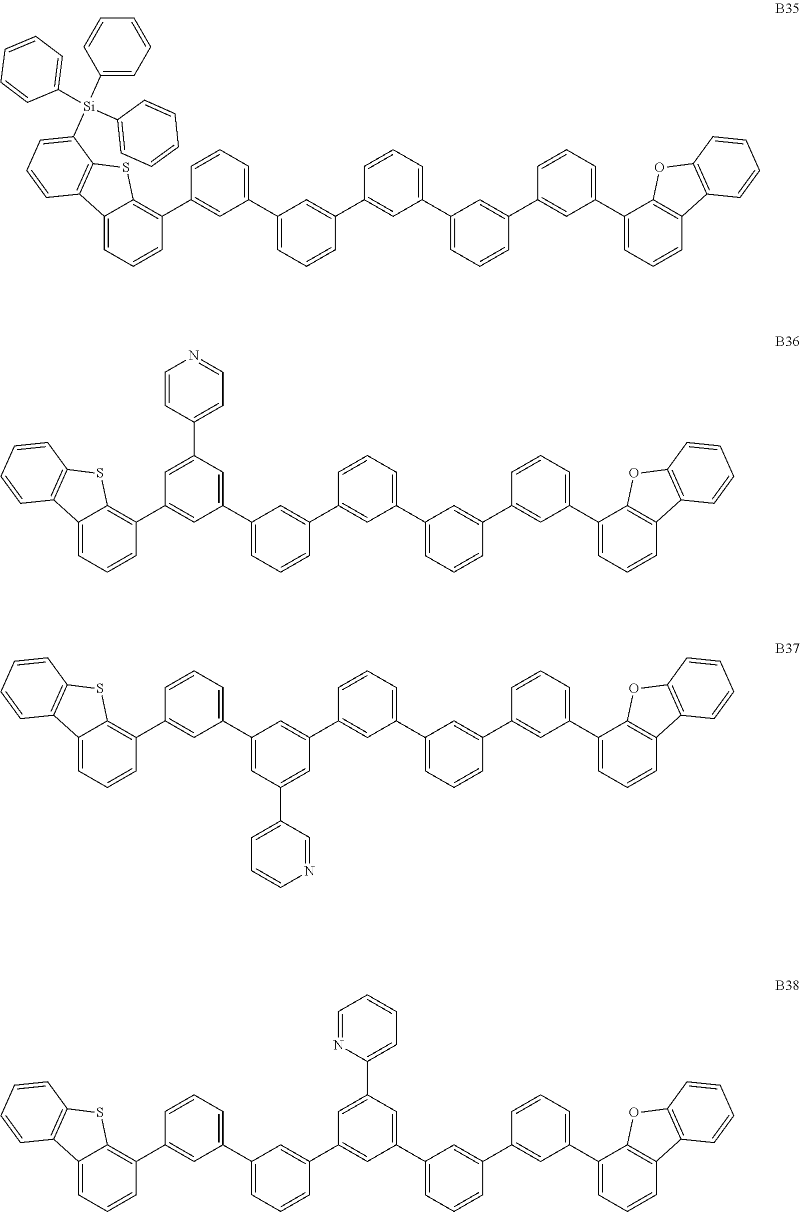

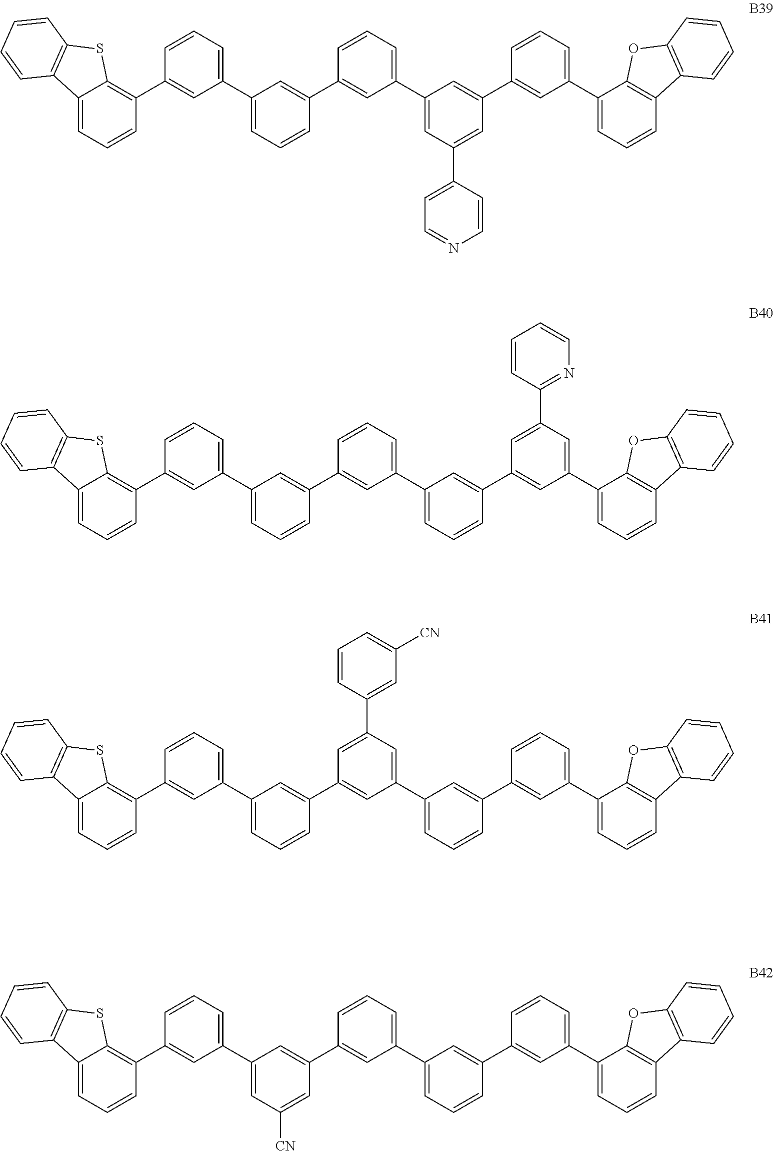

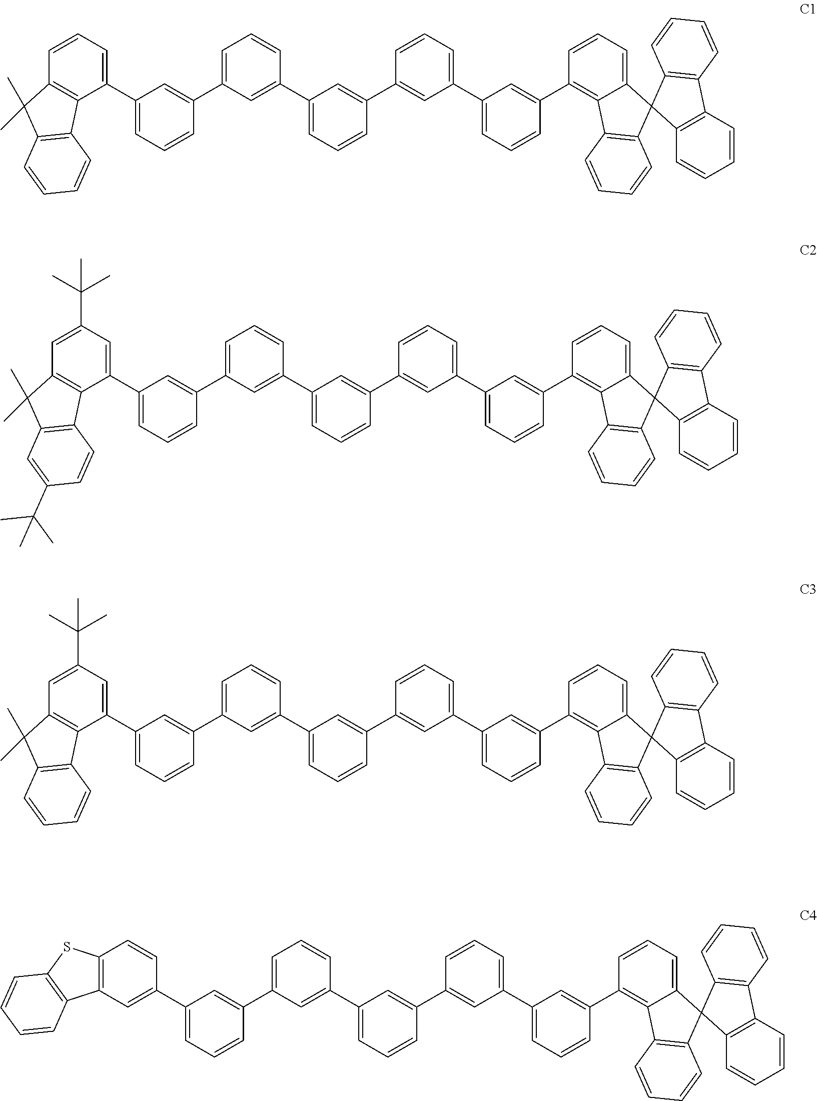

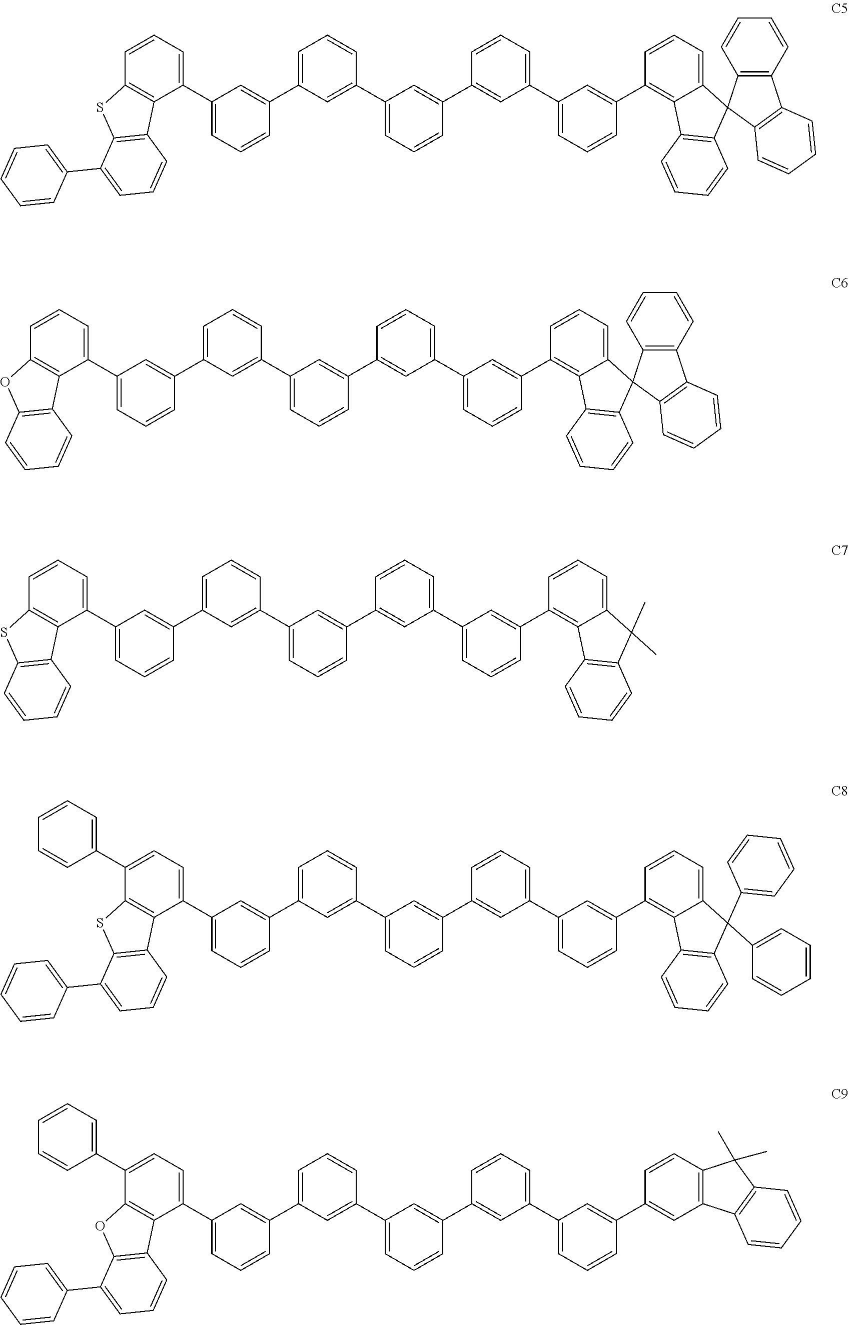

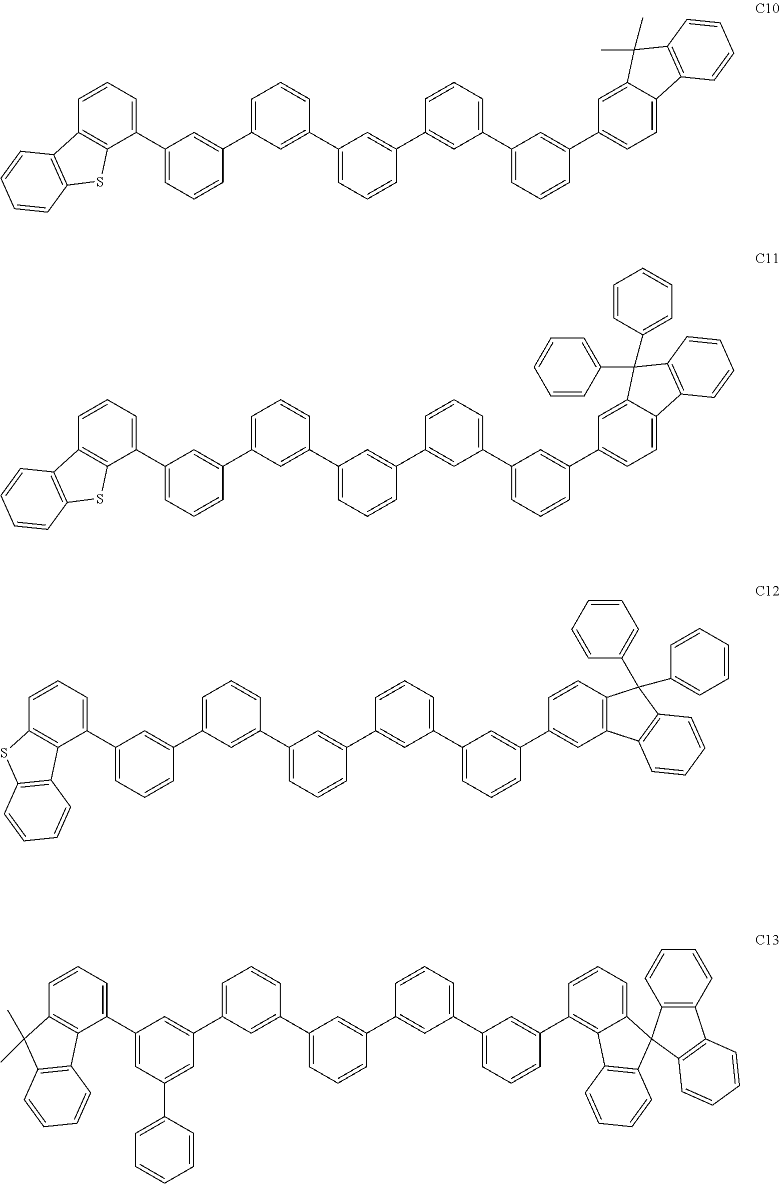

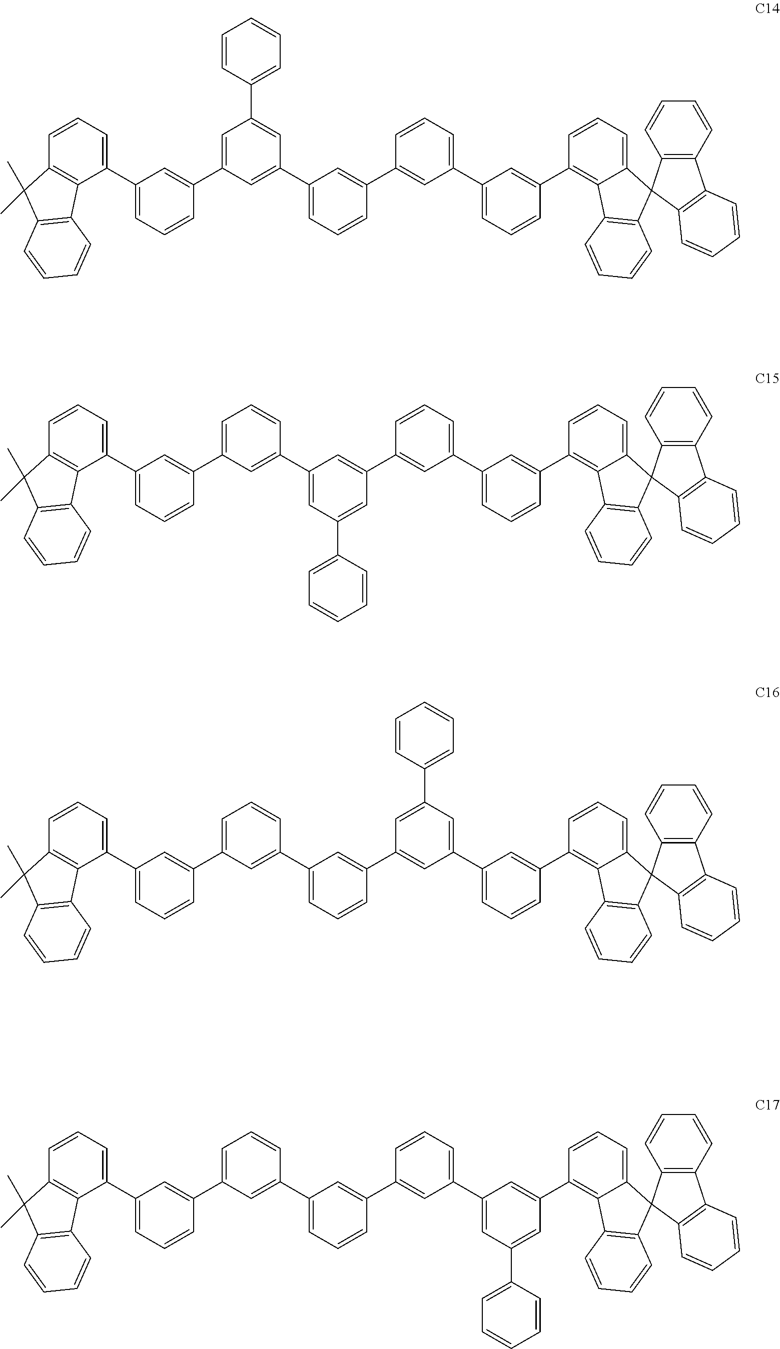

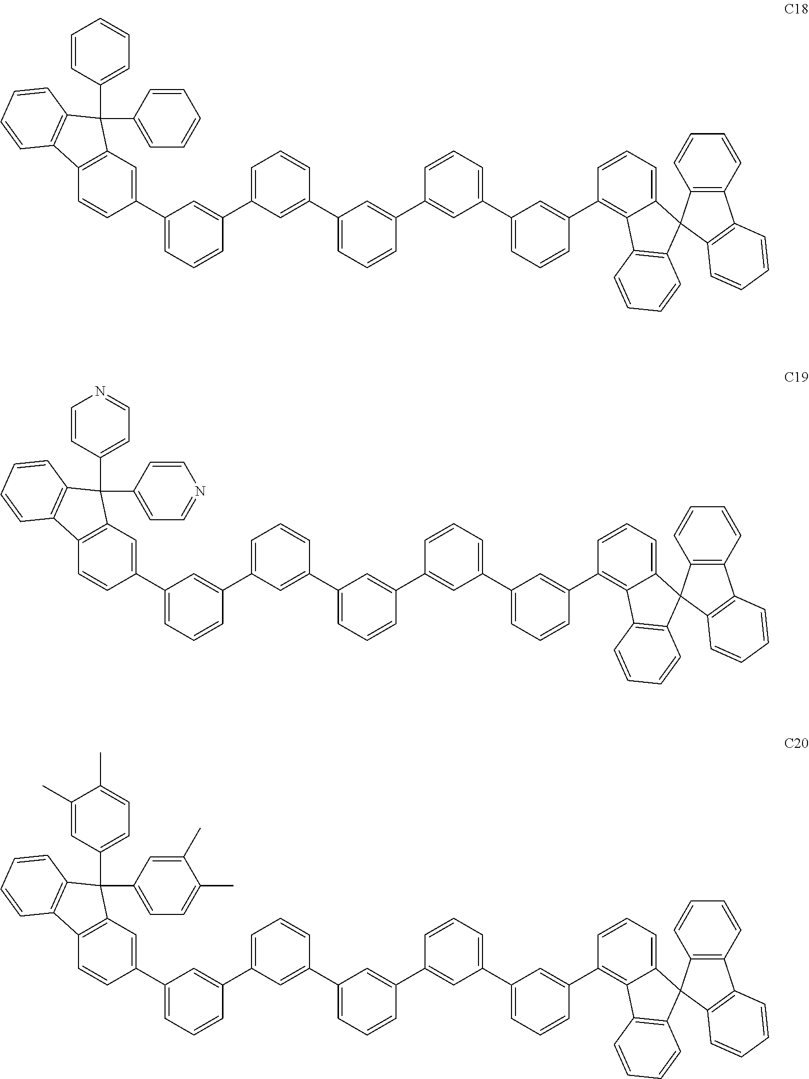

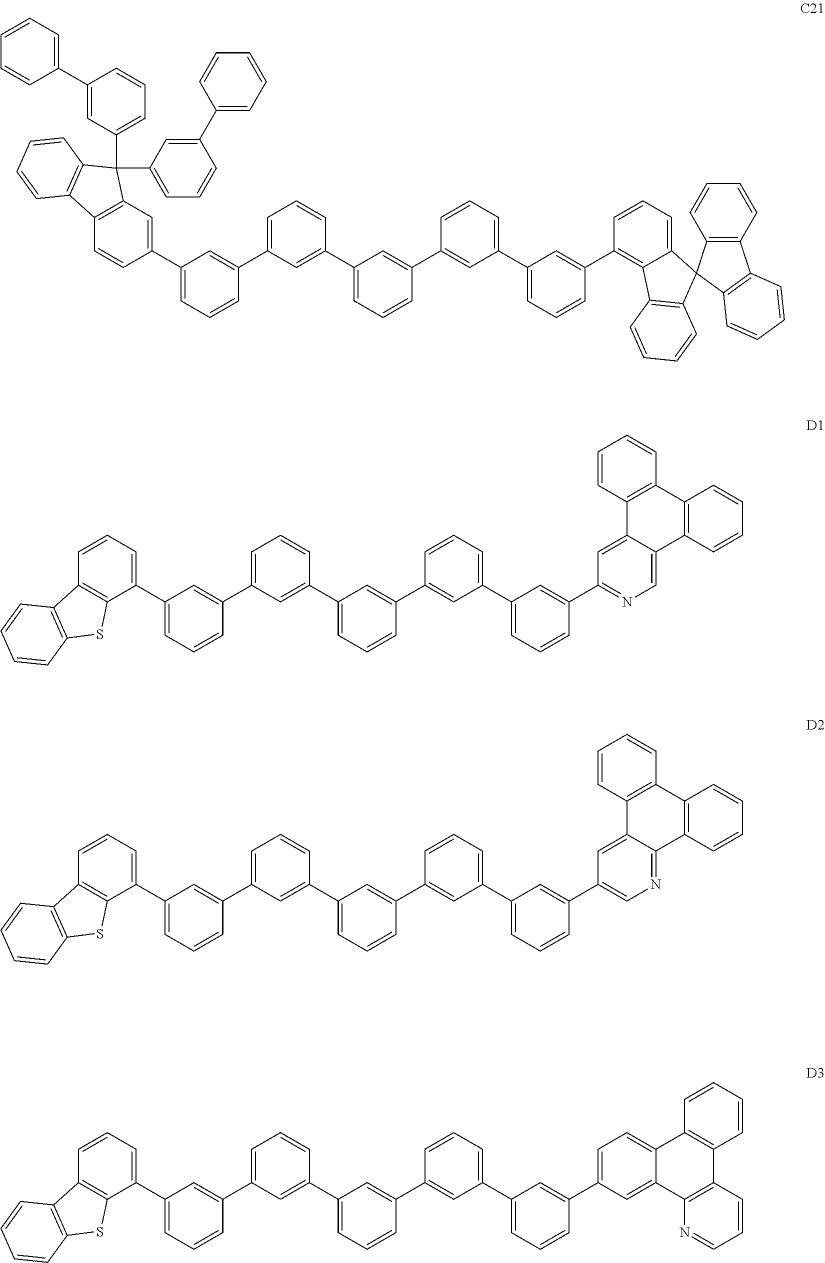

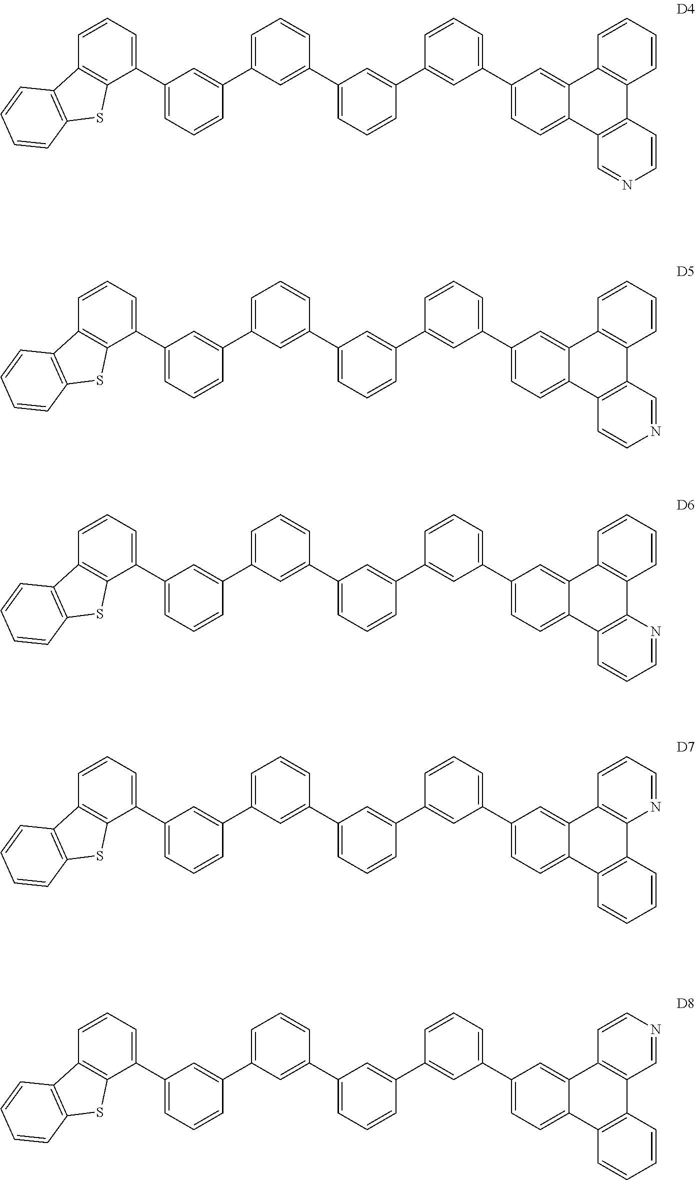

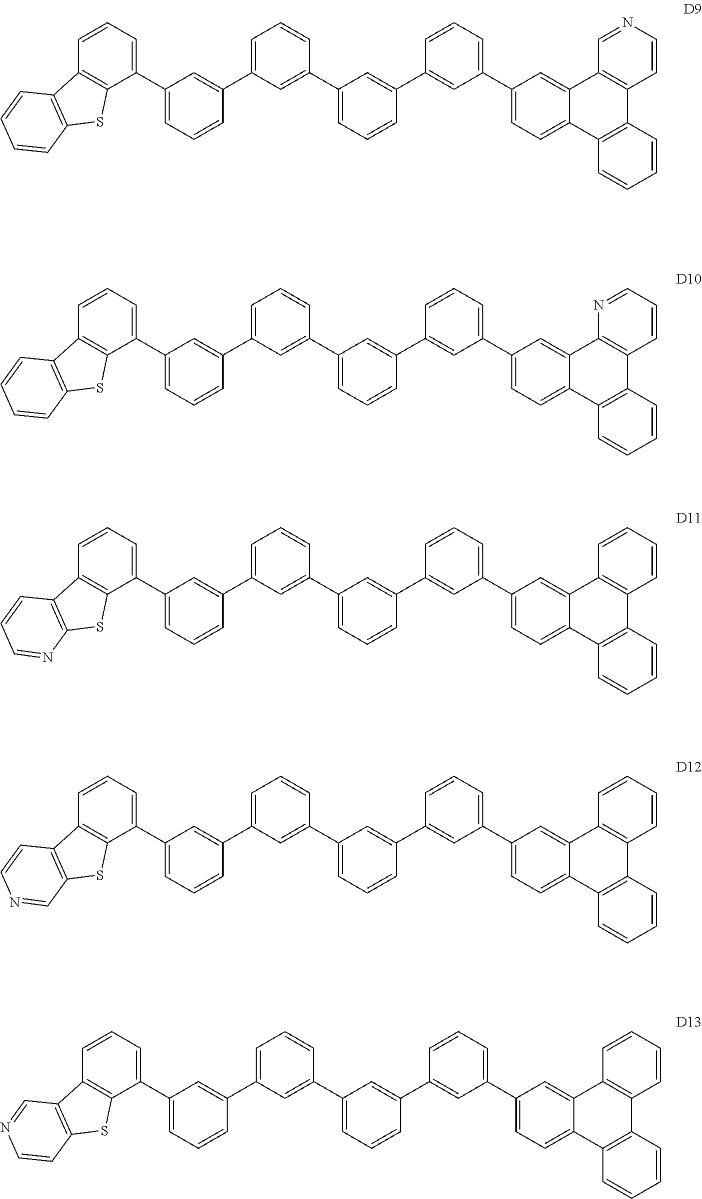

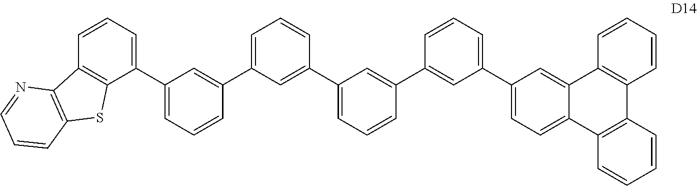

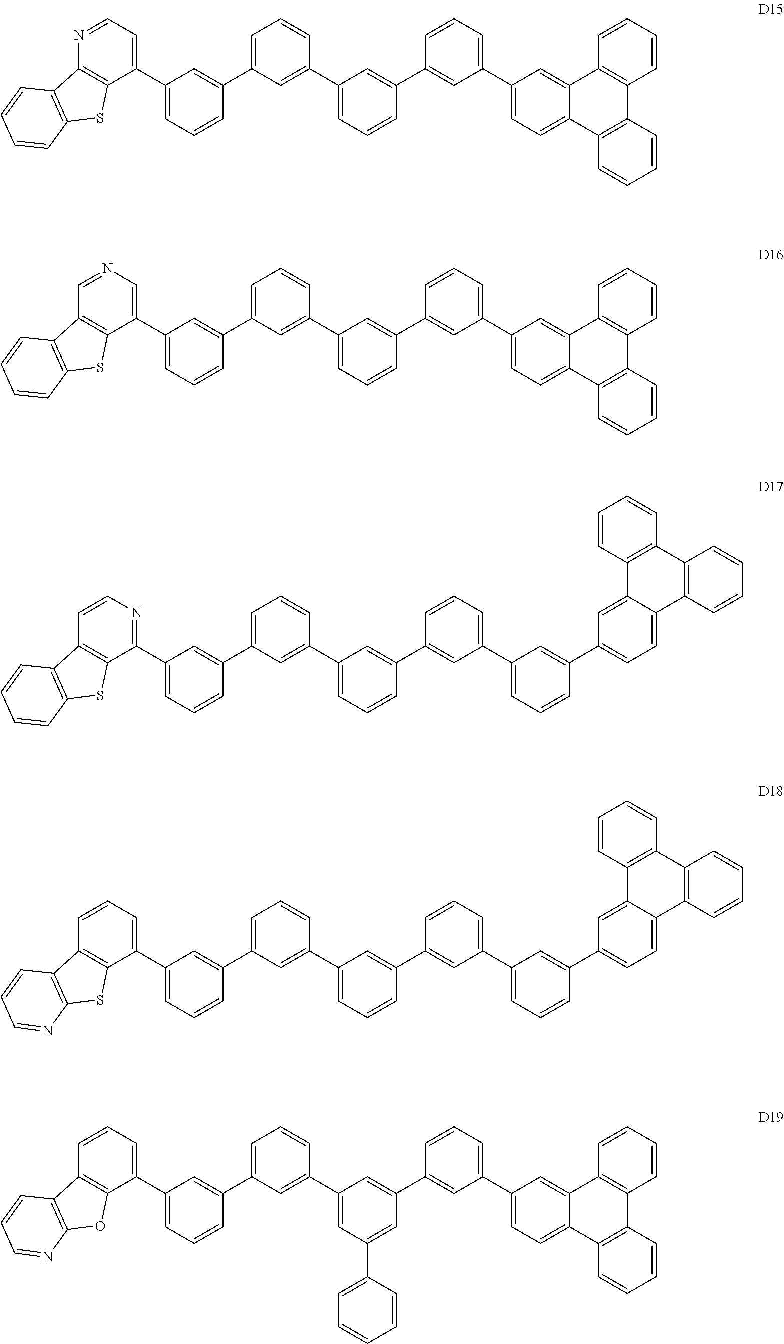

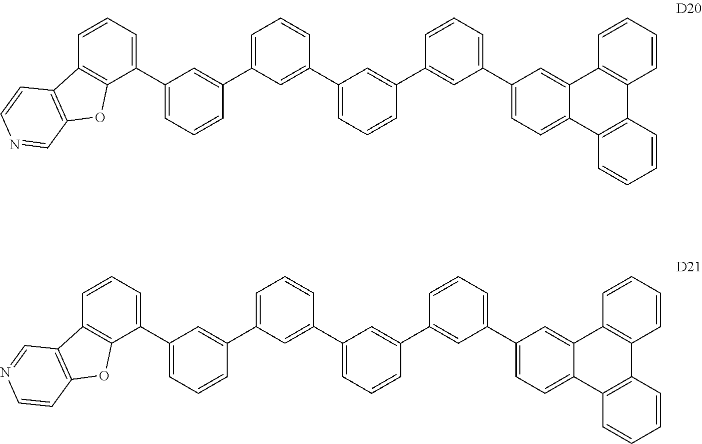

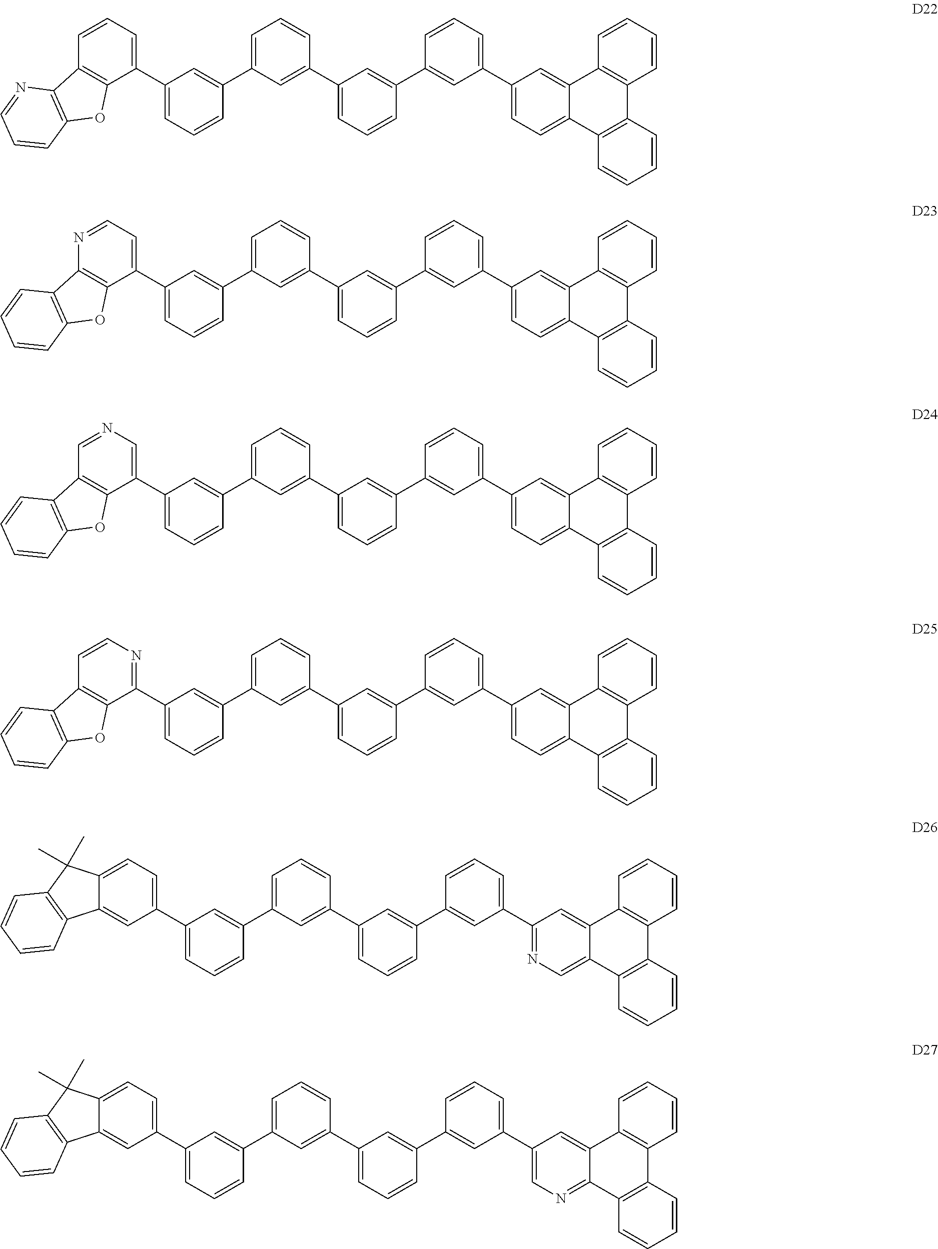

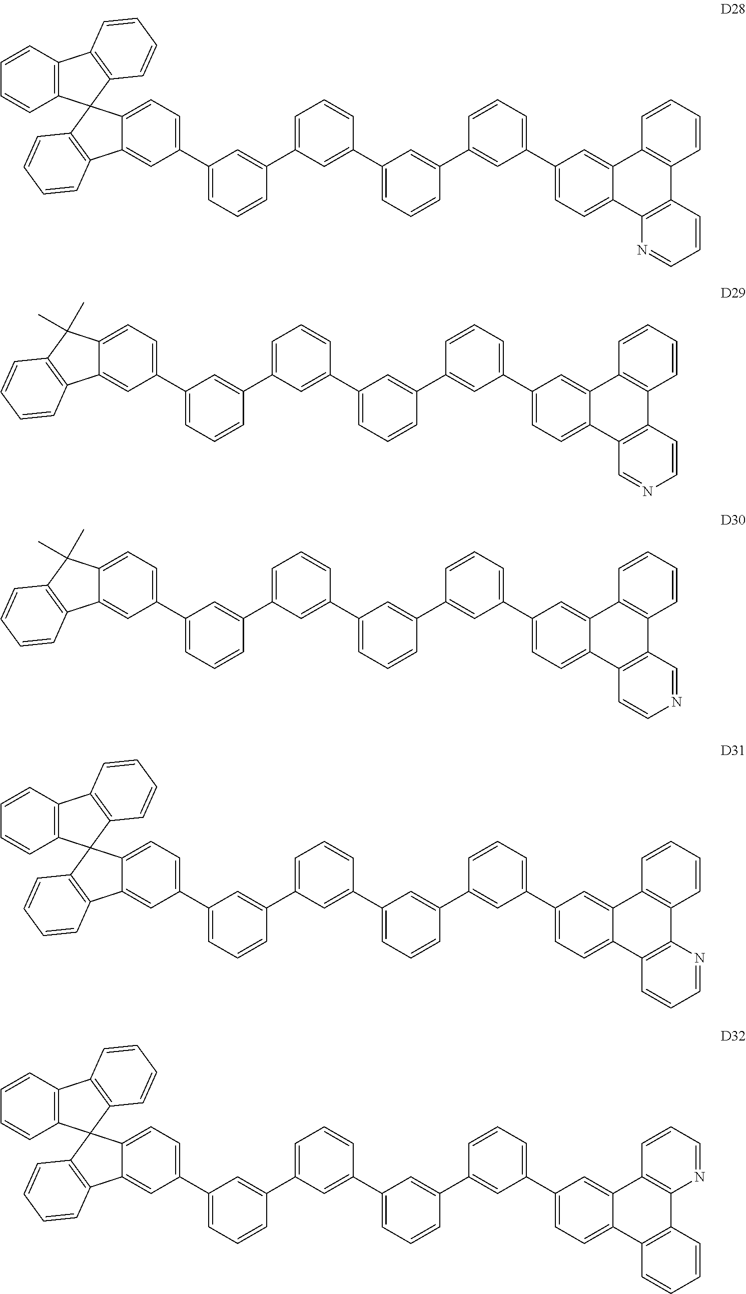

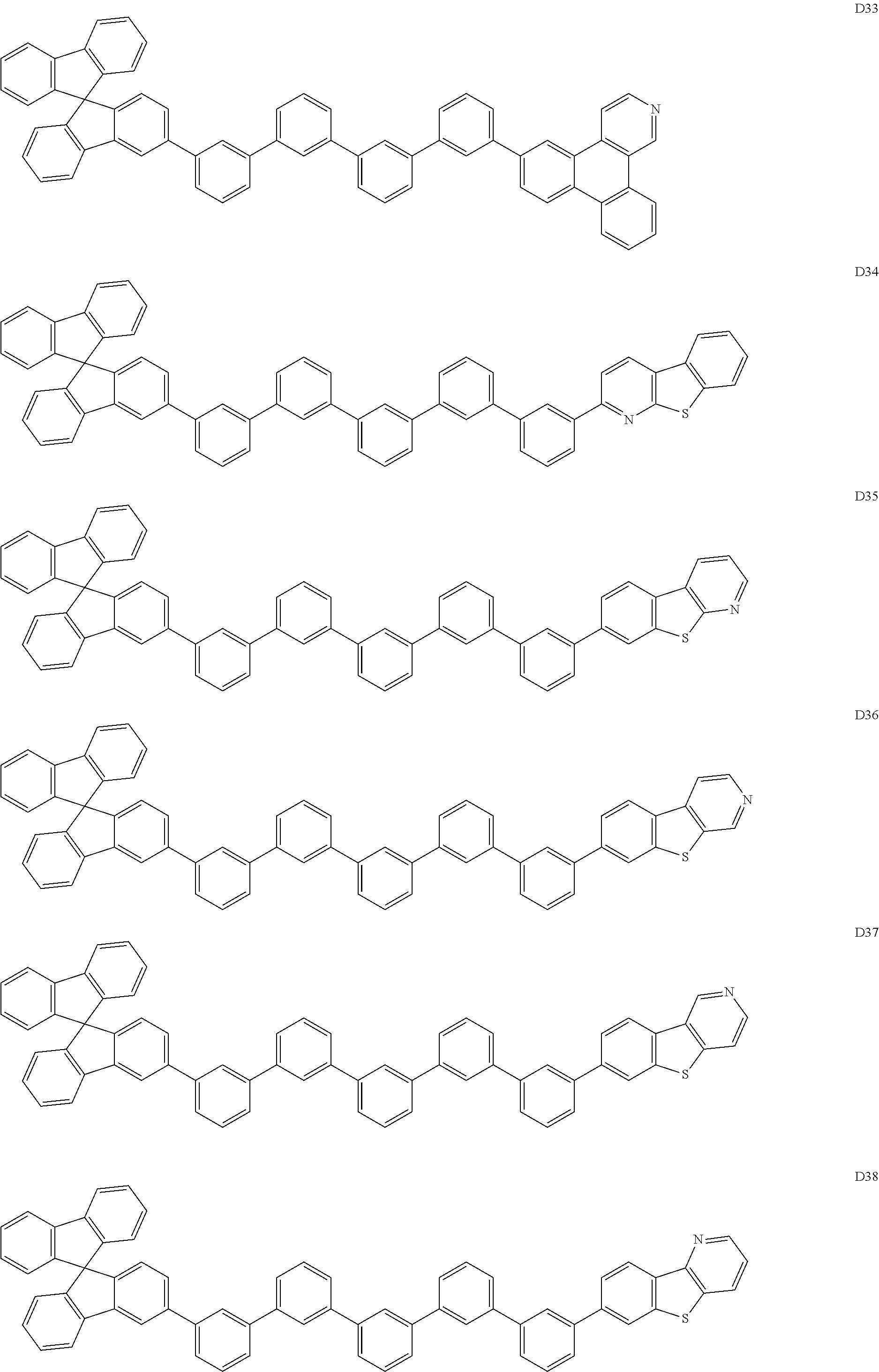

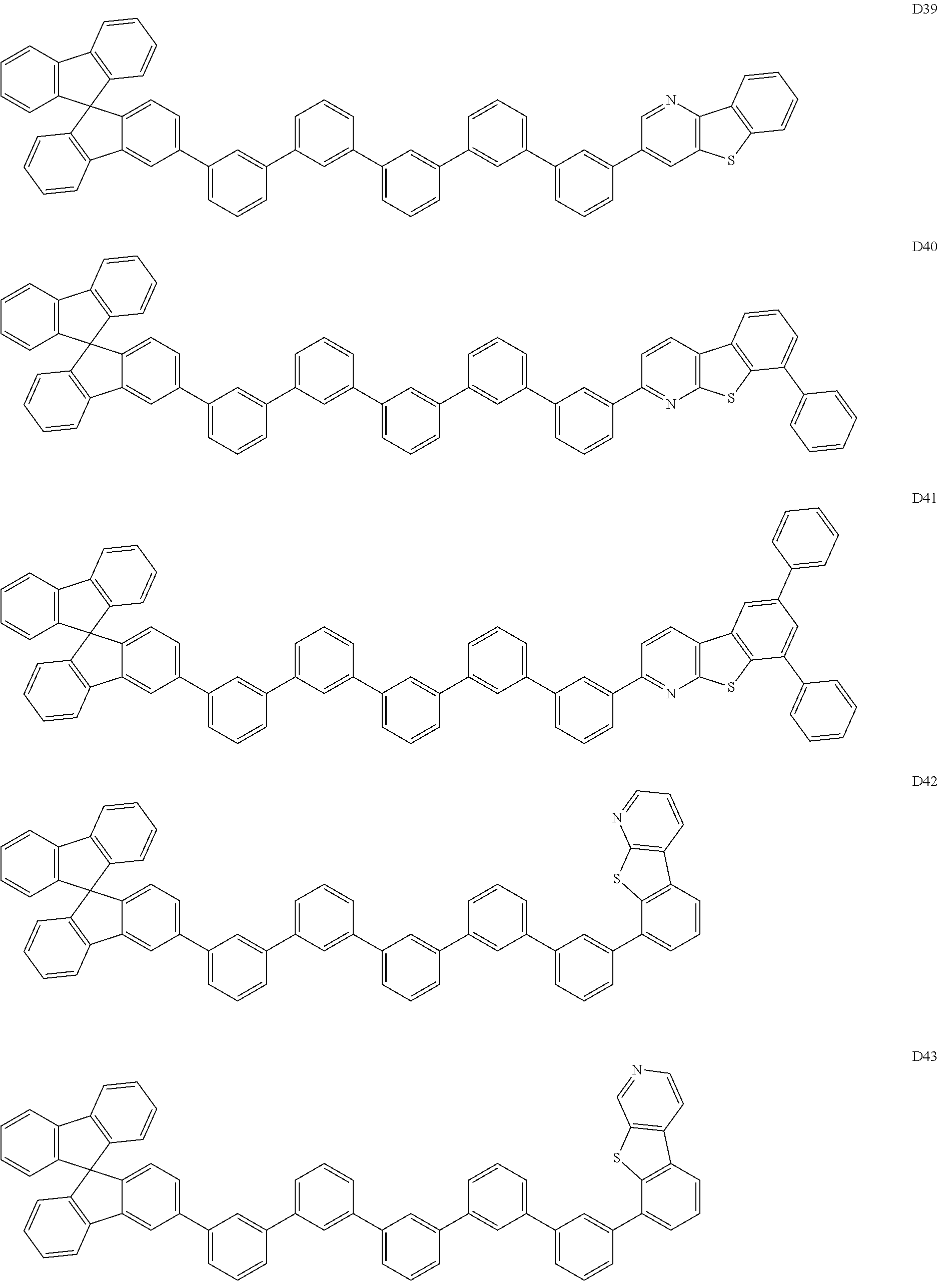

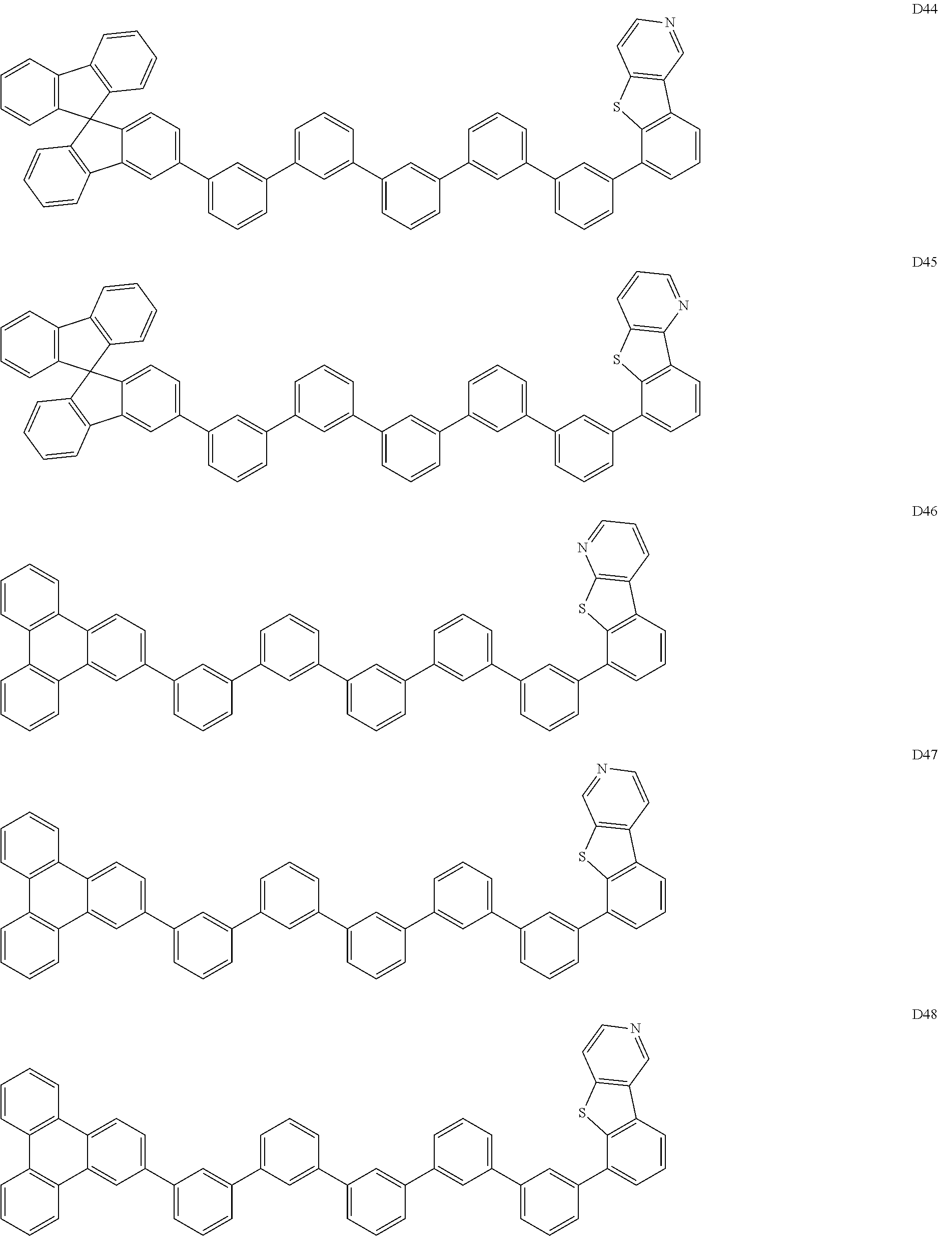

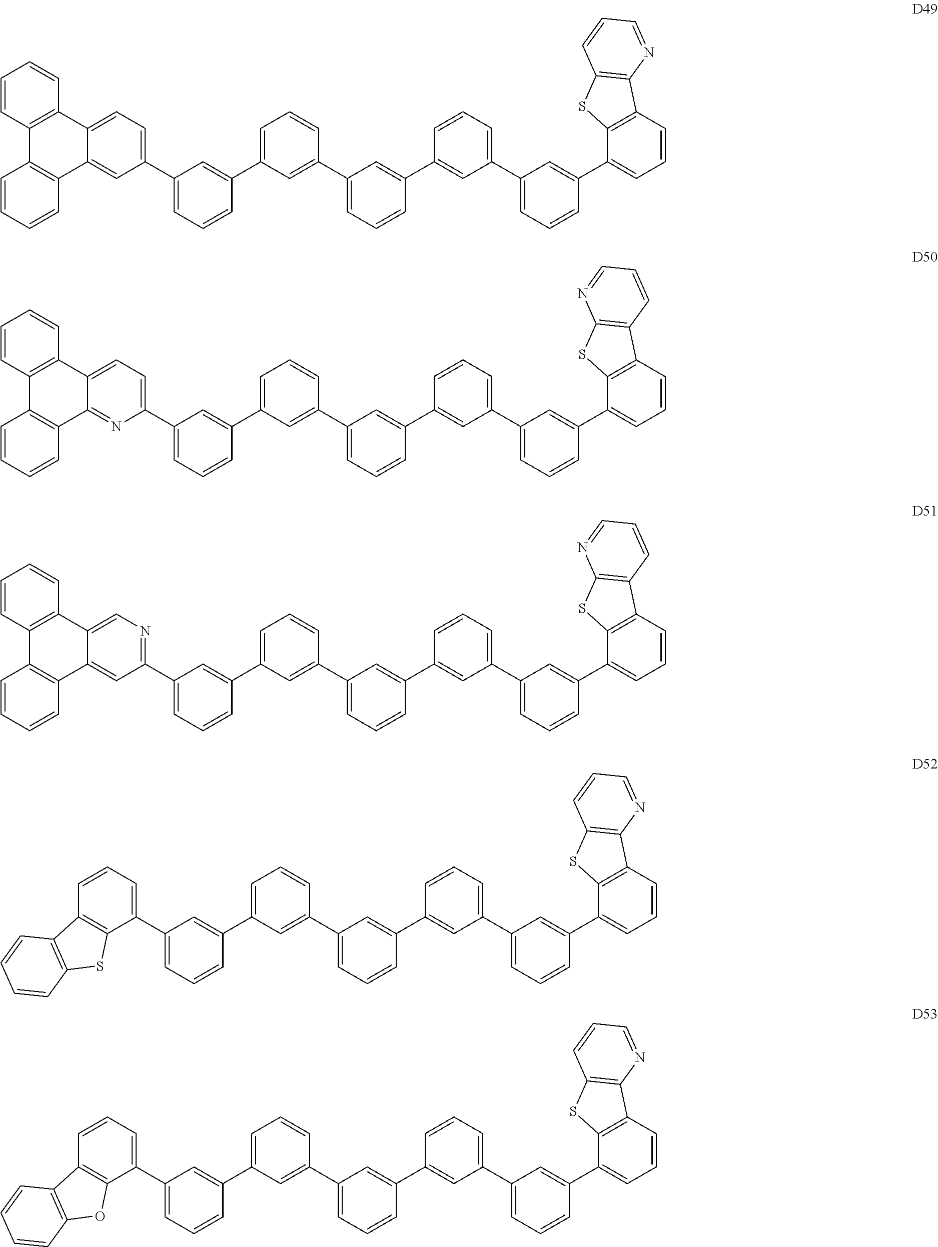

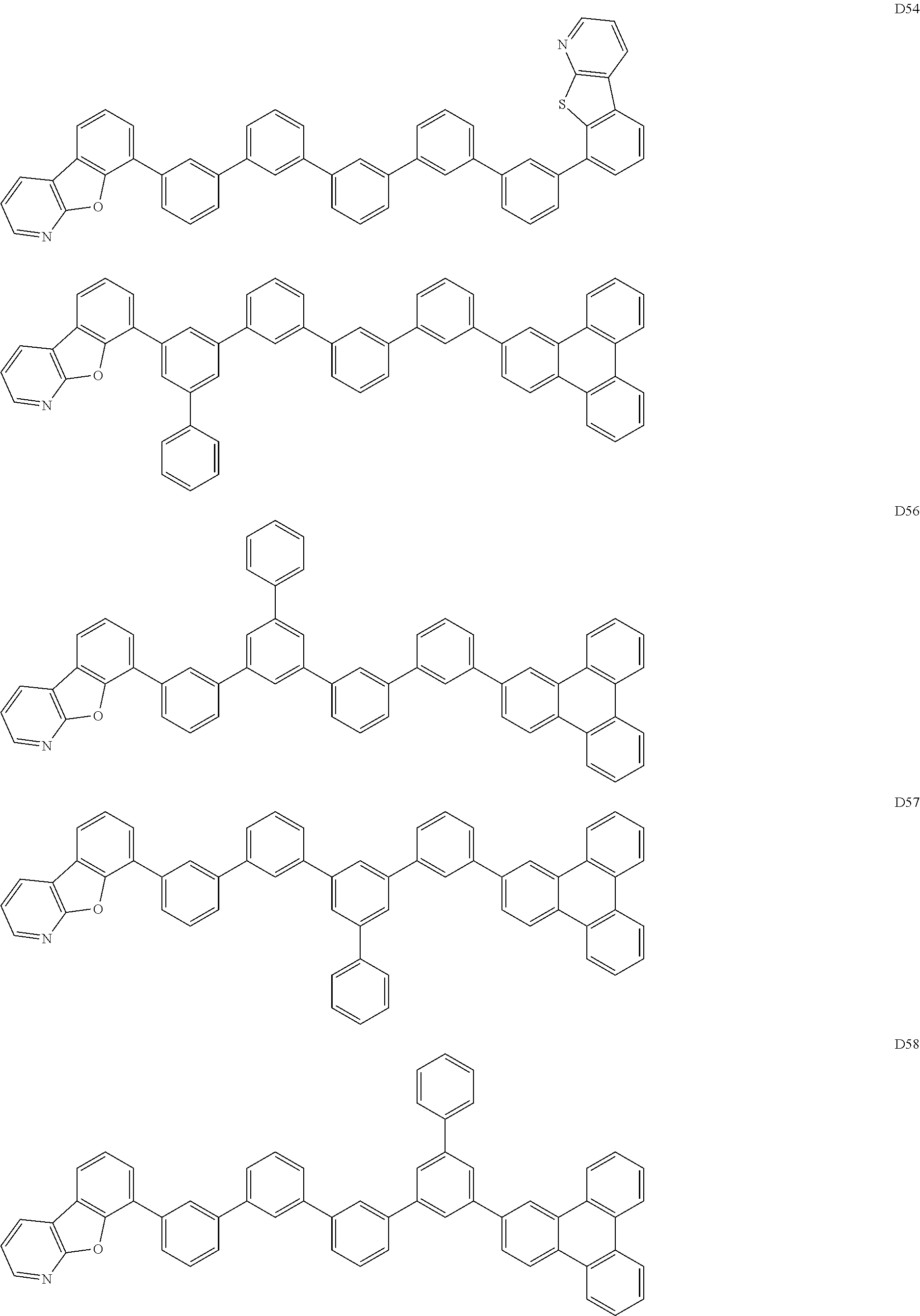

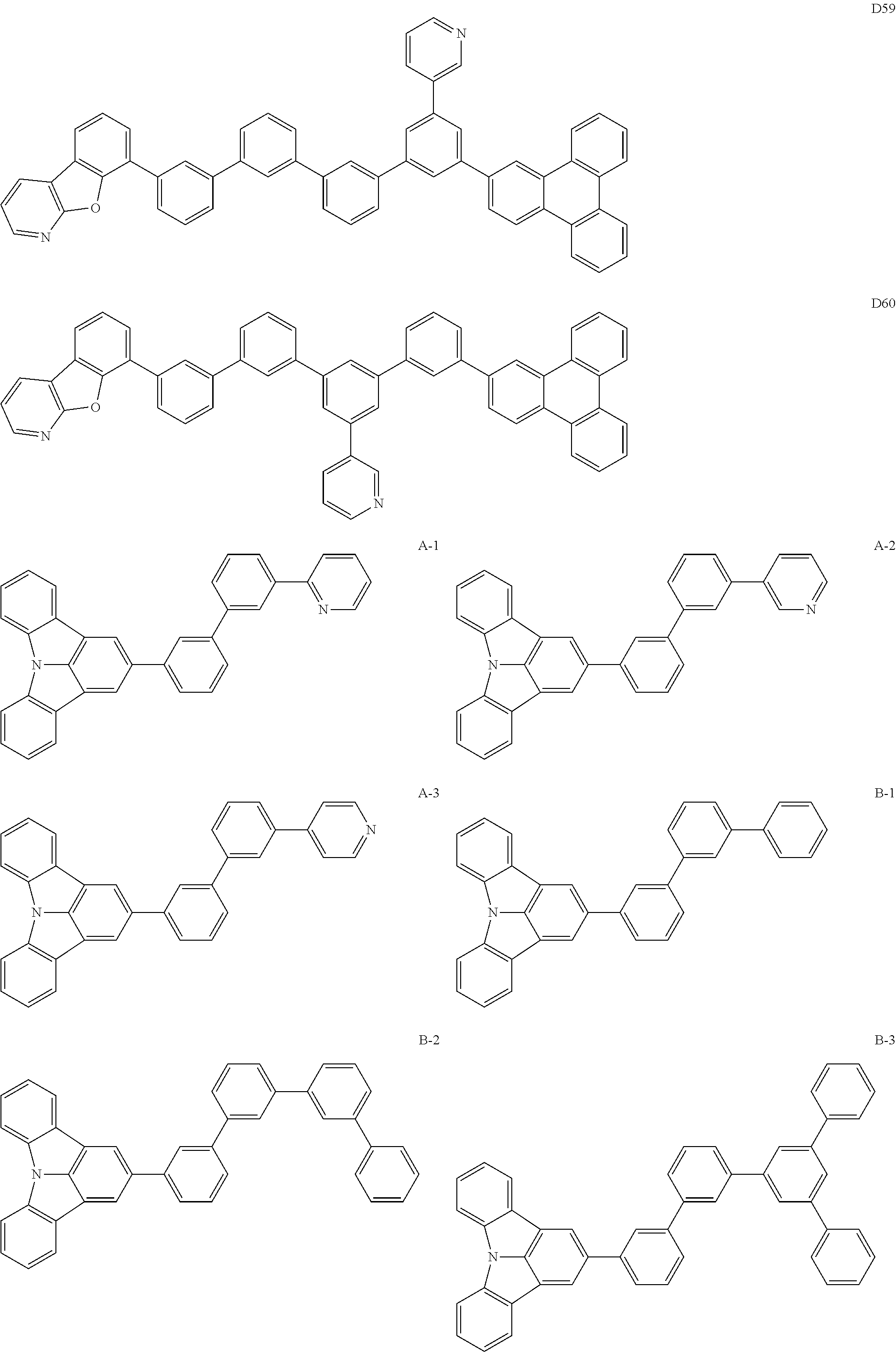

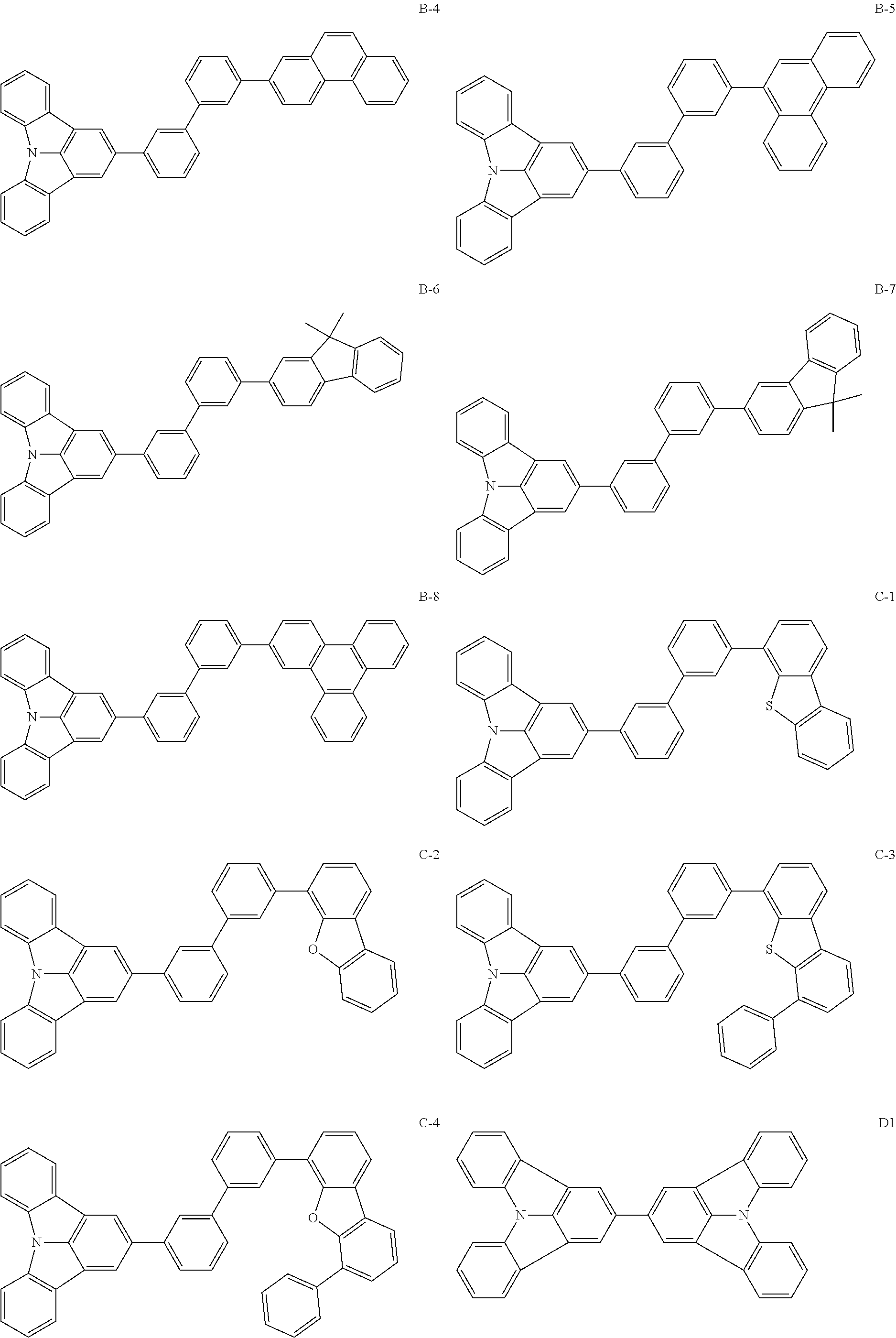

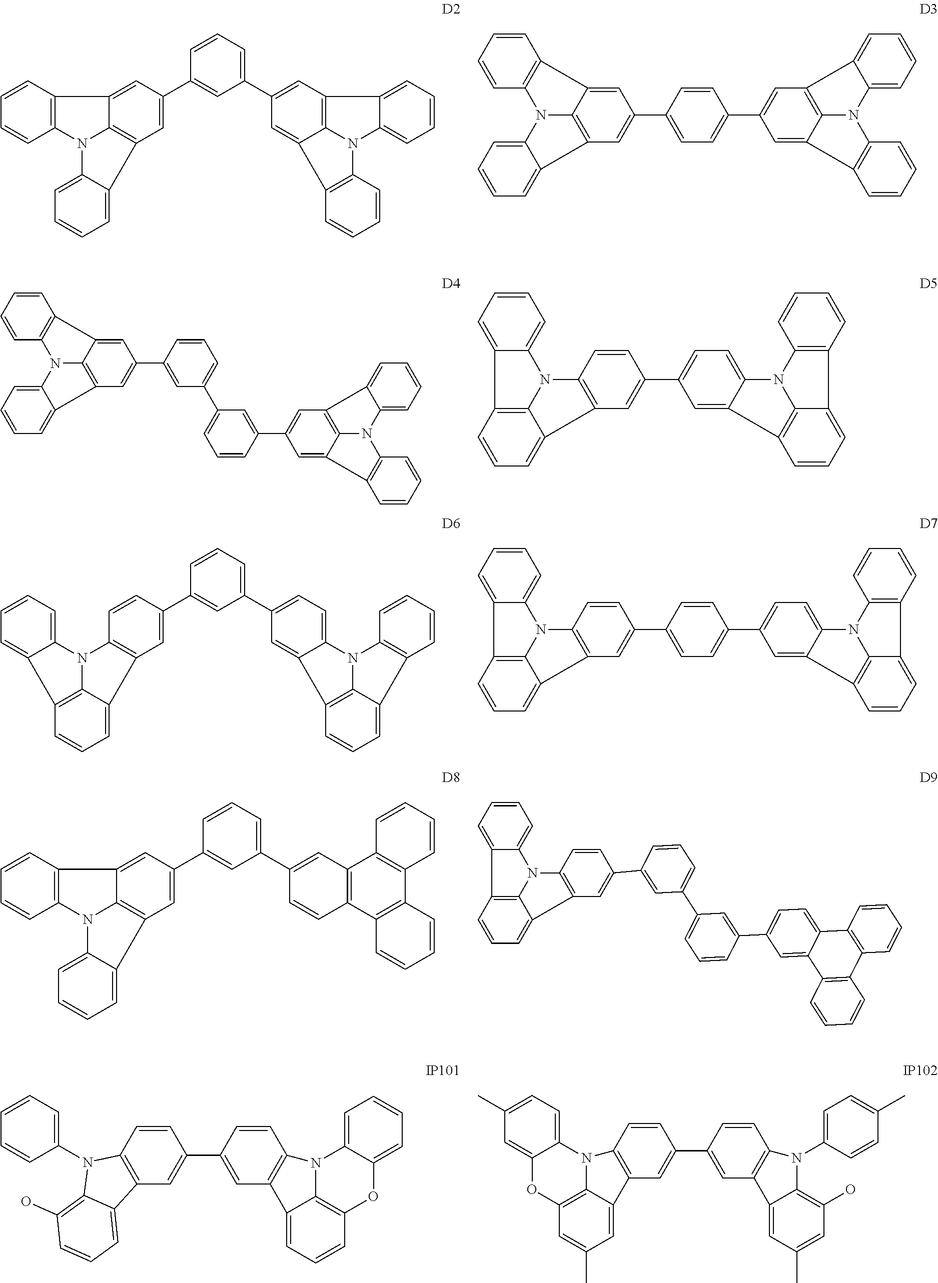

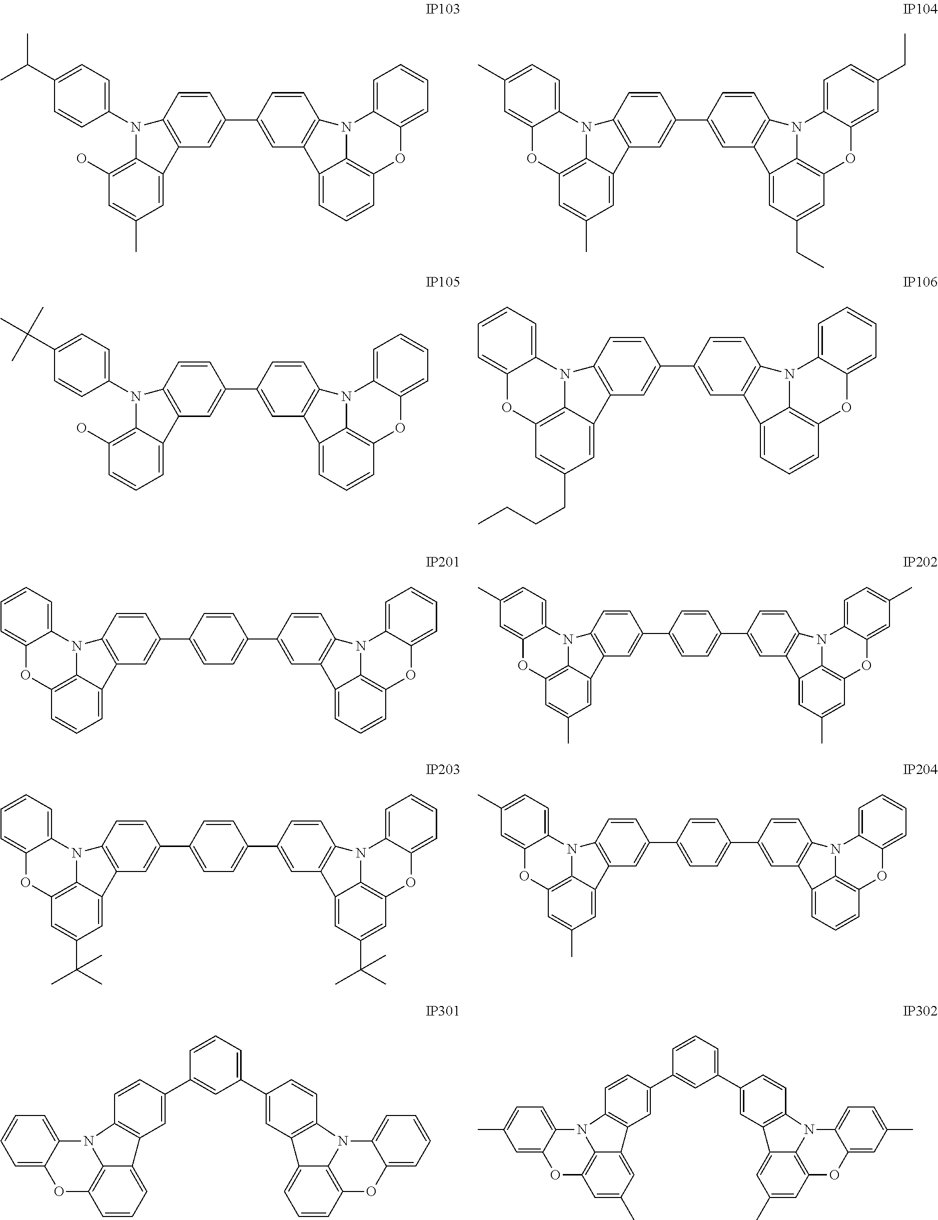

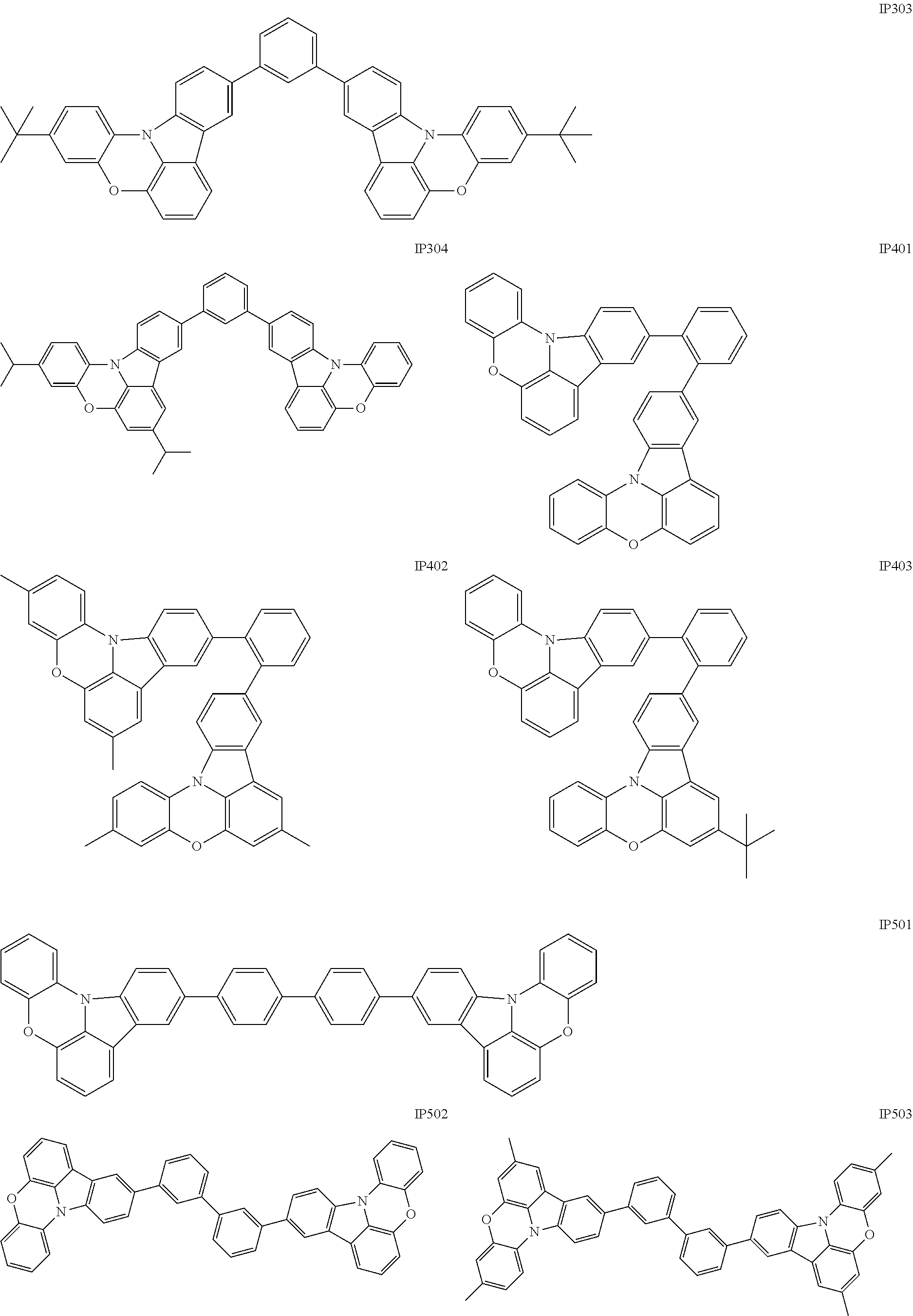

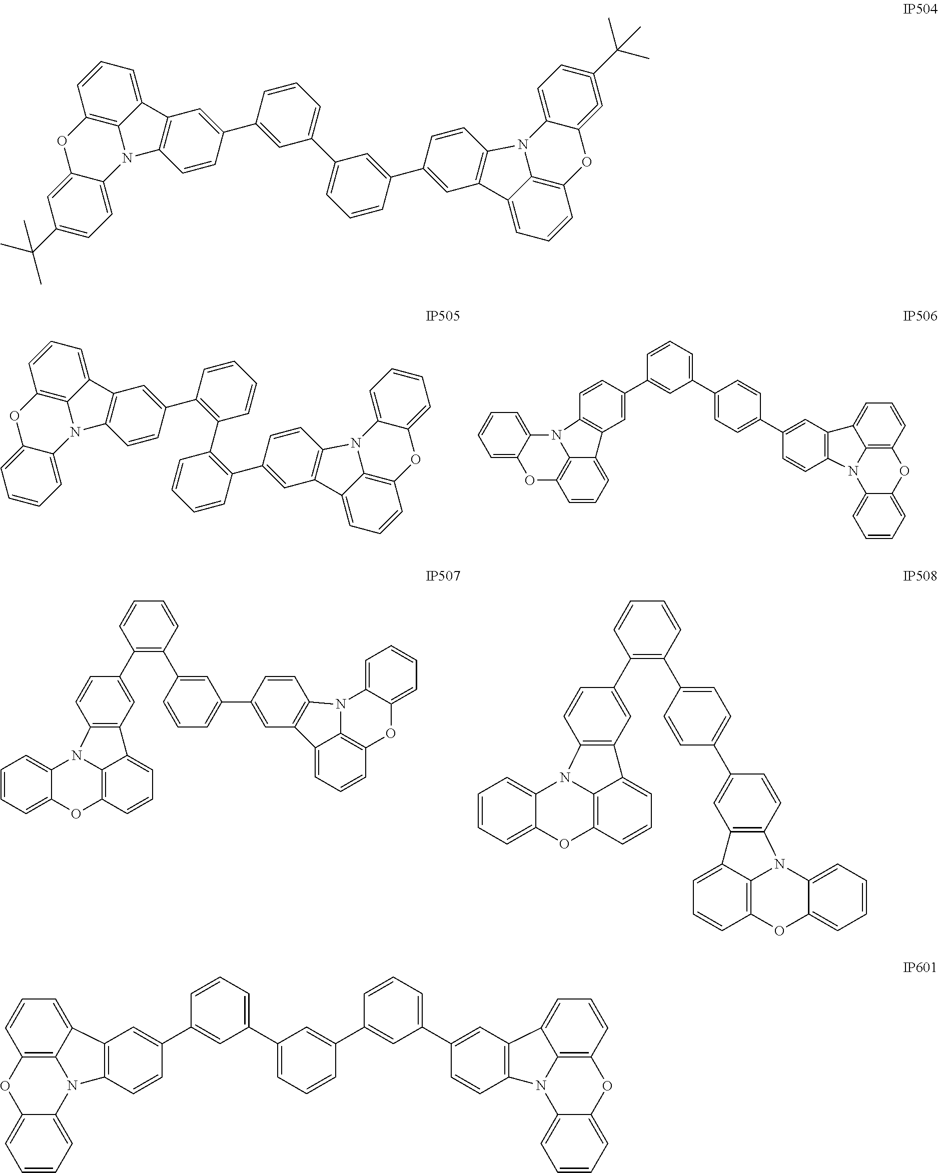

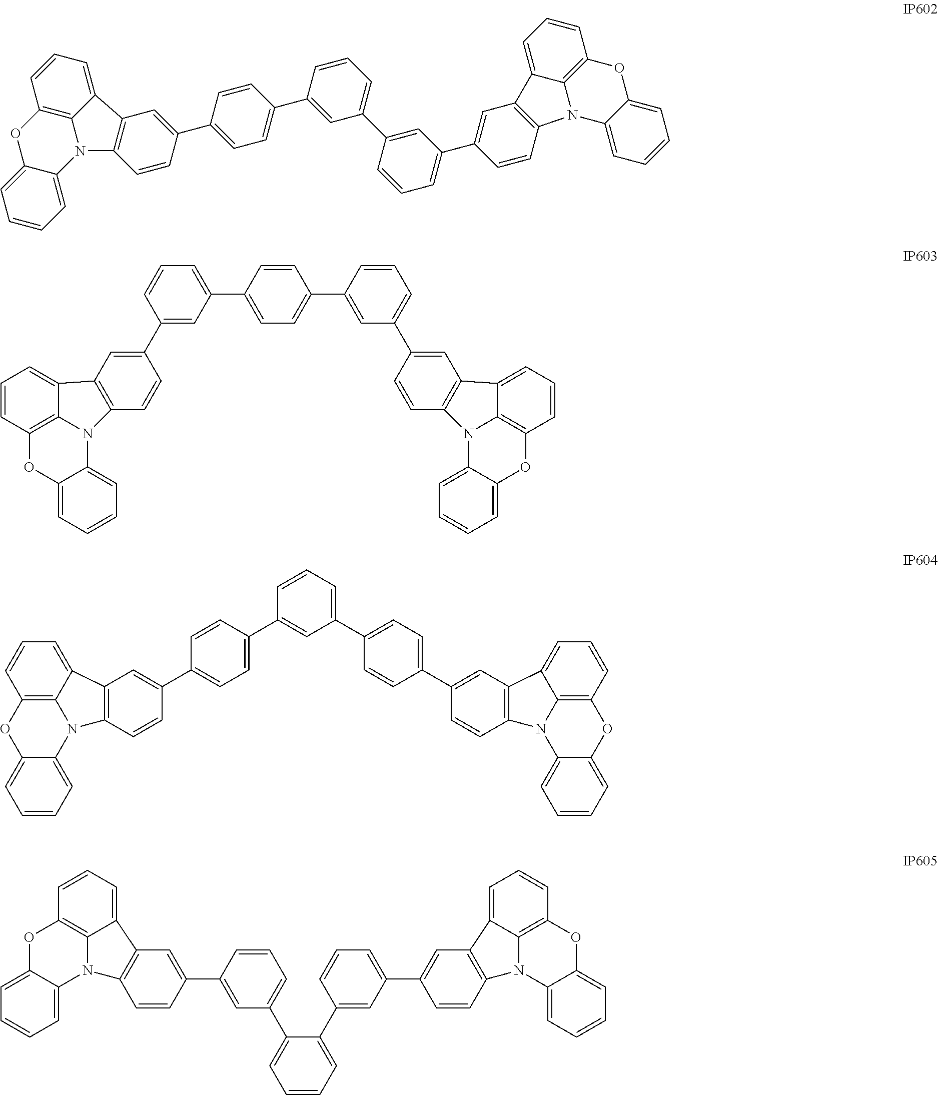

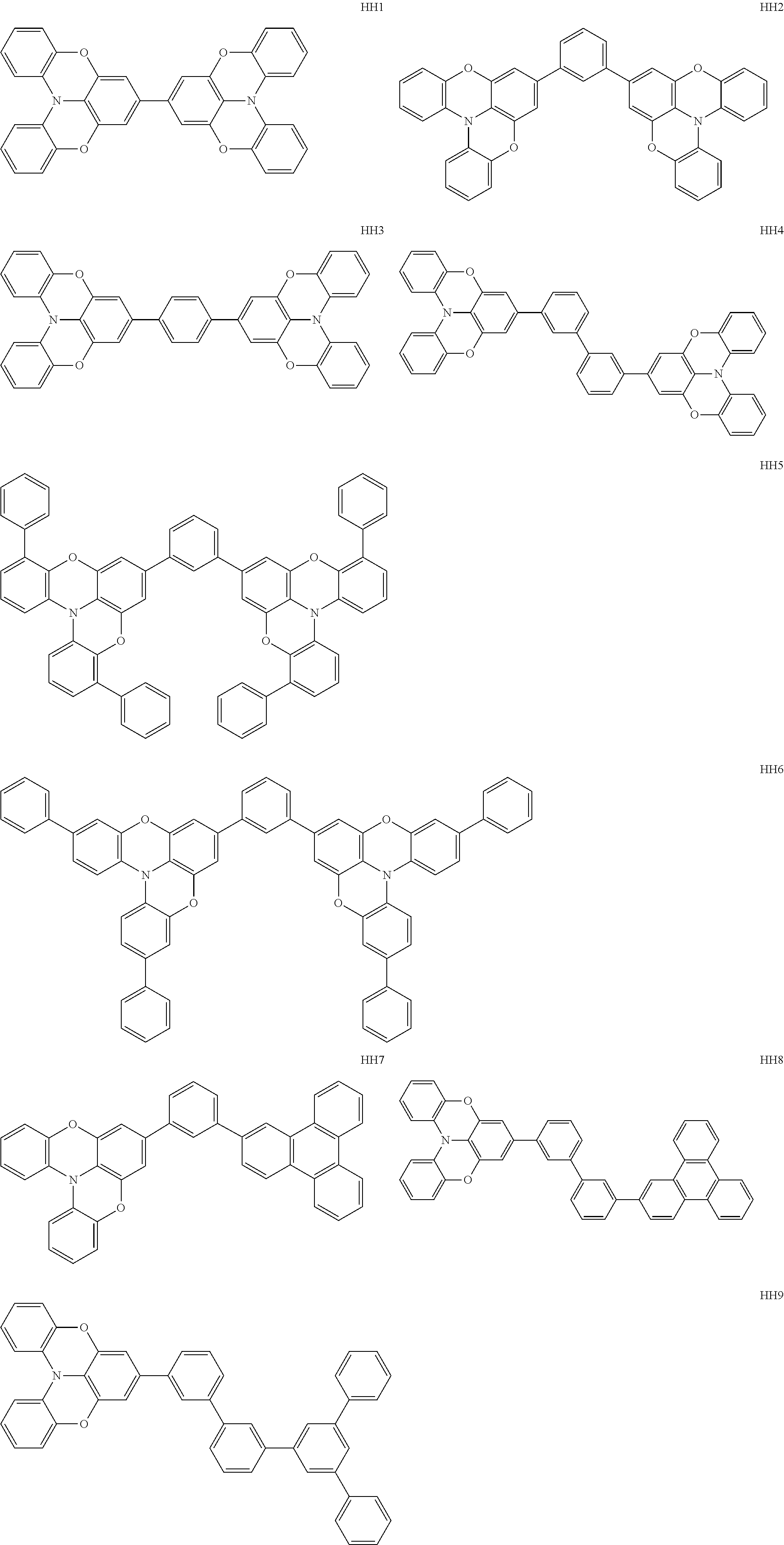

### (6) the First Light Emitting Layer 503 is a Phosphorescence Emitting Layer, and the Second Light Emitting Layer 304 is a Fluorescence Emitting Layer.

In the organic light emitting element according to this embodiment, when the first light emitting layer 503 contains a first light emitting material and the second light emitting layer 304 contains a third light emitting material, the first light emitting material is a phosphorescence emitting material, and the third light emitting material is a fluorescent material.

In addition, when the first light emitting portion contains a first light emitting material, the second light emitting portion contains a second light emitting material, and the second light emitting layer 304 contains a third light emitting material, the first light emitting material and the second light emitting material are phosphorescence emitting materials, and the third light emitting material is a fluorescent material.

The phosphorescence emitting material may be any compound that mainly emits phosphorescence, and examples thereof include compounds represented by general formula (4) and the following example compounds BD9, GD10 to GD18, and RD3 to RD10.

M(L)m(L′)n(L″)p (4)

In general formula (4), M represents a metal atom. Specific examples thereof include an iridium atom and a platinum atom. L, L′, and L″ each represent a bidentate ligand and are different from one another. m is selected from integers of 1 or more and 3 or less. n and p are each selected from integers of 0 or more and 2 or less. Here, m+n+p=3. When m is 2 or more, multiple L may be the same or different. When n is 2 or more, multiple L′ may be the same or different. When p is 2 or more, multiple L″ may be the same or different.

M(L)m is represented by general formula (4-1).

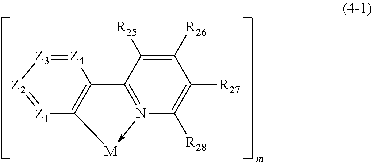

In general formula (4-1), Z₁ to Z₄ are each independently selected from C(R₂₁) and a nitrogen atom. R₂₁ to R₂₈ are each independently selected from a hydrogen atom, a deuterium atom, a halogen atom, a substituted or unsubstituted alkyl group, a substituted or unsubstituted alkoxy group, a substituted or unsubstituted silyl group, a substituted or unsubstituted aryl group, a substituted or unsubstituted heteroaryl group, a substituted or unsubstituted amino group, a substituted or unsubstituted aryloxy group, a substituted or unsubstituted heteroaryloxy group, or a cyano group. However, at least one of R₂₁ to R₂₈ is selected from a substituted or unsubstituted aryl group and a substituted or unsubstituted heteroaryl group. When Z₁ to Z₄ are represented by C(R₂₁), R₂₁ may be the same or different from one another.

In addition, adjacent R₂₁ to R₂₈ may bond together to form a ring.

M(L′)n is represented by general formula (4-2).

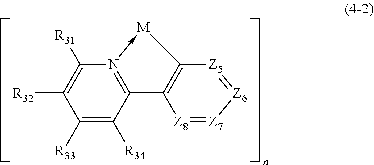

In general formula (4-2), Z₅ to Z₈ are each independently selected from C(R₃₅) and a nitrogen atom. R₃₁ to R₃₅ are each independently selected from a hydrogen atom, a deuterium atom, a halogen atom, a substituted or unsubstituted alkyl group, a substituted or unsubstituted alkoxy group, a substituted or unsubstituted silyl group, a substituted or unsubstituted aryl group, a substituted or unsubstituted heteroaryl group, a substituted or unsubstituted amino group, a substituted or unsubstituted aryloxy group, a substituted or unsubstituted heteroaryloxy group, or a cyano group. When Z₅ to Z₈ are represented by C(R₃₅), R₃₅ may be the same or different from one another.

In addition, adjacent R₃₁ to R₃₅ may bond together to form a ring.

M(L″)p is represented by general formula (4-3).

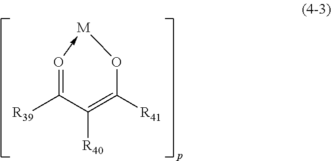

In formula (4-3), R₃₉ to R₄₁ are each independently selected from a hydrogen atom, a deuterium atom, a halogen atom, a substituted or unsubstituted alkyl group, a substituted or unsubstituted alkoxy group, a substituted or unsubstituted silyl group, a substituted or unsubstituted aryl group, a substituted or unsubstituted heteroaryl group, a substituted or unsubstituted amino group, a substituted or unsubstituted aryloxy group, a substituted or unsubstituted heteroaryloxy group, or a cyano group.

Specific examples of the partial structure M(L)m of an organic metal complex, which is a light emitting compound, are described below; however, these examples are not limiting. In the specific examples described below, coordinate bonds are indicated by straight lines, dotted lines, or arrows.

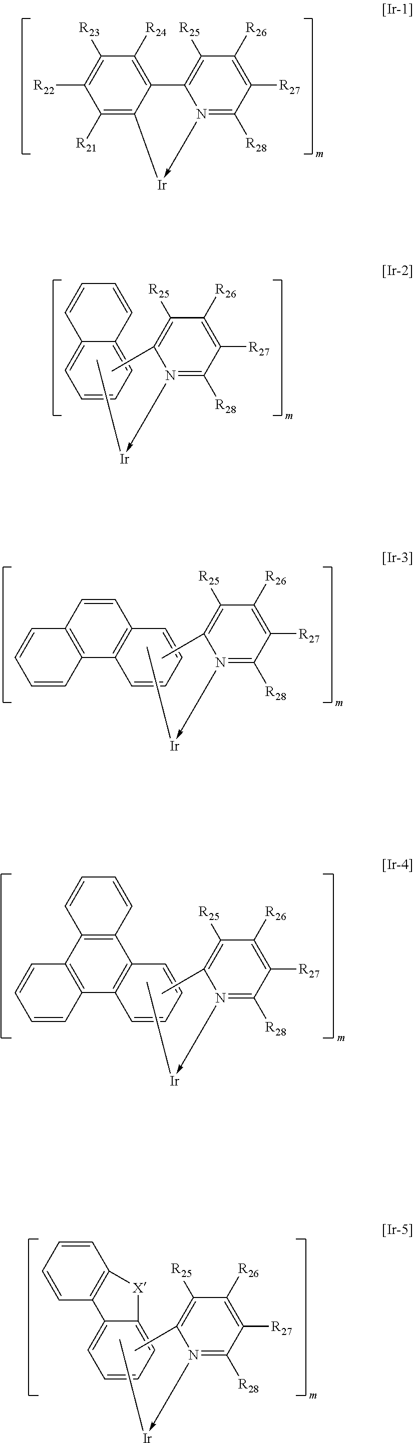

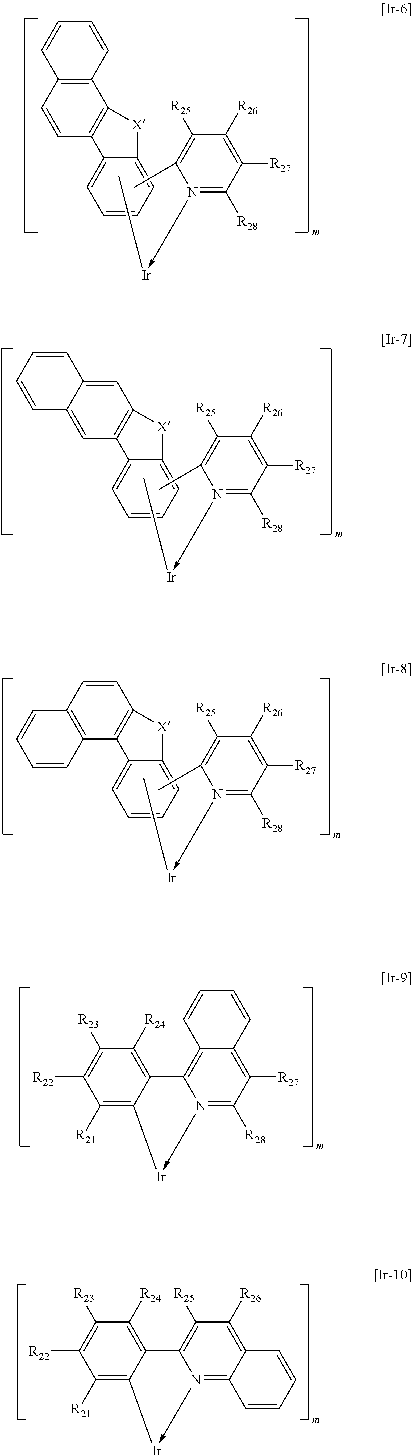

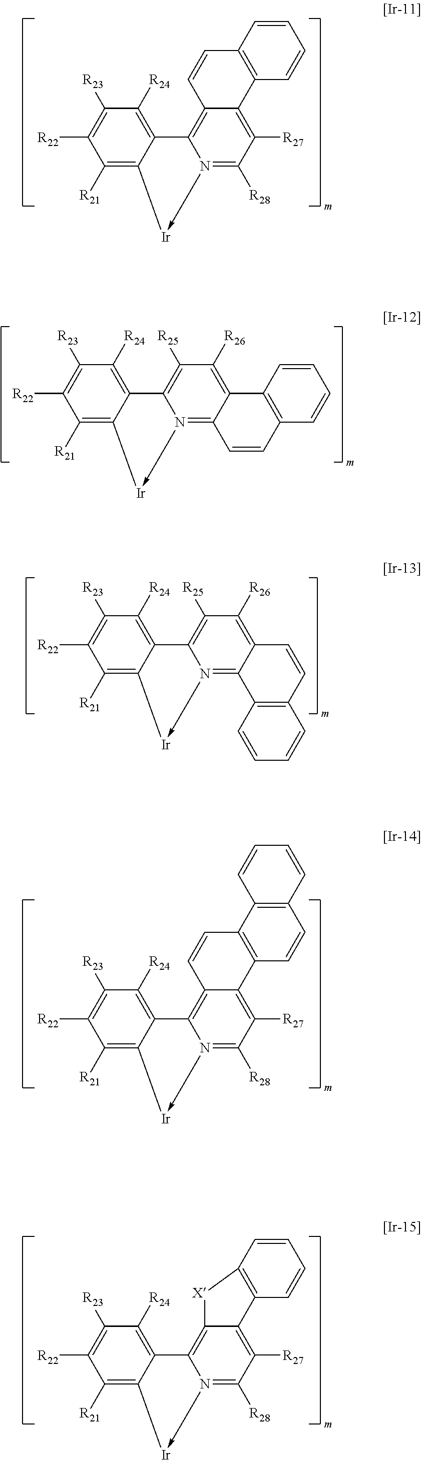

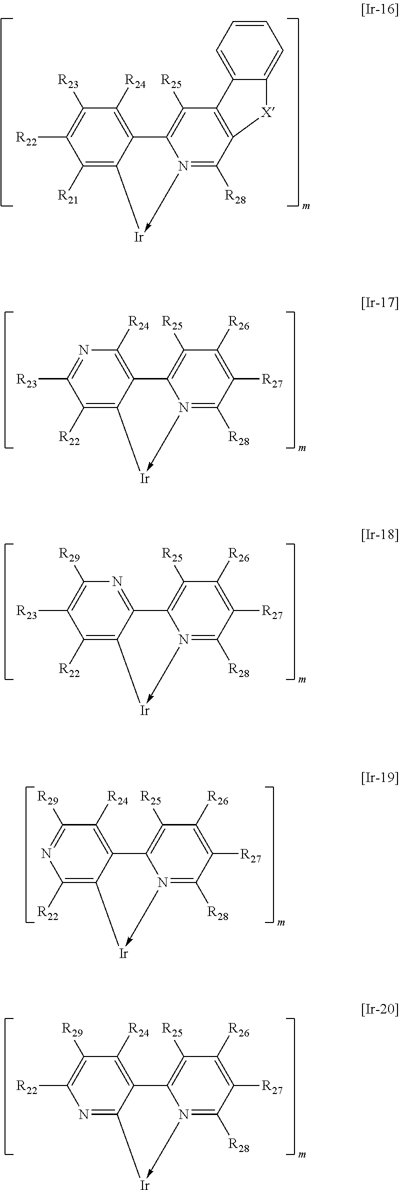

In general formulae [Ir-5] to [Ir-8], [Ir-15], and [Ir-16], X′ is selected from an oxygen atom, a sulfur atom, a substituted or unsubstituted carbon atom, and a substituted or unsubstituted nitrogen atom. R₂₁ to R₂₈ are as indicated by general formula (4-1).

In general formula [Ir-1] to [Ir-20], adjacent R₂₁ to R₂ may bond together to form a ring.

Although specific examples of phosphorescence emitting material are described below, these examples are not limiting.

Specific examples of the light emitting compound are as follows. These examples do not limit the invention.

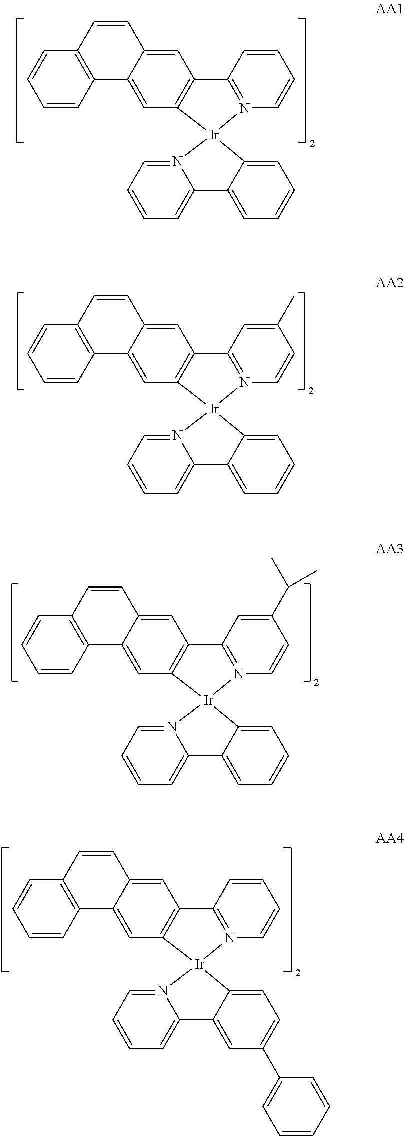

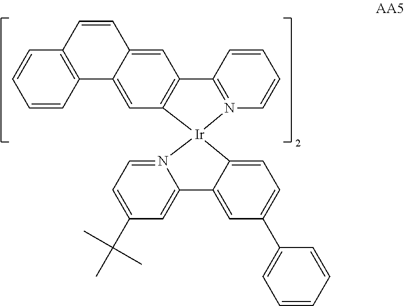

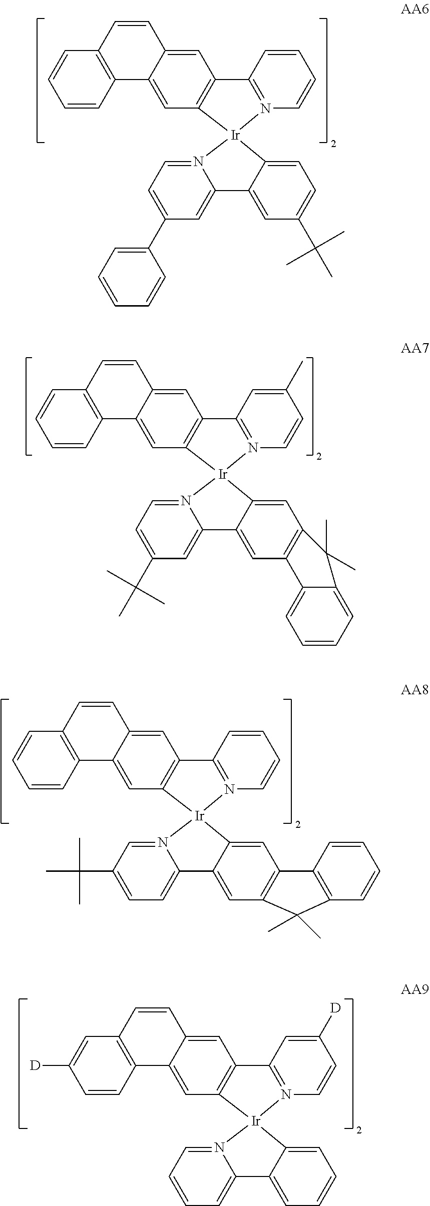

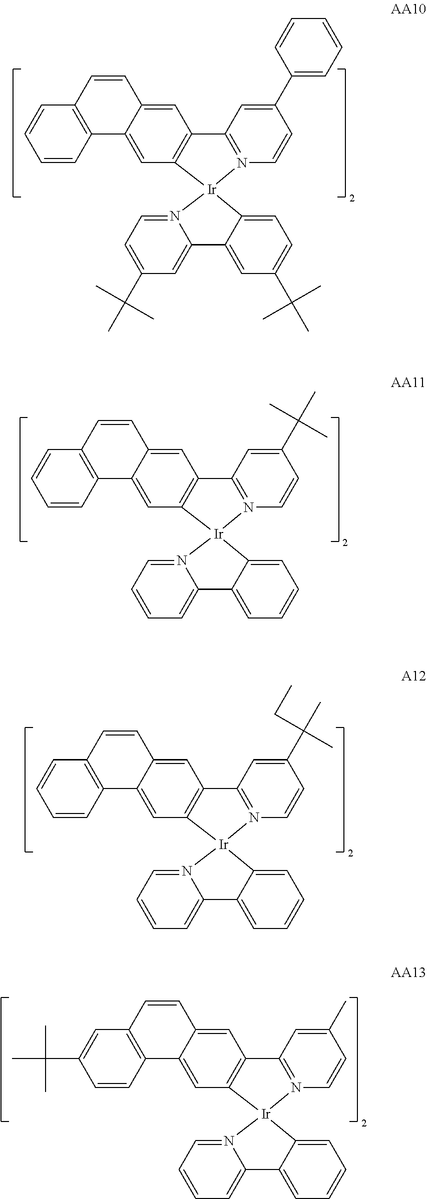

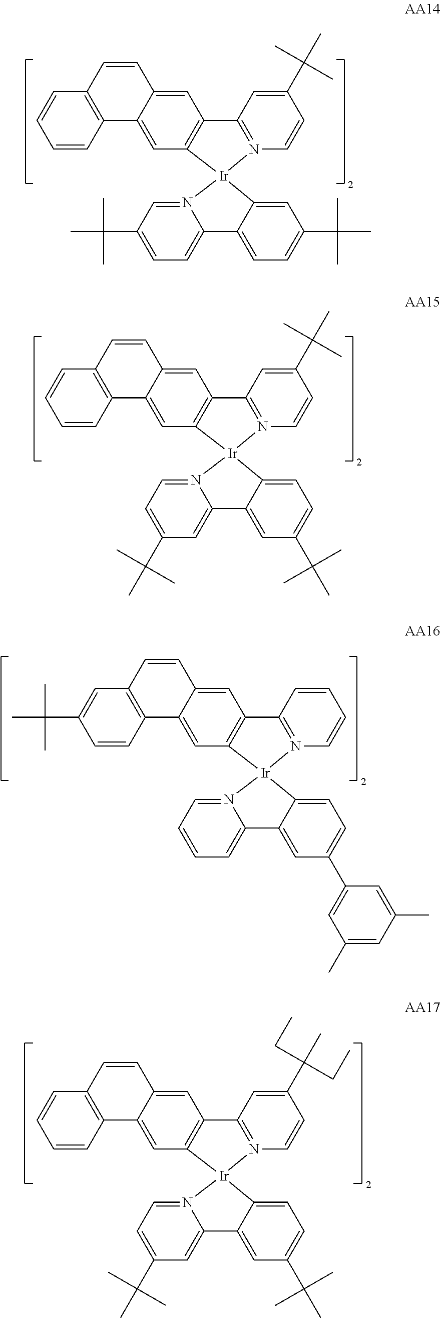

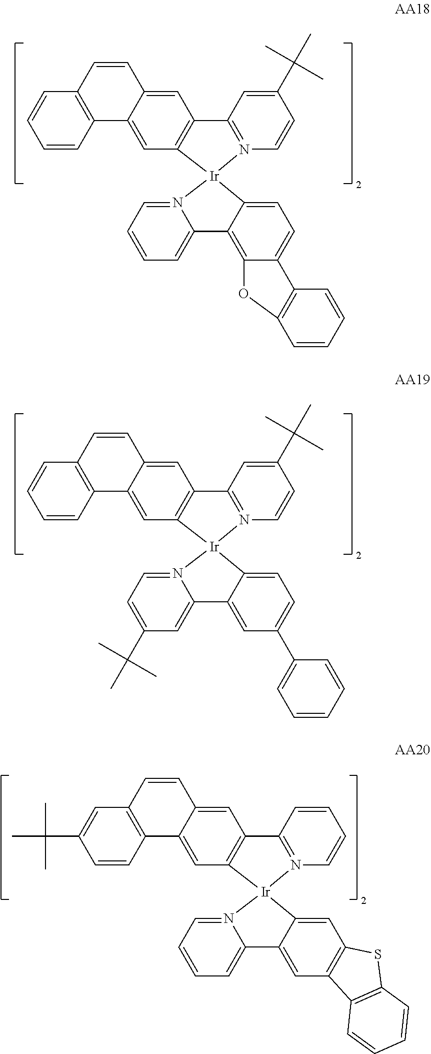

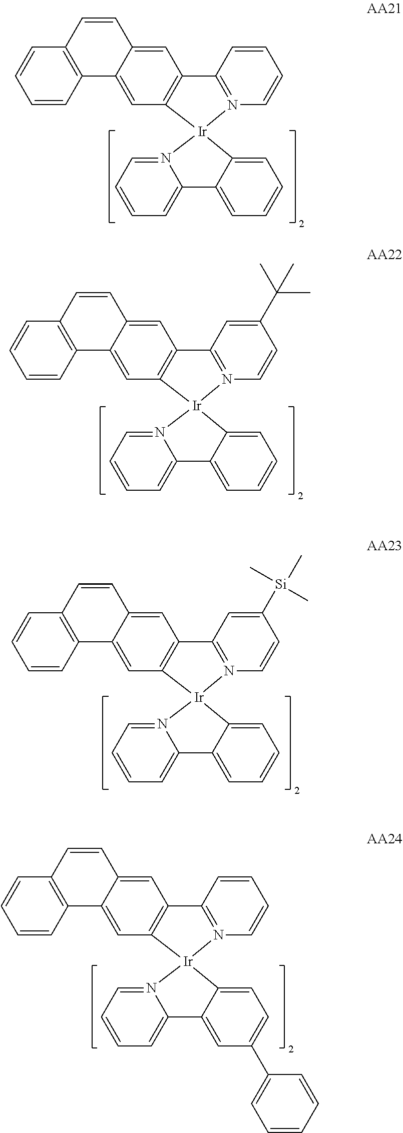

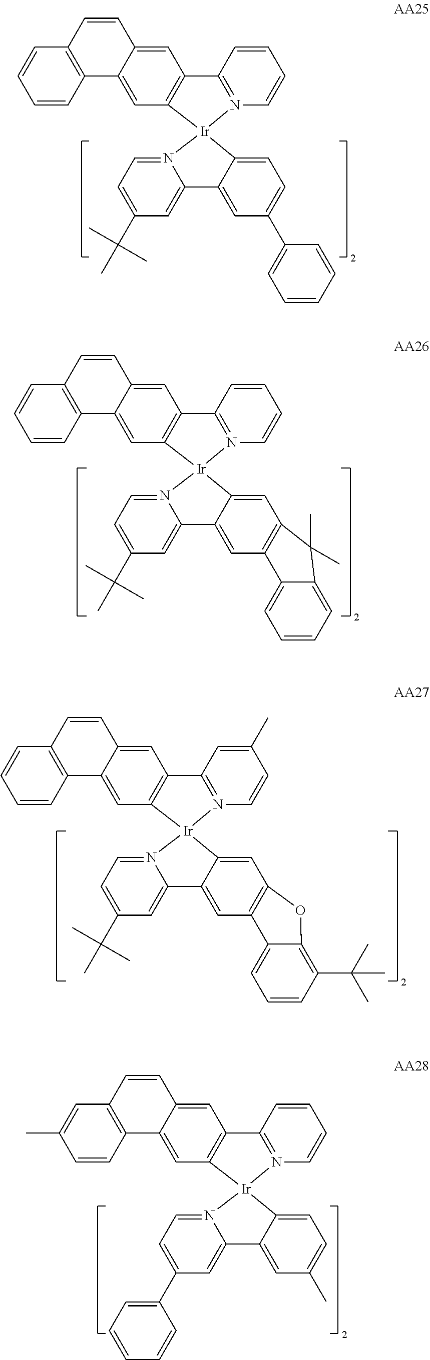

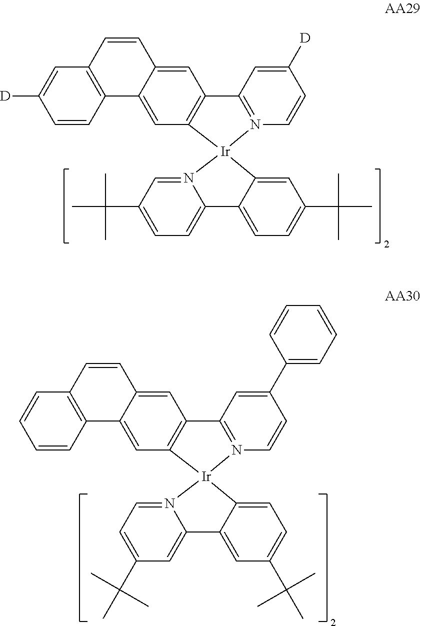

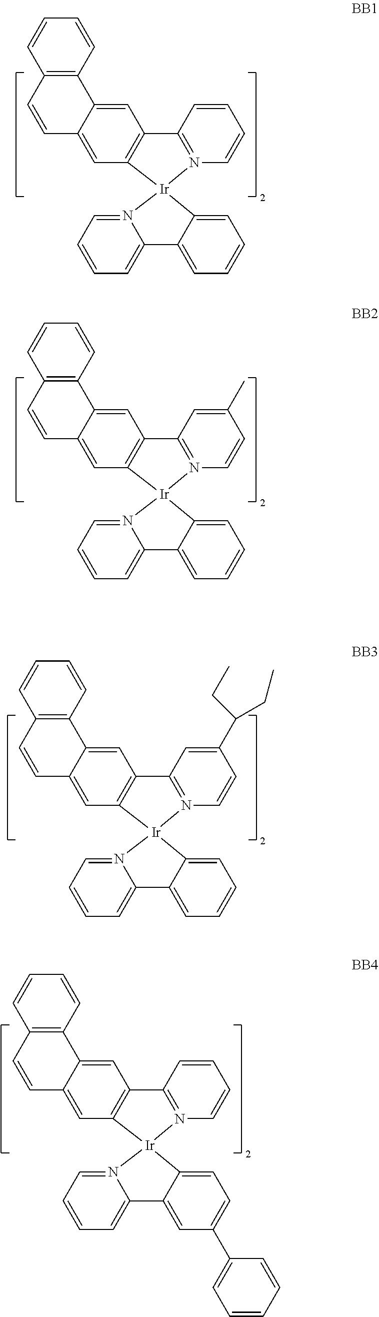

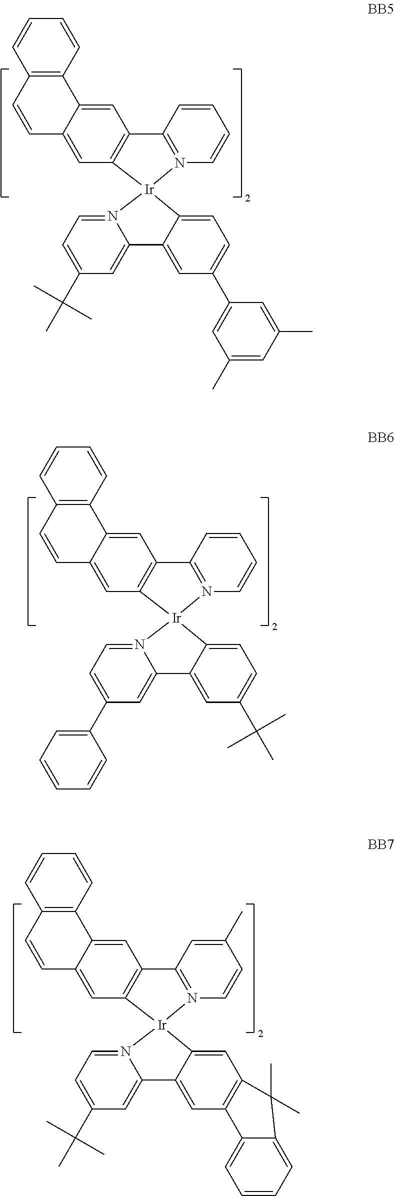

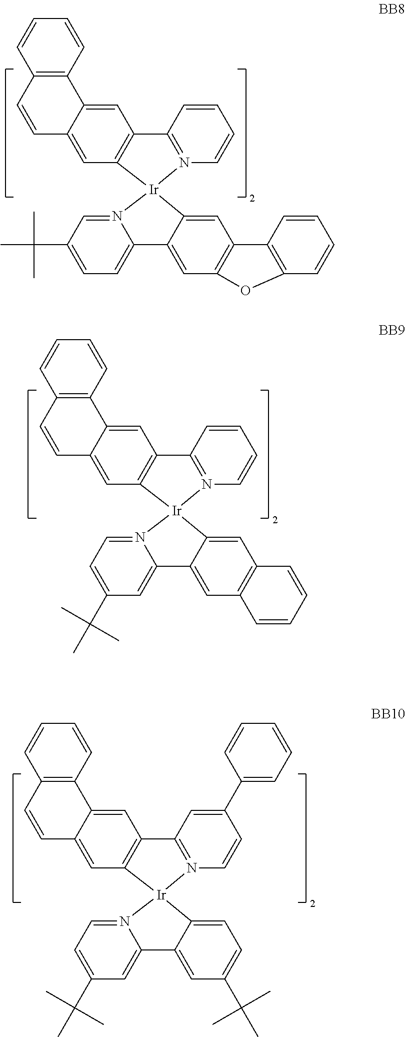

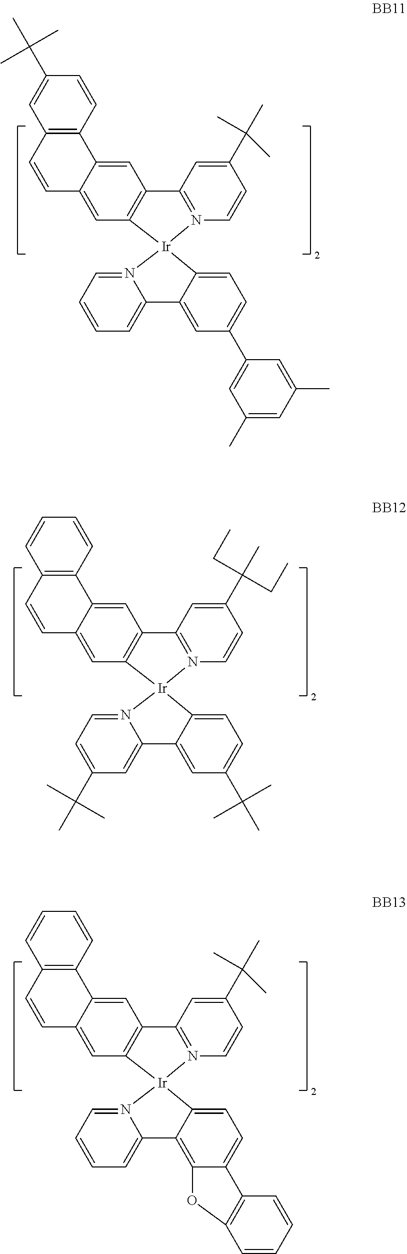

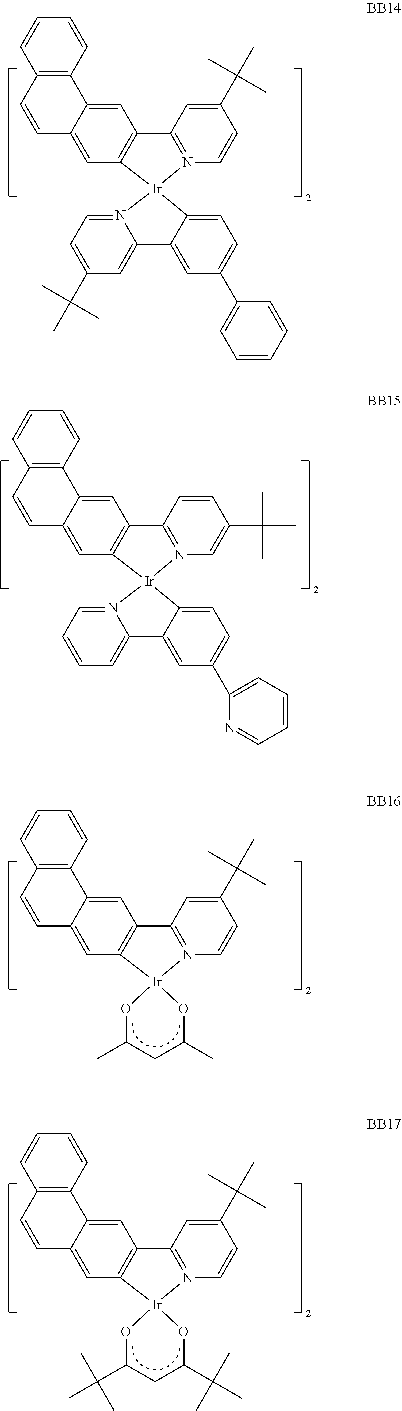

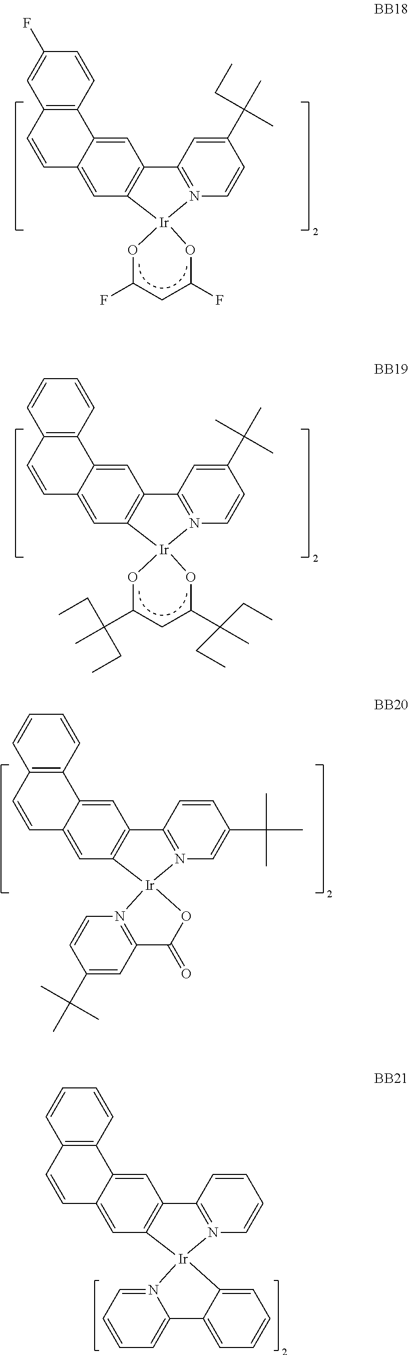

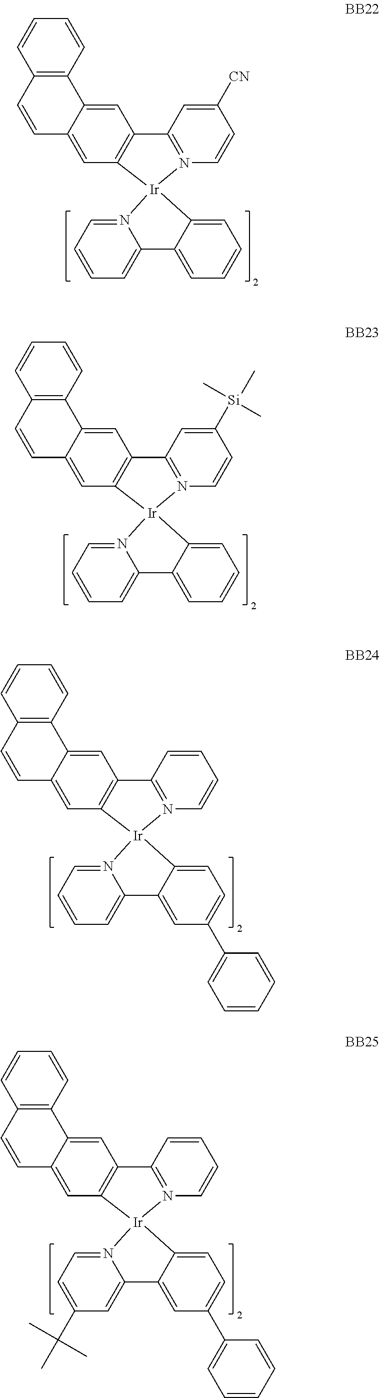

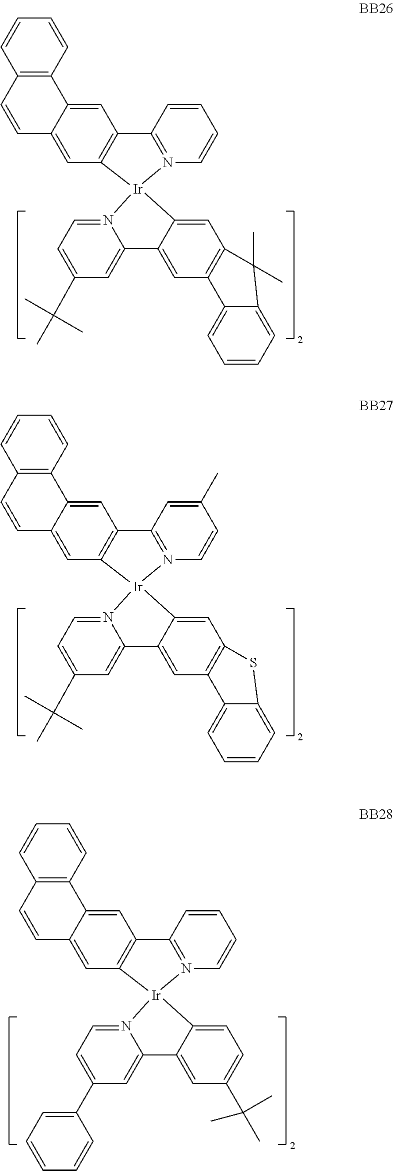

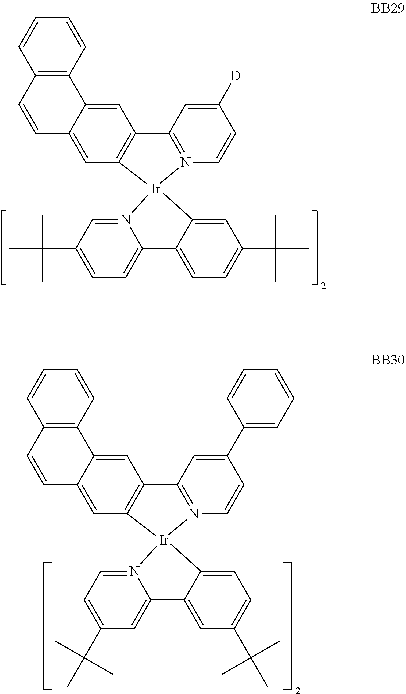

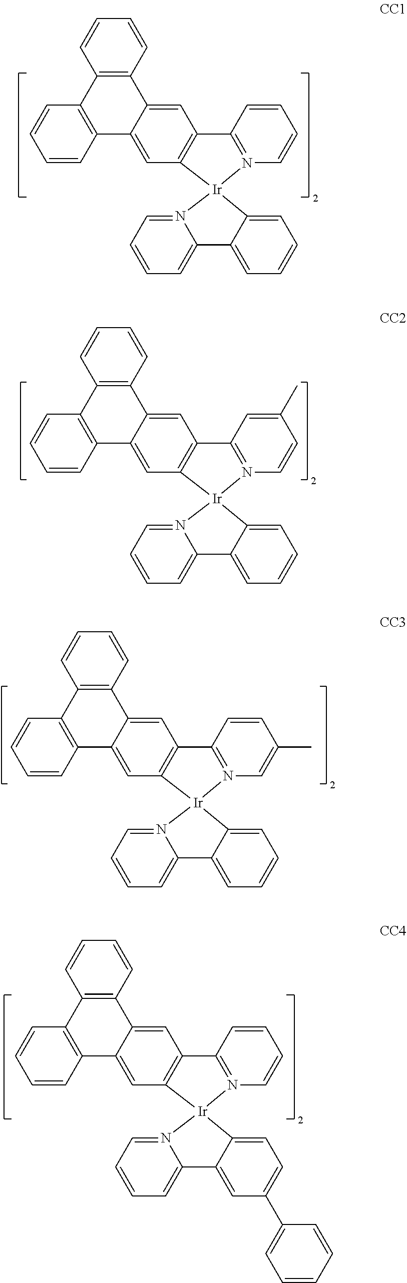

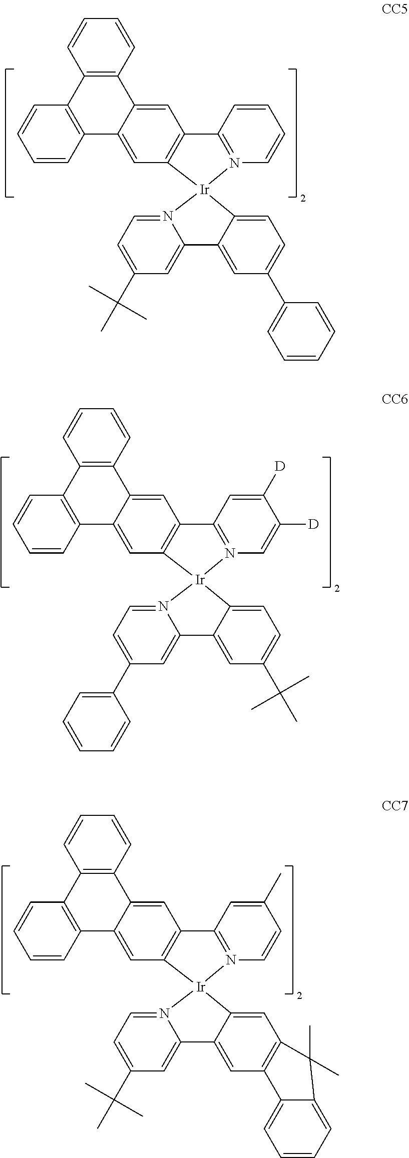

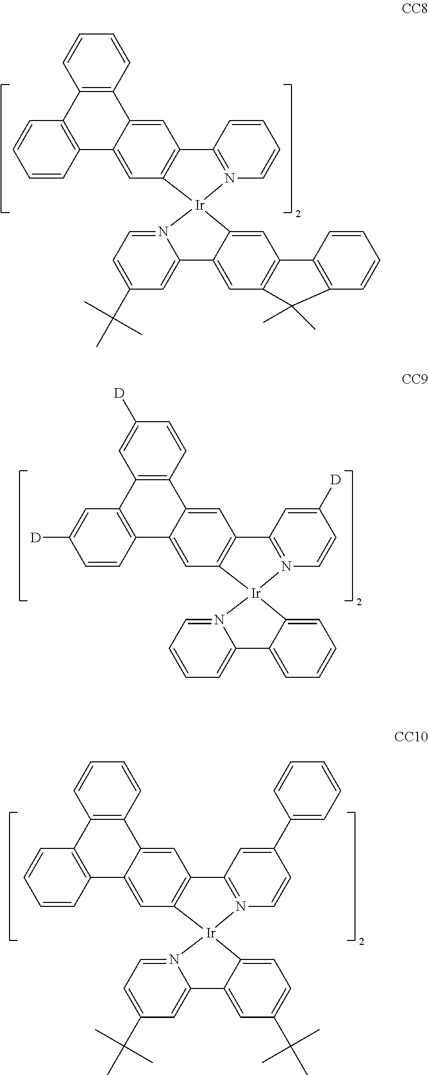

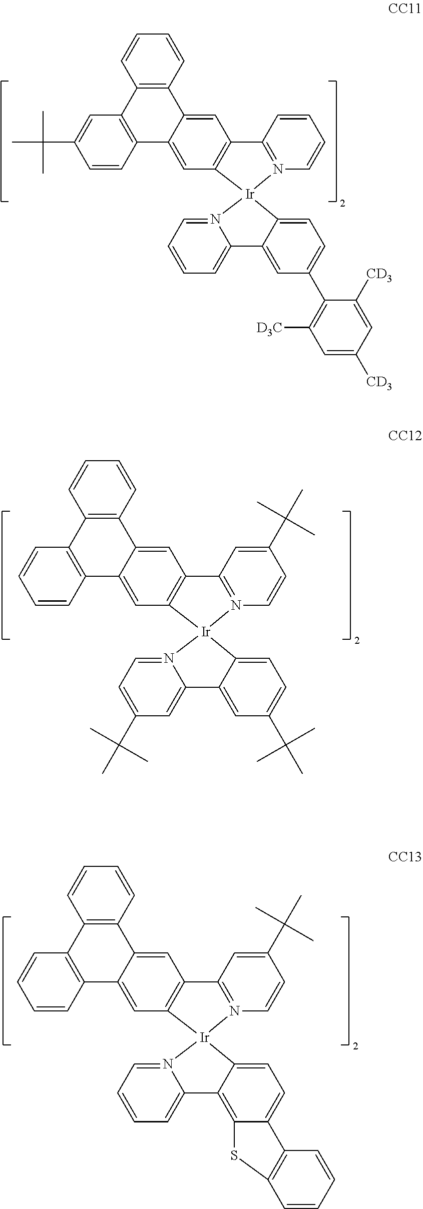

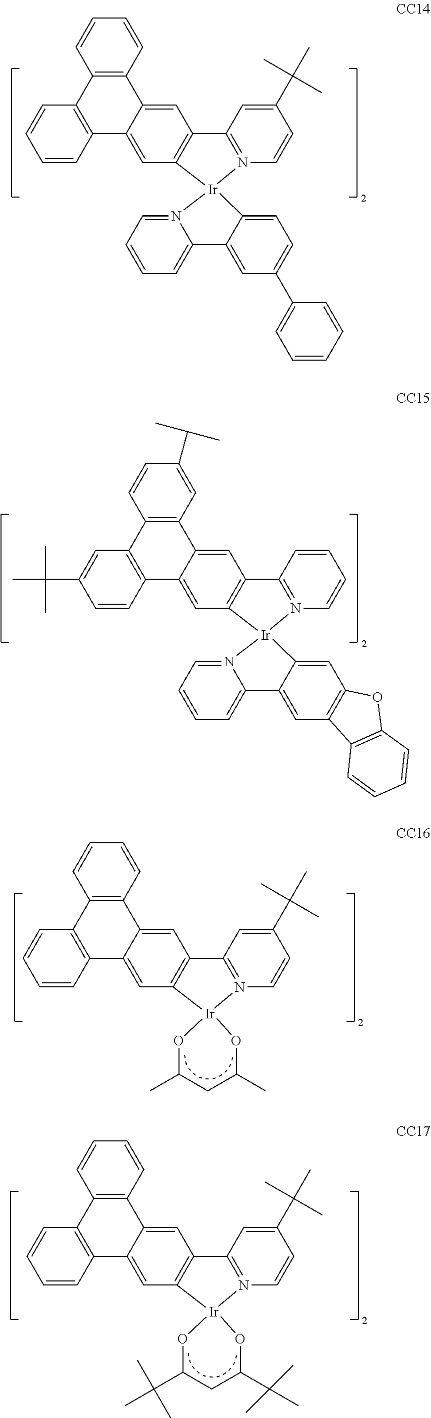

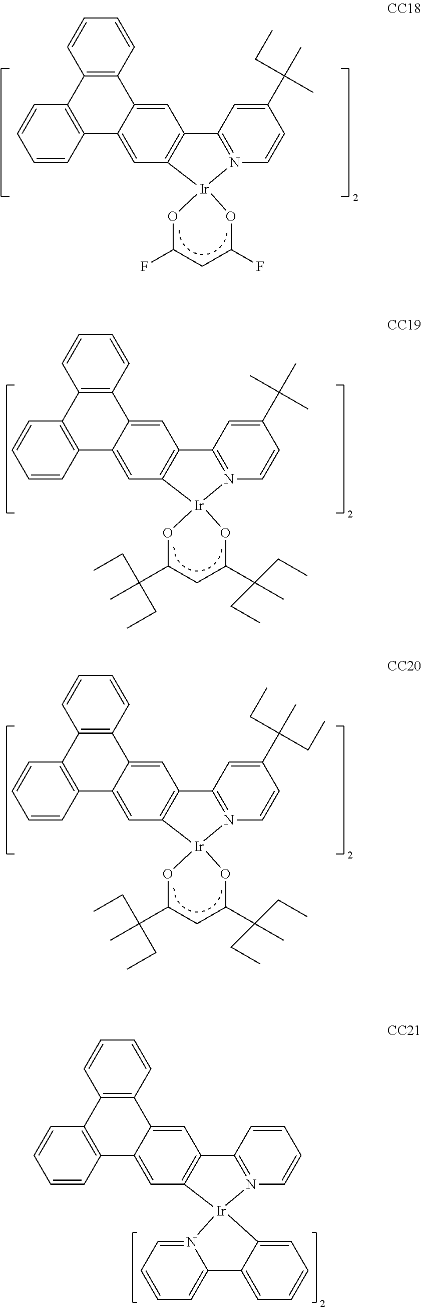

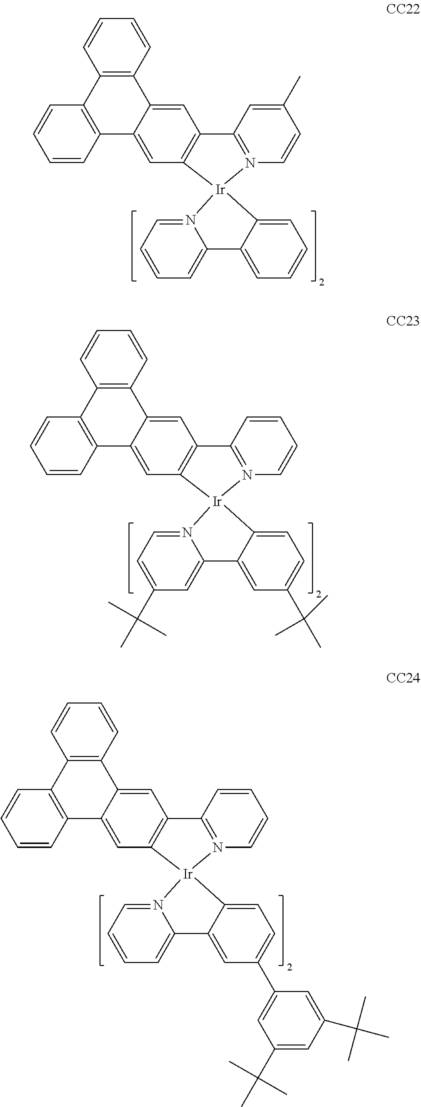

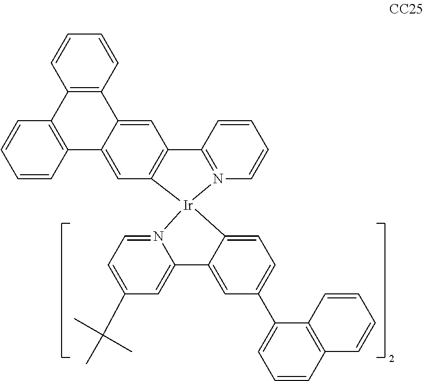

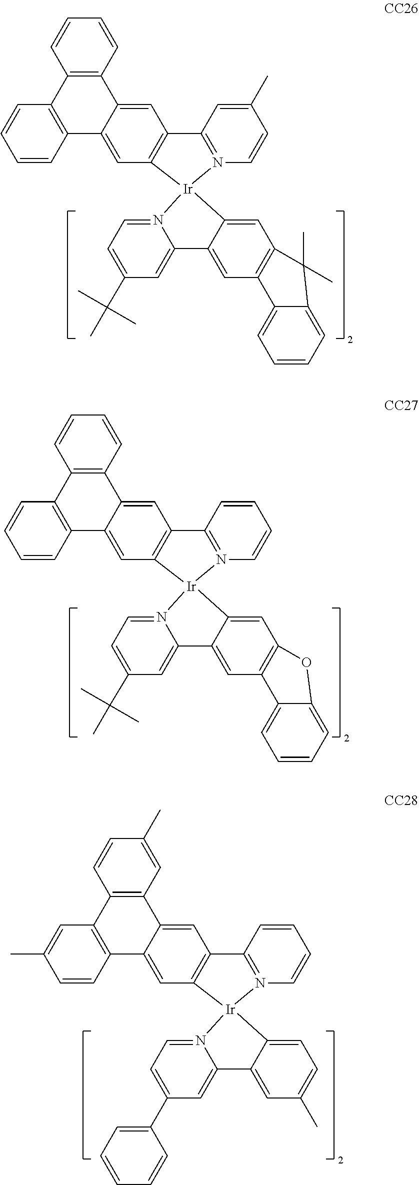

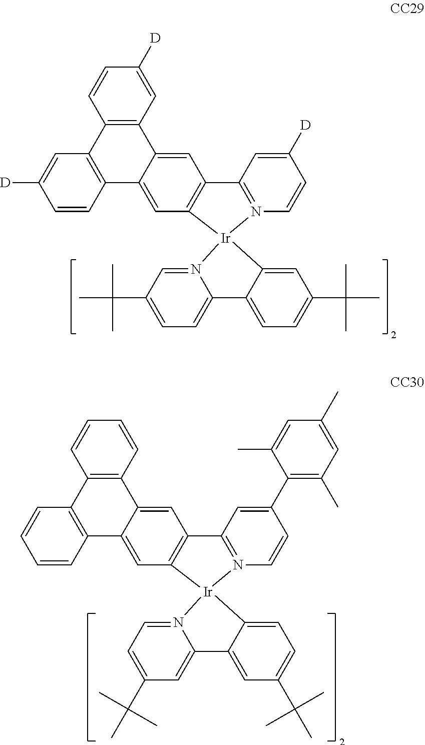

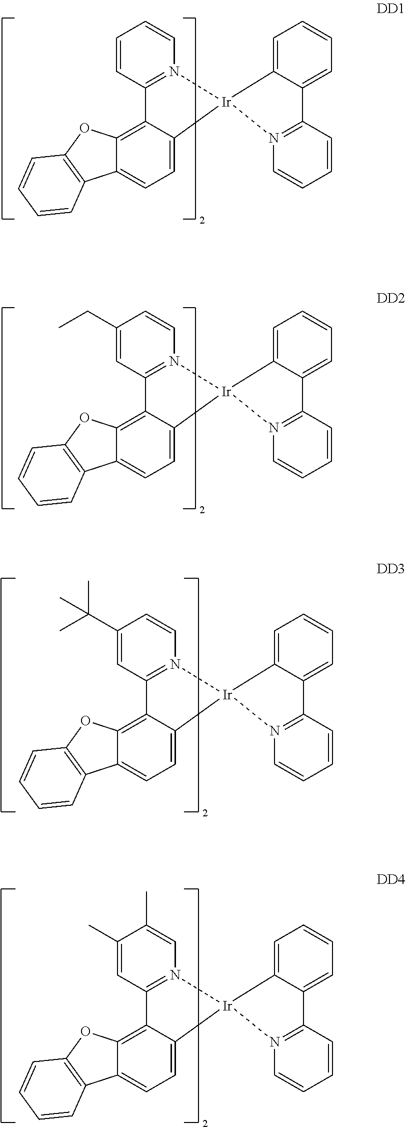

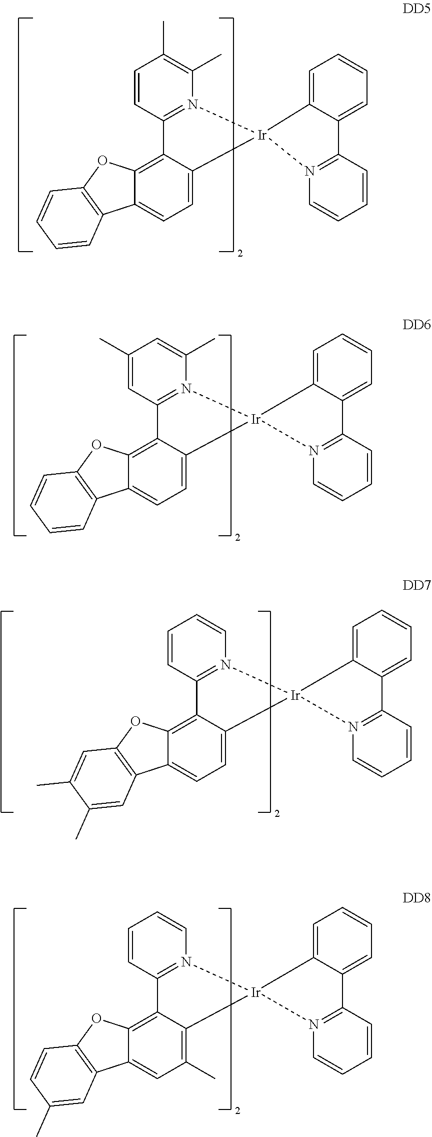

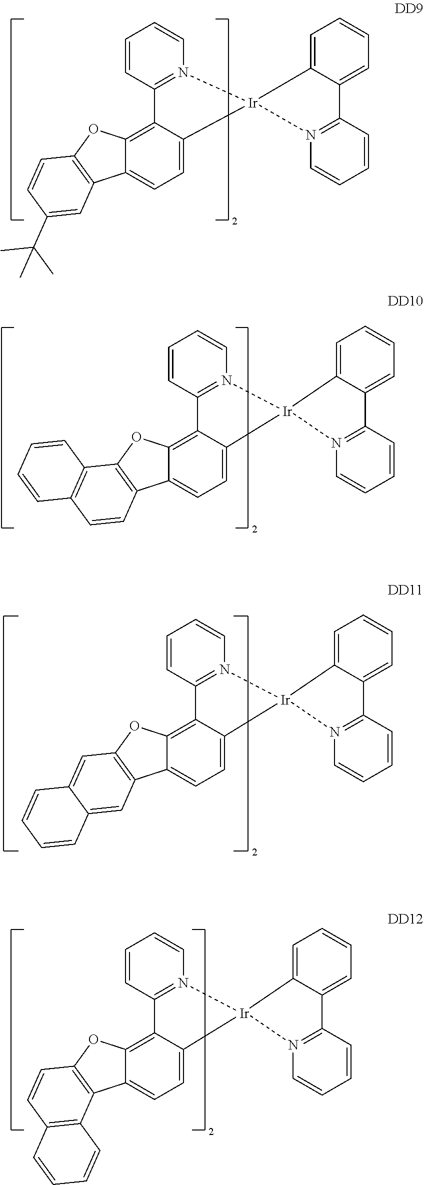

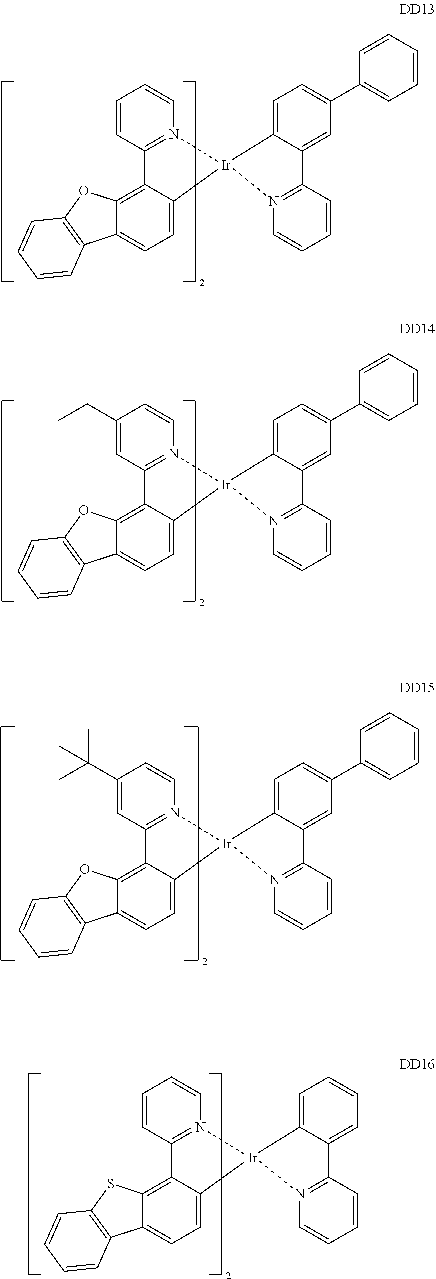

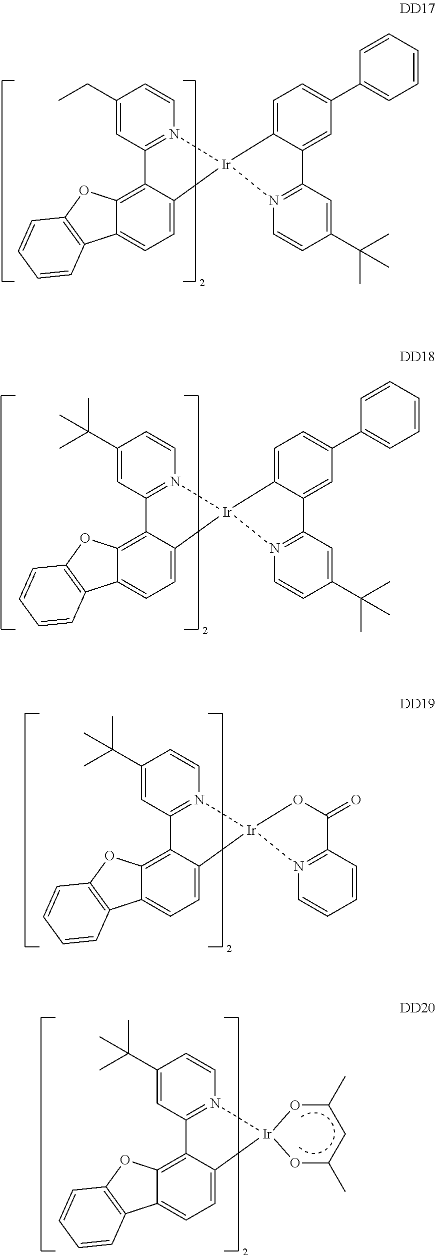

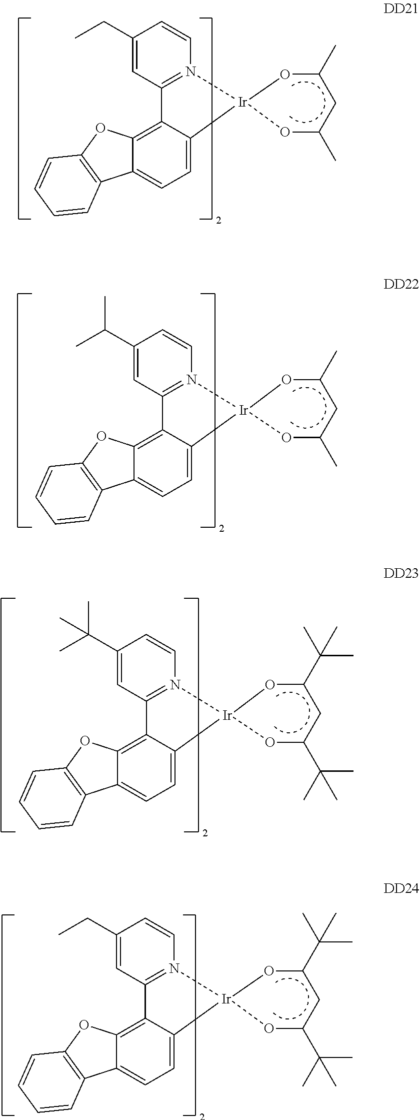

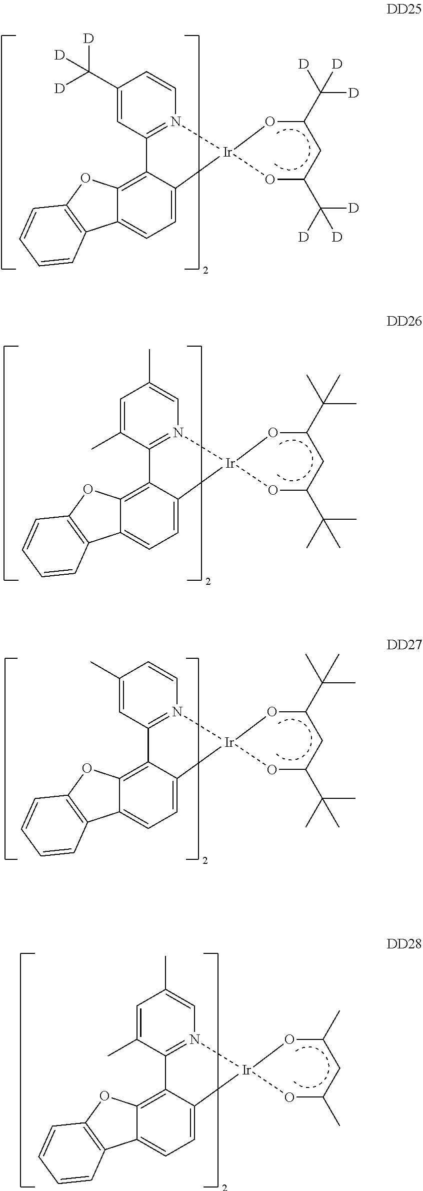

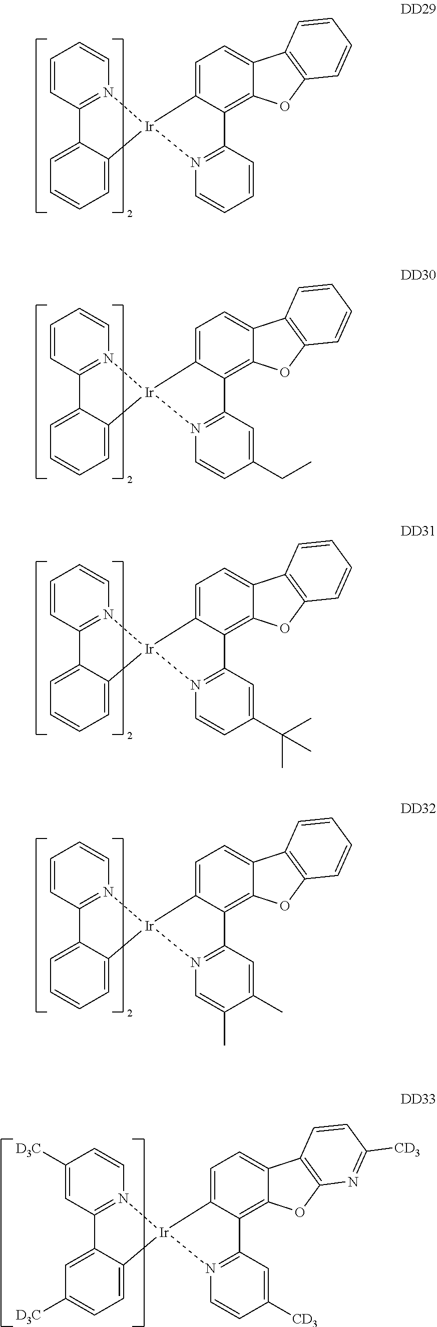

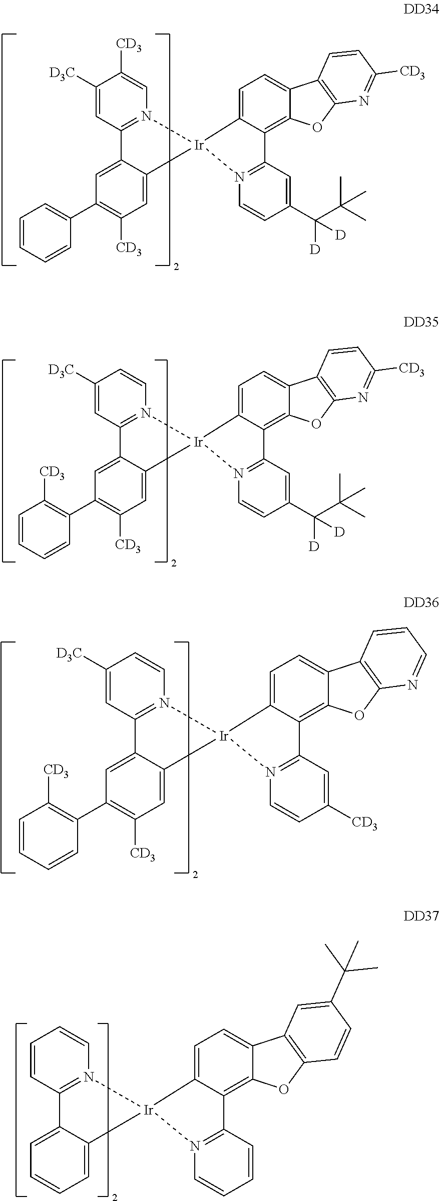

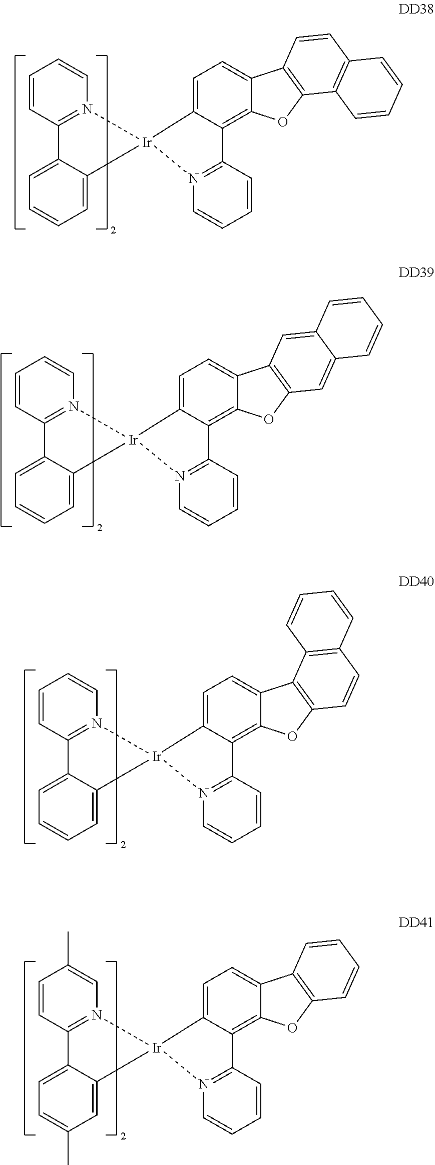

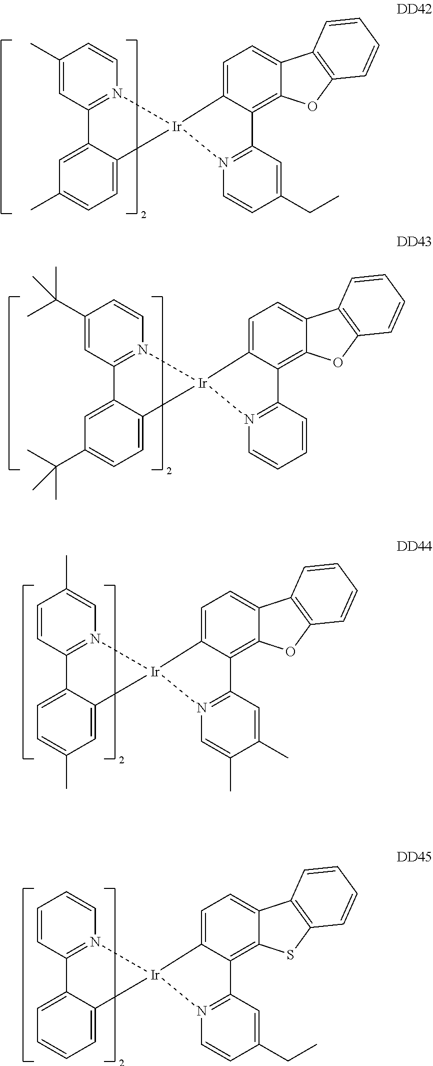

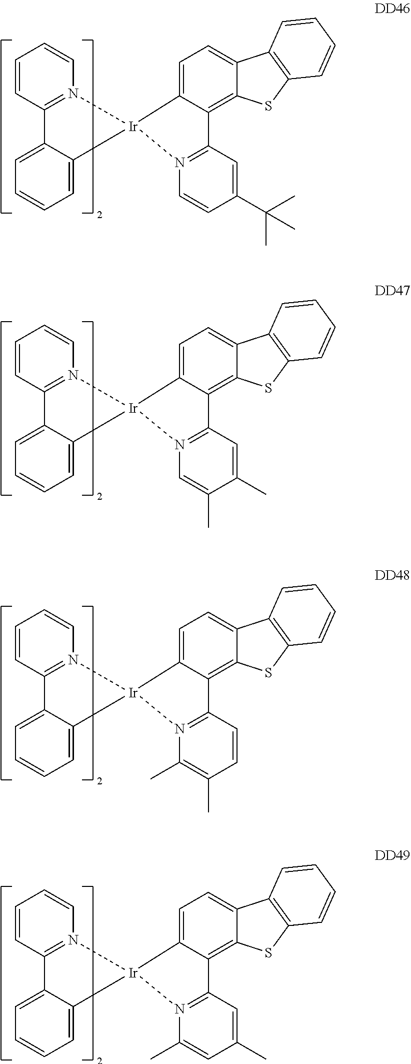

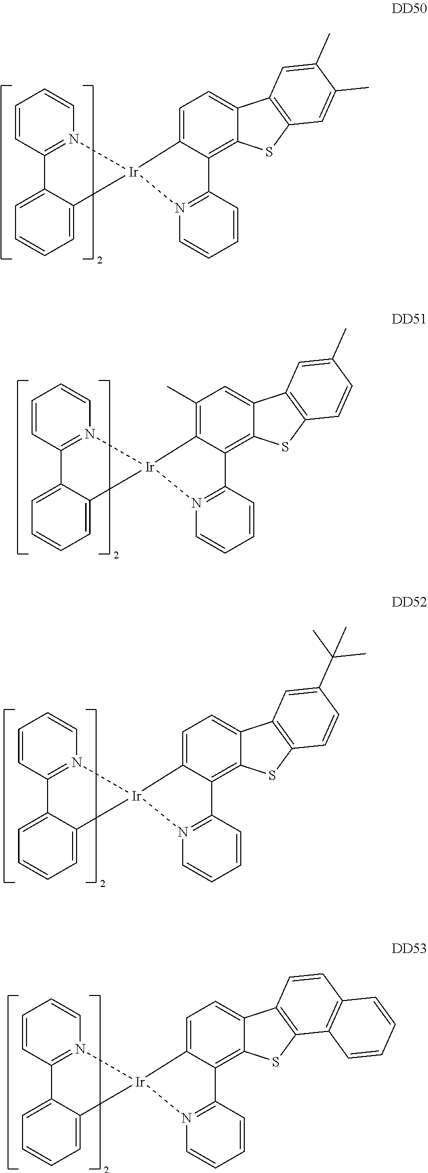

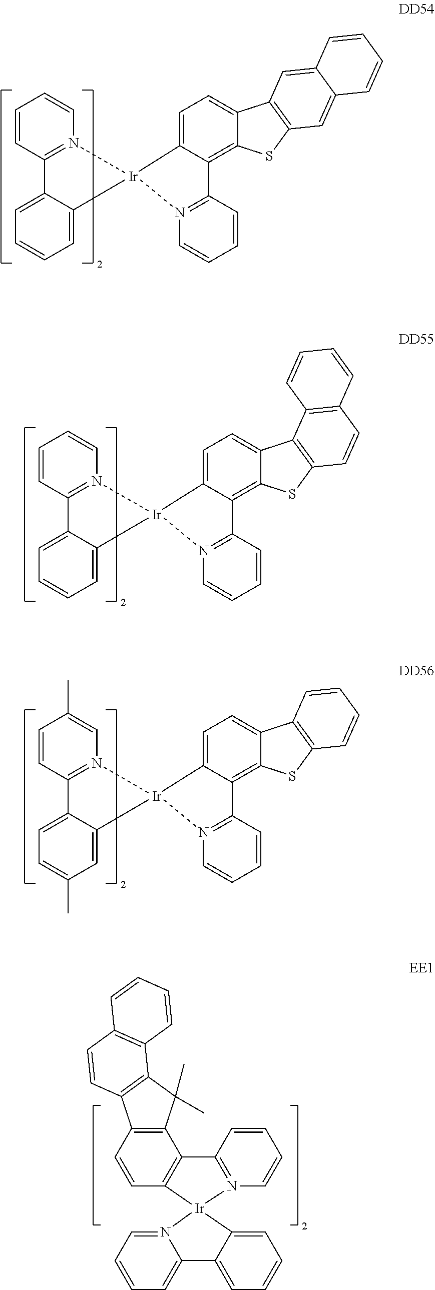

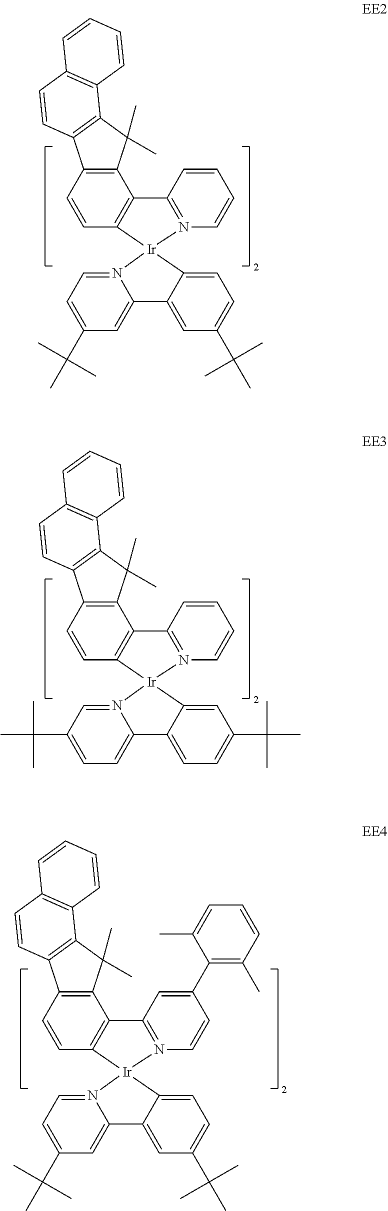

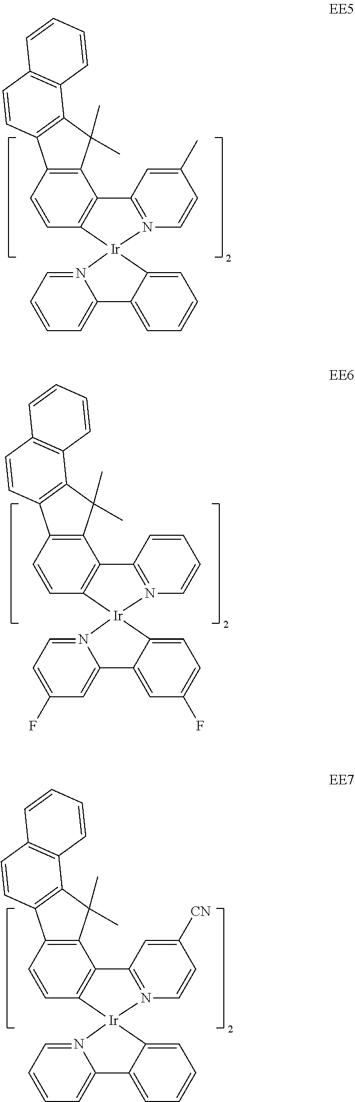

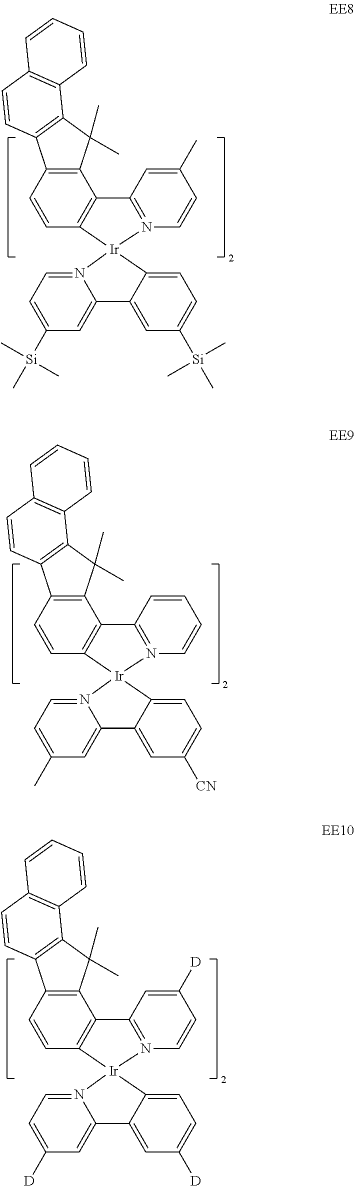

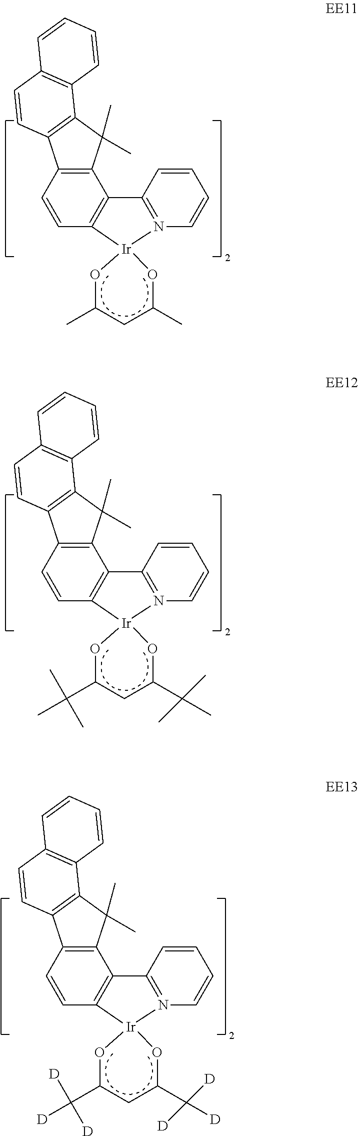

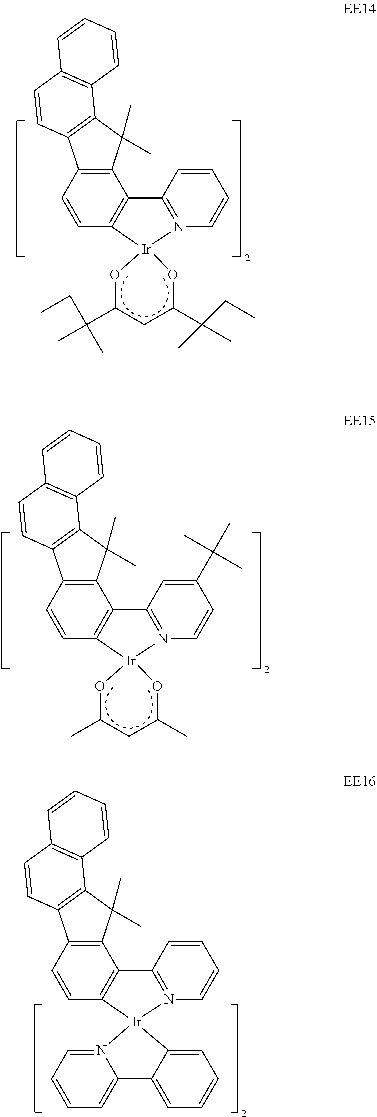

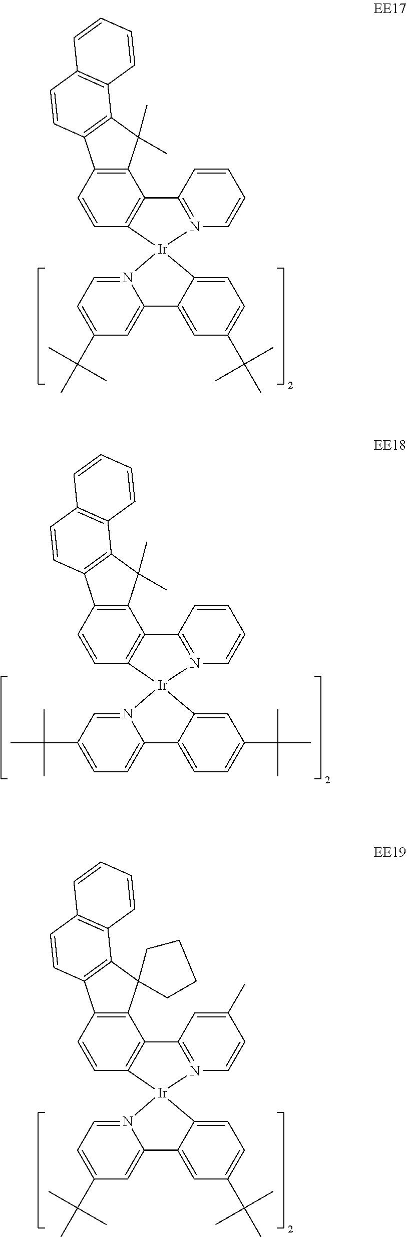

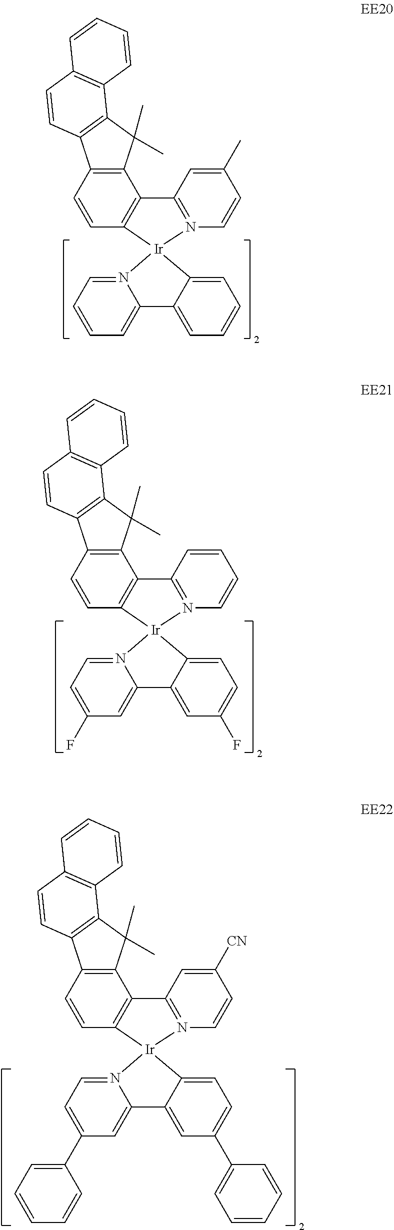

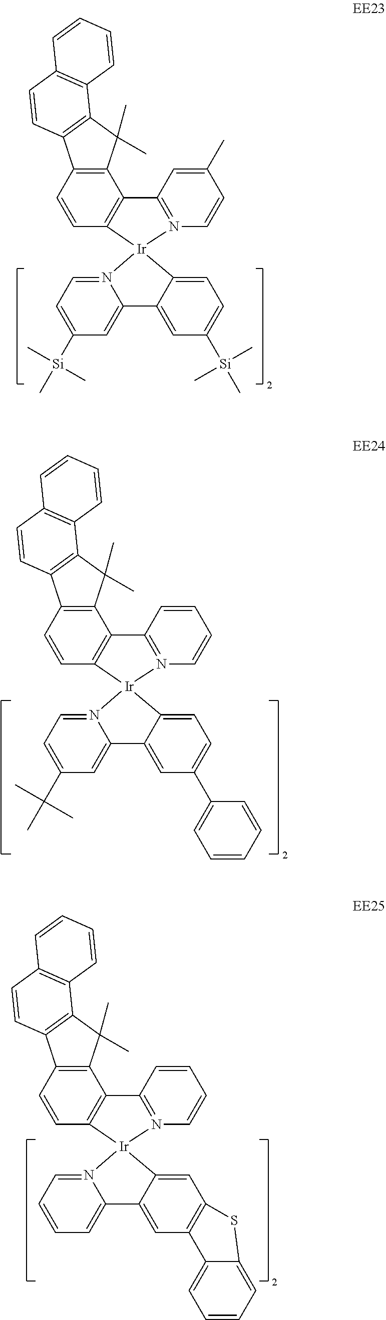

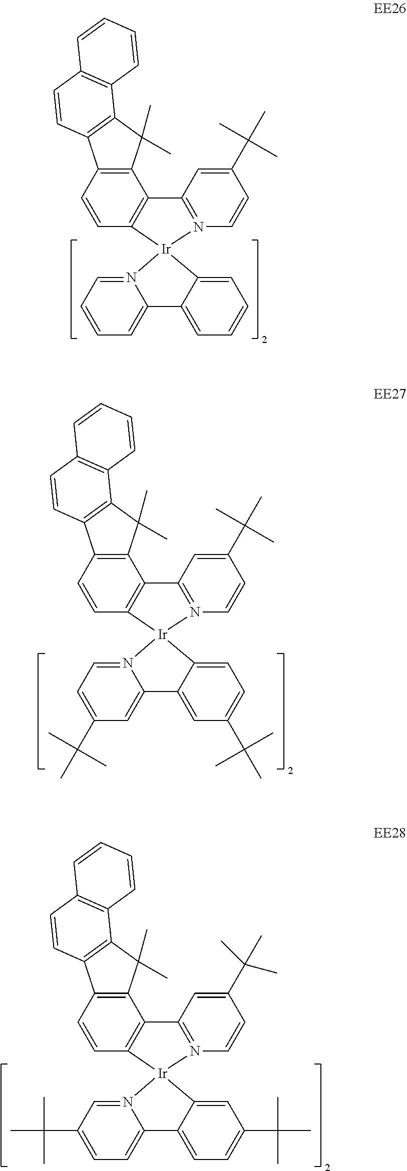

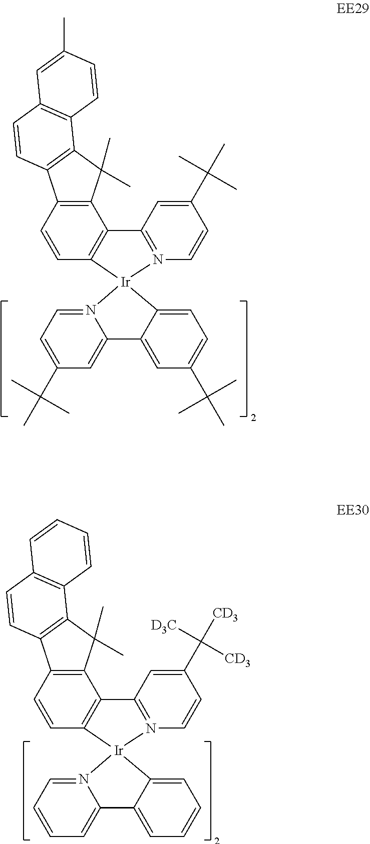

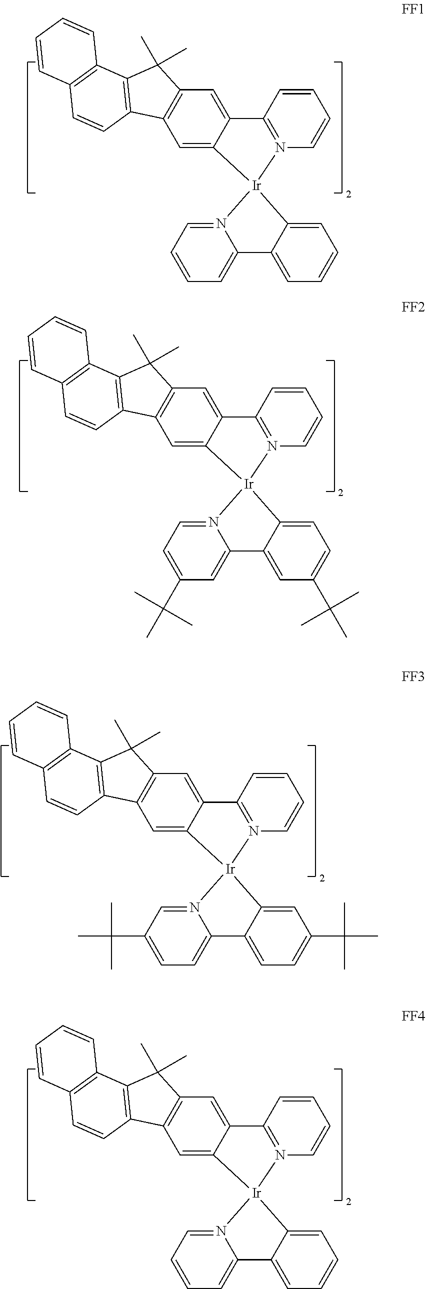

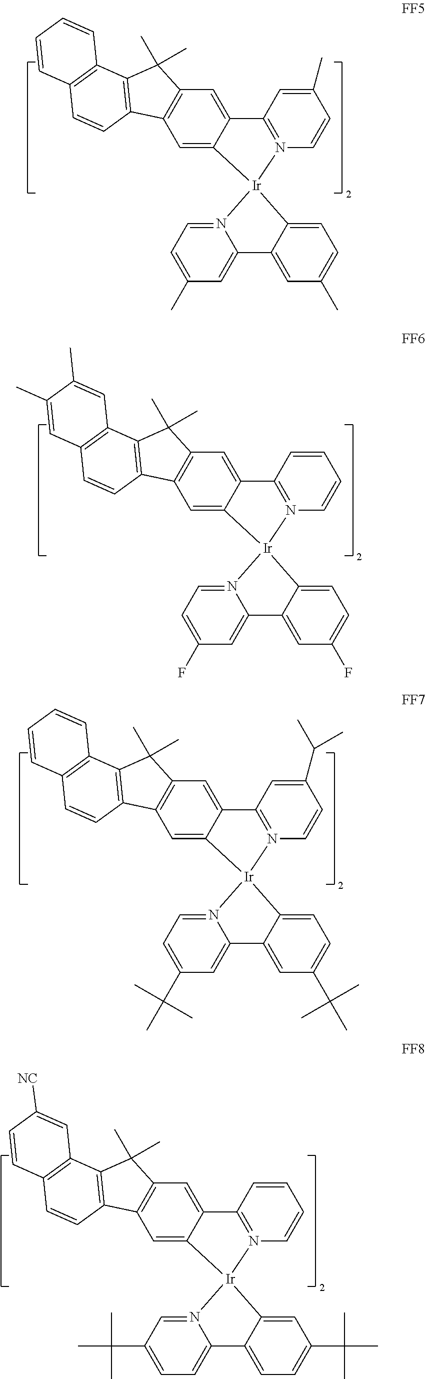

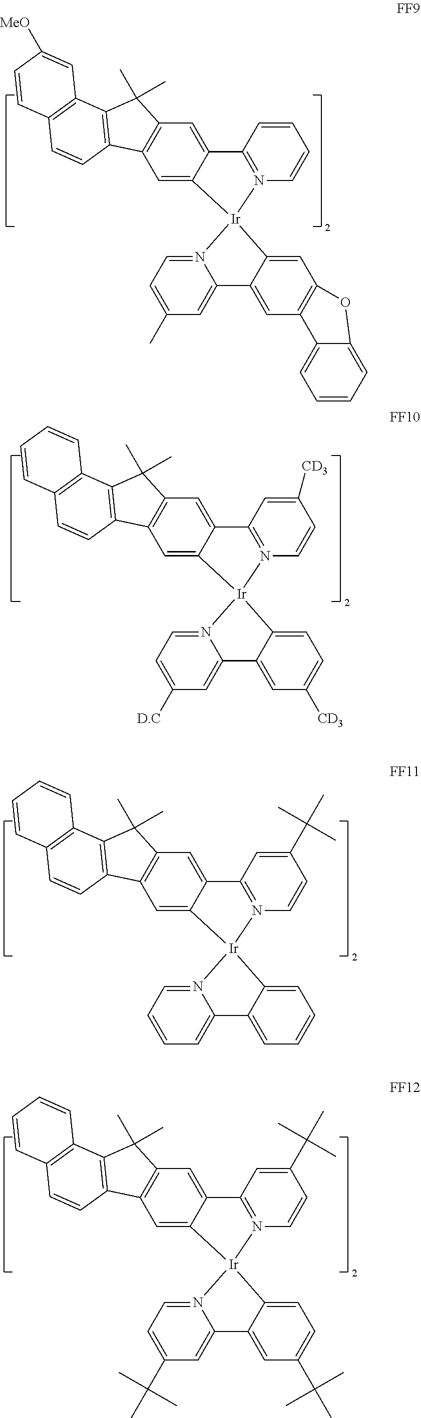

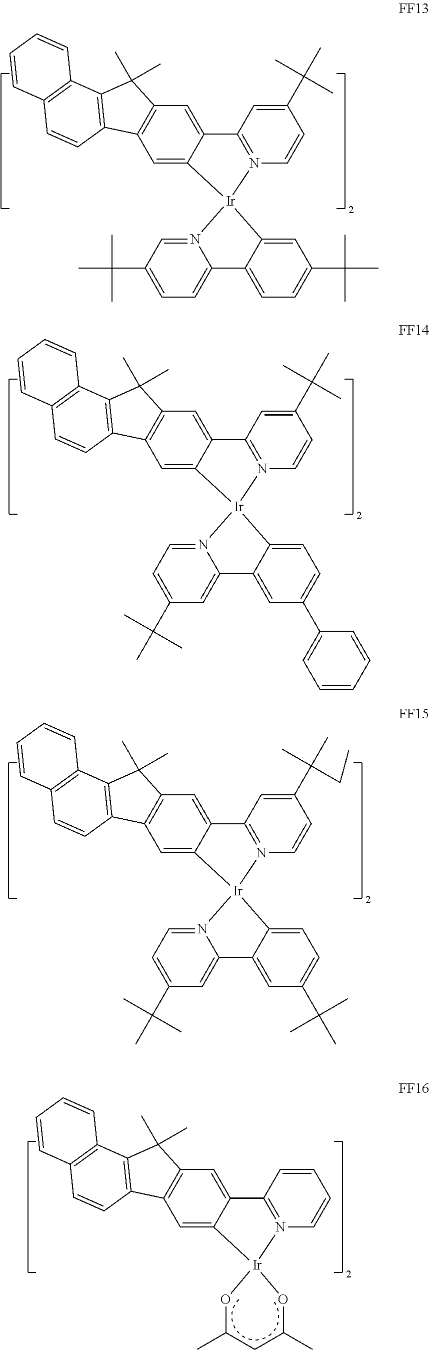

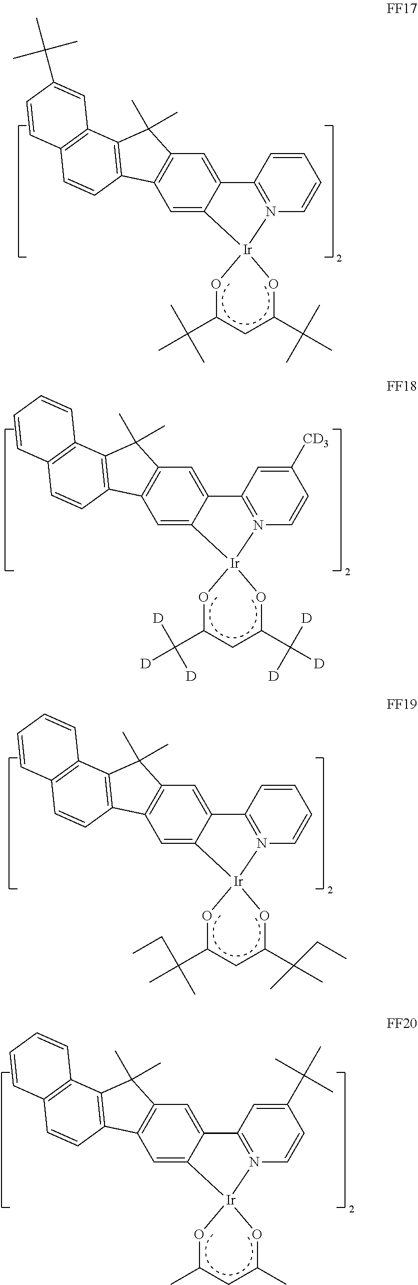

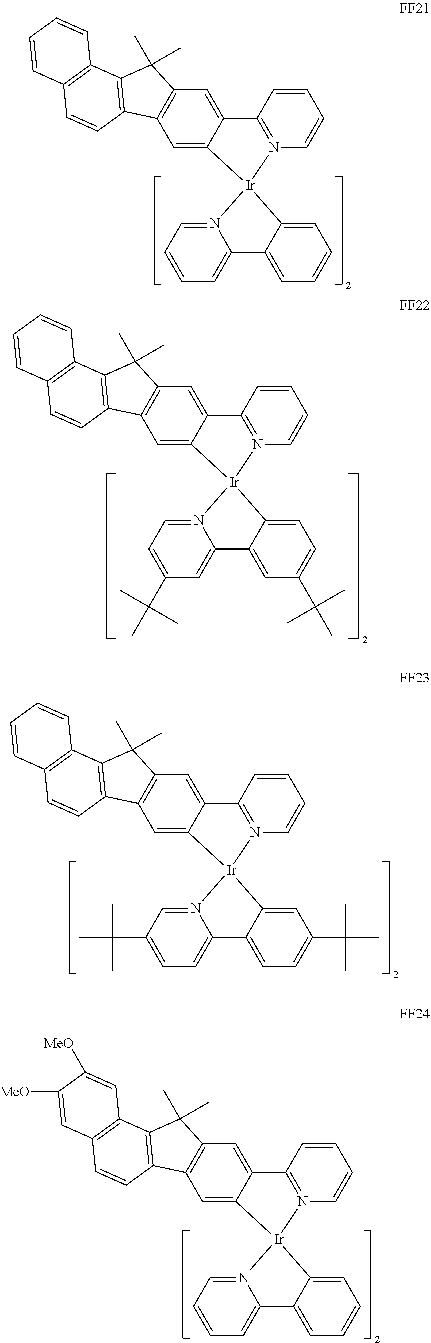

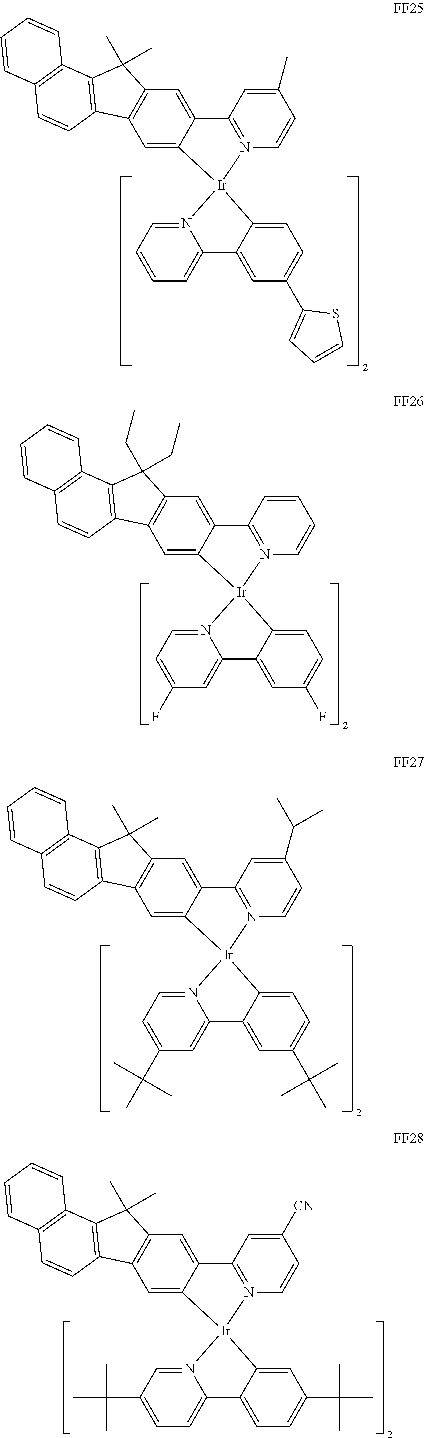

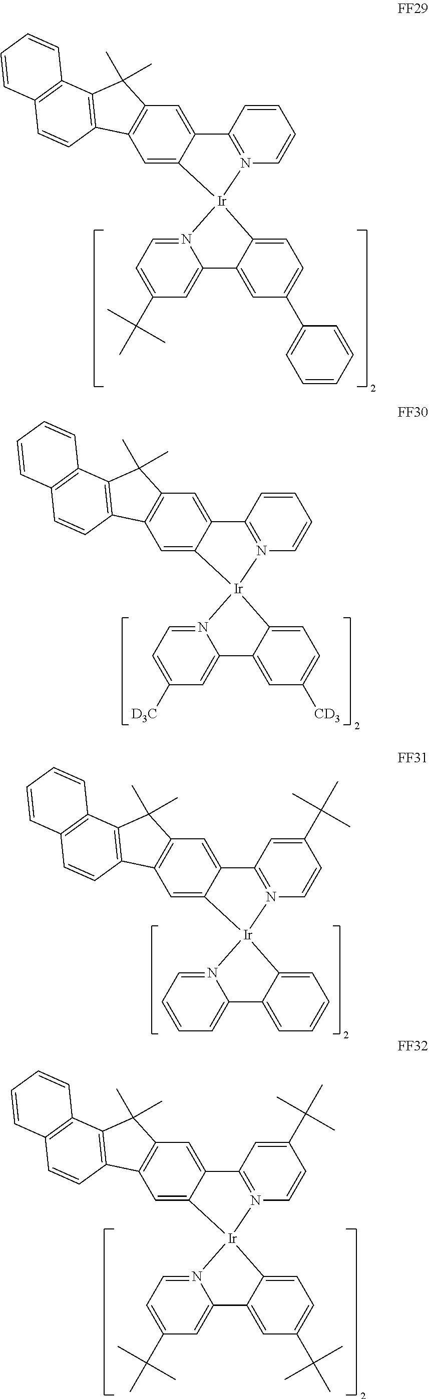

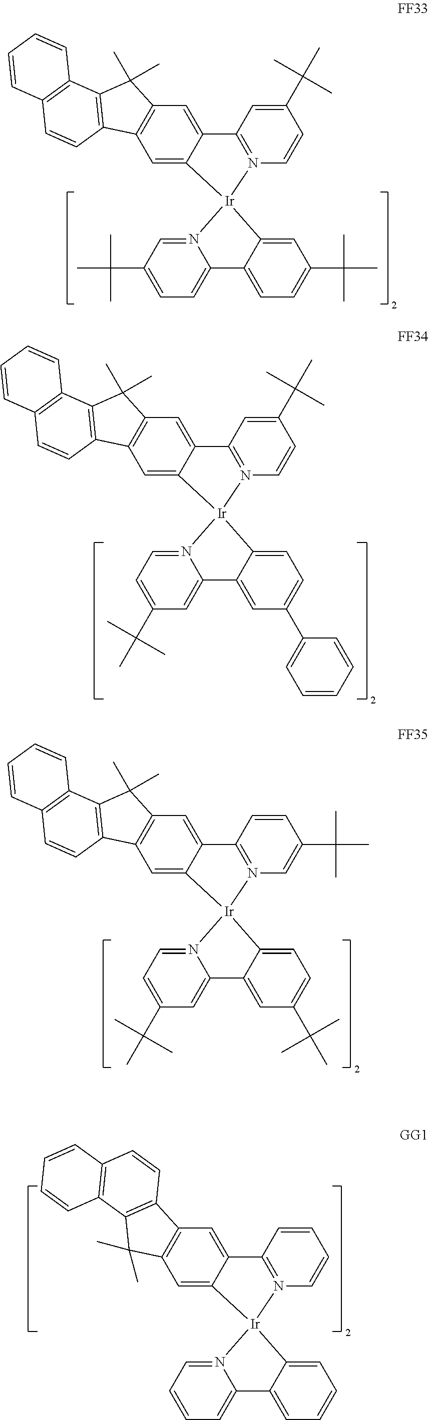

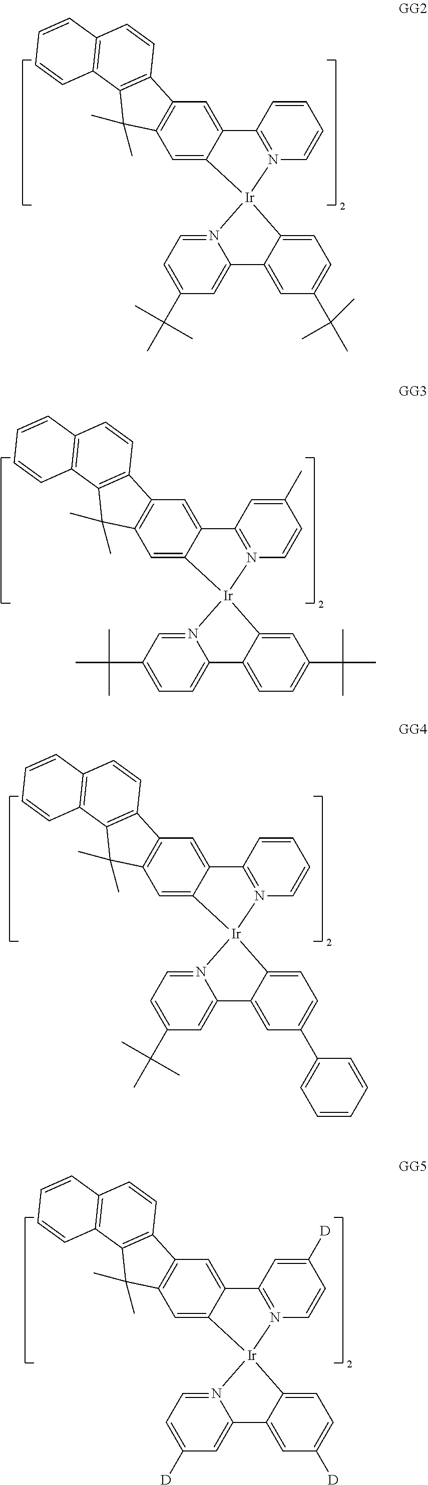

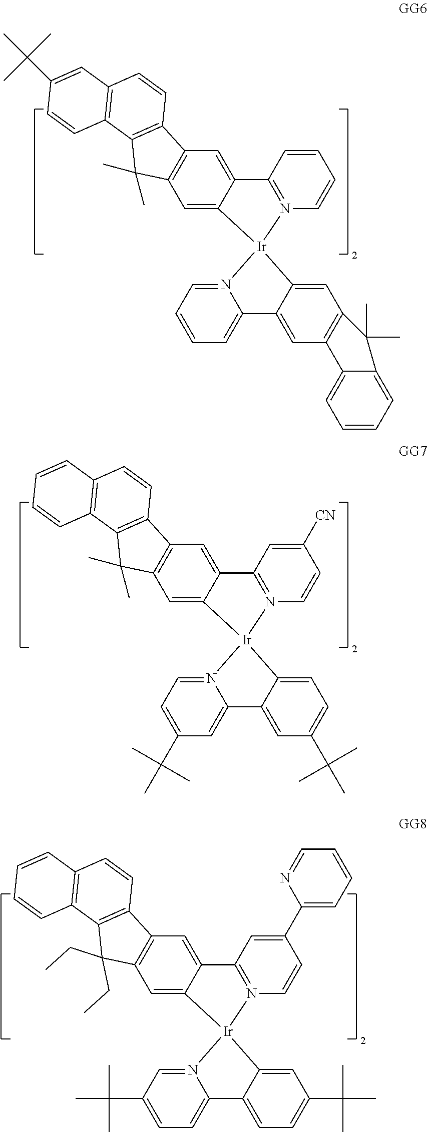

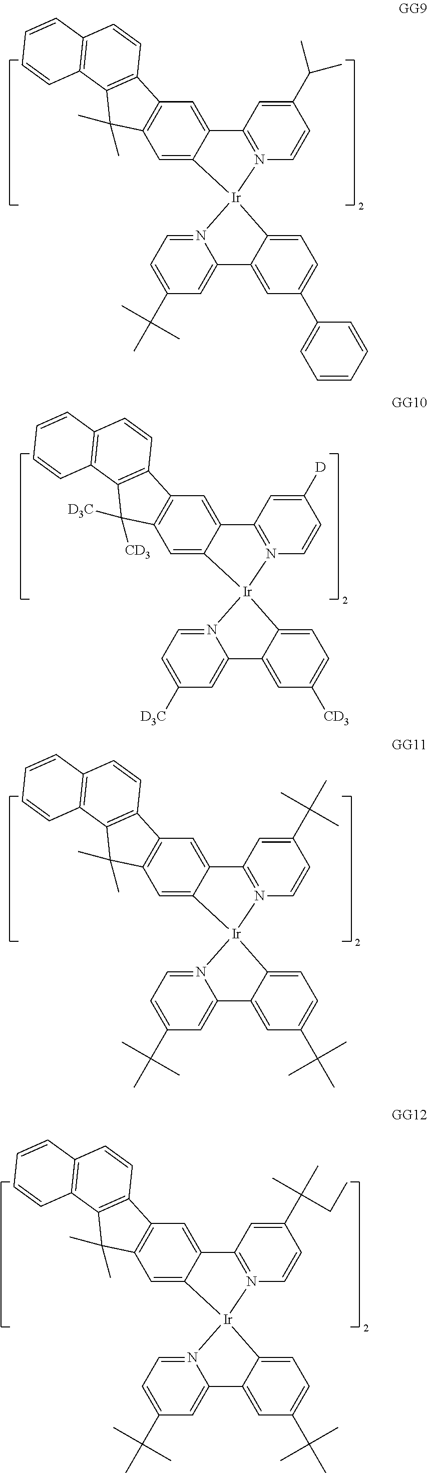

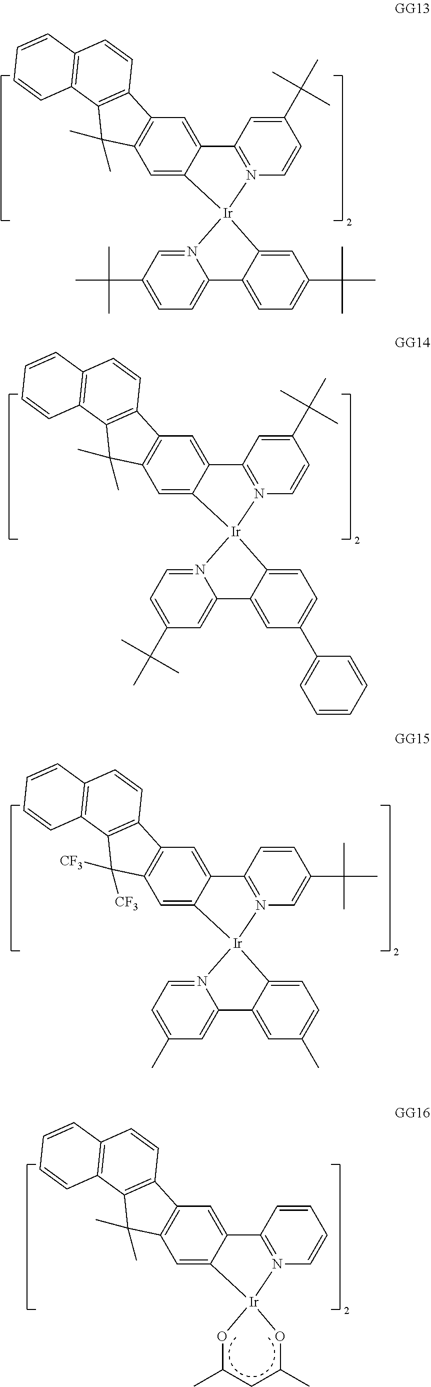

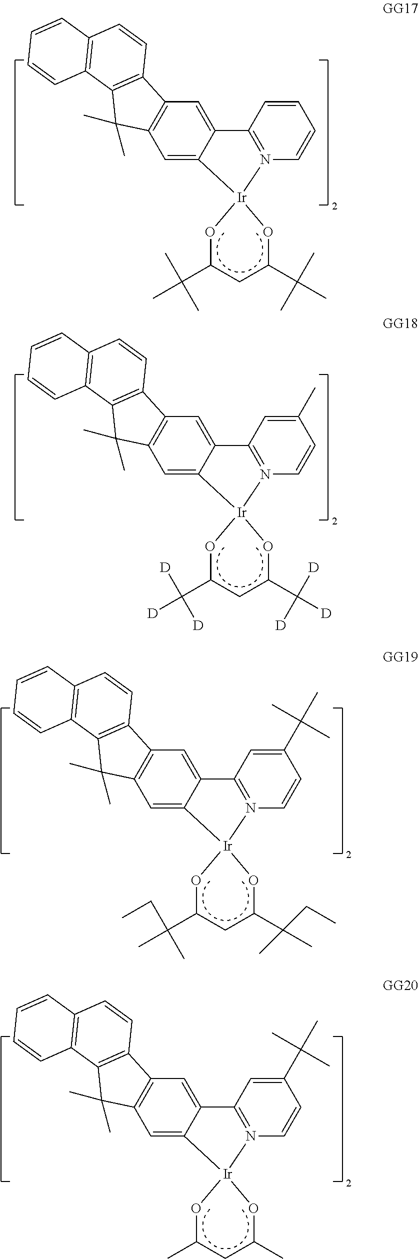

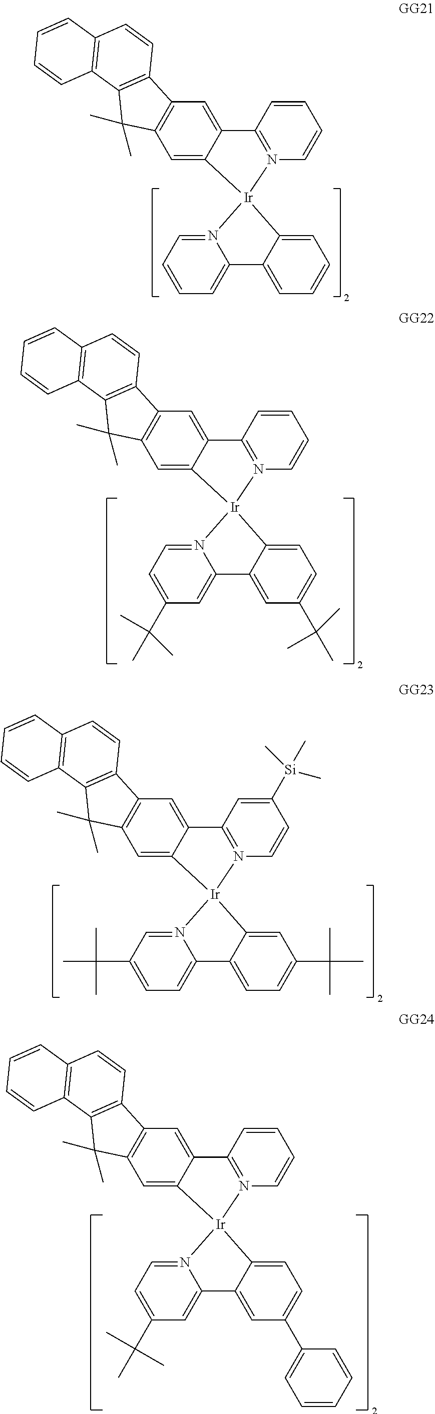

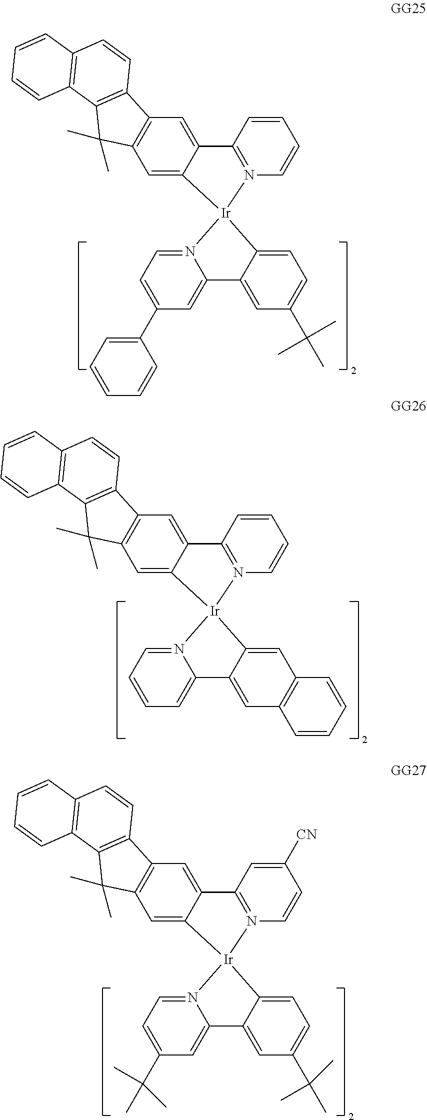

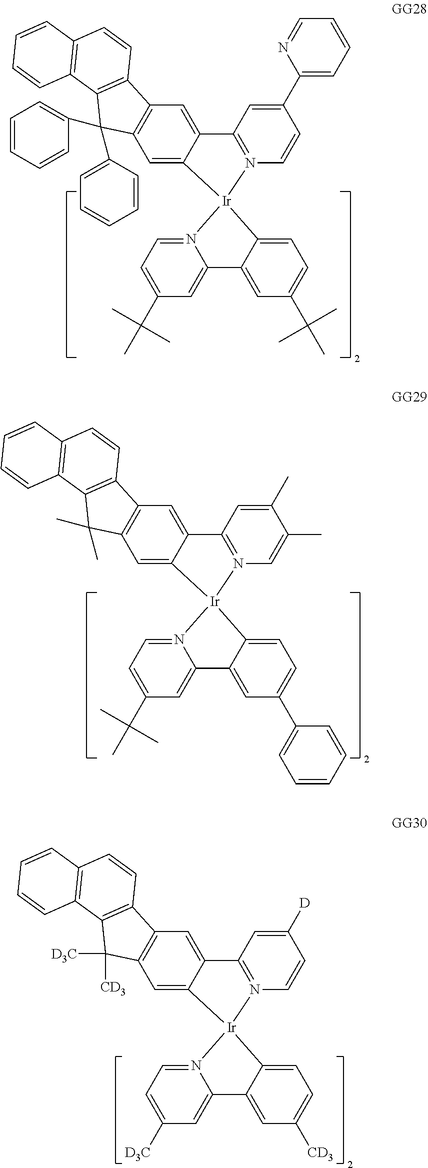

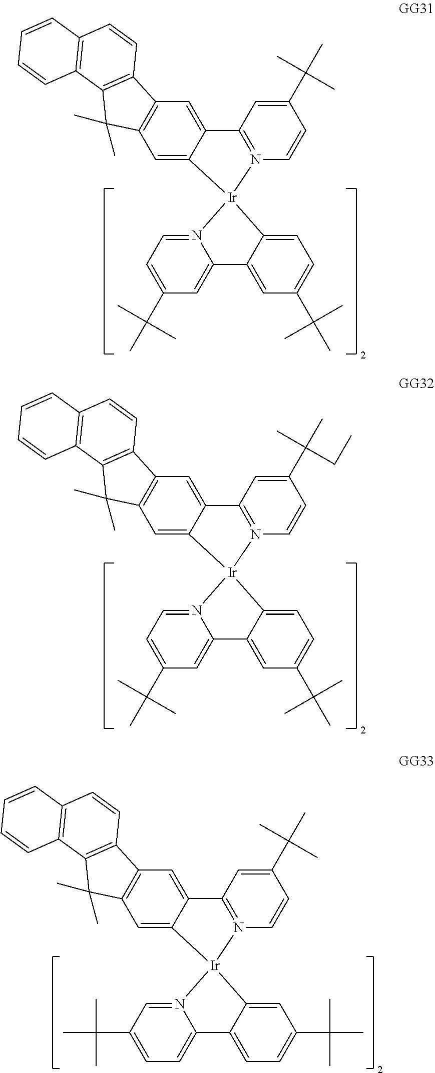

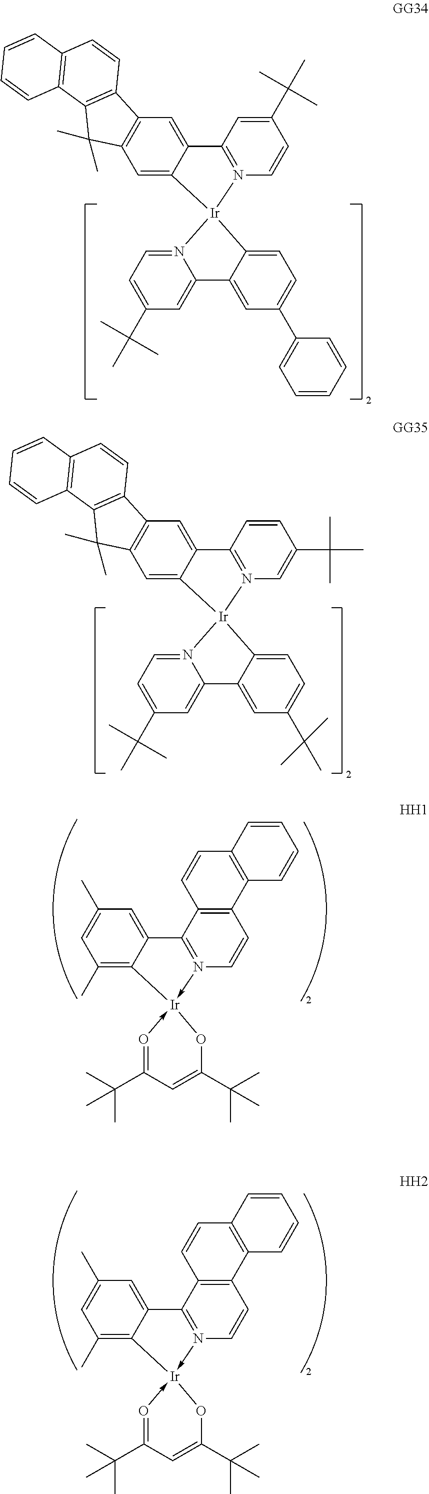

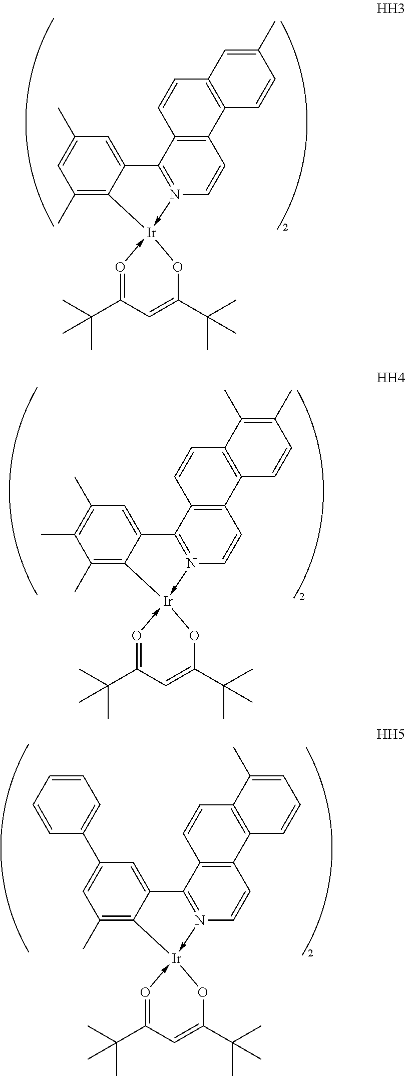

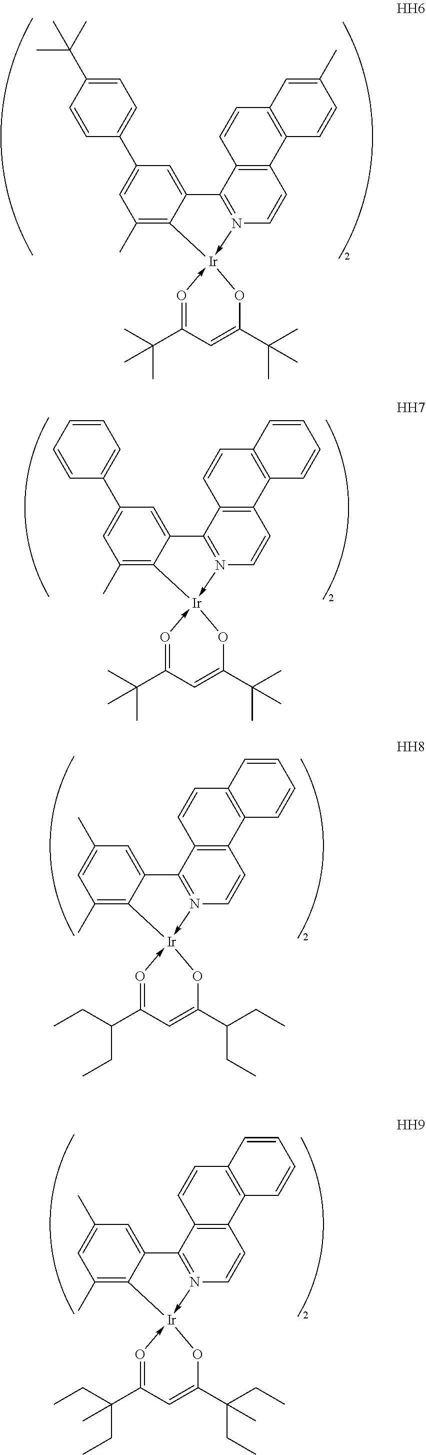

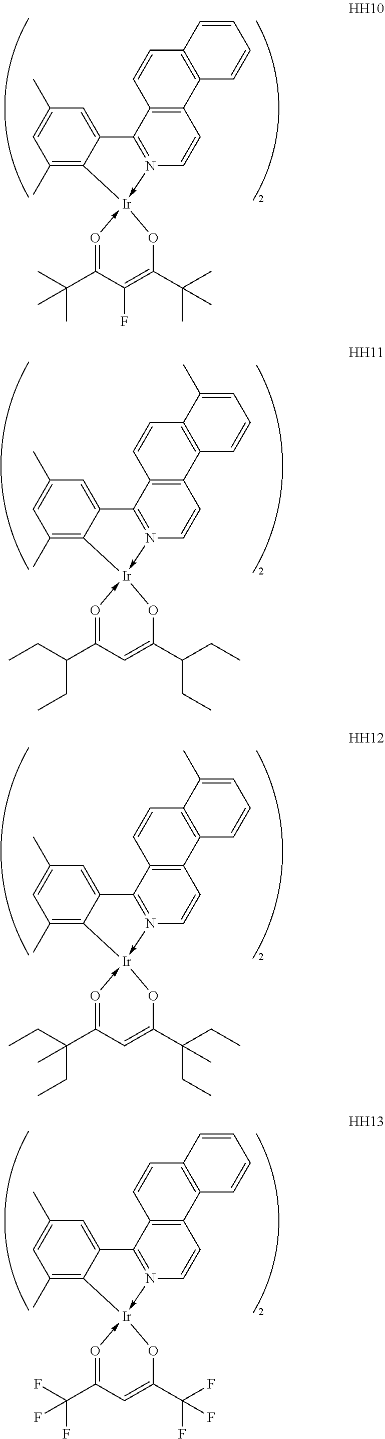

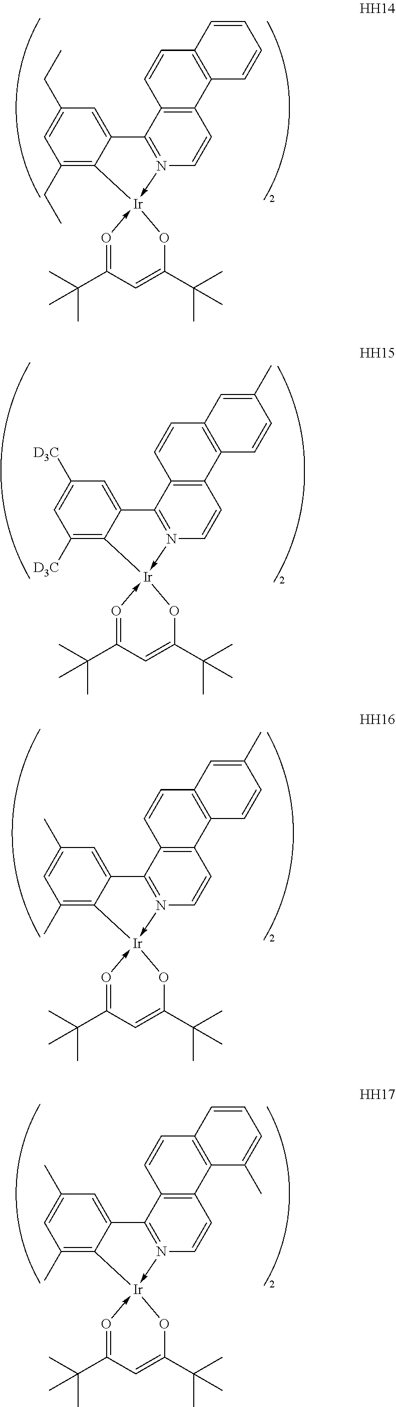

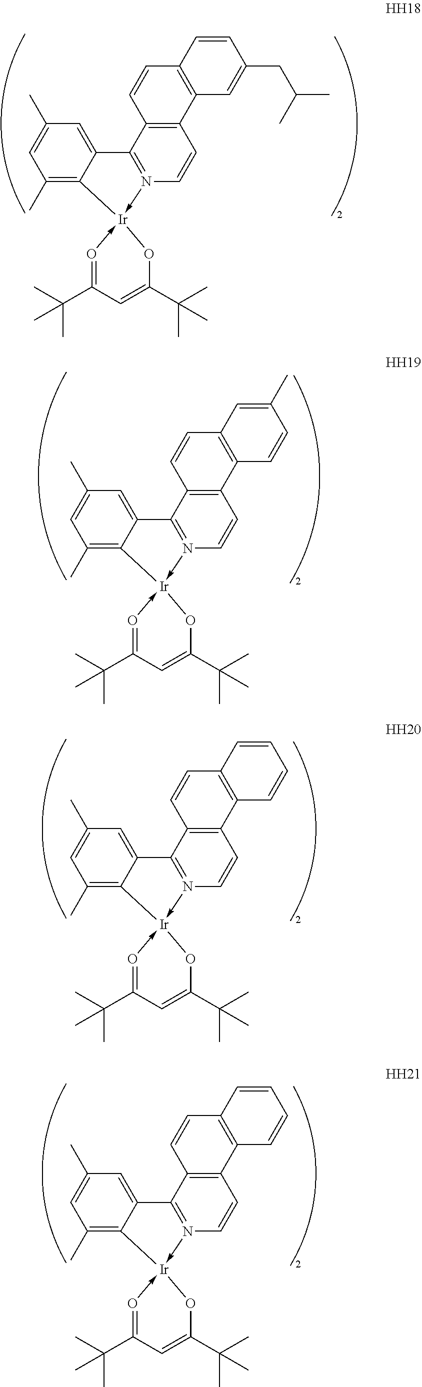

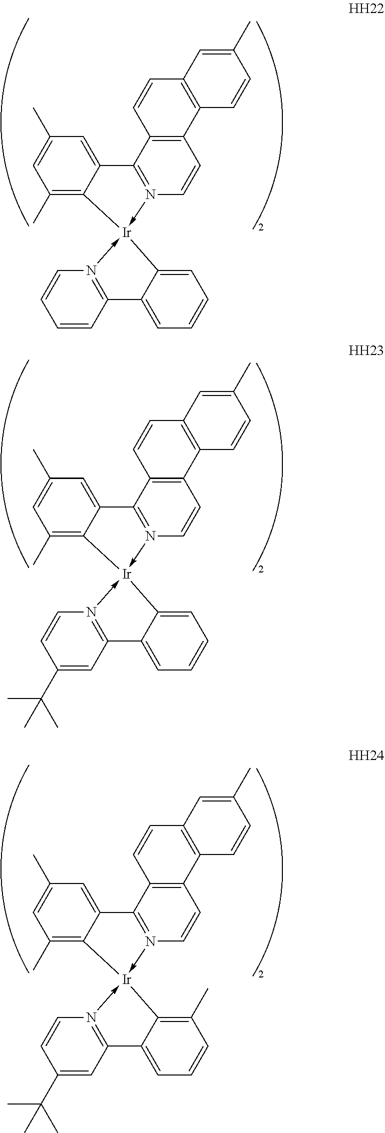

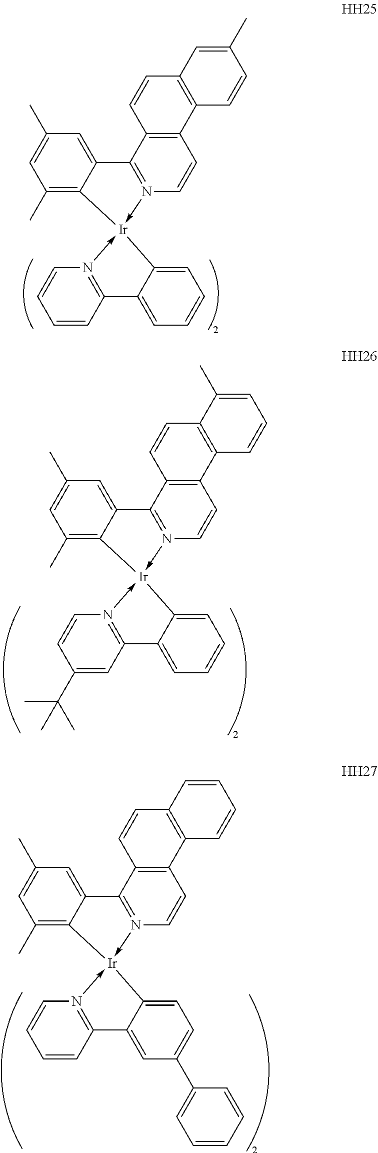

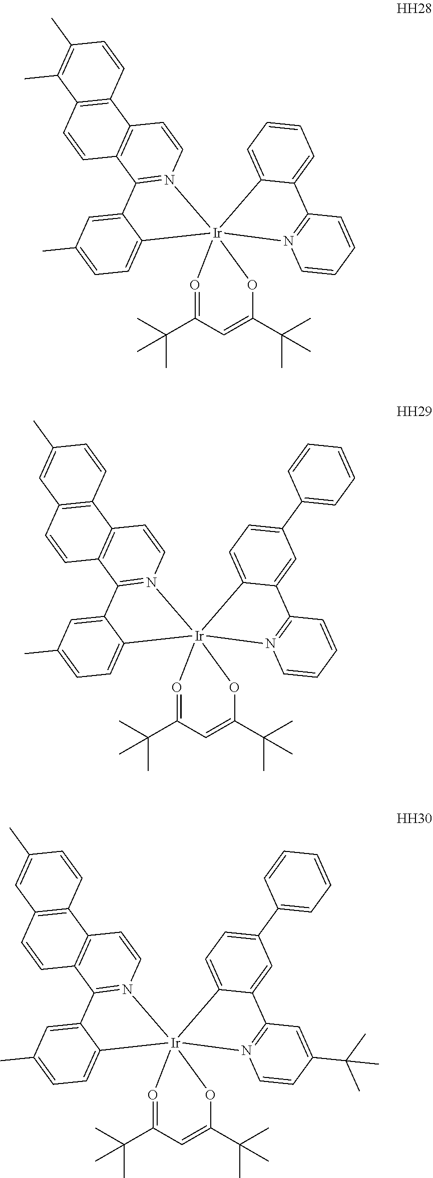

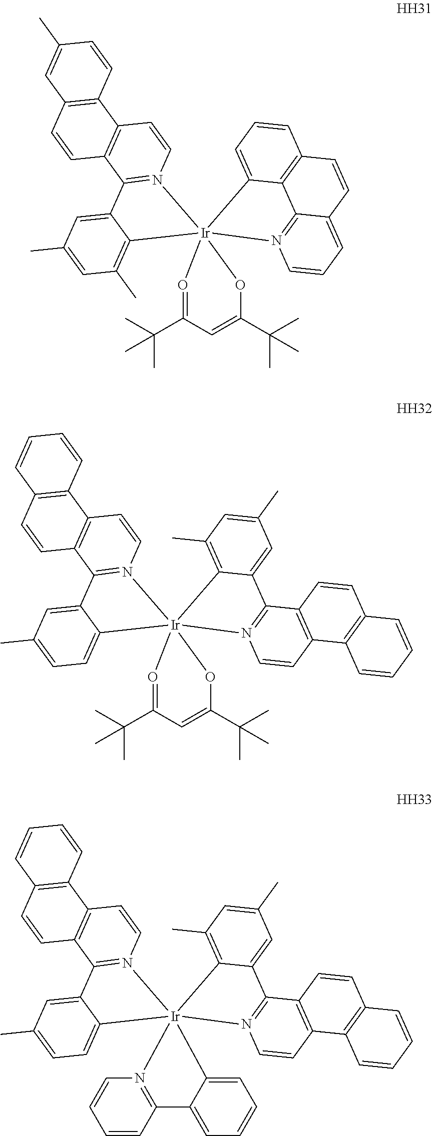

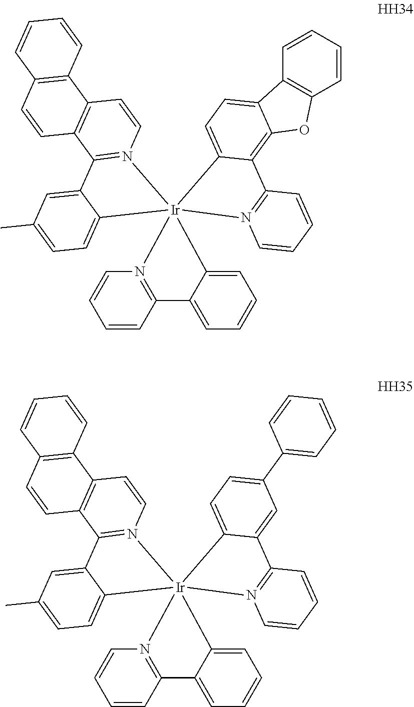

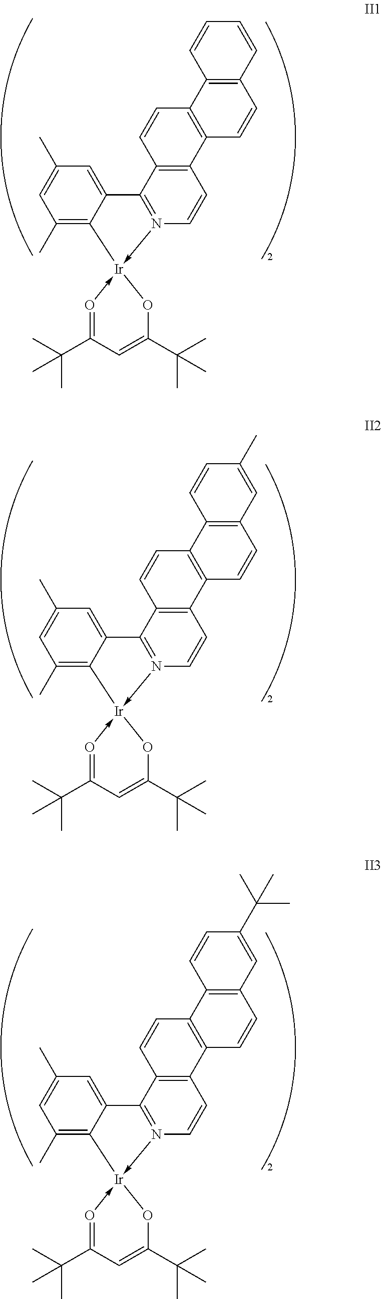

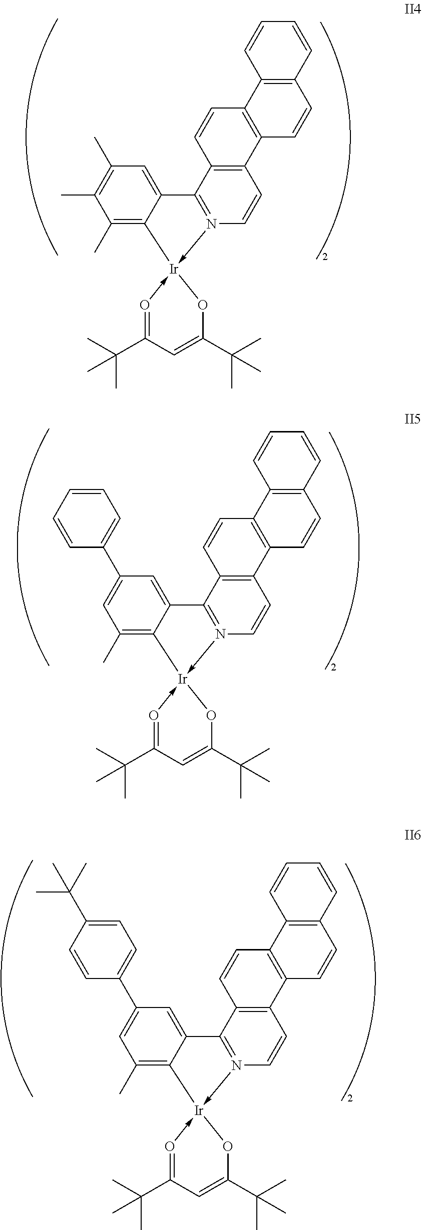

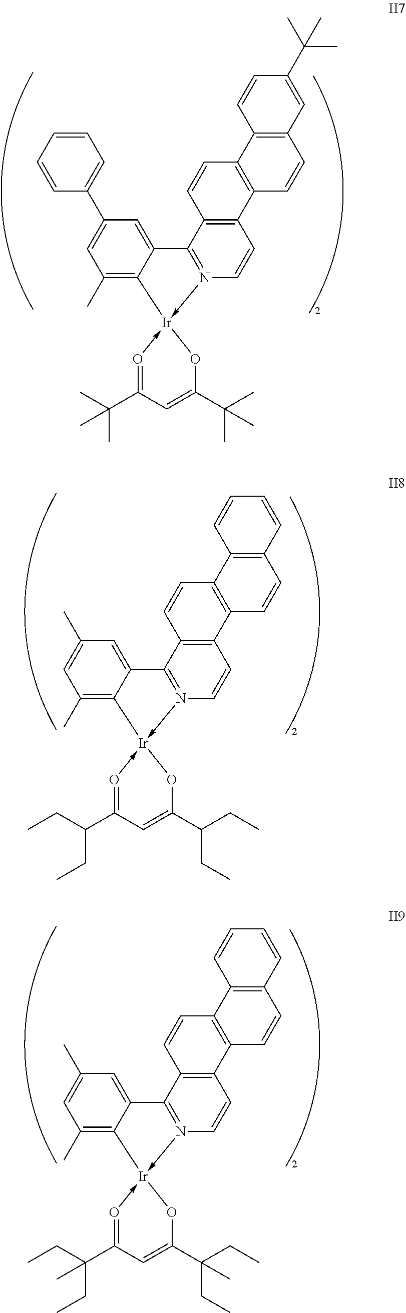

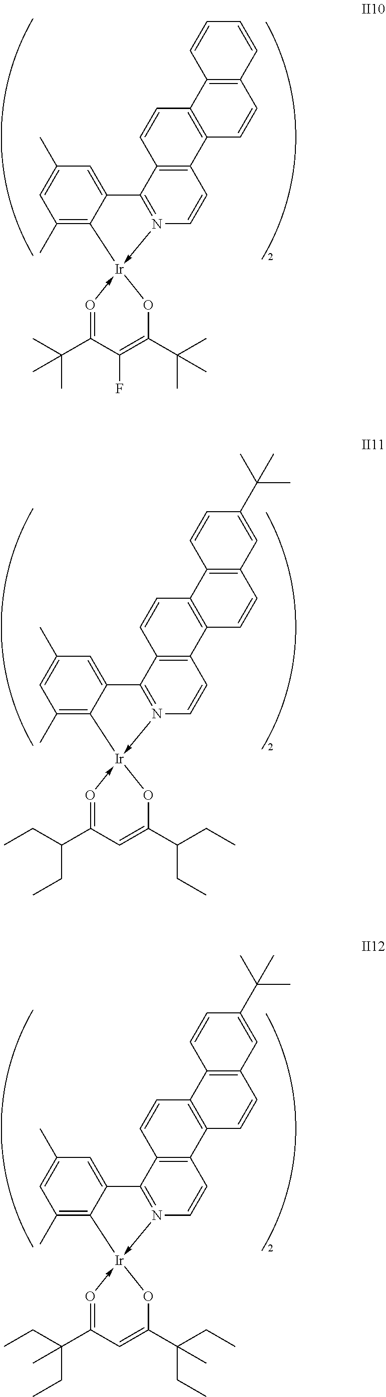

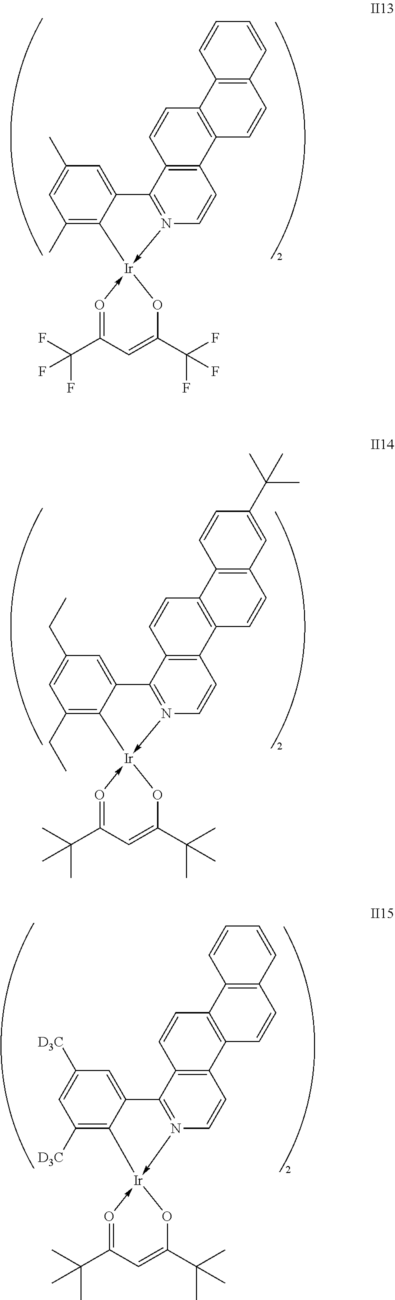

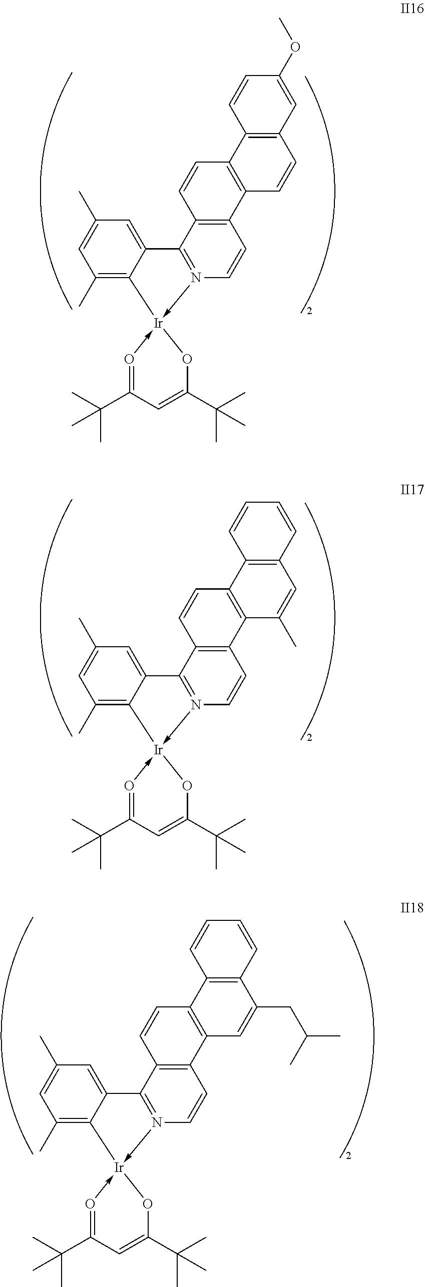

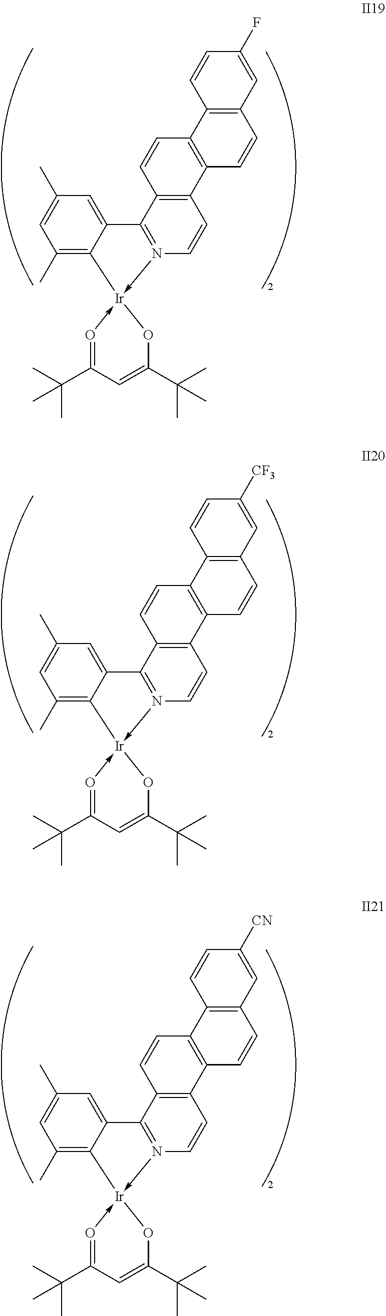

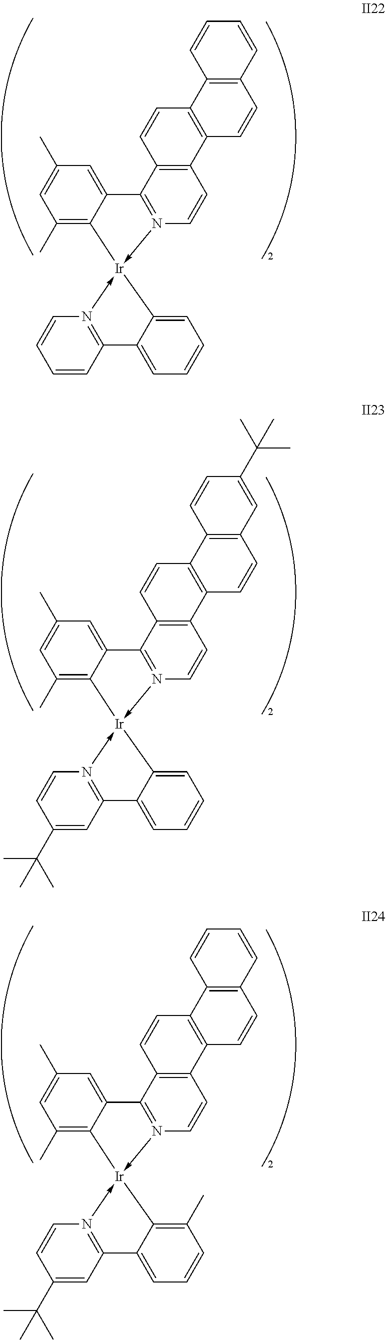

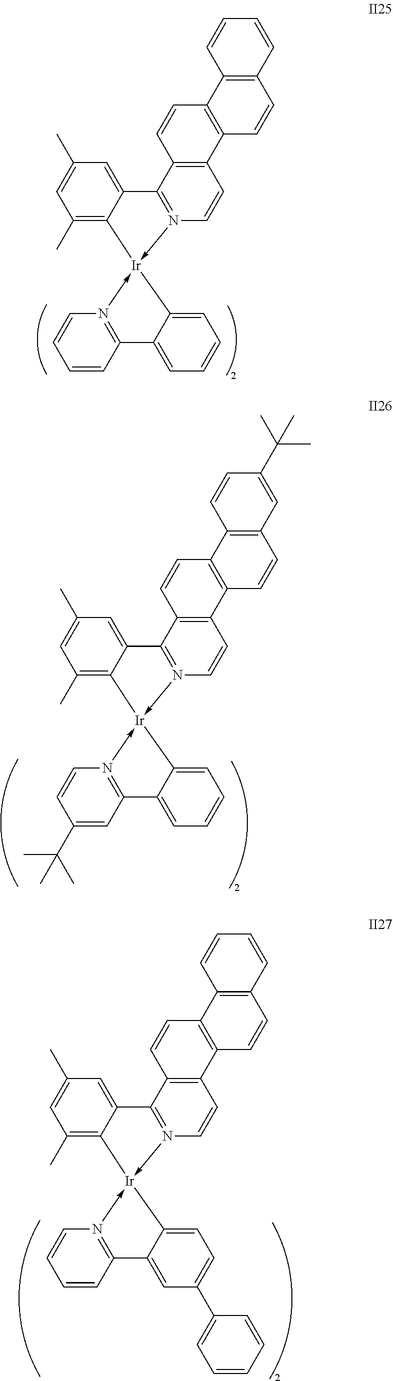

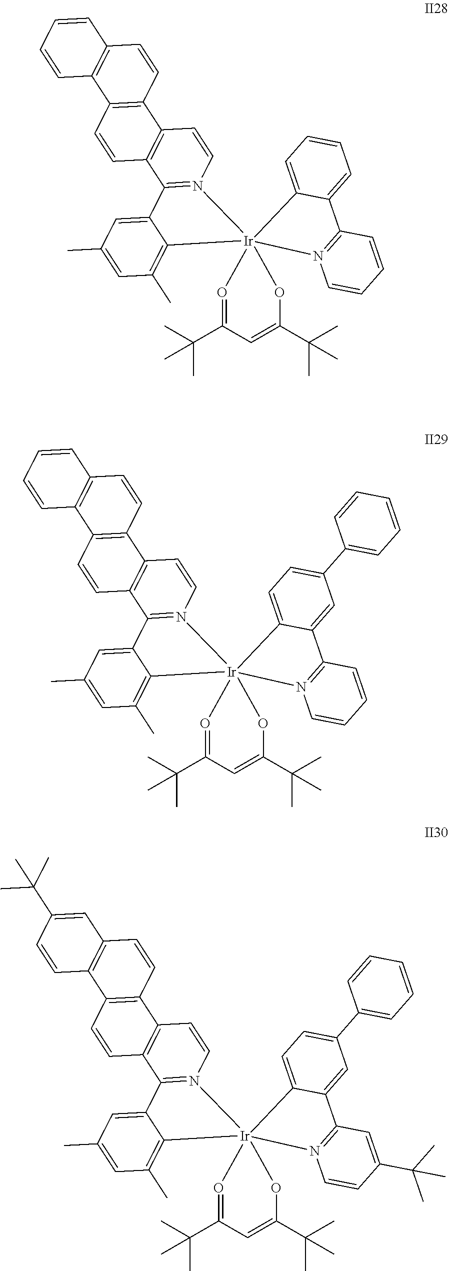

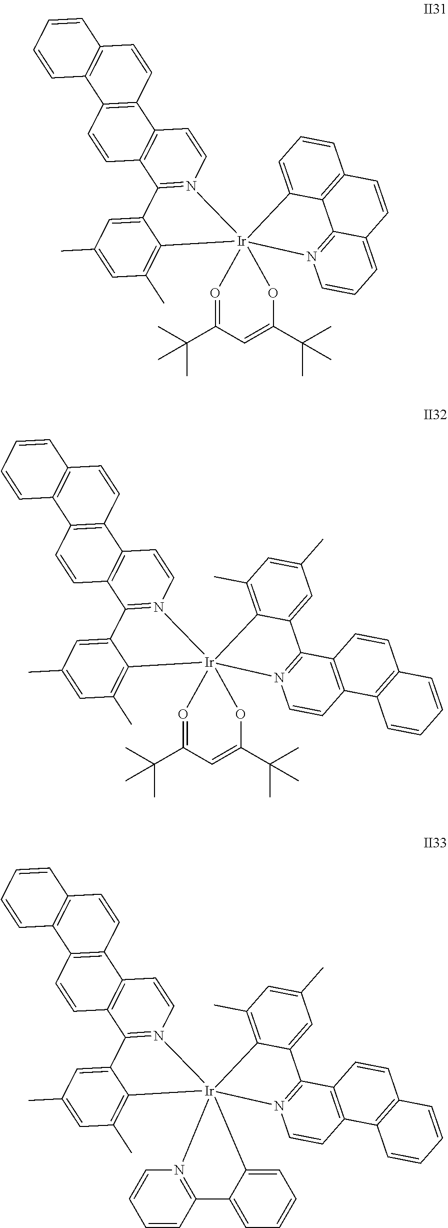

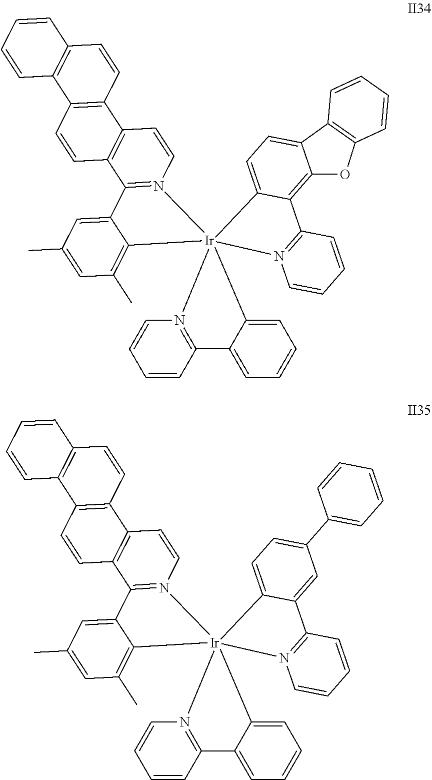

The fluorescence emitting material may be any compound that mainly emits fluorescence, and examples thereof include compounds represented by general formulae (5) to (10), compounds having multiple structures represented by general formula (5), compounds having multiple structures represented by general formula (7), and example compounds BD1 to BD8, BD10, BD11, GD1 to GD9, RD1, RD2, and ZBD-1 to ZBD-4.

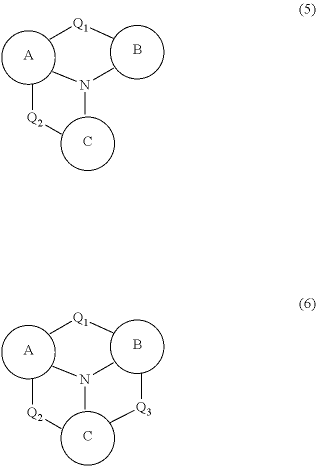

In general formulae (5) and (6), ring units A to C are each independently selected from substituted or unsubstituted aryl groups or substituted or unsubstituted heteroaryl groups. Q₁ to Q₃ are each independently selected from a direct bond, C(R_{A})(R_{B}), N(R_{C}), B(R_{D}), an oxygen atom, a sulfur atom, a selenium atom, and a tellurium atom. Q₁ to Q₃ may be B(R_{D}). R_{A} to R_{D} are each independently selected from a hydrogen atom, a deuterium atom, a halogen atom, a substituted or unsubstituted alkyl group, a substituted or unsubstituted alkoxy group, a substituted or unsubstituted aryl group, or a substituted or unsubstituted heteroaryl group. R_{A} and R_{B} may bond together to form a ring, R_{A} may bond with an adjacent ring unit A to C to form a ring, and R_{B} may bond with an adjacent ring unit A to C to form a ring. R_{C} may form a ring together with an adjacent ring unit A to C.

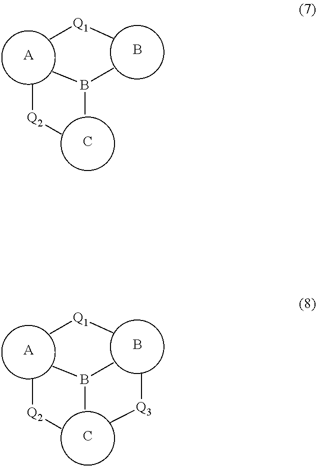

In general formulae (7) and (8), ring units A to C are each independently selected from substituted or unsubstituted aryl groups or substituted or unsubstituted heteroaryl groups. Q₁ to Q₃ are each independently selected from a direct bond, C(R_{A})(R_{B}), N(R_{C}), B(R_{D}), an oxygen atom, a sulfur atom, a selenium atom, and a tellurium atom. Q₁ to Q₃ may be N(R_{C}). R_{A} to R_{D} are each independently selected from a hydrogen atom, a deuterium atom, a halogen atom, a substituted or unsubstituted alkyl group, a substituted or unsubstituted alkoxy group, a substituted or unsubstituted aryl group, or a substituted or unsubstituted heteroaryl group. R_{A} and R_{B} may bond together to form a ring, R_{A} may bond with an adjacent ring unit A to C to form a ring, R_{B} may bond with an adjacent ring unit A to C to form a ring. R_{C} may form a ring together with an adjacent ring unit A to C.

In the compound composed of multiple structures represented by general formula (5), the multiple structures represented by general formula (5) may be fused via the ring A, via the ring B, or via the ring C. The same applies to the compound composed of multiple structures represented by general formula (6). An example of the compound composed of multiple structures represented by general formula (5) is described below, but this example is not limiting.

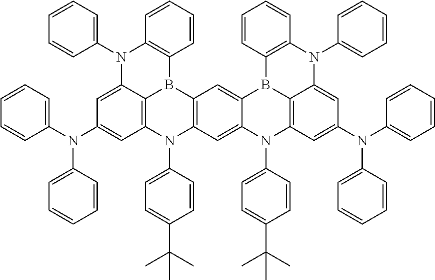

In the compound composed of multiple structures represented by general formula (7), the multiple structures represented by general formula (7) may be fused via the ring A, via the ring B, or via the ring C. The same applies to the compound composed of multiple structures represented by general formula (8).

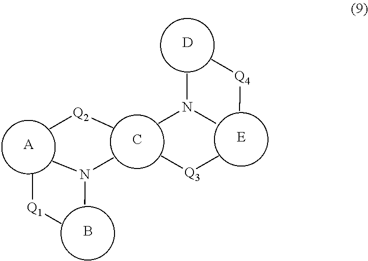

In general formula (9), ring units A to E are each independently selected from substituted or unsubstituted aryl groups or substituted or unsubstituted heteroaryl groups. The ring units A to E may be substituted or unsubstituted benzene skeletons. The ring units A, B, D, and E may be substituted or unsubstituted benzene skeletons, and the ring unit C may be a substituted or unsubstituted benzene skeleton or a naphthalene skeleton. Q₁ to Q₃ are each independently selected from a direct bond, C(R_{A})(R_{B}), N(R_{C}), B(R_{D}), an oxygen atom, a sulfur atom, a selenium atom, and a tellurium atom. Q₁ to Q₄ may be direct bonds. R_{A} to R_{D} are each independently selected from a hydrogen atom, a deuterium atom, a halogen atom, a substituted or unsubstituted alkyl group, a substituted or unsubstituted alkoxy group, a substituted or unsubstituted aryl group, or a substituted or unsubstituted heteroaryl group.

Specific examples of the compound represented by general formula (9) are described below, but these examples are not limiting.

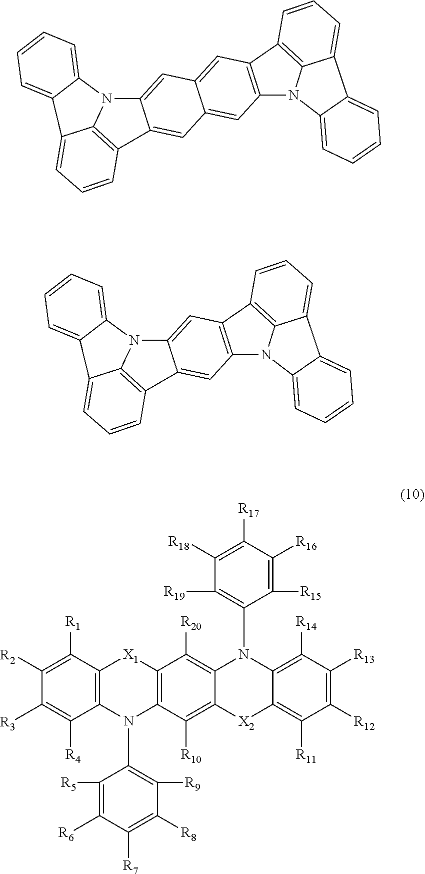

In general formula (10), R₁ to R₂₀ are each independently selected from the group consisting of a hydrogen atom, a deuterium atom, a halogen atom, a substituted or unsubstituted alkyl group, a substituted or unsubstituted alkoxy group, a substituted or unsubstituted silyl group, a substituted or unsubstituted amino group, a substituted or unsubstituted aryl group, a substituted or unsubstituted heteroaryl group, and a cyano group. R₁ to R₂₀ may bond together to form a ring. This bond may be formed via a chalcogen atom. At least one of the combination of R₄ and R₅, the combination of R₉ and R₁₀, the combination of R₁₄ and R₁₅, and the combination of R₁₉ and R₂₀ forms a bond. Preferably, at least one of the combination of R₉ and R₁₀ and the combination of R₁₉ and R₂₀ forms a bond. X1 and X2 are each independently selected from the group consisting of chalcogen atom, a substituted or unsubstituted imino group, a substituted or unsubstituted methylene group, and a substituted or unsubstituted silylene group.

Although specific examples of general formula (10) are described below, these examples are not limiting.

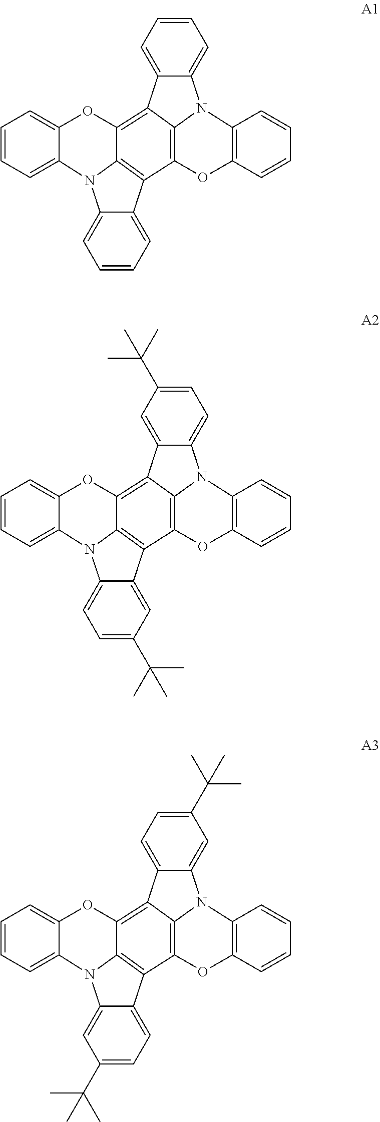

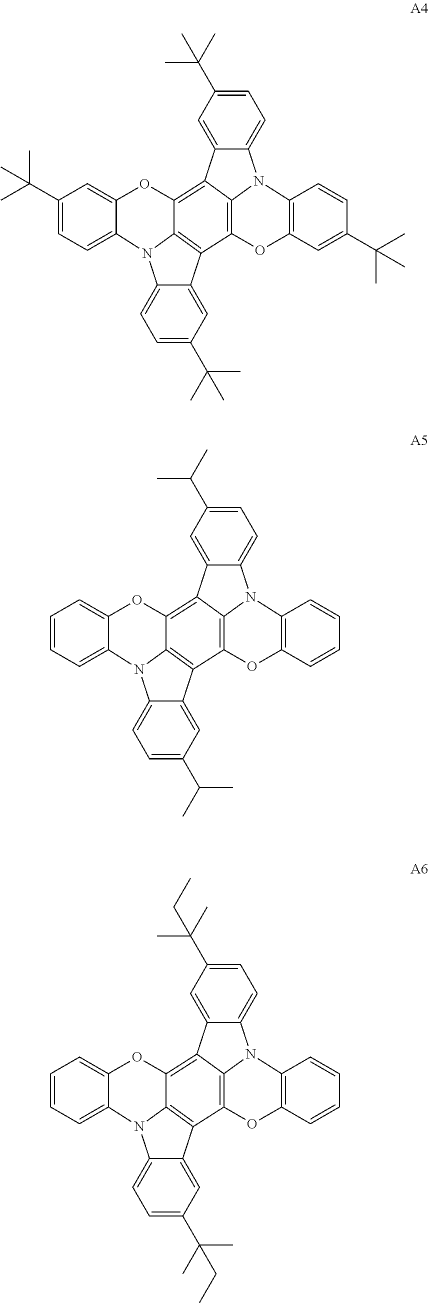

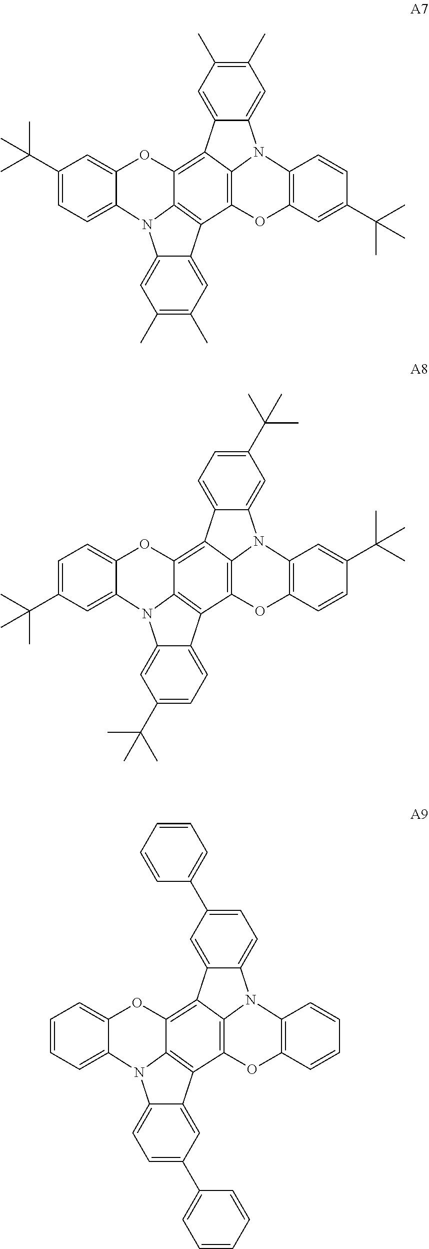

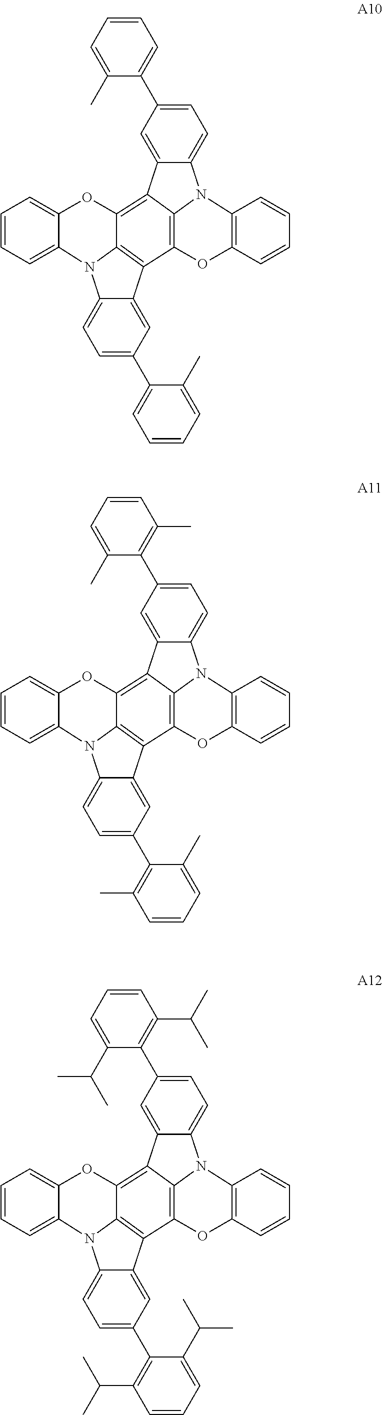

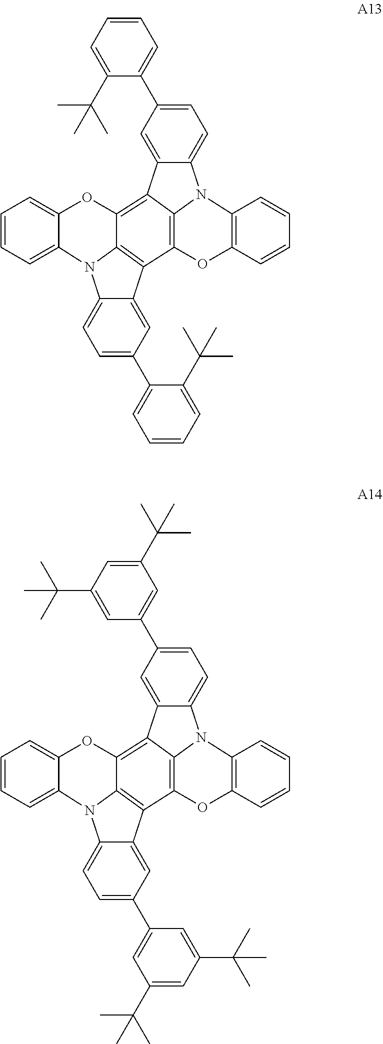

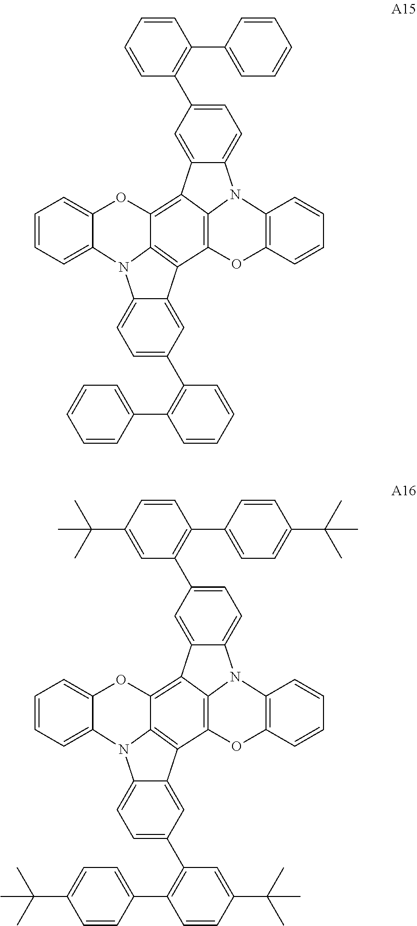

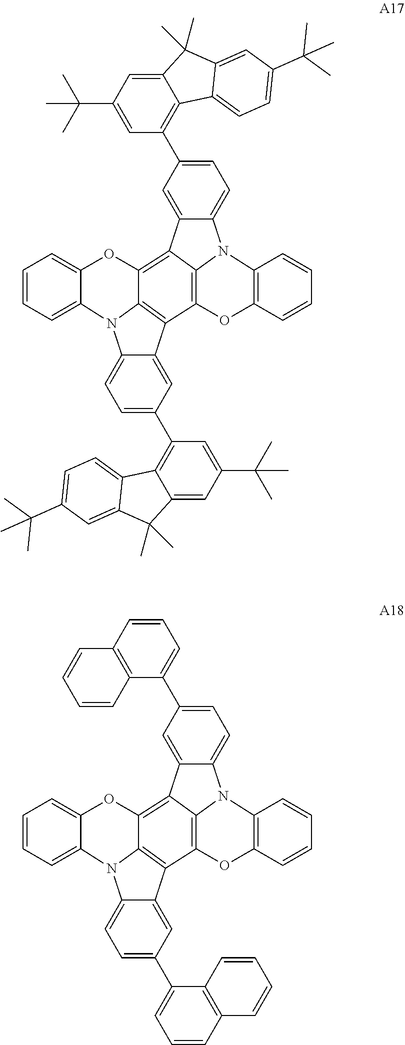

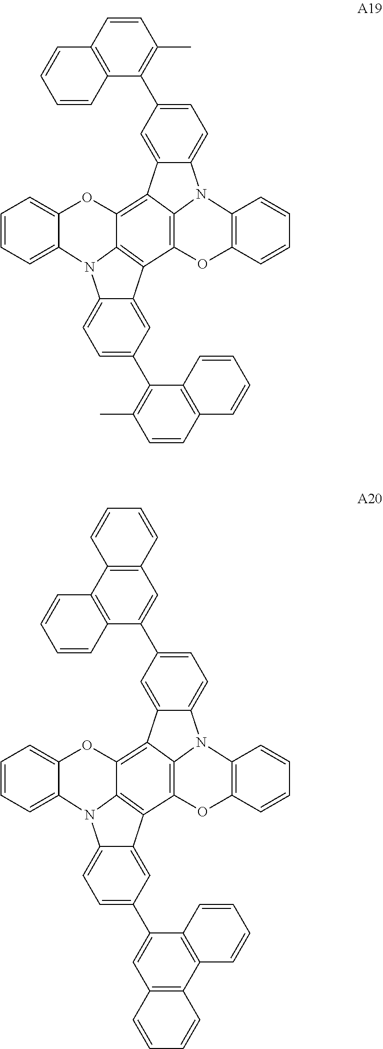

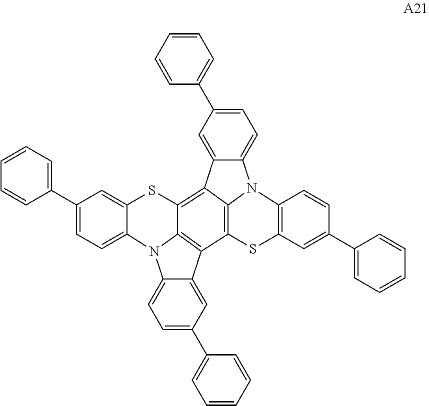

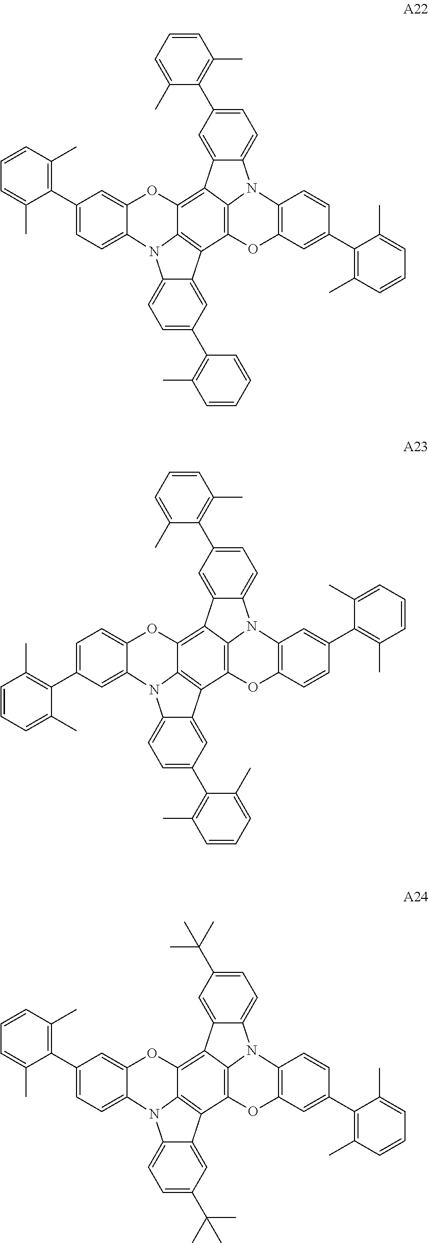

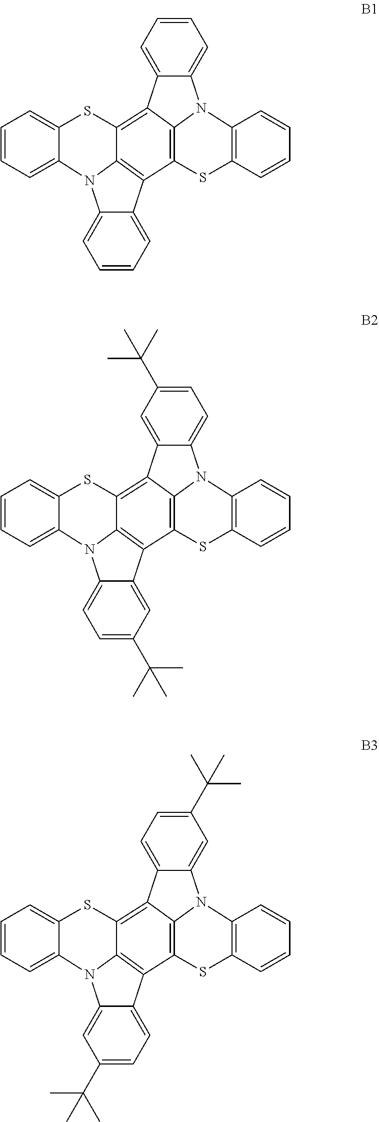

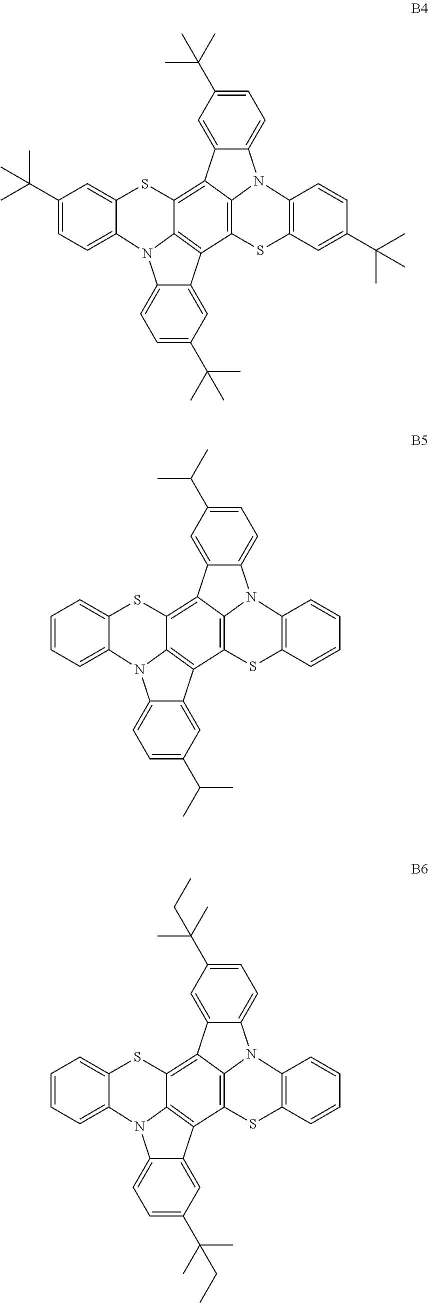

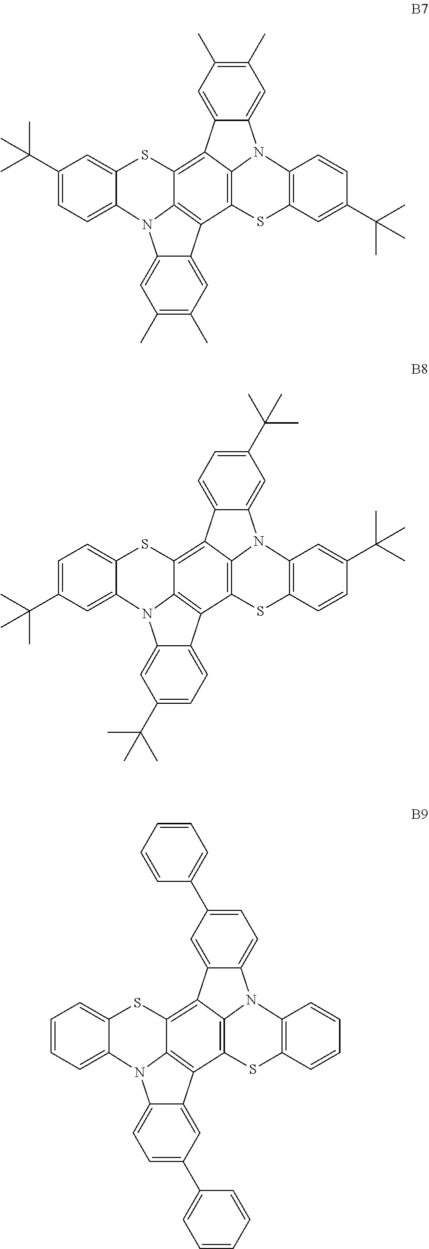

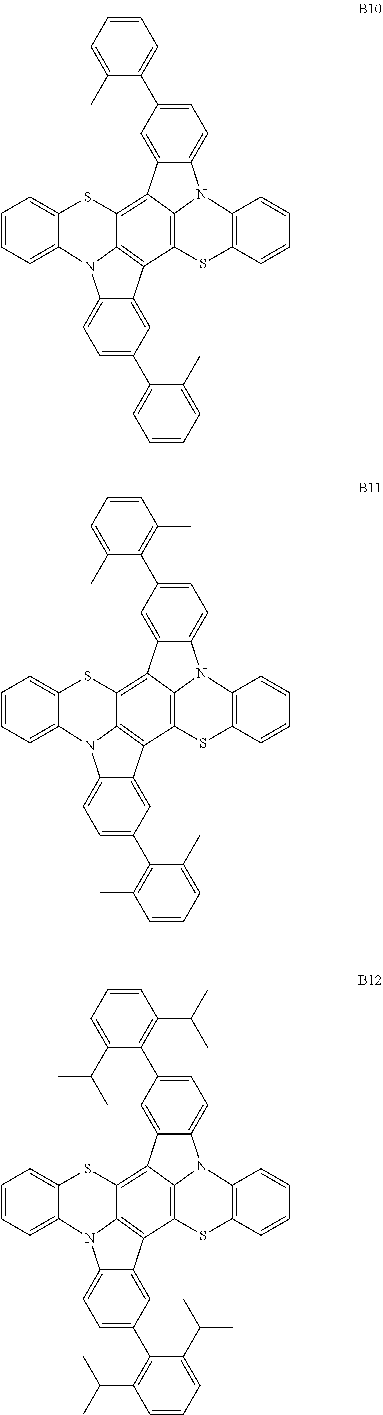

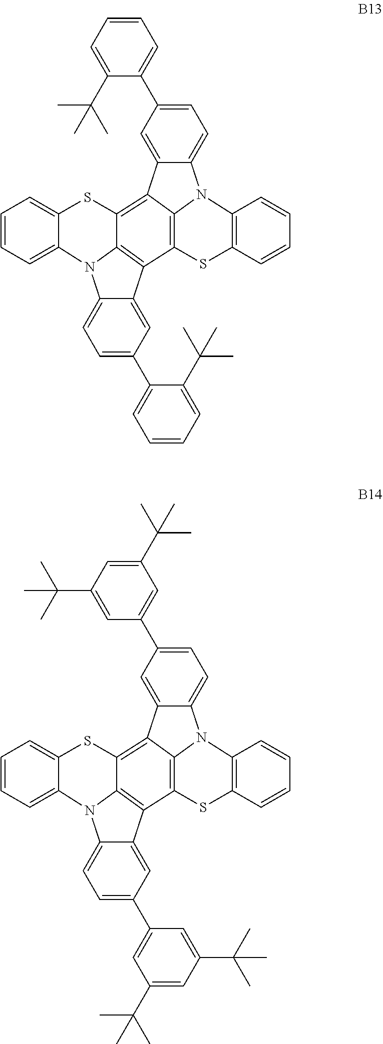

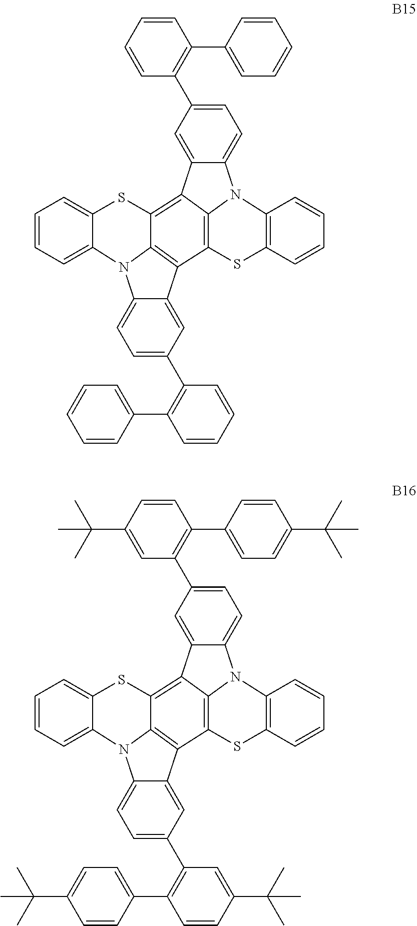

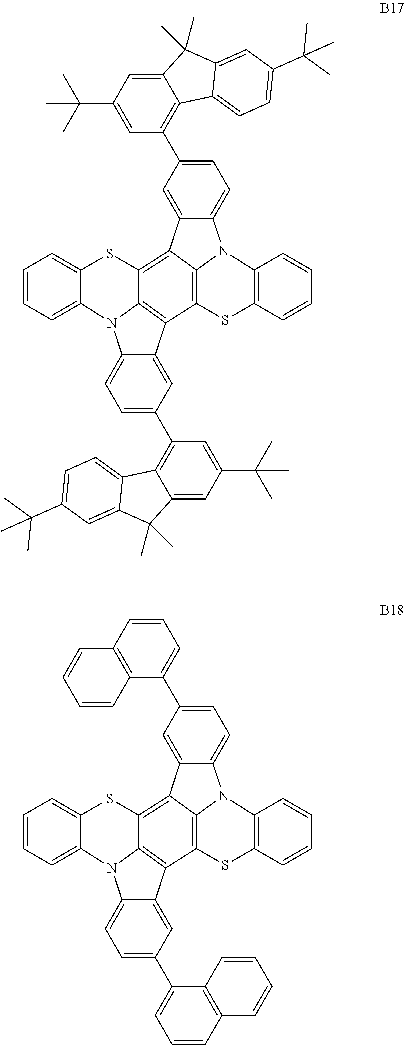

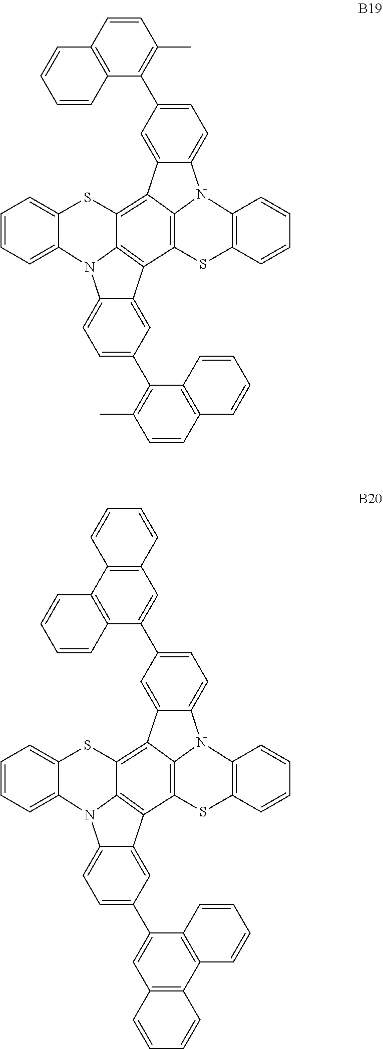

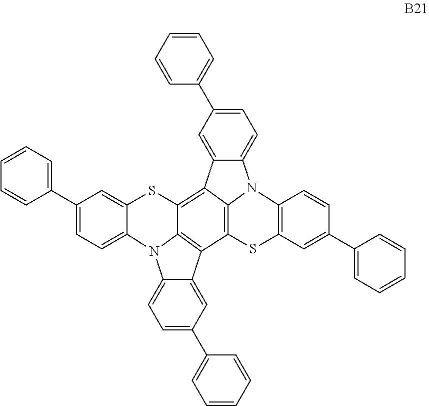

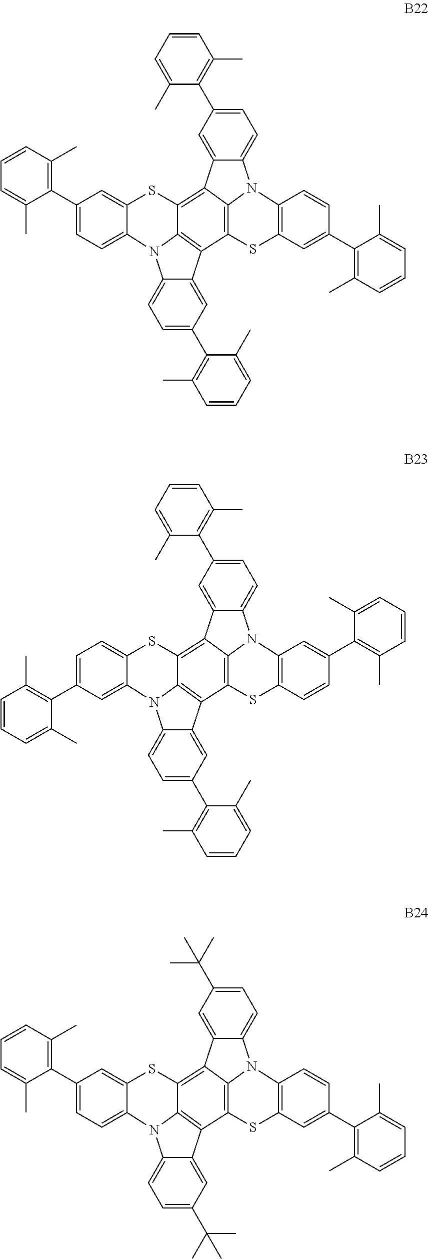

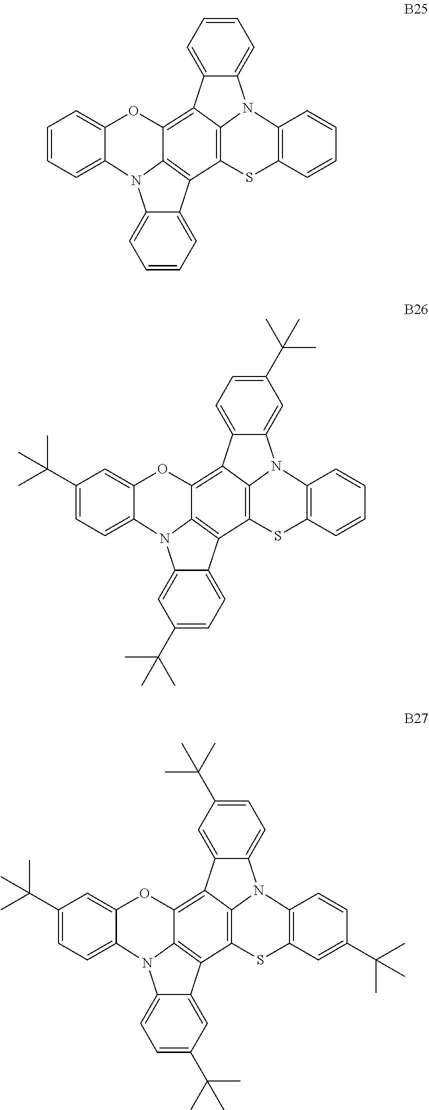

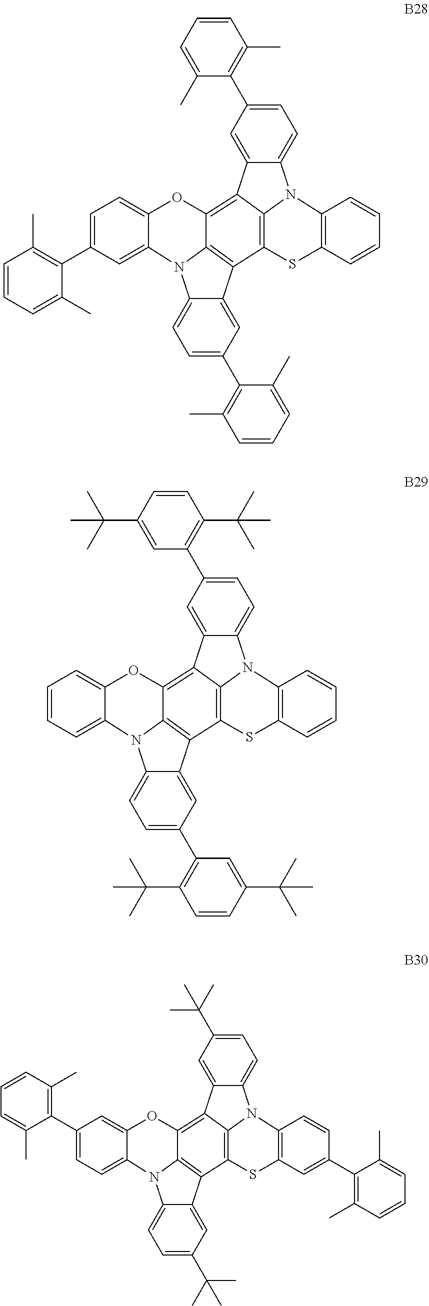

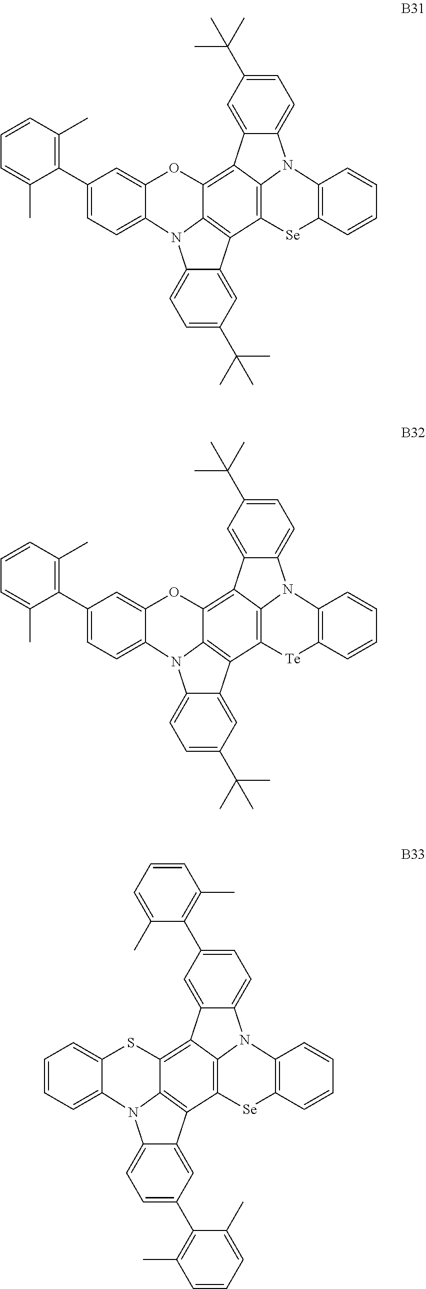

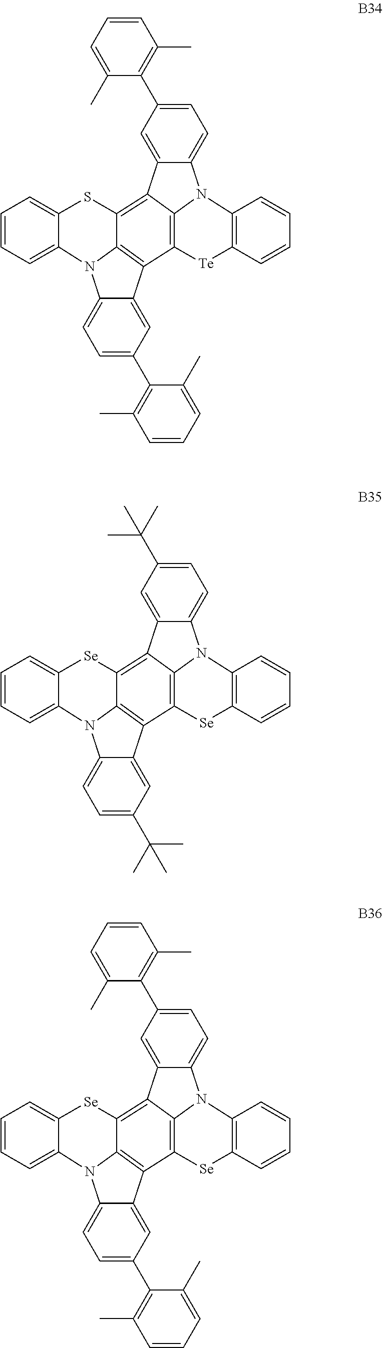

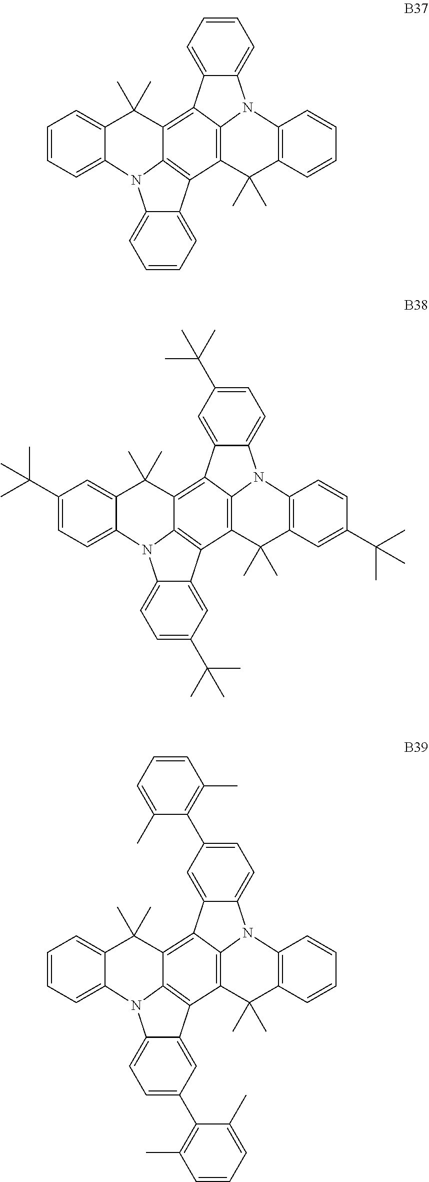

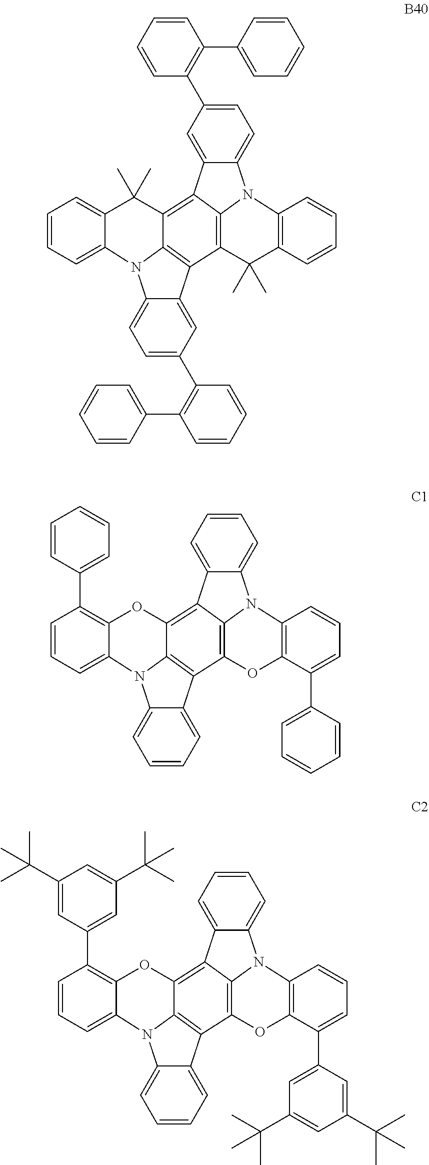

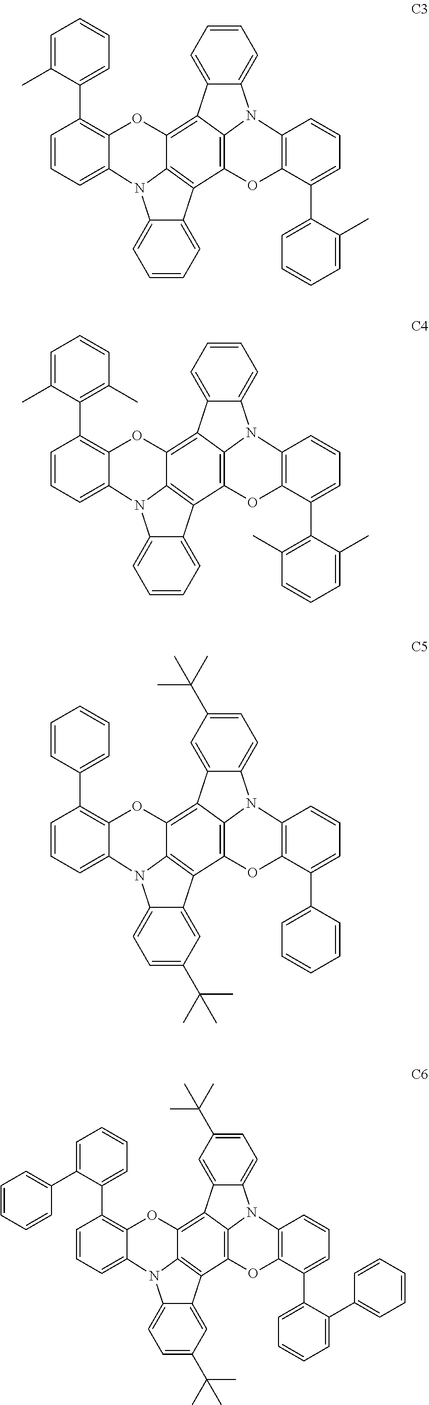

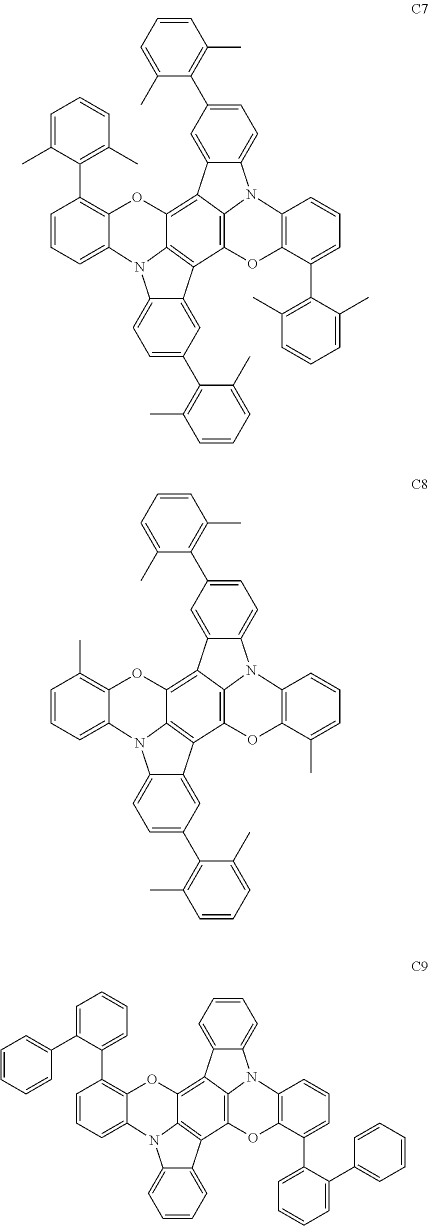

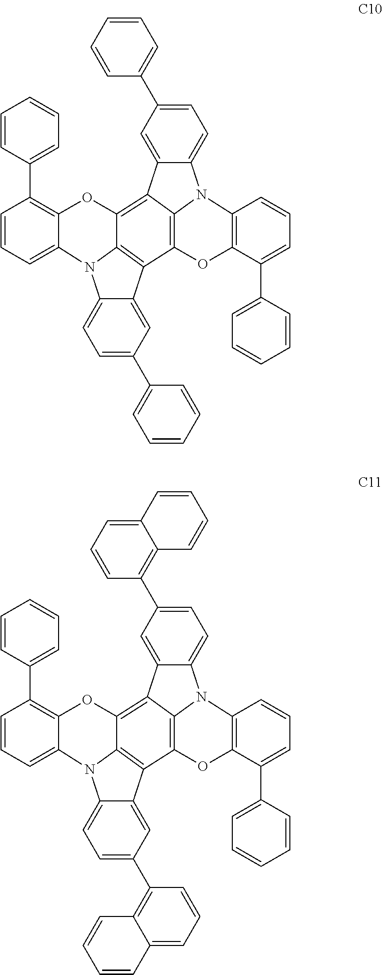

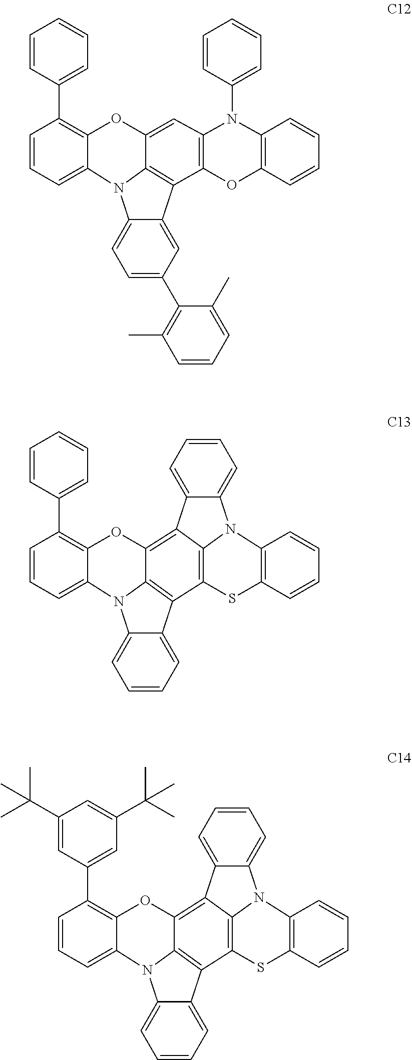

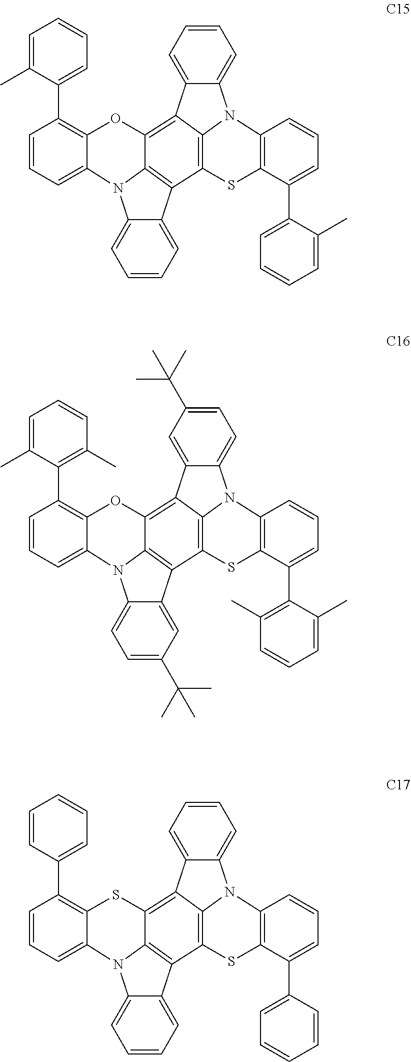

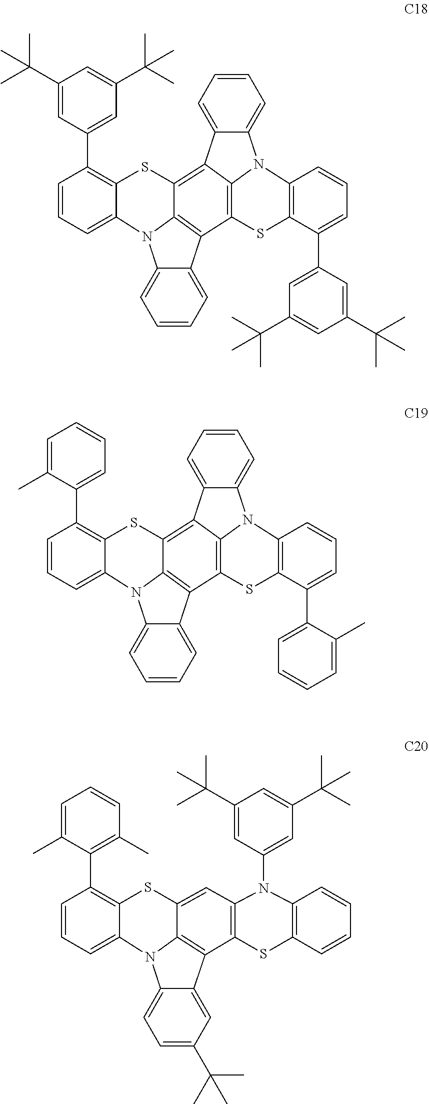

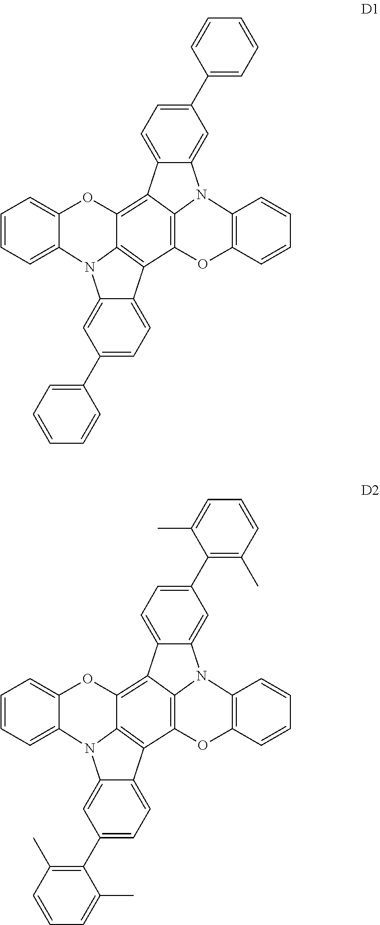

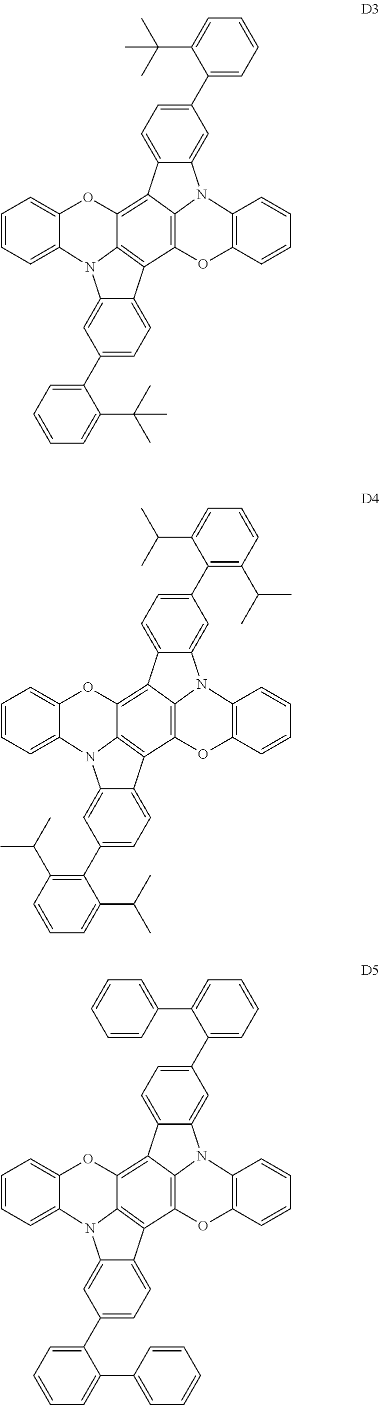

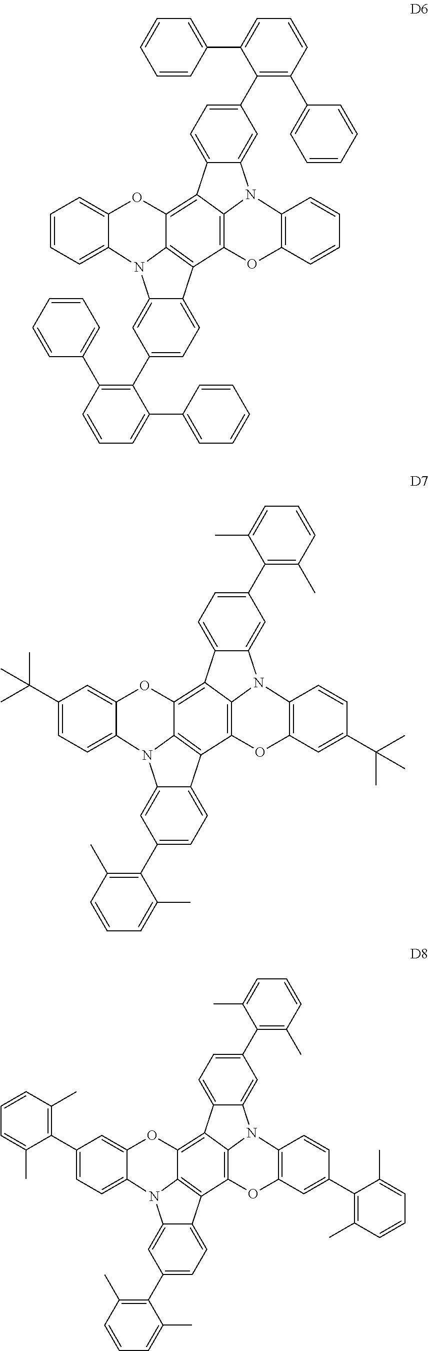

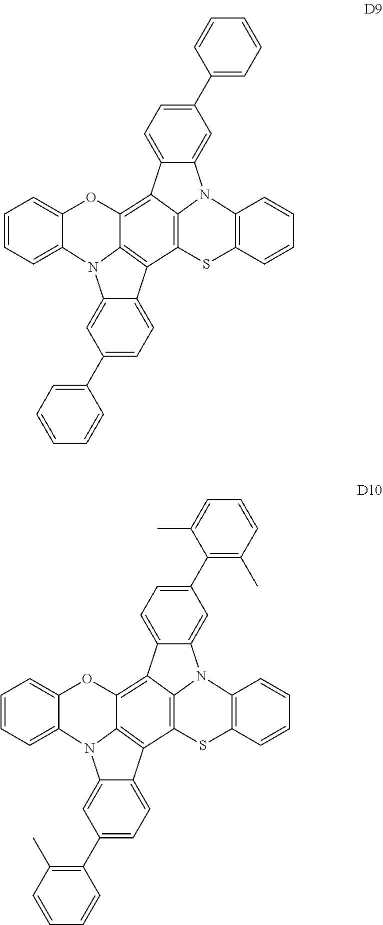

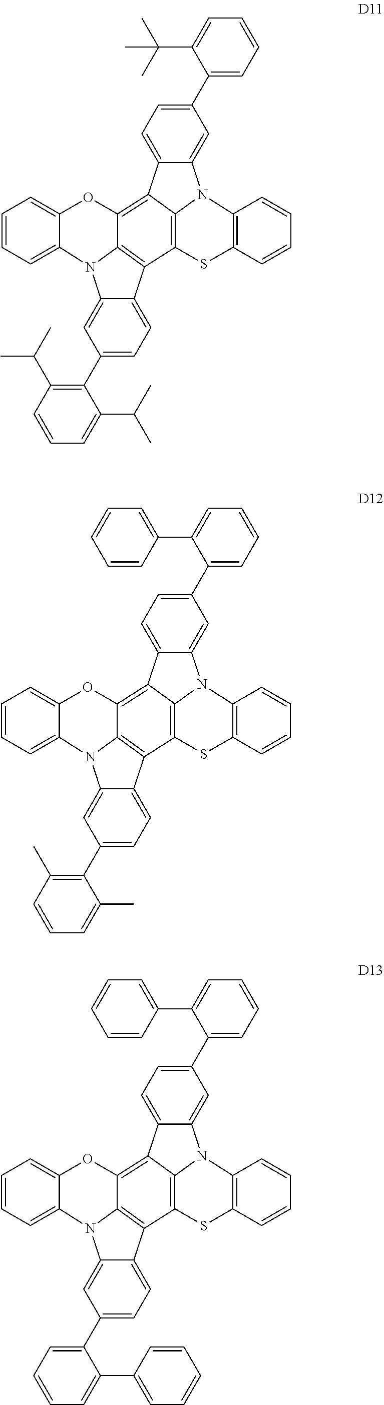

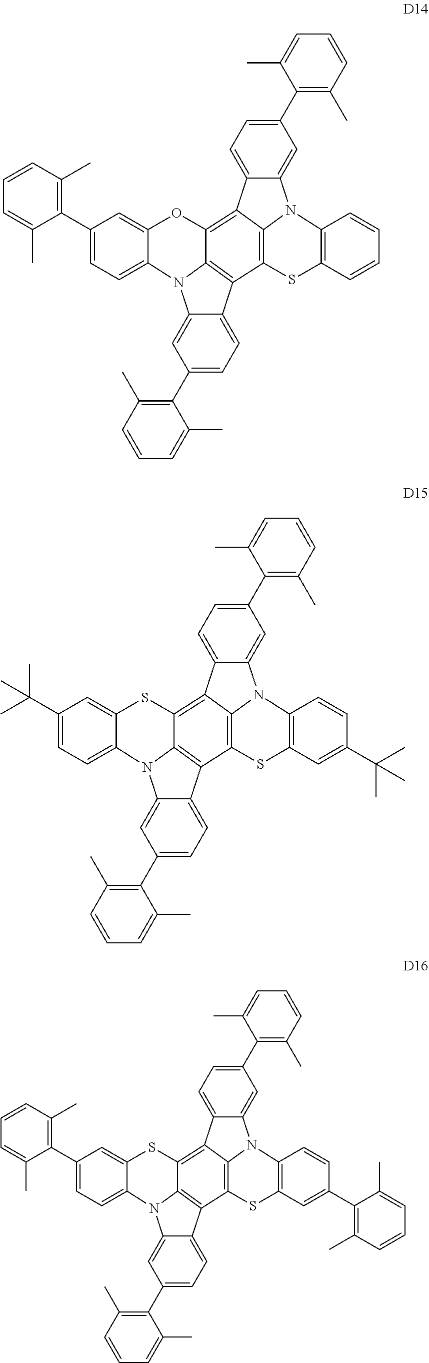

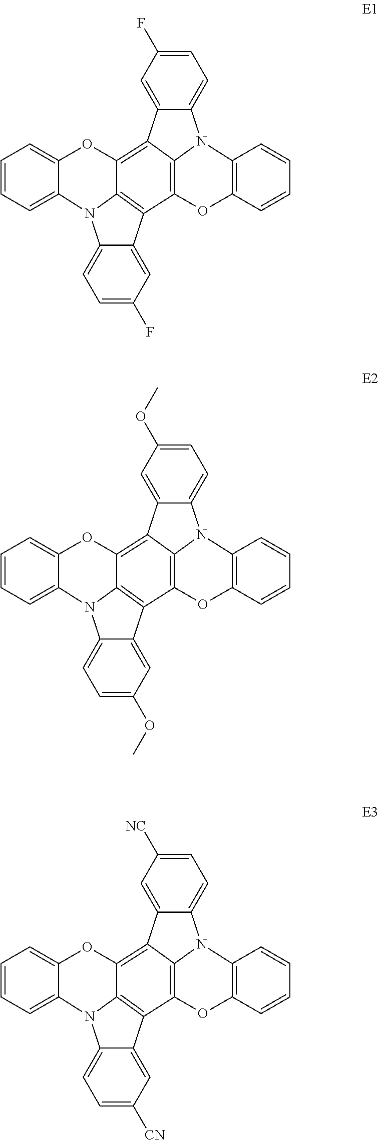

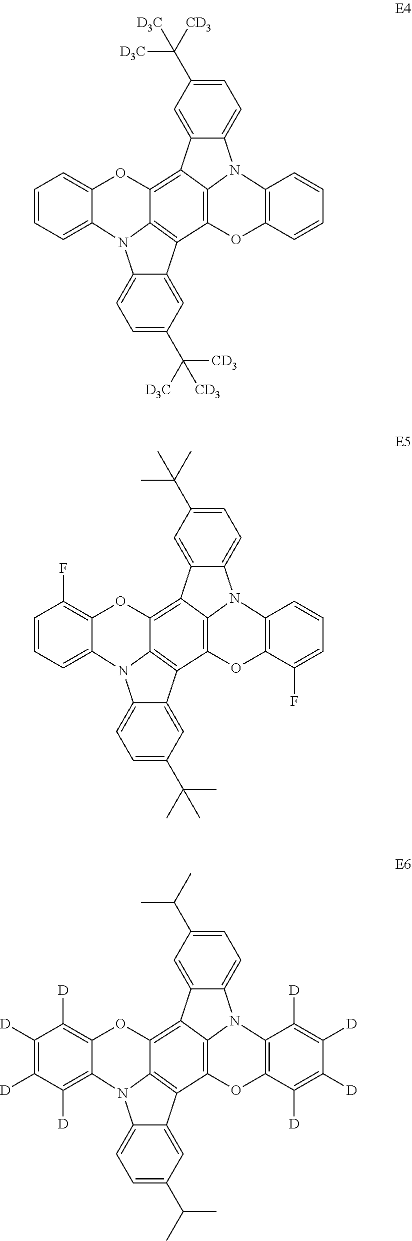

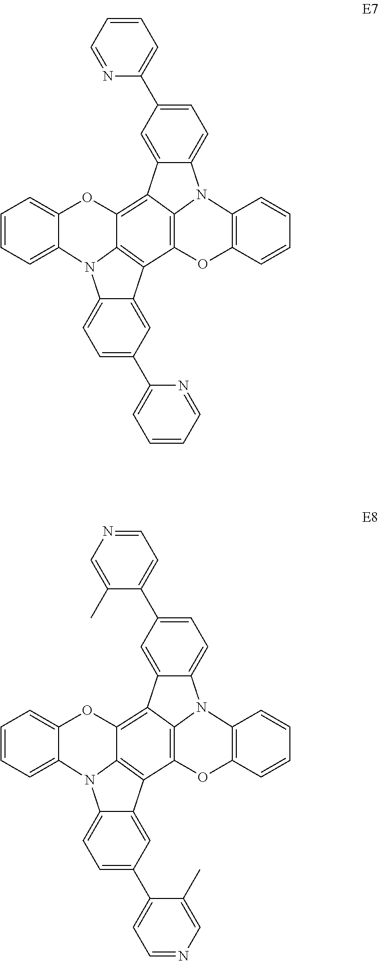

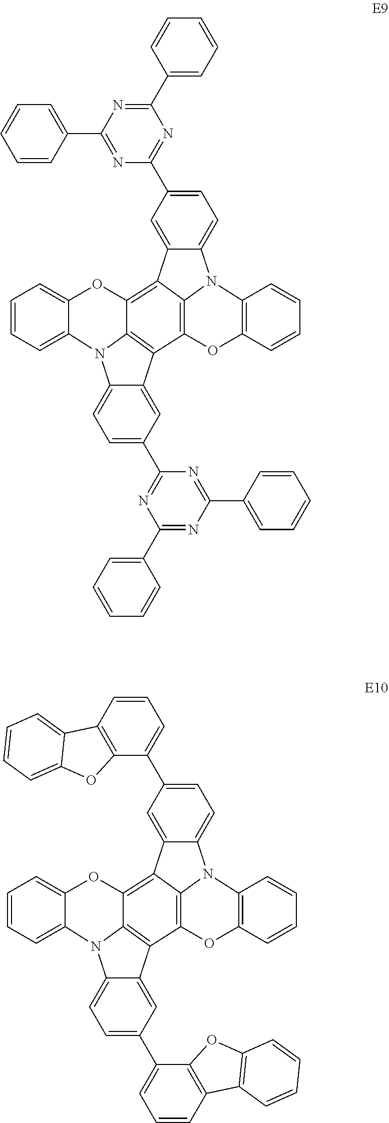

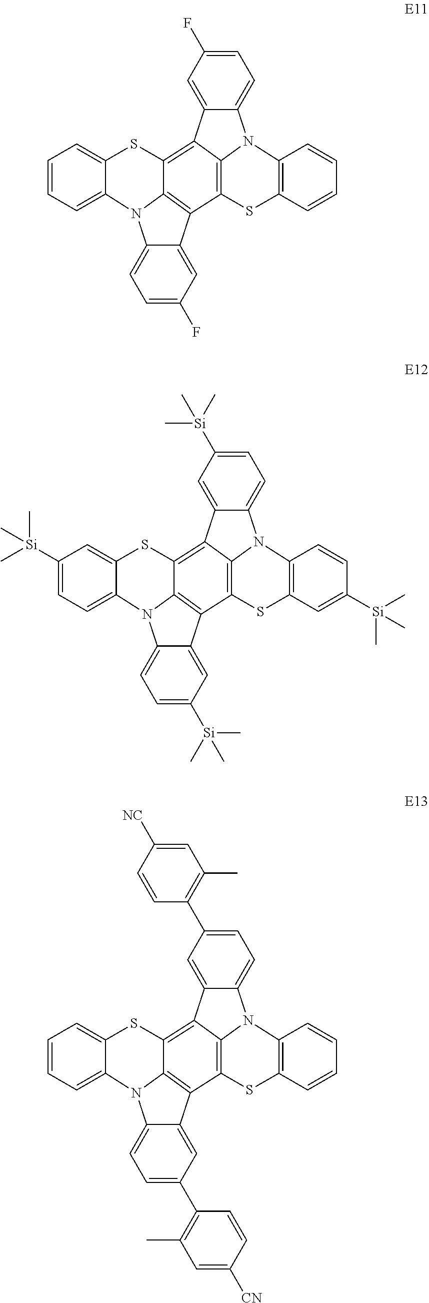

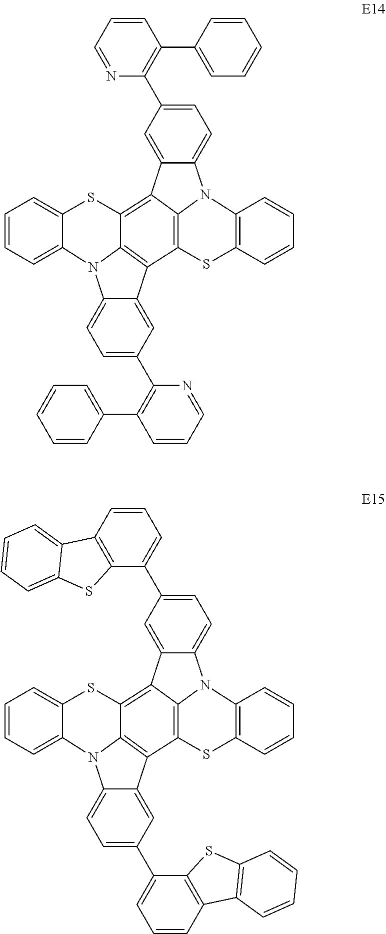

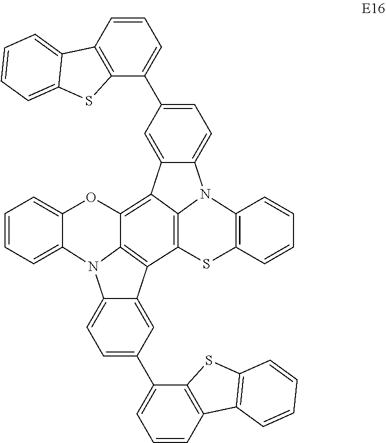

The organic light emitting element according to this embodiment will now be described in further details.

### Other Materials

Other examples of the host compound and the assist compound contained in the first light emitting layer 503 and the second light emitting layer 304 include, but are not limited to, aromatic hydrocarbon compounds and derivatives thereof, carbazole derivatives, azine derivatives, xanthone derivatives, dibenzofuran derivatives, dibenzothiophene derivatives, organoaluminum complexes such as tris(8-quinolinolato)aluminum, and organoberyllium complexes. Specific examples thereof are as follows.

The durability of the light emitting layers can be improved by using, for example, aromatic hydrocarbon compounds, such as pyrene derivatives (specific examples: EM1 to EM4, EM10, EM12, EM26, and EM27), perylene derivatives (specific examples: EM22 and EM23), anthracene derivatives (specific examples: EM5 to EM8), and fluoranthene derivatives (EM25). Although specific examples thereof are described below, these examples are not limiting.

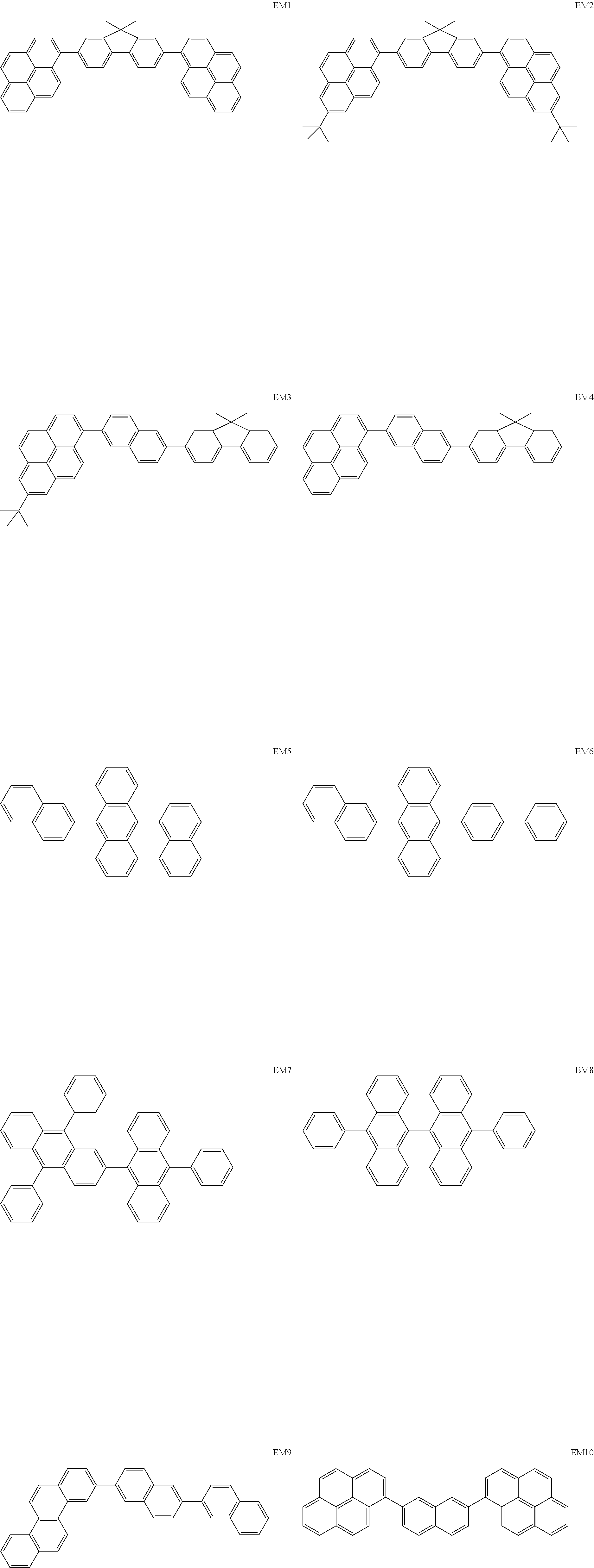

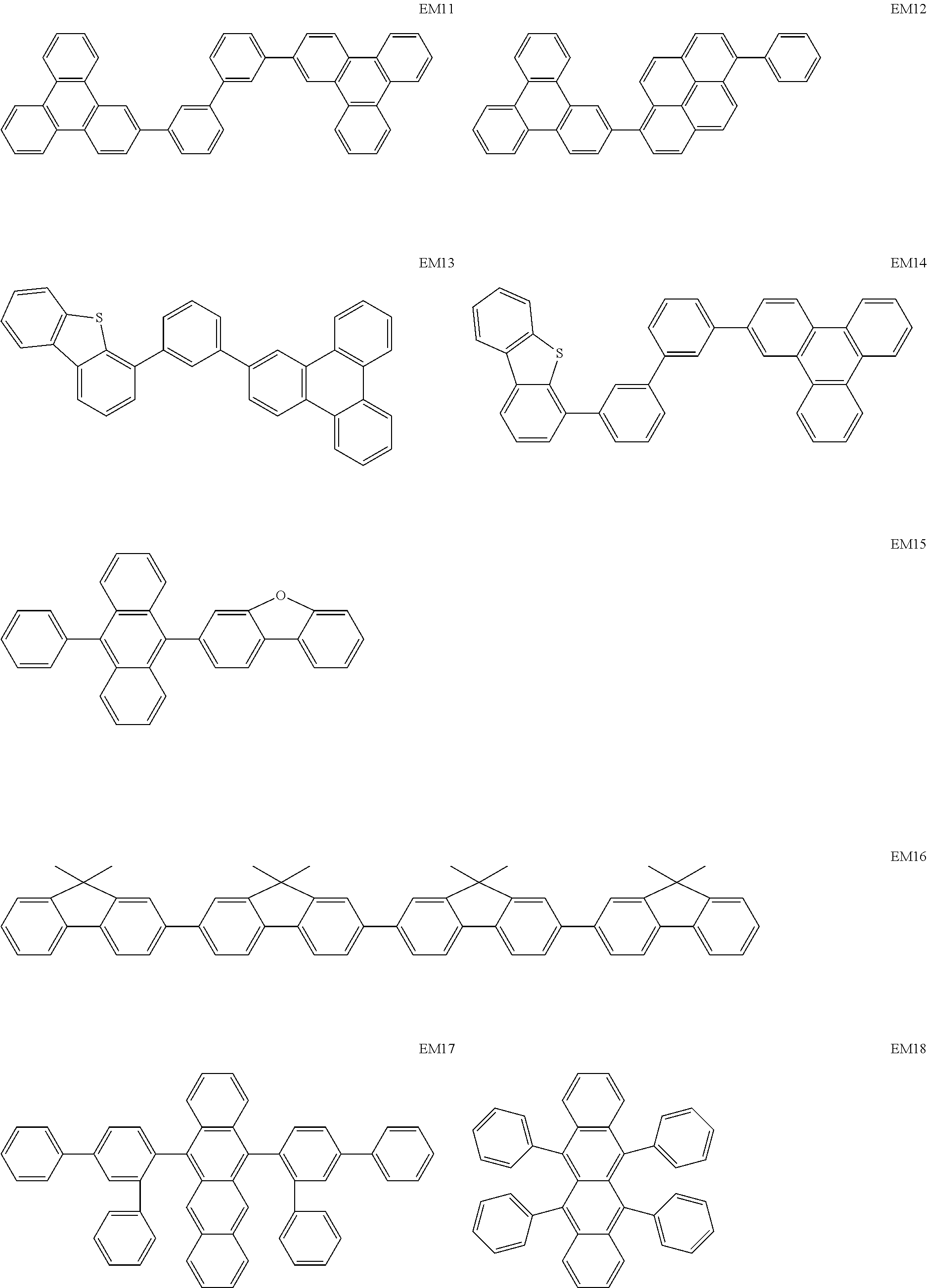

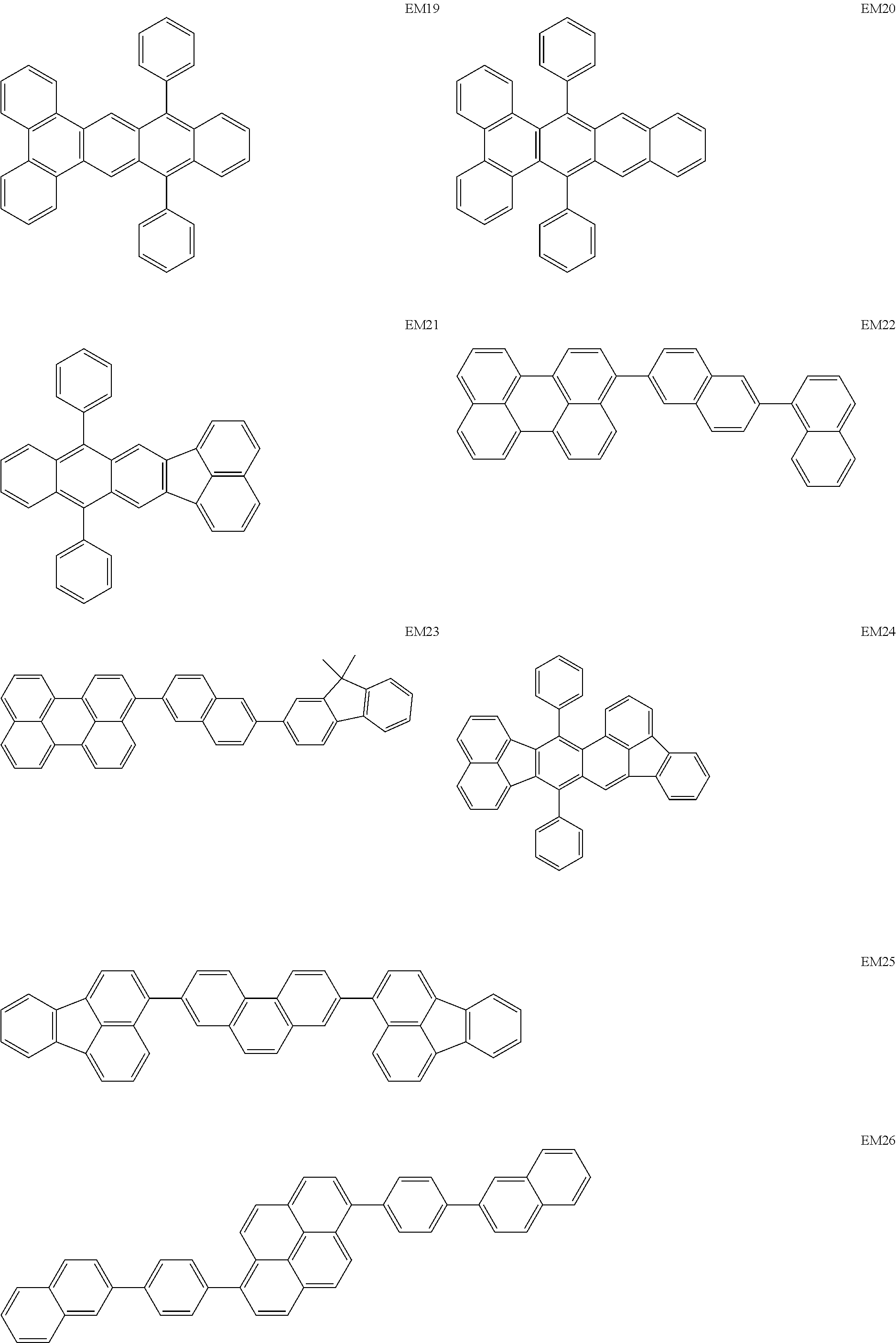

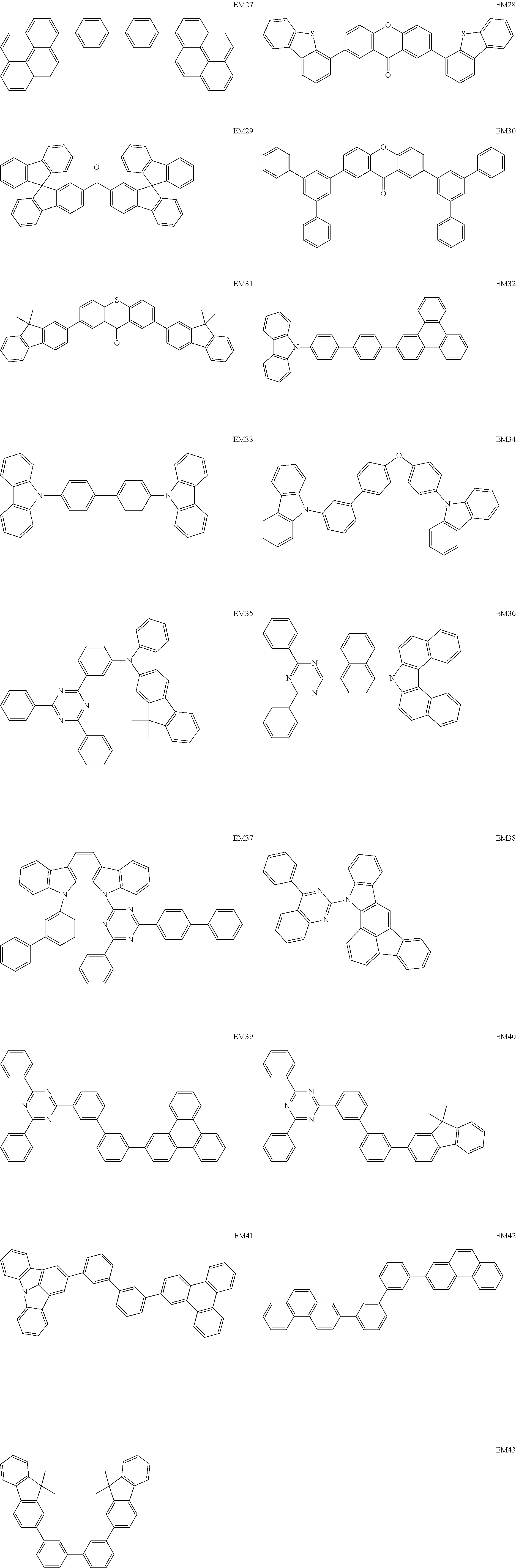

Other examples of the guest material involved mainly in the light emission function include fused ring compounds (for example, fluorene derivatives, naphthalene derivatives, pyrene derivatives, perylene derivatives, tetracene derivatives, anthracene derivatives, and rubrene), quinacridone derivatives, coumarin derivatives, stilbene derivatives, organoaluminum complexes such as tris(8-quinolinolato)aluminum, iridium complexes, platinum complexes, rhenium complexes, copper complexes, europium complexes, ruthenium complexes, and polymer derivatives such as poly(phenylenevinylene) derivatives, poly(fluorene) derivatives, and poly(phenylene) derivatives. Although specific examples of the compound used as the light emitting material are described below, these examples are not limiting.

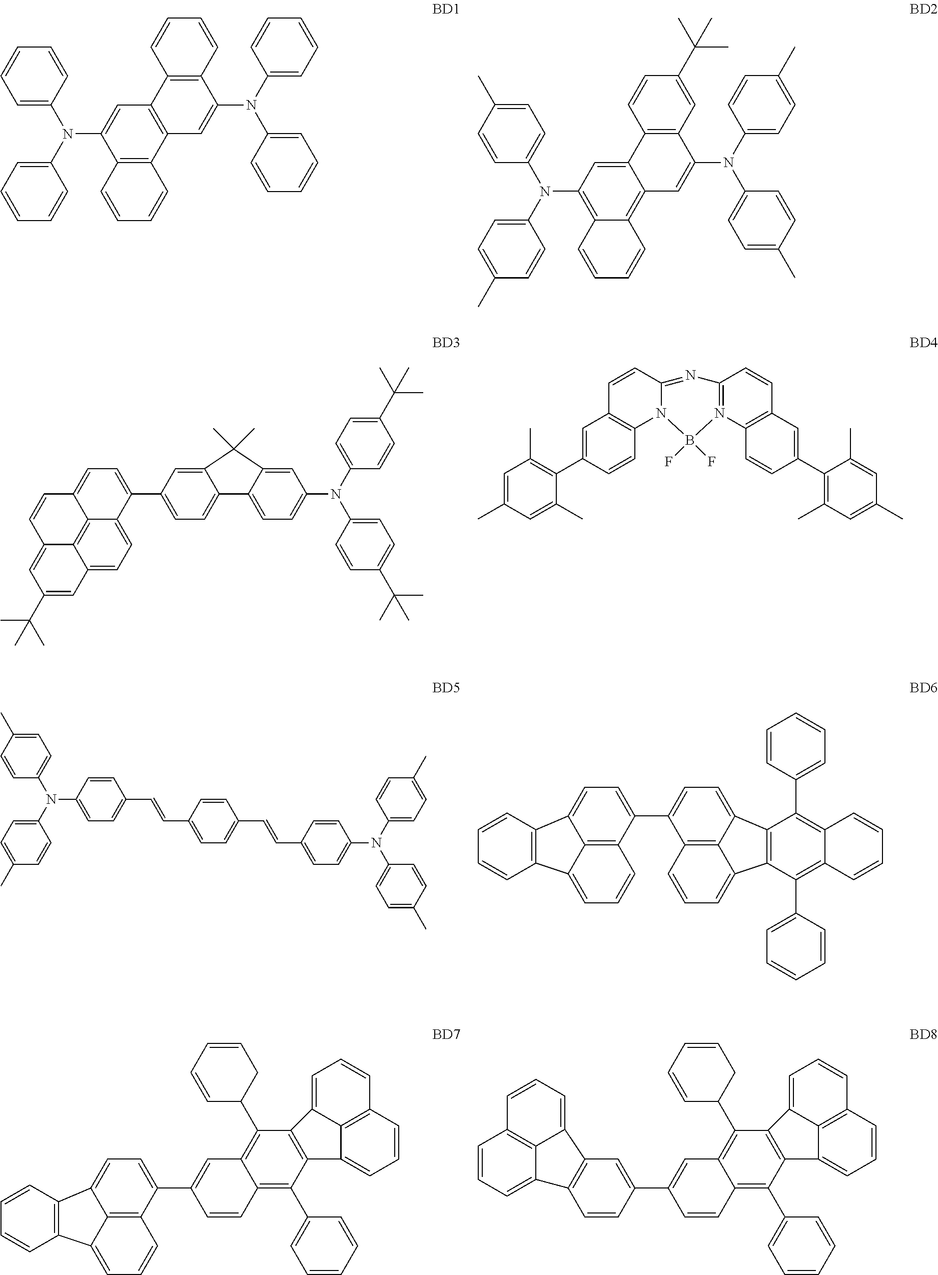

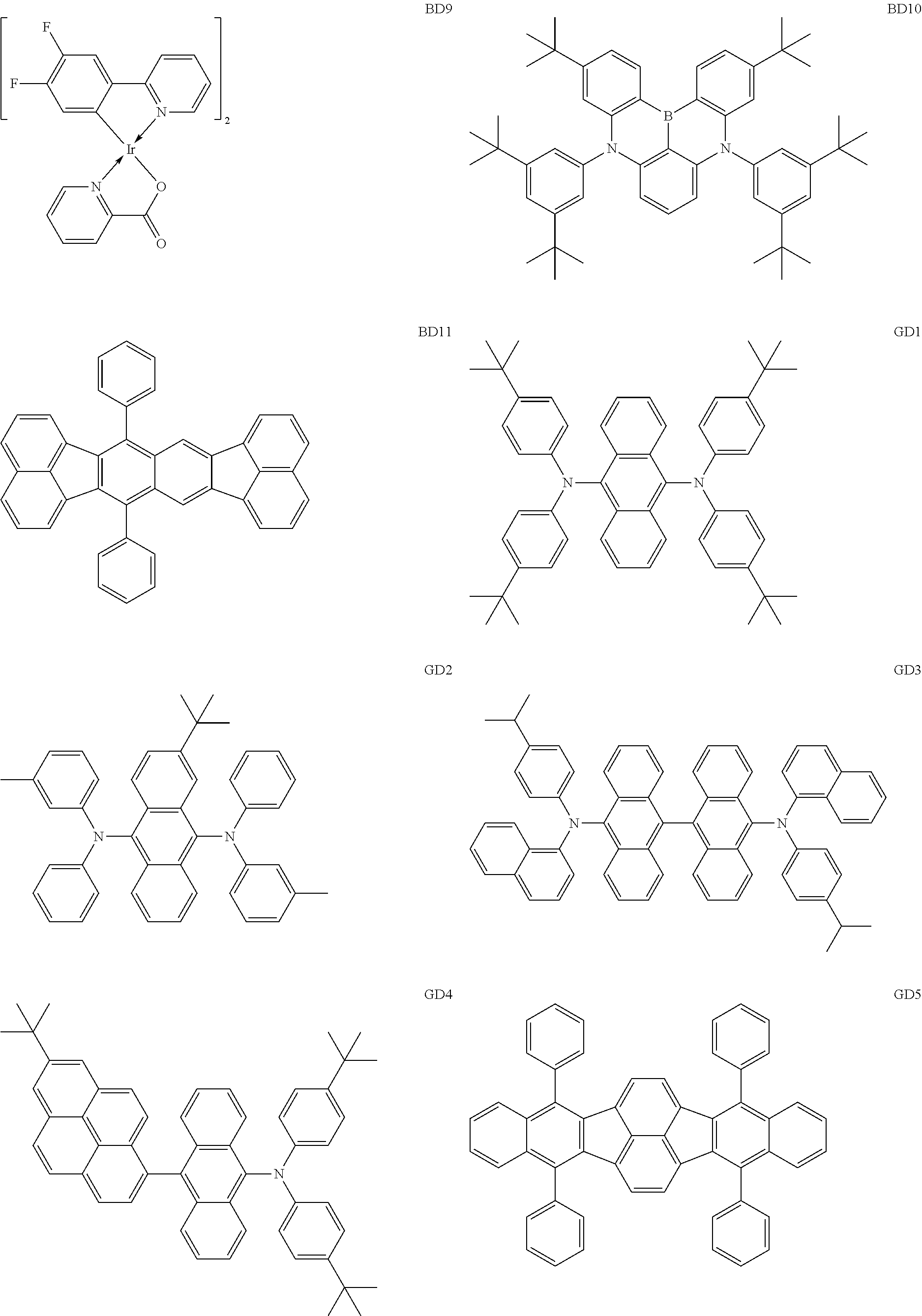

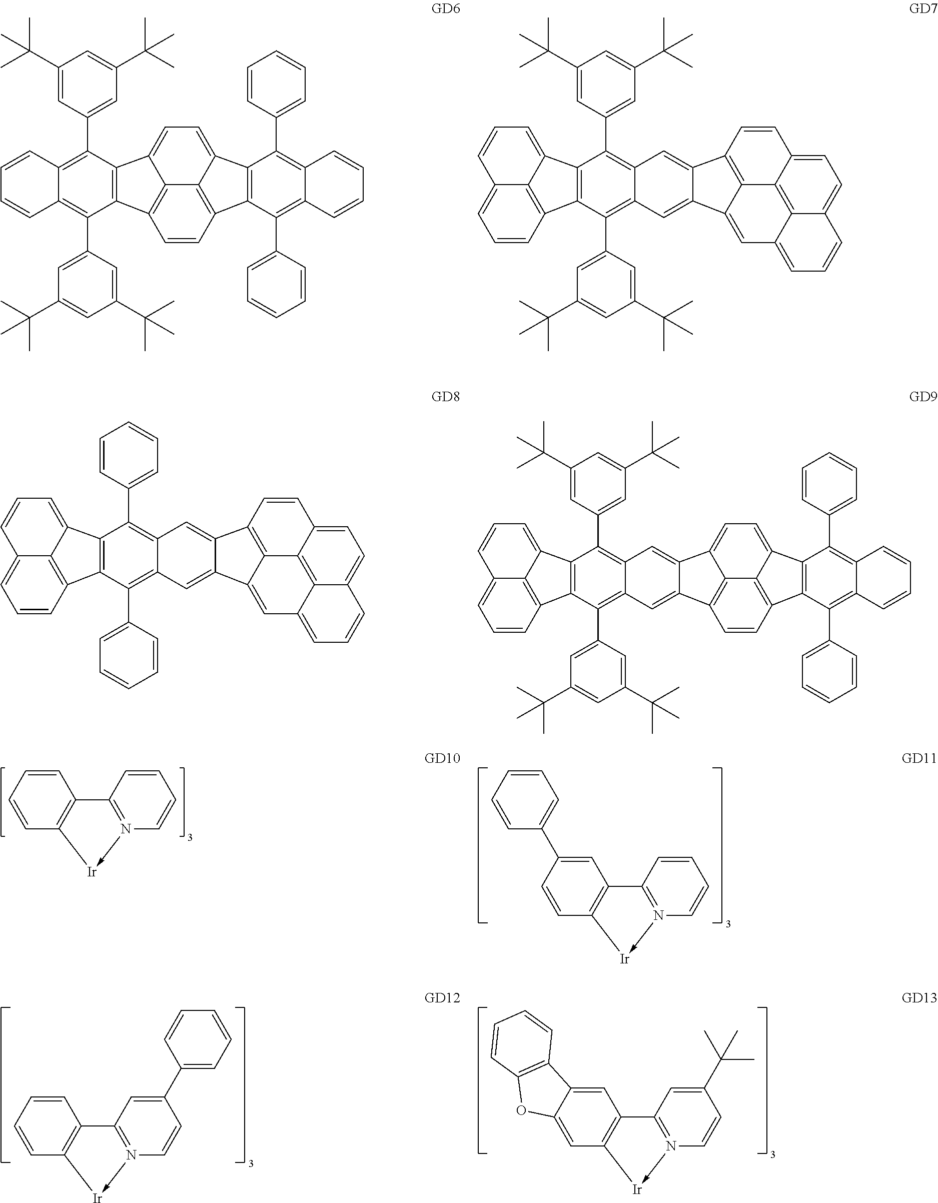

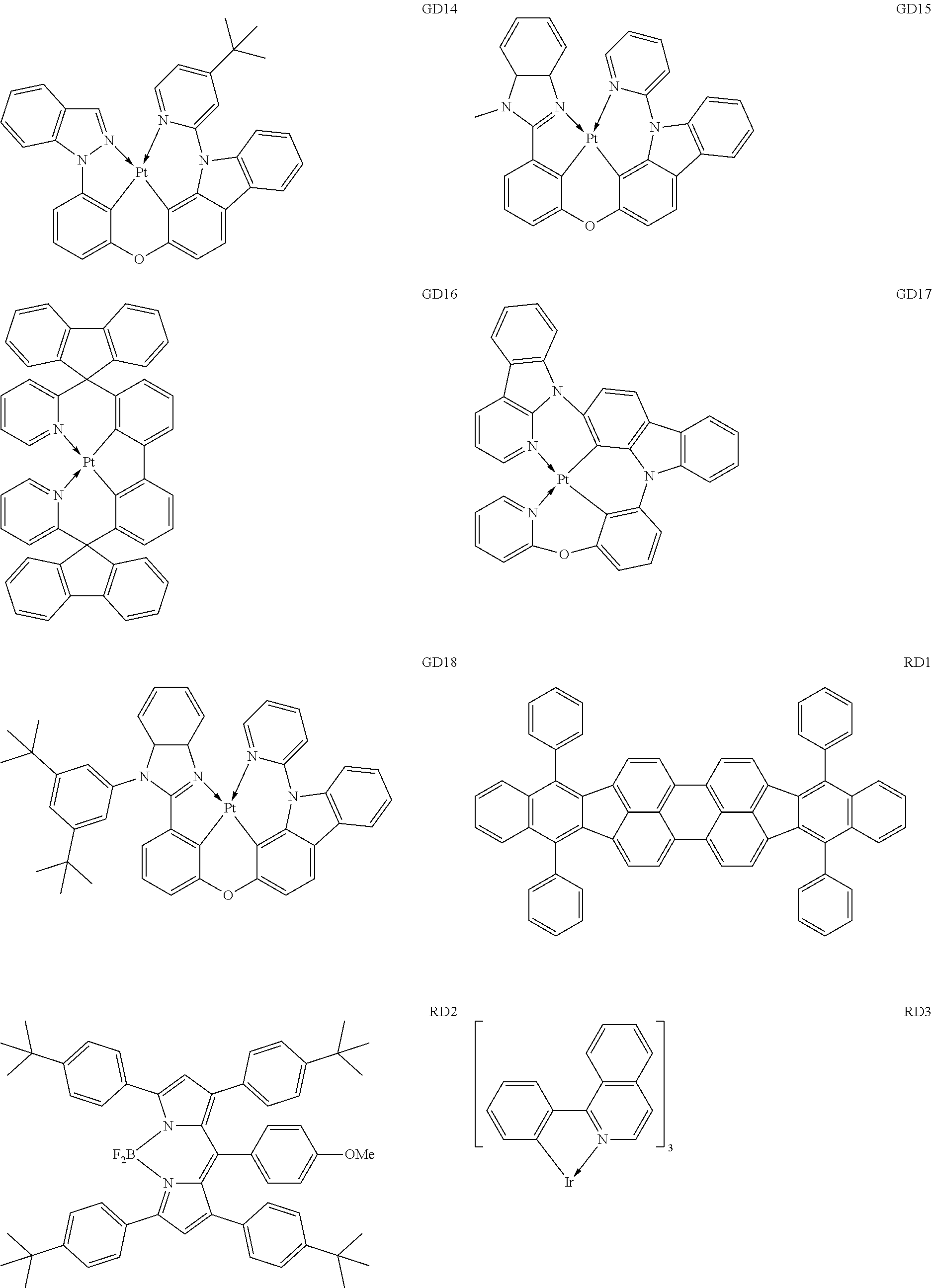

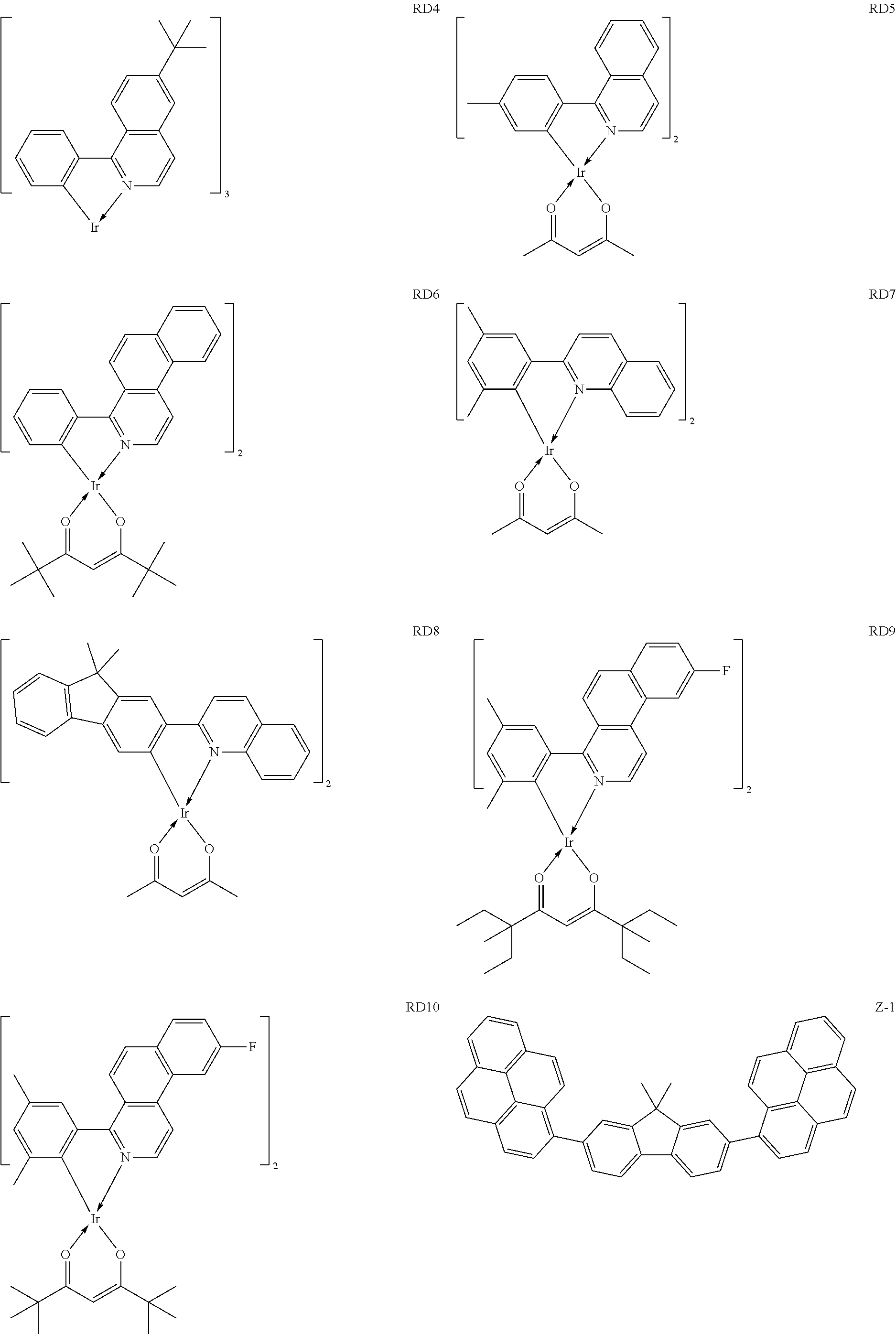

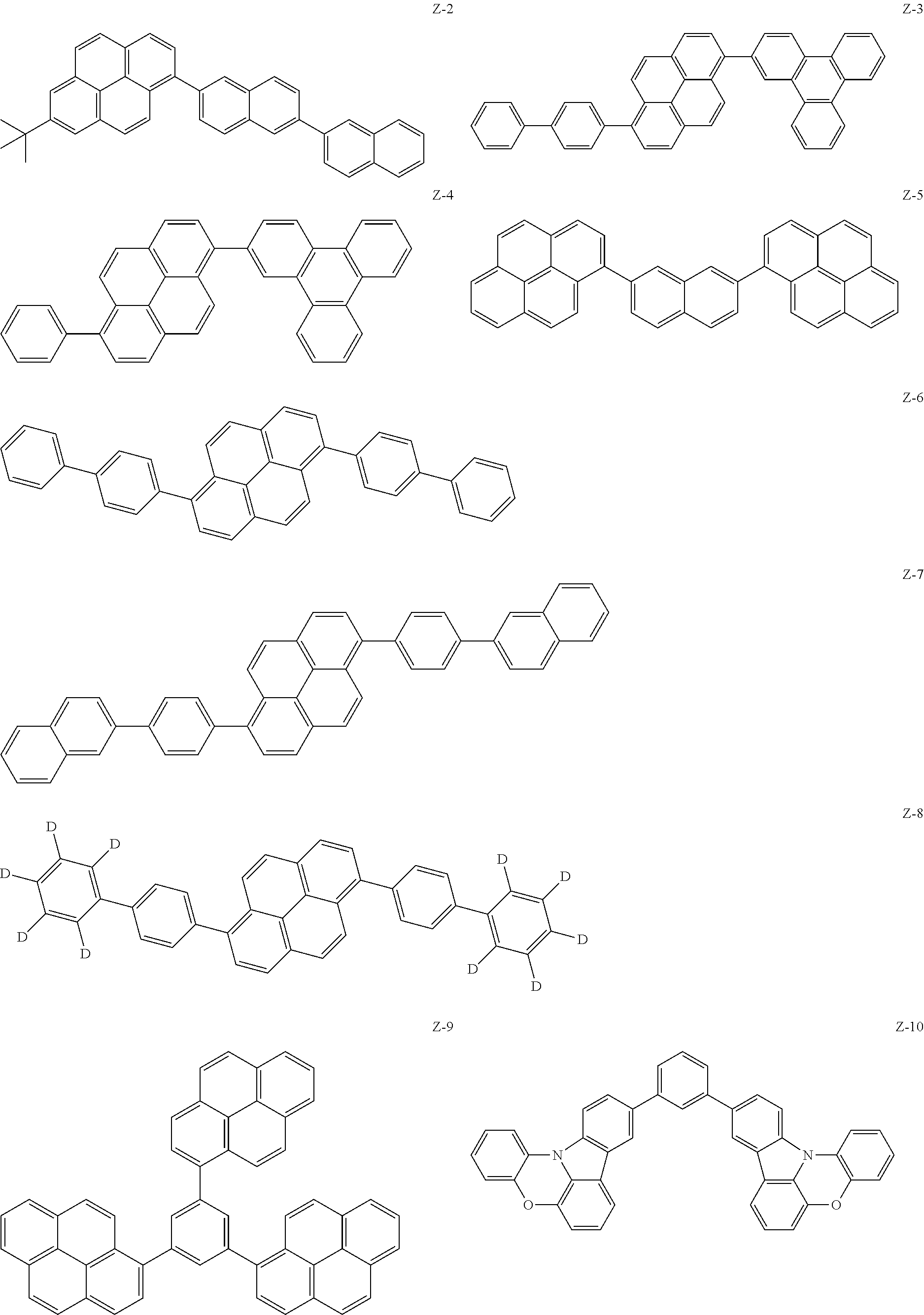

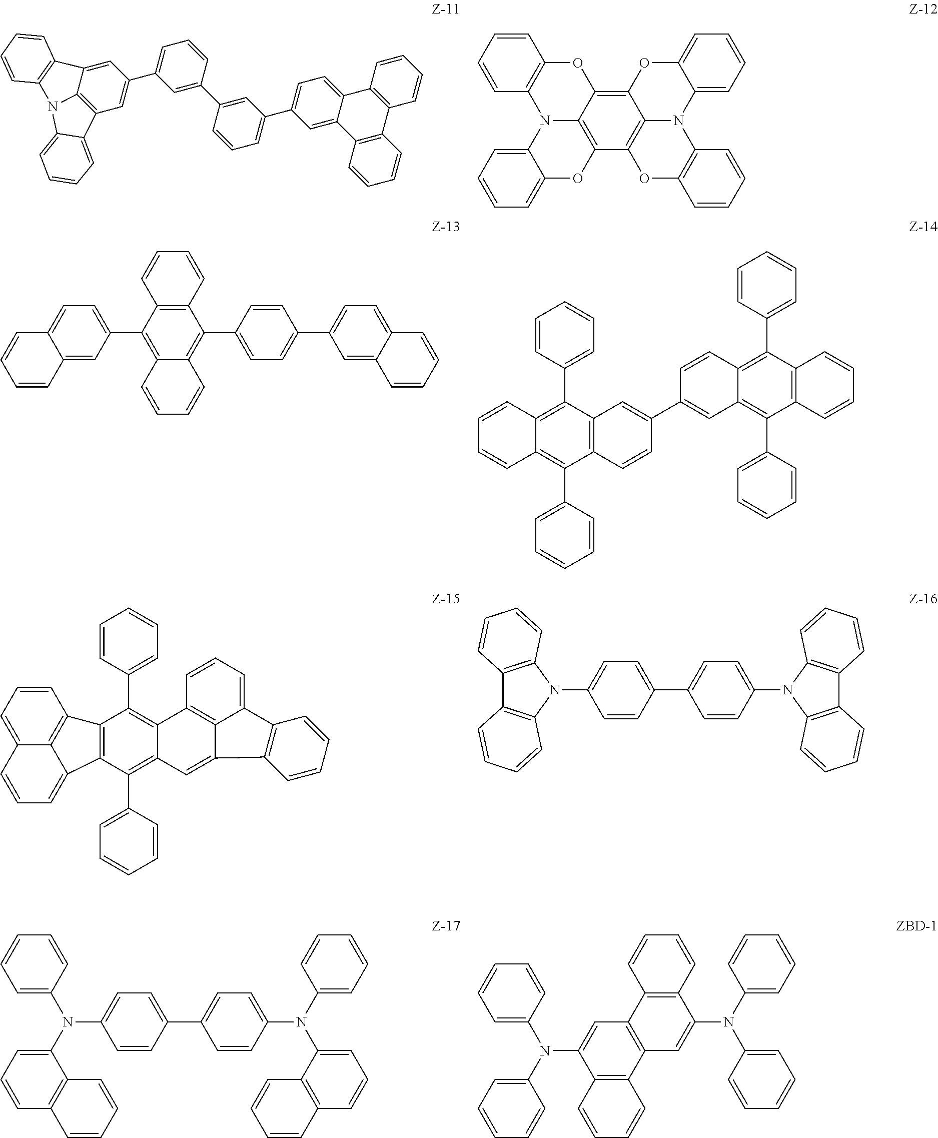

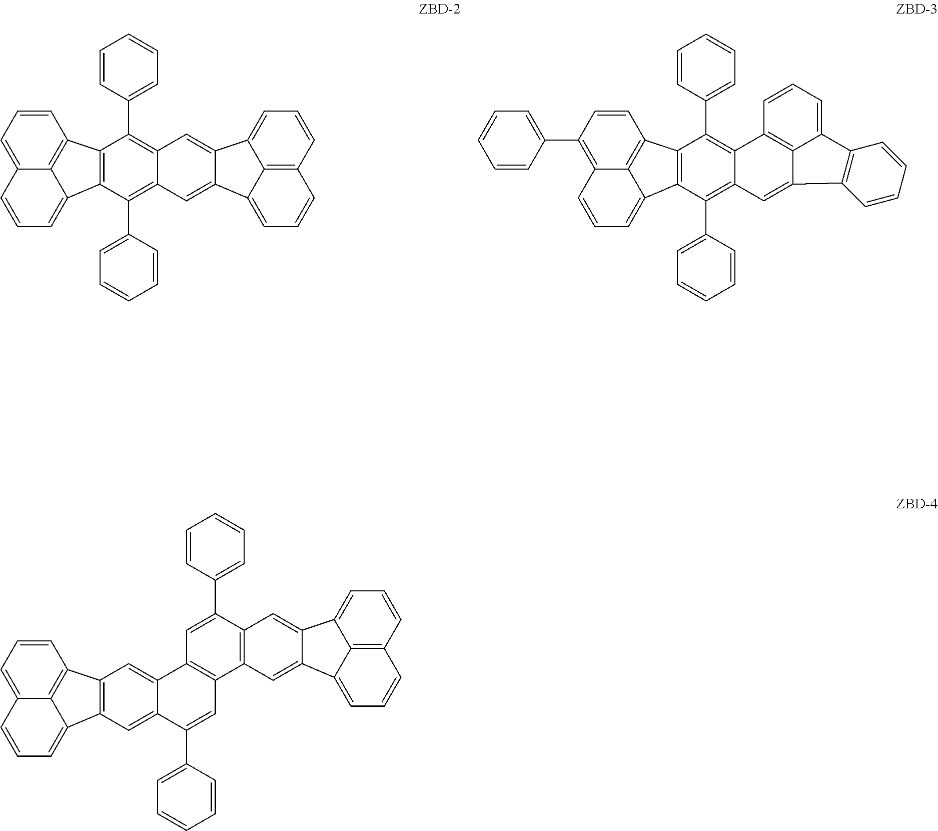

The hole injection/transport material may be a material that facilitates injection of holes from the anode and has a high hole mobility enabling transport of the injected holes to the light emitting layer. In addition, in order to reduce deterioration of the film quality, such as crystallization, in the organic light emitting element, the material may have a high glass transition point. Examples of the low-molecular-weight and high-molecular-weight materials having hole injection/transport properties include triarylamine derivatives, arylcarbazole derivatives, phenylenediamine derivatives, stylbene derivatives, phthalocyanine derivatives, porphyrin derivatives, poly(vinylcarbazole), poly(thiophene), and other conductive polymers. Furthermore, the aforementioned hole injection/transport material may be used in an electron blocking layer of a p-type charge generation layer. Although specific examples of the compound used as the hole injection/transport material are described below, these examples are not limiting.

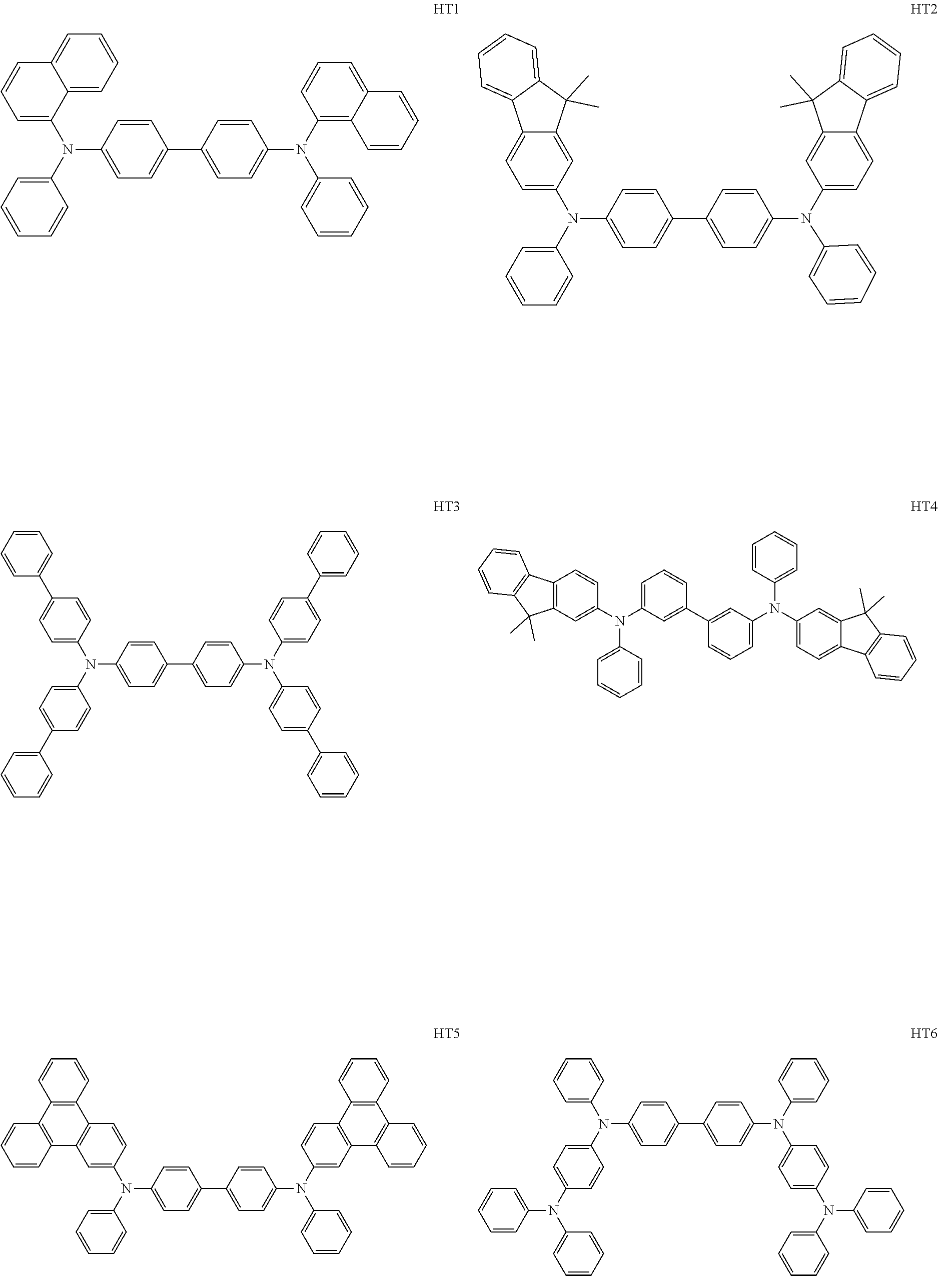

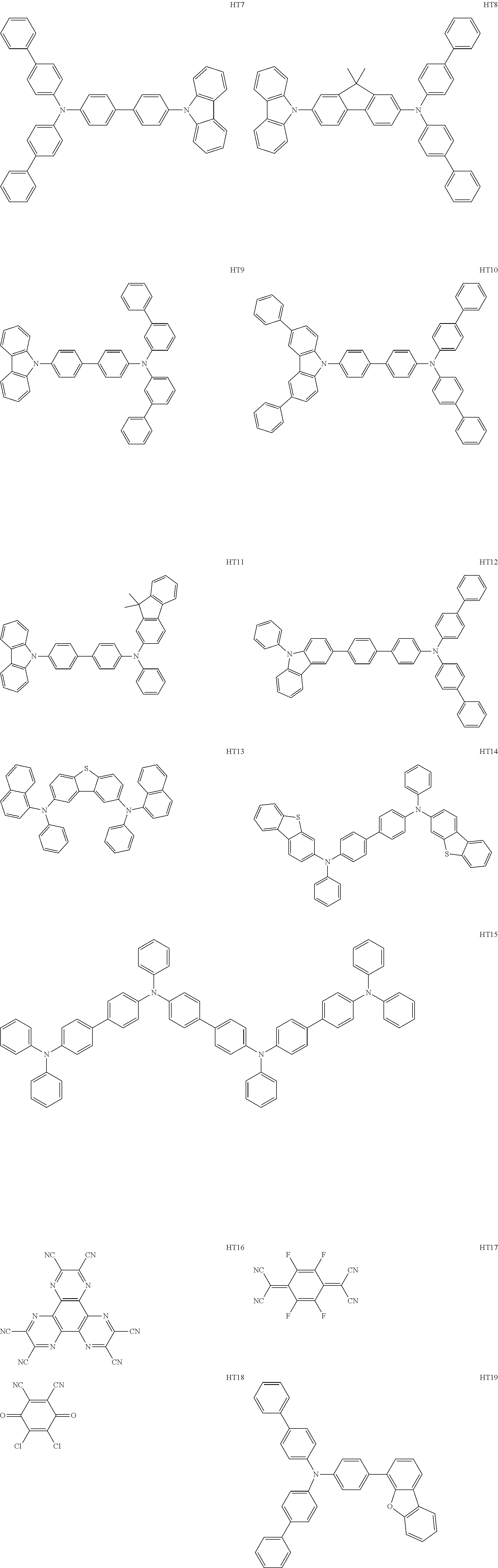

The electron transport material can be freely selected from those that can transport electrons injected from the cathode to the light emitting layer, and the selection is made by considering the balance with the hole mobility of the hole transport material, etc. Examples of the material having the electron transport properties include oxadiazole derivatives, oxazole derivatives, pyrazine derivatives, triazole derivatives, triazine derivatives, quinoline derivatives, quinoxaline derivatives, phenanthroline derivatives, naphthyridine derivatives, organoaluminum complexes, and fused ring compounds (for example, fluorene derivatives, naphthalene derivatives, chrysene derivatives, and anthracene derivatives). The aforementioned electron transport materials may be used in the hole blocking layer. Although specific examples of the compound used as the electron transport material are described below, these examples are not limiting. The use of a compound composed of a hydrocarbon in the hole blocking layer adjacent to the light emitting layer reduces deterioration of the hole blocking layer and increases the durability of the light emitting element itself; however, the compound is not limited to compounds composed of hydrocarbons. Specific examples thereof are as follows.

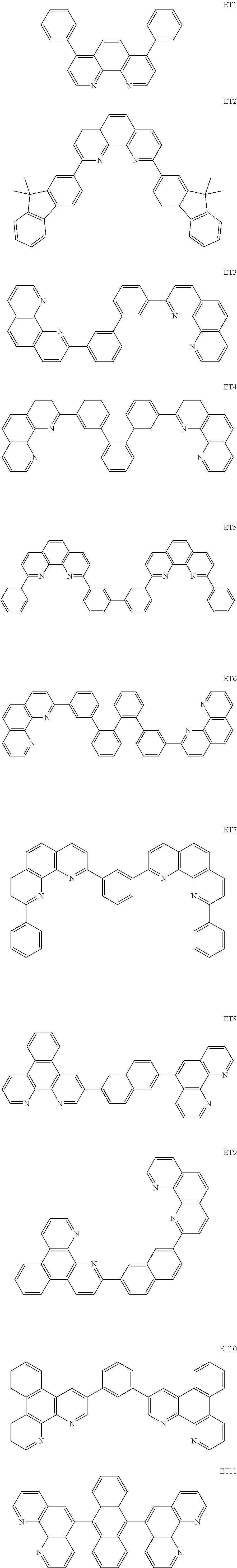

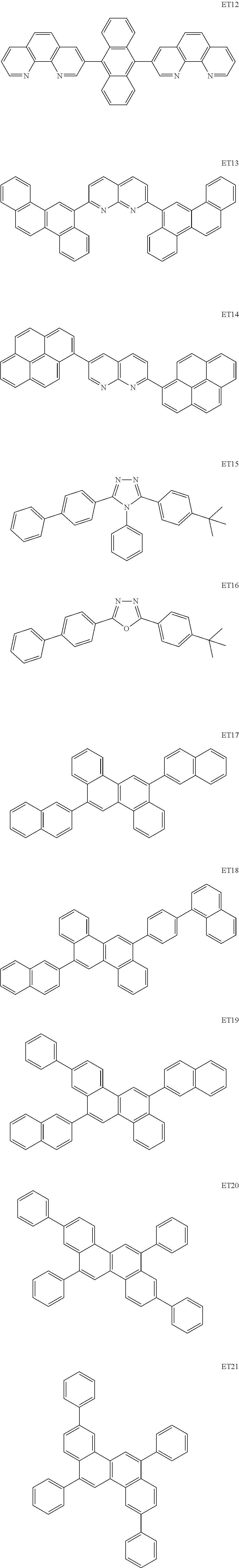

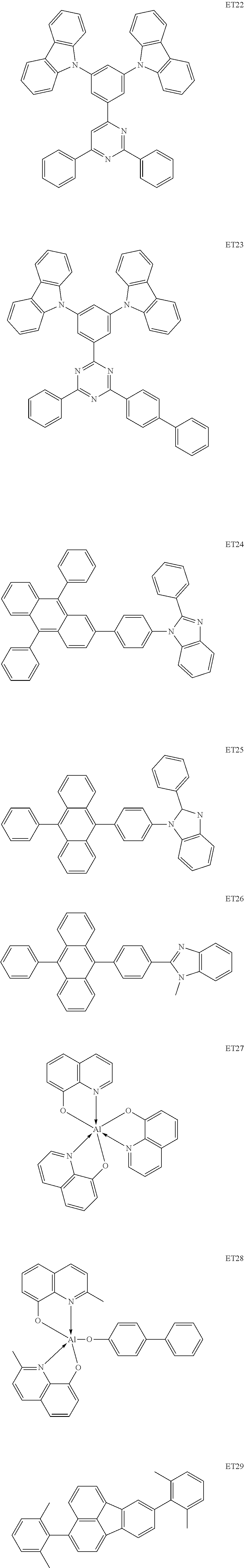

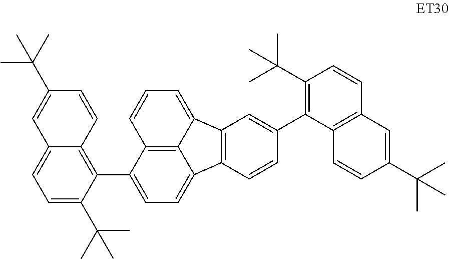 [SMILES: CC(C)(C)c1ccc2c(-c3ccc4c(c3)-c3cccc5c(-c6c(C(C)(C)C)ccc7cc(C(C)(C)C)ccc67)ccc-4c35)c(C(C)(C)C)ccc2c1]

The electron injection material can be freely selected from those that facilitate electron injection from the cathode, and the selection is made by considering the balance with the hole injectability. As the organic compound, n-type dopants and reducing dopants are also included. Examples thereof include alkali metal-containing compounds such as lithium fluoride, lithium complexes such as lithium quinolinol, benzimidazolidine derivatives, imidazolidine derivatives, fulvalene derivatives, and acridine derivatives. These may be used in combination with the aforementioned electron transport materials.

### Structure of Organic Light Emitting Element

The organic light emitting element is obtained by forming, on a substrate, an insulating layer, a first electrode, an organic compound layer, and a second electrode. A protection layer, a color filter, a microlens, etc., may be disposed on the cathode.

When a color filter is to be provided, a planarization layer may be provided between the color filter and the protection layer. The planarization layer can be composed of an acrylic resin or the like. The same applies to the case where a planarization layer is provided between a color filter and a microlens.

### Substrate

Examples of the substrate include quartz, glass, silicon wafers, resin, and metal. Switching elements such as transistors and wiring may be provided on the substrate, and an insulating layer may be provided thereon. The insulating layer may be composed of any material as long as contact holes can be formed to enable formation of wiring with the first electrode and insulation can be ensured for the wiring not to be connected. Examples of such a material include resin such as polyimide, silicon oxide, and silicon nitride.

### Electrodes

A pair of electrodes can be used as the electrodes. The pair of electrodes may be an anode and a cathode.

When an electric field is applied in a direction in which the organic light emitting element emits light, the electrode at a higher potential is the anode, and the other is the cathode. In other words, the electrode that supplies holes to the light emitting layer is the anode, and the electrode that supplies electrons is the cathode.

The material constituting the anode may have as large work function as possible. Examples of the material that can be used include single metals such as gold, platinum, silver, copper, nickel, palladium, cobalt, selenium, vanadium, and tungsten, mixtures thereof, and alloys thereof, and metal oxides such as tin oxide, zinc oxide, indium oxide, indium tin oxide (ITO), and indium zinc oxide. Furthermore, conductive polymers such as polyaniline, polypyrrole, and polythiophene can also be used.

These electrode substances may be used alone or in combination. The anode may be made of one layer or multiple layers.

For the reflection electrode use, for example, chromium, aluminum, silver, titanium, tungsten, molybdenum, or an alloy thereof, and a multilayer product thereof can be used. The aforementioned materials can function as a reflection film that does not serve as an electrode. For the transparent electrode use, oxide transparent conductive layers such as indium tin oxide (ITO) and indium zinc oxide can be used, but these are not limiting.

Photolithography can be employed to form the electrode.

In contrast, the material constituting the cathode may have as small work function as possible. Examples thereof include alkali metals such as lithium, alkaline earth metals such as calcium, single metals such as aluminum, titanium, manganese, silver, lead, and chromium, and mixtures thereof. Alloys containing these single metals can also be used. For example, magnesium-silver, aluminum-lithium, aluminum-magnesium, silver-copper, and zinc-silver can be used. Metal oxides such as indium tin oxide (ITO) can also be used. These electrode substances may be used alone or in combination. The cathode may have a single-layer structure or a multilayer structure. In particular, silver is preferably used, and a silver alloy is more preferably used to reduce aggregation of silver. As long as aggregation of silver can be reduced, the alloying ratio may be any. For example, the silver-to-other metal ratio may be 1:1, 3:1, or the like.

An oxide conductive layer such as ITO may be used in the cathode to form a top-emission element, or a reflection electrode such as aluminum (Al) may be used in the cathode to form a bottom-emission element; and no limitation is imposed as to this feature. The cathode may be formed by any method, but a DC sputtering method and an AC sputtering method provide good film coverage and low resistance.

### Pixel Isolation Layer

A pixel isolation layer is formed of a silicon nitride (SiN) film, a silicon oxynitride (SiON) film, or a silicon oxide (SiO) film formed by a chemical vapor deposition method (CVD method).

In order to increase the resistance of the organic compound layer in the in-plane direction, the film thickness of the organic compound layer, in particular, the thickness of the hole transport layer, may be reduced at a side wall of the pixel isolation layer. Specifically, by increasing the taper angle of the side wall of the pixel isolation layer and the film thickness of the pixel isolation layer to thereby increase the vignetting during vapor deposition, the film thickness of the side wall can be made smaller.

Meanwhile, the side wall taper angle of the pixel isolation layer and the film thickness of the pixel isolation layer may be adjusted so that no gap is formed in the protection layer formed on the pixel isolation layer. Since no gap is formed in the protection layer, occurrence of defects in the protection layer can be decreased. Since fewer defects occur in the protection layer, degradation of reliability, such as occurrence of dark spots and occurrence of conduction failure in the second electrode, can be reduced.

According to this embodiment, the taper angle of the side wall of the pixel isolation layer does not have to be steep, and yet charge leakage to the adjacent pixels can be effectively suppressed. Studies conducted demonstrate that the charge leakage can be sufficiently decreased when the taper angle is in the range of 60 degrees or more and 90 degrees or less. The film thickness of the pixel isolation layer can be 10 nm or more and 150 nm or less. The same effects can also be obtained when only pixel electrodes that do not have pixel isolation layers are used. However, in such a case, the film thickness of the pixel electrode is to be a half or less of that of the organic layer or the pixel electrode end portions are to be forward tapered with an angle of less than 60° since this decreases short-circuiting of the organic light emitting element.

### Organic Compound Layer

The organic compound layer may be made of one layer or multiple layers. When there are multiple layers, these layers may be called a hole injection layer, a hole transport layer, an electron blocking layer, a light emitting layer, a hole blocking layer, an electron transport layer, and an electron injection layer according to their functions. The organic compound layer is mainly composed of an organic compound but may contain inorganic atoms and inorganic compounds. For example, copper, lithium, magnesium, aluminum, iridium, platinum, molybdenum, zinc, etc., may be contained. The organic compound layer may be disposed between the first electrode and the second electrode and may be in contact with the first electrode and the second electrode.

When there are multiple light emitting layers, a charge generation portion may be interposed between a first light emitting layer and a second light emitting layer. The charge generation portion may contain an organic compound having a lowest unoccupied molecular orbital energy (LUMO) of −5.0 eV or less. The same applies to when there is a charge generation portion between a second light emitting layer and a third light emitting layer.

### Protection Layer

A protection layer may be provided on the second electrode. For example, by bonding glass having a hygroscopic agent on the second electrode, entry of water and the like into the organic compound layer can be reduced, and occurrence of display failure can be reduced. In another embodiment, a passivation film such as silicon nitride may be provided on the cathode to reduce entry of water and the like into the organic compound layer. For example, after forming the cathode, the cathode may be transported to another chamber without breaking the vacuum, and a silicon nitride film having a thickness of 2 μm may be formed thereon by a CVD method to form a protection layer. The protection layer may be formed by performing film deposition by a CVD method and then by an atomic layer deposition method (ALD method). The material for the film used in the ALD method is not particularly limited and may be silicon nitride, silicon oxide, or aluminum oxide, for example. Silicon nitride may be further formed by a CVD method on the film formed by the ALD method. The film formed by the ALD method may have a smaller film thickness than the film formed by the CVD method. Specifically, the film thickness may be 50% or less or 10% or less.

### Color Filter

A color filter may be provided on the protection layer. For example, a color filter that takes into account the size of the organic light emitting element may be provided on a separate substrate, and this substrate may be bonded with a substrate having an organic light emitting element thereon, or a color filter may be photolithographically formed on the aforementioned protection layer by patterning. The color film may be made of a polymer.

### Planarization Layer

A planarization layer may be provided between the color filter and the protection layer. The planarization layer is provided to reduce irregularities of the underlying layer. The planarization layer may also be referred to as a material resin layer without specifying the purpose. The planarization layer may be made of an organic compound and may have a low molecular weight or a high molecular weight but preferably has a high molecular weight.

The planarization layers may be provided under and above the color filter, and the materials constituting such planarization layers may be the same or different. Specific examples thereof include polyvinylcarbazole resin, polycarbonate resin, polyester resin, ABS resin, acrylic resin, polyimide resin, phenolic resin, epoxy resin, silicone resin, and urea resin.

### Microlens

An organic light emitting device may have an optical member such as a microlens on the light emitting side. The microlens can be formed of an acrylic resin, an epoxy resin, or the like. The microlens may be provided to increase the amount of light to be extracted from the organic light emitting device or to control the direction of light to be extracted from the organic light emitting device. The microlens may have a hemispherical shape. When the microlens has a hemispherical shape, there is a tangent line parallel to the insulating layer among the tangent lines contacting the hemisphere, and the contact point between this tangent line and the hemisphere is the apex of the microlens. The apex of the microlens can be determined in the same manner by using any cross section. In other words, there is a tangent line parallel to the insulating layer among the tangent lines contacting the semicircle of the microlens in the cross section, and the contact point between this tangent line and the semicircle is the apex of the microlens.

The midpoint of the microlens can also be defined. In a cross section of the microlens, a line segment starting from one point where the arc shape ends to one point where another arc shape ends is hypothetically drawn, and the midpoint of the line segment can be referred to as the midpoint of the microlens. The cross section used to identify the apex and the midpoint may be a cross section taken perpendicular to the insulating layer.

The microlens has a first surface that has a protruding part and a second surface opposite from the first surface. The second surface may be disposed closer to the functional layer than the first surface. In order to have this structure, a microlens needs to be formed on the light emitting device. When the functional layer is an organic layer, a process that involves high temperatures may be avoided in the manufacturing process. Furthermore, when a structure in which the second surface is closer to the functional layer than the first surface is employed, the glass transition points of the organic compounds constituting the organic layer are preferably all 100° C. or higher and more preferably all 130° C. or higher.

### Counter Substrate

A counter substrate may be provided on the planarization layer. The counter substrate is at a position that counters the aforementioned substrate, and hence the name. The materials constituting the counter substrate may be the same as the aforementioned substrate. The counter substrate may be a second substrate provided that the aforementioned substrate is a first substrate.

### Organic Layers

Organic compound layers (hole injection layer, hole transport layer, electron blocking layer, a light emitting layer, a hole blocking layer, electron transport layer, electron injection layer, etc.) constituting the organic light emitting element of this embodiment are formed by the following methods.

The organic compound layers constituting the organic light emitting element according to this embodiment can be formed by a dry process such as a vacuum deposition method, an ionized deposition method, sputtering, or plasma. Instead of the dry process, a wet process can be employed to form layers by a known coating method (for example, spin coating, dip coating, casting, a LB method, or an inkjet method) that involves dissolving the material in an appropriate solvent.

Here, when layers are formed by a vacuum deposition method or a solution coating method, for example, crystallization rarely occurs, and stability over time is improved. When films are formed by a coating method, an appropriate binder resin may be used in combination to form the films.

Examples of the binder resin include, but are not limited to, polyvinyl carbazole resin, polycarbonate resin, polyester resin, ABS resin, acrylic resin, polyimide resin, phenolic resin, epoxy resin, silicone resin, and urea resin.

These binder resins may be used alone as a homopolymer or in combination as a mixture of two or more to form a copolymer. If necessary, additives such as known plasticizers, oxidation inhibitors, and ultraviolet absorbents may be used in combination.

### Pixel Circuit

A light emitting device may include a pixel circuit connected to the light emitting element. The pixel circuit may be of an active matrix type that independently controls light emission of a first light emitting element and a second light emitting element. The active matrix circuit may be voltage-programmed or current-programmed. The drive circuit has a pixel circuit for each pixel. The pixel circuit may include a light emitting element, a transistor that controls the emission luminance of the light emitting element, a transistor that controls the light emission timing, a capacitor that retains the gate voltage of the transistor that controls the emission luminance, and a transistor for establishing the connection to GND without a light emitting element.

The light emitting apparatus has a display region and a peripheral region around the display region. The display region includes pixel circuits, and the peripheral region includes display control circuits. The mobility of the transistor constituting the pixel circuit may be smaller than the mobility of the transistor constituting the display control circuit.

The gradient of the current-voltage characteristic of the transistor constituting the pixel circuit may be smaller than the gradient of the current-voltage characteristic of the transistor constituting the display control circuit. The gradient of the current-voltage characteristic can be measured by what is commonly known as Vg-Ig characteristics.

The transistor constituting the pixel circuit is a transistor connected to a light emitting element, such as a first light emitting element.

### Pixels

The organic light emitting device includes multiple pixels. Each pixel has subpixels that emit light of colors different from one another. The subpixels may emit light of RGB colors, for example.

The pixel has a region also known as a pixel aperture that emits light. This region is the same as the first region.

The pixel aperture may be 15 μm or less or 5 μm or more. More specifically, the pixel aperture may be, for example, 11 μm, 9.5 μm, 7.4 μm, or 6.4 μm.

The distance between subpixels may be 10 μm or less, specifically, 8 μm, 7.4 μm, or 6.4 μm.

The pixels may be arranged into any known pixel matrix in a plan view. Examples thereof include a stripe matrix, a delta matrix, a pentile matrix, and a bayer matrix. The shape of the subpixels in a plan view may be any known shape. Examples thereof include rectangular shapes such as an oblong shape or a rhombus shape, and hexagonal shapes. Naturally, the shape does not have to be exact, and any shape close to an oblong shape is considered an oblong shape. The shape of the subpixels and the pixel arrangement may be used in combination.

Usages of Organic Light Emitting Element According to this Embodiment

The organic light emitting element according to this embodiment can be used as a member that constitutes a display apparatus or a lighting apparatus. Other examples of the usage include an exposure light source of an electrophotographic image forming apparatus, a backlight of a liquid crystal display apparatus, and a light emitting apparatus that has a color filter on a white light source.

The display apparatus may be an image information processing apparatus that includes an image input unit through which image information is input from an area CCD, a linear CCD, a memory card, or the like, and an information processing unit that processes the input information, and that displays the input image on a display unit.

Furthermore, a display unit of an imaging apparatus or an ink jet printer may have a touch panel function. The driving system of the touch panel function may be infrared radiation, electrostatic capacitance, resistance film, electromagnetic induction, or any other system. The display apparatus may be used in a display unit of a multifunctional printer.

Next, a display apparatus according to one embodiment is described with reference to the drawings.

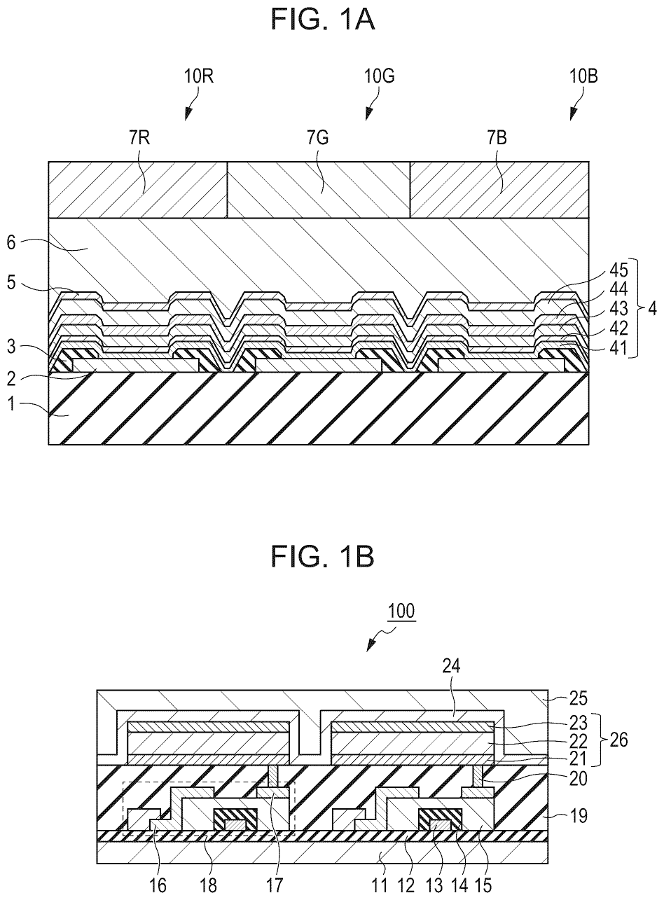

FIGS. 1A and 1B are schematic cross sectional views illustrating examples of a display apparatus that includes organic light emitting elements and transistors connected to the organic light emitting elements. The transistors are one example of the active elements. The transistors may be thin film transistors (TFT).

FIG. 1A illustrates one example of a pixel which is a constitutional feature of the display apparatus of this embodiment. The pixel has subpixels 10. The subpixels are classified as 10R, 10G, and 10B according to their emission color. The emission color may be distinguished by the wavelength of the light emitted from the light emitting layer, or a color filter or the like may be used to selectively transmit or change the color of the light emitted from the subpixels. Each of the subpixels has, on the interlayer insulating layer 1, a reflection electrode 2, which is the first electrode, an insulating layer 3 that covers edges of the reflection electrode 2, an organic compound layer 4 that covers the first electrode and the insulating layer, a transparent electrode 5, a protection layer 6, and color filters 7.

The interlayer insulating layer 1 may have a transistor and a capacitor element below or inside thereof.

The transistor and the first electrode may be electrically connected to each other via a contact hole or the like not illustrated in the drawing.

The insulating layer 3 is also referred to as a bank or a pixel isolation film. The insulating layer 3 covers the edges of the first electrode and surrounds the first electrode. The part where the insulating layer is absent is in contact with the organic compound layer 4 and functions as a light emitting region.

The organic compound layer 4 includes a hole injection layer 41, a hole transport layer 42, a first light emitting layer 43, a second light emitting layer 44, and an electron transport layer 45.

The second electrode 5 may be a transparent electrode, a reflection electrode, or a semi-transmissive electrode.

The protection layer 6 reduces penetration of moisture into the organic compound layer. Although the protection layer is depicted as one layer in the drawing, the protection layer may include multiple layers. An inorganic compound layer and an organic compound layer may be provided for each layer.

The color filters 7 are classified as 7R, 7G, and 7B according to their colors. The color filters may be formed on a planarizing film not illustrated in the drawing. A resin protection layer not illustrated in the drawing may be provided on the color filters. The color filters may be formed on the protection layer 6. Alternatively, the color filters may be formed on a counter substrate such as a glass substrate and then bonded.

A display apparatus 100 illustrated in FIG. 1B includes an organic light emitting element 26 and a TFT 18 as one example of the transistor. Also provided is a substrate 11 such as glass or silicon, and an insulating layer 12 on the substrate 11. An active element 18 such as a TFT is disposed on the insulating layer, and a gate electrode 13, a gate insulating film 14, and a semiconductor layer 15 of the active element are disposed. The TFT 18 also includes a semiconductor layer 15, a drain electrode 16, and a source electrode 17. An insulating film 19 is disposed on the TFT 18. An anode 21 constituting an organic light emitting element 26 and a source electrode 17 are connected to each other through a contact hole 20 formed in the insulating film.

Note that the type of electrical connection between the electrodes (anode and cathode) included in the organic light emitting element 26 and the electrodes (source electrode and drain electrode) included in the TFT is not limited to the one illustrated in FIG. 1B. In other words, the type of electrical connection may be any as long as one of the anode and the cathode is electrically connected to one of the source electrode and the drain electrode of the TFT. TFT stands for a thin film transistor.

In a display apparatus 100 illustrated in FIG. 1B, an organic compound layer is depicted as one layer; however, an organic compound layer 22 may include multiple layers. A first protection layer 24 and a second protection layer 25 are disposed on the cathode 23 to reduce deterioration of the organic light emitting element.

The display apparatus 100 illustrated in FIG. 1B uses a transistor as a switching element, but may use a different switching element instead.

Furthermore, the transistor used in the display apparatus 100 illustrated in FIG. 1B is not limited to a transistor that uses a single-crystal silicon wafer and may be a thin film transistor that has an active layer on an insulating surface of a substrate. Examples of the active layer include single crystal silicon, non-single-crystal silicon such as amorphous silicon or microcrystalline silicon, and non-single-crystal oxide semiconductors such as indium zinc oxide and indium gallium zinc oxide. Note that a thin film transistor is also called a TFT element.

The transistor included in the display apparatus 100 in FIG. 1B may be formed in the substrate such as a Si substrate. Here, the phrase “formed in the substrate” means that the transistor is produced by processing a substrate, such as a Si substrate, itself. In other words, “transistor in the substrate” can also be considered as that the substrate and the transistor are integrated.

The emission luminance of the organic light emitting element of this embodiment is controlled by a TFT, which is one example of a switching element, and, by providing multiple organic light emitting elements in-plane, an image can be displayed by using the emission luminance of each organic light emitting element. The switching element of this embodiment is not limited to a TFT, and may be, for example, a transistor made of a low-temperature polysilicon or an active matrix driver formed on a substrate such as a Si substrate. The phrase “on the substrate” can also mean “in the substrate”. Whether a transistor is formed in the substrate or a TFT is used is selected according to the size of the display unit; for example, when the size is about 0.5 inches, organic light emitting elements may be formed on a Si substrate.

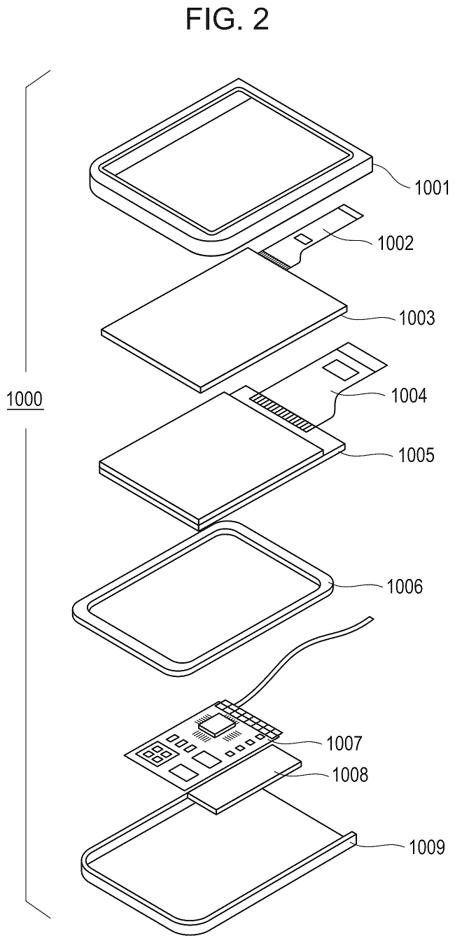

FIG. 2 is a schematic diagram illustrating one example of the display apparatus according to this embodiment. A display apparatus 1000 may include an upper cover 1001 and a lower cover 1009, and a touch panel 1003, a display panel 1005, a frame 1006, a circuit substrate 1007, and a battery 1008 that are interposed between these covers. The touch panel 1003 and the display panel 1005 are respectively connected to flexible print circuits FPC 1002 and 1004. Transistors are printed on the circuit substrate 1007. When the display apparatus is not a portable appliance, the battery 1008 may be omitted, and even when the display apparatus is a portable appliance, the battery 1008 may be provided at a different position.

The display apparatus according to this embodiment may include red, green and blue color filters. The color filters may be arranged so that red, green and blue are arranged in a delta matrix.

The display apparatus according to this embodiment may be used in a display unit of a portable terminal. Such a display apparatus may have both a display function and an operation function. Examples of the portable terminal include mobile phones such as smart phones, tablets, and head-mount displays.

The display apparatus according to this embodiment may be used in a display unit of an imaging apparatus that includes an optical unit having multiple lenses, and an imaging element that receives light that has passed through the optical unit. The imaging apparatus may include a display unit that displays the information acquired by the imaging element. The display unit may be exposed to the outside of the imaging apparatus or may be disposed in a finder. The imaging apparatus may be a digital camera or a digital camcorder.

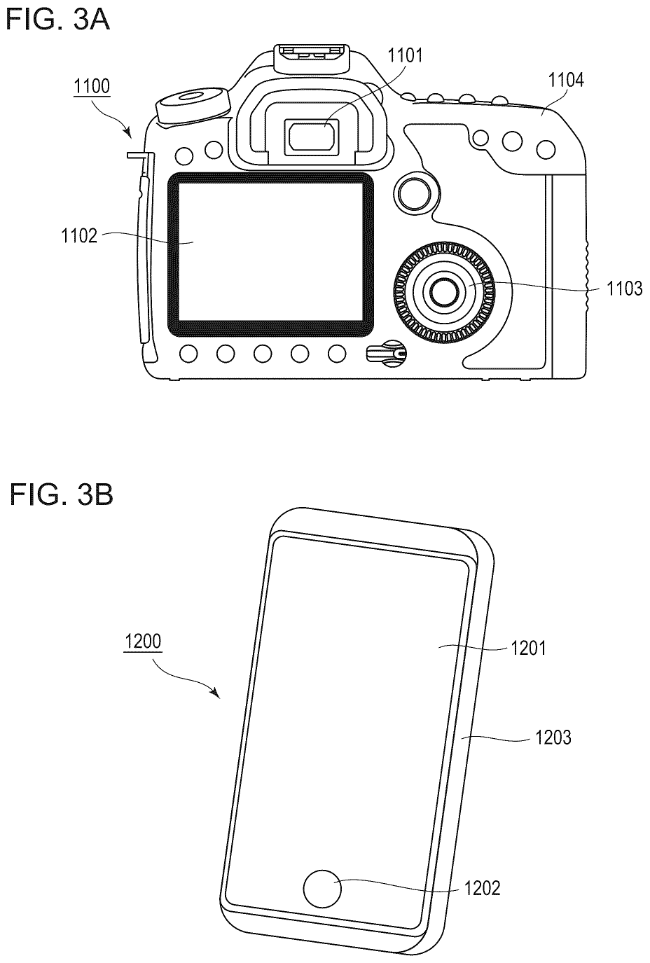

FIG. 3A is a schematic diagram illustrating one example of the imaging apparatus of this embodiment. An imaging apparatus 1100 may include a view finder 1101, a rear display 1102, an operation unit 1103, and a casing 1104. The view finder 1101 may include the display apparatus according to this embodiment. In such a case, the display apparatus may display not only the image to be captured but also the environment information, imaging instructions, etc. The environment information may include the intensity of external light, the direction of the external light, the speed in which a photographic subject moves, and a possibility of the photographic subject becoming shielded by a shielding member.

Since the timing for imaging is very short, the information may be displayed as quickly as possible. Thus, a display apparatus that uses the organic light emitting element of the present disclosure can be used. This is because the organic light emitting element has a high response speed. A display apparatus that uses an organic light emitting element is preferred over a liquid crystal display apparatus for the use in such devices required to achieve speedy display.

The imaging device 1100 includes an optical unit not illustrated in the drawing. The optical unit has multiple lenses, and an image is focused on the imaging element contained in the casing 1104. The multiple lenses can adjust the focal point by adjusting the relative positions thereof. This operation can be automated. The imaging apparatus may also be referred to as a photoelectric conversion apparatus. The photoelectric conversion apparatus can employ an imaging method that involves a method for detecting the difference from a previous image, a method for always cutting out an image from a recorded image, or the like instead of sequential imaging.

FIG. 3B is a schematic diagram illustrating one example of electronic equipment according to this embodiment. Electronic equipment 1200 includes a display unit 1201, an operation unit 1202, and a casing 1203. The casing 1203 may include a circuit, a print substrate having the circuit, a battery, and a communication unit. The operation unit 1202 may be a button or a touch panel-system sensitive unit. The operation unit may be a biometric unit that performs, for example, unlocking through fingerprint recognition. The electronic equipment that includes the communication unit can also be called communication equipment. The electronic equipment may further have a camera function by being equipped with a lens and an imaging element. The image captured through the camera function is displayed on the display unit. Examples of the electronic equipment include smart phones and laptop computers.

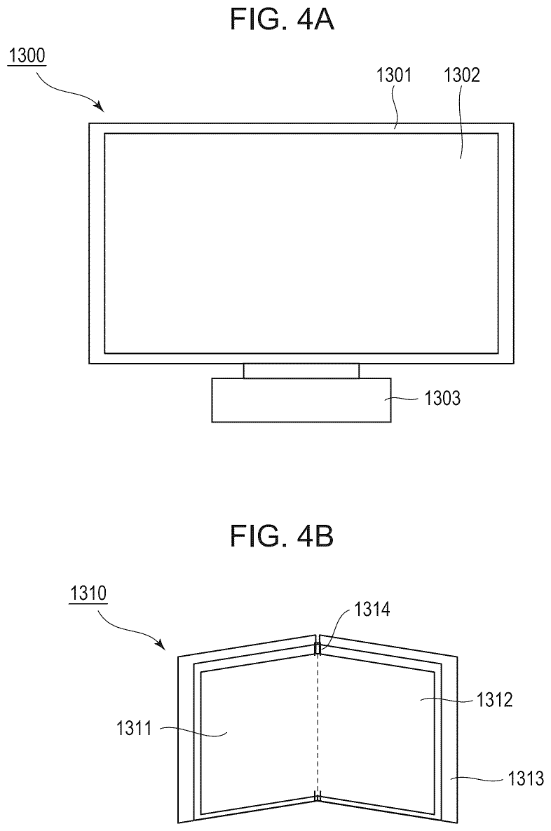

FIGS. 4A and 4B are schematic diagrams illustrating some examples of the display apparatus according to this embodiment. FIG. 4A illustrates a display apparatus such as a television monitor or a PC monitor. A display apparatus 1300 includes a frame 1301 and a display unit 1302. The light emitting apparatus of this embodiment may be used in the display unit 1302.

The display apparatus 1300 further includes a base 1303 that supports the frame 1301 and the display unit 1302. The base 1303 is not limited to the type illustrated in FIG. 4A. The lower edge of the frame 1301 may also serve as the base.

The frame 1301 and the display unit 1302 may be curved. The radius of curvature thereof may be 5000 mm or more and 6000 mm or less.

FIG. 4B is a schematic diagram illustrating another example of the display apparatus according to this embodiment. A display apparatus 1310 illustrated in FIG. 4B is bendable, in other words, is a foldable display apparatus. The display apparatus 1310 includes a first display unit 1311, a second display unit 1312, a casing 1313, and an inflection point 1314. The first display unit 1311 and the second display unit 1312 may each include a light emitting apparatus of this embodiment. The first display unit 1311 and the second display unit 1312 may constitute one seamless display apparatus. The first display unit 1311 and the second display unit 1312 can be separated at the inflection point. The first display unit 1311 and the second display unit 1312 may display different images, or may together display one image.

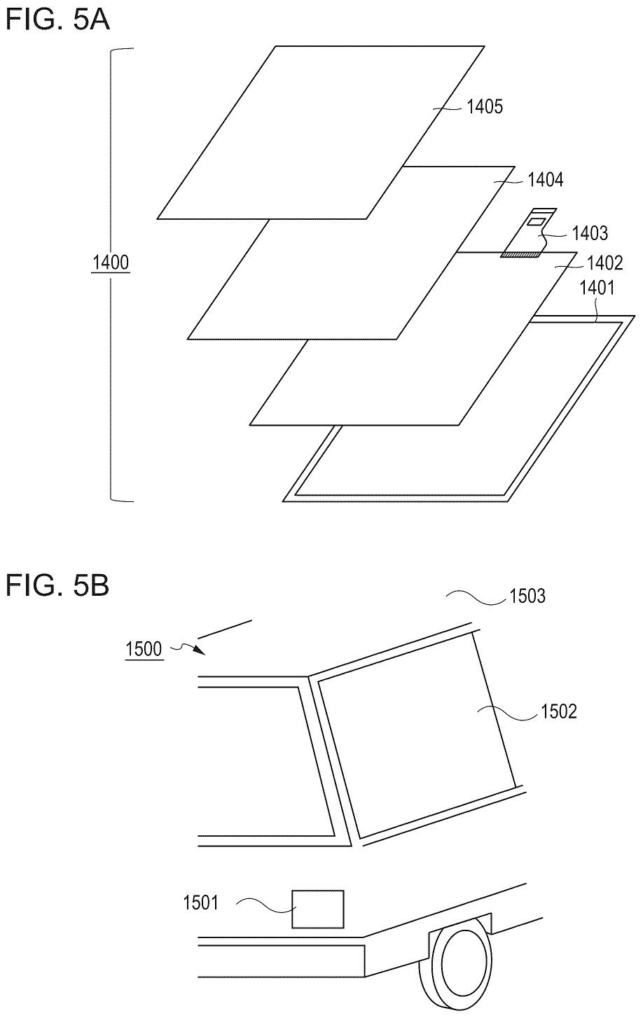

FIG. 5A is a schematic diagram illustrating one example of a lighting apparatus according to this embodiment. A lighting apparatus 1400 includes a casing 1401, a light source 1402, a circuit substrate 1403, an optical filter 1404, and a light diffusing unit 1405. The light source may include an organic light emitting element of this embodiment. The optical filter may be a filter that improves the color rendering properties of the light source. The light diffusing unit can effectively diffuse light from the light source, such as for lighting up, and can deliver the light to a wide range. The optical filter and the light diffusing unit may be disposed on the light emitting side of the lighting. If necessary, a cover may be provided on the outermost side.

The lighting apparatus is, for example, an apparatus that illuminates the room. The lighting apparatus may emit light that is white, neutral white, or any color from blue to red. The lighting apparatus may include a light modulating circuit that modulates these types of light.

The lighting apparatus may include an organic light emitting element of the present disclosure and a power supply circuit connected to the organic light emitting element. The power supply circuit is a circuit that converts AC voltage into DC voltage. White is a color that has a color temperature of 4200 K and the neutral white is a color that has a color temperature of 5000 K. The lighting apparatus may include a color filter.

The lighting apparatus of this embodiment may include a heat releasing unit. The heat releasing unit is a unit that releases the heat inside the apparatus to the outside of the apparatus, and examples thereof include metals having a high specific heat, and liquid silicone.

FIG. 5B is a schematic diagram of an automobile which is one example of a moving body according to this embodiment. The automobile includes a tail lamp, which is one example of a lighting unit. An automobile 1500 may include a tail lamp 1501 and may turn on the tail lamp upon braking operation or the like.

The tail lamp 1501 may include an organic light emitting element of this embodiment. The tail lamp may also include a protection member that protects the organic EL element. The protection member may be composed of any material that has a sufficiently high strength and is transparent, and can be composed of polycarbonate or the like. The polycarbonate may be mixed with a furandicarboxylic acid derivative, an acrylonitrile derivative, or the like.

The automobile 1500 may include a car body 1503 and a window 1502 attached to the car body 1503. The window may be a transparent display if not a window for checking the front and rear sides of the automobile. This transparent display may include an organic light emitting element according to this embodiment. In such a case, the materials constituting the electrodes, etc., of the organic light emitting element are transparent.

The moving body according to this embodiment includes one or both of a driving force generation unit that generates a driving force used mainly in moving the moving body and a rotating body used in moving the moving body. The driving force generation unit may be an engine or a motor, for example. The rotating body may be a tire, a wheel, a ship screw, an air vehicle propeller, etc. Specific examples thereof include bicycles, automobiles, trains, ships, airplanes, and drones. The moving body may include a body and a lighting unit attached to the body. The lighting unit may emit light to indicate the position of the body. The lighting unit includes an organic light emitting element of this embodiment.

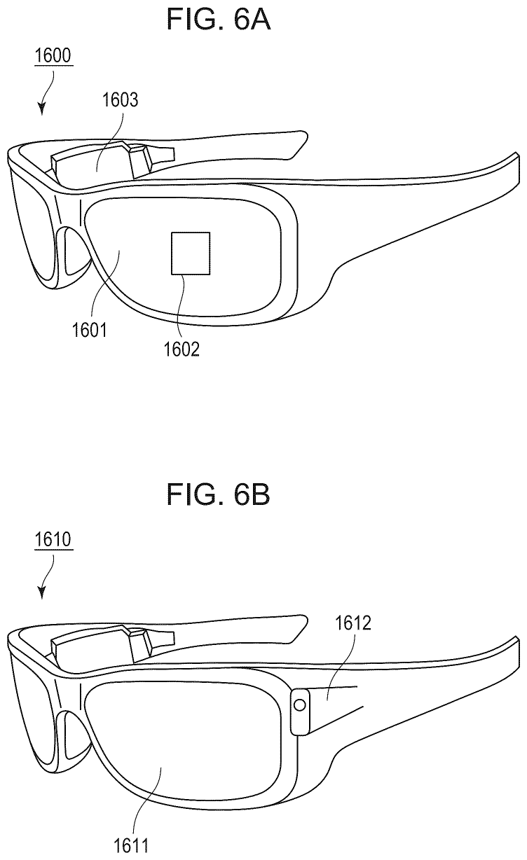

Referring now to FIGS. 6A and 6B, examples of applications of the display apparatuses of the aforementioned embodiments are described. The display apparatus can be applied to wearable device systems such as smart glasses, HMD, and smart contact lenses. An imaging display apparatus used in such application examples includes an imaging apparatus capable of converting visible light into electricity, and a display apparatus capable of emitting visible light.

FIG. 6A illustrates glasses 1600 (smart glasses) according to one application example. An imaging apparatus 1602 such as a CMOS sensor or SPAD is disposed on a front side of a lens 1601 of the glasses 1600. The display apparatus according to any of the embodiments described above is disposed on a rear side of the lens 1601.

The glasses 1600 further include a controller 1603. The controller 1603 functions as a power supply that supplies power to the imaging apparatus 1602 and the display apparatus of the embodiment. The controller 1603 also controls the operation of the imaging apparatus 1602 and the display apparatus. An optical system for focusing light onto the imaging apparatus 1602 is formed in the lens 1601.

FIG. 6B illustrates glasses 1610 (smart glasses) according to one application example. The glasses 1610 include a controller 1612. An imaging apparatus corresponding to the imaging apparatus 1602 and the display apparatus are mounted on the controller 1612. In a lens 1611, an optical system for projecting light emitted from the display apparatus in the controller 1612 is formed, and images are projected onto the lens 1611. The controller 1612 functions as a power supply that supplies power to the imaging apparatus and the display apparatus, and also controls the operation of the imaging apparatus and the display apparatus. The controller may include a line-of-sight detecting unit that detects the line of sight of a wearer. The line of sight may be detected by using infrared radiation.

The infrared radiation emitting unit emits infrared radiation toward an eyeball of a user gazing the displayed image. A captured image of the eyeball is obtained when the imaging unit having a light receiving element detects reflection of the emitted infrared radiation from the eyeball. The degradation of the image quality is decreased by providing a unit for reducing light from the infrared radiation emitting unit to the display unit in a plan view.

The line of sight of the user with respect to the displayed image is detected from the captured image of the eyeball obtained by infrared imaging. Any known technique can be applied to the line-of-sight detection using the captured image of the eyeball. For example, a line-of-sight detection method based on a Purkinje image formed by reflection of the irradiated light at the cornea can be employed.

More specifically, a line-of-sight detection process based on the pupil-corneal reflection method is performed. The line of sight of the user is detected by calculating the eye vector that indicates the direction (rotation angle) of the eyeball on the basis of the image of the pupil and the Purkinje image included in the captured image of the eyeball by using the pupil-corneal reflection method.

The display apparatus according to this embodiment may include an imaging apparatus that includes a light receiving element, and may control the image displayed on the display apparatus on the basis of the use's line-of-sight information from the imaging apparatus.

Specifically, in the display apparatus, a first display region that the user gazes and a second display region other than the first display region are determined on the basis of the line-of-sight information. The first display region and the second display region may be determined by the controller in the display apparatus, or may be determined by an external controller and received. In the display region of the display apparatus, the display resolution of the first display region may be controlled to be higher than the display resolution of the second display region. In other words, the resolution of the second display region may be lower than that of the first display region.

Alternatively, the display region has a first display region and a second display region different from the first display region, and a region having a higher priority is determined from the first display region and the second display region on the basis of the line-of-sight information. The first display region and the second display region may be determined by the controller in the display apparatus, or may be determined by an external controller and received. The resolution of the region with higher priority may be controlled to be higher than the resolution of the region other than the region with higher priority. In other words, the resolution of a region having relatively low priority may be decreased.

Note that an AI may be used to determine the first display region or the region with high priority. The AI may be a model configurated to estimate the angle of the line of sight and the distance to the object at the end of the line of sight from the image of the eyeball by using, as teaching data, the image of the eyeball and the direction in which the eyeball in the image was actually gazing. The AI program may be included in the display apparatus, the imaging apparatus, or an external apparatus. When an external apparatus includes the AI program, the data is transmitted to the display apparatus via communication.

When the display is controlled on the basis of the visual recognition, smart glasses that further include an imaging apparatus that captures the images of the outside can be implemented. The smart glasses can display the captured outside information in real time.

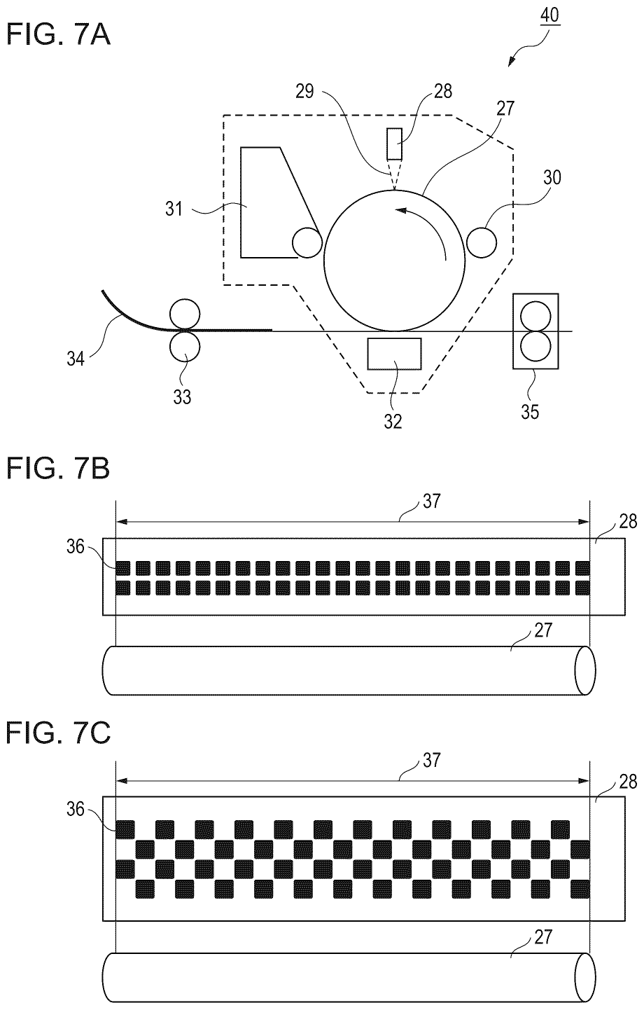

FIG. 7A illustrates an image forming apparatus according to this embodiment. FIG. 7A is a schematic diagram of an image forming apparatus 36 apparatus according to this embodiment. The image forming apparatus includes a photosensitive body, an exposure light source, a developing unit, a charging unit, a transferring device, a conveying roller, and a fixing device.

Light 29 is emitted from an exposure light source 28, and an electrostatic latent image is formed on a surface of a photosensitive body 27. The exposure light source includes the organic light emitting element of the present disclosure. A developing unit 31 includes a toner etc. A charging unit 30 charges the photosensitive body. A transferring device 32 transfers a developed image onto a recording medium 34. A conveying unit 33 conveys the recording medium 34. The recording medium 34 is, for example, a sheet of paper. A fixing device 35 fixes the image formed on the recording medium.

FIGS. 7B and 7C are schematic diagrams illustrating the exposure light source 28 in which multiple light emitting units 38 are arranged on a long substrate. Reference sign 37 indicates a direction parallel to the axis of the photosensitive body and a direction in which rows of the organic light emitting elements extend. This row direction is coincident with the axis of rotation of the photosensitive body 27. This direction can also be referred to as the longitudinal axis direction of the photosensitive body.

FIG. 7B is an arrangement in which the light emitting units are arranged along the longitudinal axis direction of the photosensitive body. FIG. 7C illustrates an arrangement different from the one illustrated in FIG. 7B, in which the light emitting units in the first row and the second row are staggered. The first row and the second row are at different positions in the column direction.

The first row includes multiple light emitting units with spaces therebetween. The second row includes light emitting units at positions corresponding to the spaces between the light emitting units in the first row. In other words, multiple light emitting units are arranged with spaces therebetween in the column direction also.

The arrangement illustrated in FIG. 7C can also be referred to as, for example, a grid arrangement state, a houndstooth pattern, or a checkered pattern.

As described above, by using apparatuses that use the organic light emitting elements of this embodiment, a display with excellent image quality and stable for a long period of time can be achieved.

### EXAMPLES

The examples described below do not limit the content of the present disclosure.

### Example 1

In this example, a top emission-type multilayer organic light emitting element in which an anode serving as a first electrode, a first light emitting unit, a charge generation layer, a second light emitting unit, and a cathode serving as a second electrode were sequentially formed on a substrate was prepared. A blue light emitting layer was provided in the first light emitting unit, a yellow light emitting layer was provided in the second light emitting unit, and a two-surface-emission-type organic light emitting element was prepared.

First, an ITO film was formed on a glass substrate, and subjected to desired patterning to form an ITO electrode (anode). Here, the film thickness of the ITO electrode was 100 nm. As such, a substrate on which the ITO electrode was formed was used as the ITO substrate. Next, a first light emitting unit, a charge generation layer, a second light emitting unit, and a cathode indicated in Table 3 below were sequentially deposited on the ITO substrate by vacuum vapor deposition under resistive heating in a vacuum chamber. Here, the electrode area of the opposing electrodes (anode and cathode) was set to 3 mm². After forming films up to the cathode, the substrate was moved to a glove box and sealed with a desiccant-containing glass cap in a nitrogen atmosphere to obtain a multilayer organic light emitting element.

TABLE 3

| | | | | Film |
|---|---|---|---|---|
| | | | | thick/ |
| | | | Material and | ness |
| | | | composition | nm |
| Cathode | | | Mg:Ag = | 10 |
| | | | 50:50 (mass | |
| | | | ratio) | |
| Second | Second electron injection layer | | LIF | 1 |
| light | Second electron transport | | ET1 | 20 |
| emitting | layer | | | |
| unit | Second hole blocking layer | | ET20 | 26 |
| | First light | Second light | Z-16:EM30:GD11 | 16 |
| | emitting layer | emitting portion | = | |
| | | | 51:40:9 | |
| | | | (mass ratio) | |
| | | First light | Z-16:GD11:RD6 | 4 |
| | | emitting | = | |
| | | portion | 78:20:2 (mass | |
| | | | ratio) | |

| | | | |
|---|---|---|---|
| | Second electron blocking layer | HT7 | 10 |
| Charge | p-Type charge generation | HT16 | 8 |
| generation | layer | | |
| layer | n-Type charge generation | ET1:Li = | 10 |
| | layer | 99:1 (parts by | |
| | | mass) | |
| First light | First electron transport layer | ET1 | 20 |
| emitting | First hole blocking layer | ET20 | 33 |
| unit | Second light emitting layer | Z-1:BD1 = | 20 |
| | | 98:2 (parts by | |
| | | mass) | |
| | First electron blocking layer | HT7 | 10 |
| | First hole transport layer | HT2 | 25 |
| | First hole injection layer | HT16 | 7 |

| | | |
|---|---|---|
| Anode | ITO | 100 |

### Examples 2 to 9 and Comparative Examples 1 to 4

In Examples 2 to 9 and Comparative Examples 1 to 4, organic light emitting elements were prepared as in Example 1 except that the compounds were changed as indicated in Table 4.

For each of the obtained organic light emitting elements, the voltage-current characteristic was measured with a pico ammeter 4140B produced by Hewlett-Packard Company, and an emission spectrum was obtained by using SR-3 produced by TOPCON CORPORATION. The organic light emitting elements of Examples 1 to 9 exhibited excellent white light emission. In addition, under a constant current condition of 100 mA/cm², a drive test of the organic light emitting element was performed to evaluate the light emission efficiency and drive voltage. The results are indicated in Table 4.

The voltage ratio is an improvement rate with respect to the drive voltage of Comparative Example 1 assumed to be 1.0. The efficiency ratio is a value relative to the light emission efficiency of Comparative Example 1, 1.0.

In the table, ΔHOMO(1), ΔLUMO(1), and ΔLUMO(2) are as follows.

$$\begin{matrix}Δ HOMO ( 1 ) = HOMO ( D ) - HOMO ( C ) \\ Δ LUMO ( 1 ) = LUMO ( E ) - LUMO ( D ) \\ Δ LUMO ( 2 ) = LUMO ( A ) - LUMO ( B )\end{matrix}$$

TABLE 4

| | First light emitting unit | | | | | | | | Second light emitting anit | | | | | Light | |
|---|---|---|---|---|---|---|---|---|---|---|---|---|---|---|---|
| | Third | | Fourth | | Fifth | | | | First | | Second | | | emitting | |
| | compound | | compound | | compound | | | | compound | | compound | | | effi- | Volt- |
| | | LUMO/eV | | LUMO/eV | | LUMO/eV | ΔHOMO | ΔLUMO | | LUMO/eV | | LUMO/eV | ΔLUMO | ciency | age |
| | No. | HOMO/eV | No. | HOMO/EV | No. | HOMO/ev | (1) | (1) | No. | HOMO/eV | No. | HOMO/ev | (2) | ratio | ratio |
| Example 1 | HT7 | −27 | Z-1 | −3.0 | ET20 | −2.9 | −0.3 | 0.1 | Z-16 | −2.7 | GD11 | −3.1 | 0.4 | 1.2 | 1.3 |
| | | −5.7 | | −6.0 | | −5.9 | | | | −6.7 | | −5.4 | | | |
| Example 2 | HT7 | −2.7 | Z-1 | −3.0 | ET20 | −2.9 | −0.3 | 0.1 | Z-16 | −2.7 | GD12 | −3.1 | 0.4 | 1.2 | 1.3 |
| | | −5.7 | | −6.0 | | −5.9 | | | | −6.2 | | −5.5 | | | |
| Example 3 | HT7 | −2.7 | Z-1 | −3.0 | ET20 | −2.9 | −0.3 | 0.1 | EM14 | −2.8 | GD11 | −3.1 | 0.3 | 1.2 | 1.2 |
| | | −5.7 | | −6.0 | | −5.9 | | | | −6.3 | | −5.4 | | | |
| Example 4 | HT7 | −2.7 | Z-1 | −3.0 | ET20 | −2.9 | −0.3 | 0.1 | Z-11 | −2.9 | GD11 | −3.1 | 0.2 | 1.2 | 1.2 |
| | | −5.7 | | −6.0 | | −5.9 | | | | −6.1 | | −5.4 | | | |
| Example 5 | HT7 | −2.7 | Z-1 | −3.0 | ET20 | −2.9 | −0.3 | 0.1 | EM30 | −2.9 | GD11 | −3.1 | 0.2 | 1.2 | 1.2 |
| | | −5.7 | | −6.0 | | −5.9 | | | | −6.6 | | −5.4 | | | |
| Example 6 | HT7 | −2.7 | Z-1 | −3.0 | ET20 | −2.9 | −0.3 | 0.1 | EM8 | −2.9 | GD13 | −3.1 | 0.2 | 1.1 | 1.1 |
| | | −5.7 | | −6.0 | | −5.9 | | | | −6.0 | | −5.4 | | | |
| Example 7 | HT7 | −2.7 | Z-1 | −3.0 | ET20 | −2.9 | −0.3 | 0.1 | EM32 | −3.0 | GD11 | −3.1 | 0.1 | 1.1 | 1.1 |
| | | −5.7 | | −6.0 | | −5.9 | | | | −6.1 | | −5.4 | | | |
| Example 8 | HT7 | −2.7 | Z-1 | −3.0 | ET20 | −2.9 | −0.3 | 0.1 | EM34 | −2.8 | GD11 | −3.1 | 0.3 | 1.1 | 1.1 |
| | | −5.7 | | −6.0 | | −5.9 | | | | −6.1 | | −5.4 | | | |
| Example 9 | HT7 | −2.7 | Z-12 | −2.6 | ET20 | −2.9 | 0.2 | −0.3 | EM9 | −2.8 | GD11 | −3.1 | 0.3 | 1.1 | 1.1 |
| | | −5.7 | | −5.5 | | −5.9 | | | | −6.1 | | −5.4 | | | |
| Comparative | HT7 | −2.7 | Z-12 | −2.6 | ET20 | −2.9 | 0.2 | −0.3 | EM28 | −3.1 | GD7 | −3.1 | 0.0 | 1.0 | 1.0 |
| Example 1 | | −5.7 | | −5.5 | | −5.9 | | | | −6.2 | | −5.4 | | | |
| Comparative | HT7 | −2.7 | Z-12 | −2.6 | ET20 | −2.9 | 0.2 | −0.3 | EM30 | −3.4 | GD7 | −3.1 | −0.3 | 1.0 | 1.0 |
| Example 2 | | −5.7 | | −5.5 | | −5.9 | | | | −6.6 | | −5.4 | | | |
| Comparative | HT7 | −2.7 | Z-12 | −2.6 | ET20 | −2.9 | 0.2 | −0.3 | EM31 | −3.3 | GD7 | −3.1 | −0.2 | 1.0 | 0.9 |
| Example 3 | | −5.7 | | −5.5 | | −5.9 | | | | −6.5 | | −5.4 | | | |
| Comparative | HT7 | −2.7 | Z-1 | −3.0 | ET20 | −2.9 | −0.3 | 0.1 | EM28 | −3.1 | GD7 | −3.1 | 0.0 | 0.9 | 0.9 |
| Example 4 | | −5.7 | | −6.0 | | −5.9 | | | | −6.2 | | −5.4 | | | |

Table 4 indicates that, compared to Comparative Examples 1 to 4, the drive voltage of the organic light emitting elements of Examples 1 to 9 exhibited high improvement rates. In other words, it was found that the organic light emitting elements of Examples 1 to 9 exhibited low drive voltage. Since the first light emitting layers in the second light emitting units of the organic light emitting elements of Examples 1 to 9 had excellent electron trapping properties, low drive voltage was exhibited.

Furthermore, the organic light emitting elements that satisfied ΔHOMO(1)≥0 eV exhibited lower drive voltage and thus higher light emission efficiency. In other words, since the hole injectability of the second light emitting layer in the first light emitting unit was high, an organic light emitting element that exhibited lower drive voltage and higher light emission efficiency could be obtained. This was because the holes generated from the anode could be more efficiently injected into the second light emitting layer.

Furthermore, the organic light emitting elements that satisfied ΔLUMO(1)≥0 eV exhibited lower drive voltage and thus higher light emission efficiency. In other words, since the electron injectability of the second light emitting layer in the first light emitting unit was high, an organic light emitting element that exhibited lower drive voltage and higher light emission efficiency could be obtained. This was because the electrons generated from the charge generation layer could be more efficiently injected into the second light emitting layer.

In these examples, the first compound is the host material contained in the first light emitting layer, the second compound is the guest material contained in the first light emitting layer, the third compound is the first electron blocking layer, the fourth compound was the host material of the second light emitting layer, and the fifth compound was the first hole blocking layer.

As described above, the organic light emitting element according to the present disclosure exhibits low drive voltage. Moreover, the organic light emitting elements according to this embodiment exhibit higher light emission efficiency. Furthermore, the organic light emitting elements according to this embodiment exhibits better durability.

According to the present disclosure, an organic light emitting element that exhibits lower drive voltage can be provided.

While the present disclosure has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2024-033850, filed Mar. 6, 2024, which is hereby incorporated by reference herein in its entirety.

What is claimed is:

1. An organic light emitting element comprising:
a first electrode;
a first light emitting unit;
a charge generation layer;
a second light emitting unit; and
a second electrode
that are arranged in this order,
wherein the second light emitting unit includes a first light emitting layer,
the first light emitting unit includes a first organic layer, a second light emitting layer, and a second organic layer arranged in this order of proximity to the first electrode,
the first light emitting layer contains a first compound and a second compound,
the first organic layer contains a third compound, the second light emitting layer contains a fourth compound, and the second organic layer contains a fifth compound, and
the first compound, the second compound, the third compound, the fourth compound, and the fifth compound satisfy relationships (a) and (c):
$$LUMO ( A ) > LUMO ( B ) \qquad ( a )$$
$$HOMO ( D ) - HOMO ( C ) \geq 0 eV \qquad ( c )$$
where LUMO(A) and LUMO(B) respectively represent a lowest unoccupied molecular orbital (LUMO) energy level of the first compound and a LUMO energy level of the second compound, and
HOMO(C) and HOMO(D) respectively represent a highest occupied molecular orbital (HOMO) energy level of the third compound and a HOMO energy level of the fourth compound.

2. The organic light emitting element according to claim 1, wherein the third compound, the fourth compound, and the fifth compound satisfy relationship (c1):
$$HOMO ( D ) - HOMO ( C ) > LUMO ( E ) - LUMO ( D ) \qquad ( c1 )$$
where LUMO(D) and LUMO(E) respectively represent a LUMO energy level of the fourth compound and a LUMO energy level of the fifth compound.

3. The organic light emitting element according to claim 1, wherein the first organic layer and the second light emitting layer are in contact with each other, and the second light emitting layer and the second organic layer are in contact with each other.

4. The organic light emitting element according to claim 1, wherein the first compound and the second compound satisfy relationship (f):
$$LUMO ( A ) - LUMO ( B ) \geq 0.15 eV \qquad ( f )$$

5. The organic light emitting element according to claim 1, wherein the first compound is a compound that has a fused polycyclic hydrocarbon skeleton that optionally has a substituent or a heterocyclic skeleton that optionally has a substituent.

6. The organic light emitting element according to claim 5, wherein the fused polycyclic hydrocarbon skeleton that optionally has a substituent has 10 or more and 25 or less carbon atoms.

7. The organic light emitting element according to claim 5, wherein the fused polycyclic hydrocarbon skeleton that optionally has a substituent is selected from the group consisting of a naphthalene skeleton, a fluorene skeleton, an anthracene skeleton, a phenanthrene skeleton, a pyrene skeleton, a chrysene skeleton, a triphenylene skeleton, a tetracene skeleton, a fluoranthene skeleton, and a perylene skeleton.

8. The organic light emitting element according to claim 5, wherein the heterocyclic skeleton that optionally has a substituent has 3 or more and 30 or less carbon atoms.

9. The organic light emitting element according to claim 5, wherein the heterocyclic skeleton that optionally has a substituent is selected from the group consisting of a dibenzofuran skeleton, a dibenzothiophene skeleton, a xanthone skeleton, a thioxanthone skeleton, a carbazole skeleton, an indolocarbazole skeleton, and a triazine skeleton.

10. The organic light emitting element according to claim 1, wherein the first compound has a freely rotatable bond, and the freely rotatable bond is a carbon-carbon bond.

11. The organic light emitting element according to claim 1,
wherein the first light emitting layer includes a first light emitting portion and a second light emitting portion arranged in this order, and
the second light emitting portion contains the first compound and the second compound.

12. The organic light emitting element according to claim 11, wherein the first light emitting portion contains the first compound.

13. The organic light emitting element according to claim 1, wherein the first light emitting layer contains a first light emitting material, and the second light emitting layer contains a third light emitting material, and
the first light emitting material is a phosphorescence emitting material, and the third light emitting material is a fluorescence emitting material.

14. The organic light emitting element according to claim 11, wherein the first light emitting portion contains a first light emitting material, the second light emitting portion contains a second light emitting material, and the second light emitting layer contains a third light emitting material, and
the first light emitting material and the second light emitting material are phosphorescence emitting materials, and the third light emitting material is a fluorescence emitting material.

15. A display apparatus comprising:
a plurality of pixels,
wherein at least one pixel of the plurality of pixels includes the organic light emitting element according to claim 1 and a transistor connected to the organic light emitting element.

16. A display apparatus comprising:
a display unit that includes the organic light emitting element according to claim 1; and
a casing in which the display unit is installed.

17. A photoelectric conversion apparatus comprising:
an imaging element that receives light; and
a display unit that displays an image taken by the imaging element,
wherein the display unit includes the organic light emitting element according to claim 1.

18. Electronic equipment comprising:
a display unit that includes the organic light emitting element according to claim 1;
a casing in which the display unit is installed; and
a communication unit installed in the casing and used to communicate outside of the electronic equipment.

19. A wearable device comprising:
a display unit that includes the organic light emitting element according to claim 1;
an optical system that focuses light of the display unit; and
a controller that controls display of the display unit.

20. A lighting apparatus comprising:
a light source that includes the organic light emitting element according to claim 1; and
a casing in which the light source is installed.

21. A moving body comprising:
a lighting unit that includes the organic light emitting element according to claim 1; and
a body that accommodates the lighting unit.

22. An image forming apparatus comprising:
a photosensitive body; and
an exposure light source that exposes the photosensitive body to light,
wherein the exposure light source includes the organic light emitting element according to claim 1.

23. An organic light emitting element comprising:
a first electrode;
a first light emitting unit;
a charge generation layer;
a second light emitting unit; and
a second electrode
that are arranged in this order,
wherein the second light emitting unit includes a first light emitting layer,
the first light emitting unit includes a first organic layer, a second light emitting layer, and a second organic layer arranged in this order of proximity to the first electrode,
the first light emitting layer contains a first compound and a second compound,
the first organic layer contains a third compound, the second light emitting layer contains a fourth compound, and the second organic layer contains a fifth compound, and
the first compound, the second compound, the third compound, the fourth compound, and the fifth compound satisfy relationships (a) and (b):
$$LUMO ( A ) > LUMO ( B ) \qquad ( a )$$
$$LUMO ( E ) - LUMO ( D ) \geq 0 eV \qquad ( b )$$
where LUMO(A), LUMO(B), LUMO(D), and LUMO(E) respectively represent a LUMO energy level of the first compound, a lowest unoccupied molecular orbital (LUMO) energy level of the second compound, a LUMO energy level of the fourth compound, and a LUMO energy level of the fifth compound.

24. The organic light emitting element according to claim 23, wherein the third compound, the fourth compound, and the fifth compound satisfy relationship (b1):
$$LUMO ( E ) - LUMO ( D ) > HOMO ( D ) - HOMO ( C ) \qquad ( b1 )$$
where HOMO(C) and HOMO(D) respectively represent a highest occupied molecular orbital (HOMO) energy level of the third compound and a HOMO energy level of the fourth compound.

25. The organic light emitting element according to claim 23, wherein the first organic layer and the second light emitting layer are in contact with each other, and the second light emitting layer and the second organic layer are in contact with each other.

26. The organic light emitting element according to claim 23, wherein the first compound and the second compound satisfy relationship (f):
$$LUMO ( A ) - LUMO ( B ) \geq 0.15 eV \qquad ( f )$$

27. The organic light emitting element according to claim 23, wherein the first compound is a compound that has a fused polycyclic hydrocarbon skeleton that optionally has a substituent or a heterocyclic skeleton that optionally has a substituent.

28. The organic light emitting element according to claim 27, wherein the fused polycyclic hydrocarbon skeleton that optionally has a substituent is selected from the group consisting of a naphthalene skeleton, a fluorene skeleton, an anthracene skeleton, a phenanthrene skeleton, a pyrene skeleton, a chrysene skeleton, a triphenylene skeleton, a tetracene skeleton, a fluoranthene skeleton, and a perylene skeleton.

29. The organic light emitting element according to claim 27, wherein the heterocyclic skeleton that optionally has a substituent is selected from the group consisting of a dibenzofuran skeleton, a dibenzothiophene skeleton, a xanthone skeleton, a thioxanthone skeleton, a carbazole skeleton, an indolocarbazole skeleton, and a triazine skeleton.

30. The organic light emitting element according to claim 23, wherein the first compound has a freely rotatable bond, and the freely rotatable bond is a carbon-carbon bond.

31. The organic light emitting element according to claim 23,
wherein the first light emitting layer includes a first light emitting portion and a second light emitting portion arranged in this order, and
the second light emitting portion contains the first compound and the second compound.

32. The organic light emitting element according to claim 31, wherein the first light emitting portion contains the first compound.

33. The organic light emitting element according to claim 23, wherein the first light emitting layer contains a first light emitting material, and the second light emitting layer contains a third light emitting material, and
the first light emitting material is a phosphorescence emitting material, and the third light emitting material is a fluorescence emitting material.

34. The organic light emitting element according to claim 31, wherein the first light emitting portion contains a first light emitting material, the second light emitting portion contains a second light emitting material, and the second light emitting layer contains a third light emitting material, and
the first light emitting material and the second light emitting material are phosphorescence emitting materials, and the third light emitting material is a fluorescence emitting material.
